(19) United States
(12) Patent Application Publication
(10) Pub. No.: US 2024/0138263 A1
(43) Pub. Date: Apr. 25, 2024

(54) LIGHT EMITTING ELEMENT AND POLYCYCLIC COMPOUND FOR THE SAME

(71) Applicant: Samsung Display Co., LTD., Yongin-si (KR)

(72) Inventors: Makoto YAMAMOTO, Yokohama (JP); Keigo HOSHI, Yokohama (JP); Yuji SUZAKI, Yokohama (JP); Hirokazu KUWABARA, Yokohama (JP); Nobutaka AKASHI, Yokohama (JP); Ryuhei FURUE, Yokohama (JP); Toshiyuki MATSUURA, Yokohama (JP); Yoshiro SUGITA, Yokohama (JP); Yuma AOKI, Yokohama (JP); Yuuki MIYAZAKI, Yokohama (JP)

(21) Appl. No.: 18/469,108

(22) Filed: Sep. 18, 2023

(30) Foreign Application Priority Data
Sep. 19, 2022 (KR) 10-2022-0118096
Sep. 15, 2023 (KR) 10-2023-0123183

(51) Int. Cl. H10K 85/60; C09K 11/06

(52) U.S. Cl. CPC H10K 85/658; C09K 11/06; H10K 85/631; H10K 85/6572; H10K 85/6574; H10K 85/6576; H10K 2101/20

(57) ABSTRACT

A light emitting element of one or more embodiments includes a first electrode, a second electrode oppositely to the first electrode, and an emission layer between the first electrode and the second electrode. The light emitting element of one or more embodiments includes a polycyclic compound represented by a specific chemical structure in the emission layer, thereby showing improved emission efficiency and life characteristics.

### CROSS-REFERENCE TO RELATED APPLICATIONS

This application claims priority to and the benefit of Korean Patent Application Nos. 10-2022-0118096, filed on Sep. 19, 2022, and 10-2023-0123183, filed on Sep. 15, 2023, the entire contents of which are hereby incorporated by reference.

### BACKGROUND

### 1. Field

Embodiments of the present disclosure herein relate to a light emitting element and a polycyclic compound for the light emitting element, and, for example, to a light emitting element including a polycyclic compound in an emission layer.

### 2. Related Art

Recently, the development of an organic electroluminescence display device as an image display device is being actively conducted. The organic electroluminescence display device is a so-called display device of a self-luminescent type (or kind) in which holes and electrons injected from a first electrode and a second electrode recombine in an emission layer so that a light emitting material in the emission layer emits light to achieve a display.

In the application of a light emitting element to a display device, the increase of emission efficiency and the lifetime is desired or required, and development of materials for a light emitting element, stably achieving the required or desired characteristics is being consistently investigated.

### SUMMARY

Embodiments of the present disclosure provide a light emitting element showing improved emission efficiency and element lifetime.

In addition, embodiments of the present disclosure also provide a polycyclic compound which is used as a material for a light emitting element having excellent emission efficiency and element lifetime.

One or more embodiments of the present disclosure provide a light emitting element including a first electrode, a second electrode on the first electrode, and an emission layer between the first electrode and the second electrode, wherein the emission layer includes a first compound represented Formula 1.

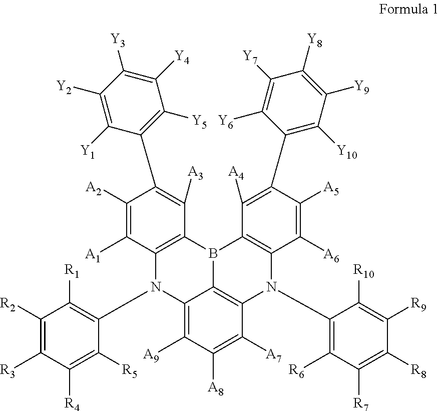

In Formula 1, A₁ to A₉ may each independently be a hydrogen atom, a deuterium atom, a halogen atom, a cyano group, a nitro group, a substituted or unsubstituted boron group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, where a case where at least one selected from among A₂ and A₅ is an unsubstituted carbazole group may be excluded. In Formula 1, Y₁ to Y₁₀ may be each independently a hydrogen atom, a deuterium atom, a halogen atom, a substituted or unsubstituted boron group, a substituted or unsubstituted amine group, a substituted or unsubstituted alkyl group of 1 to 20 carbon atoms, or a substituted or unsubstituted aryl group of 6 to 30 ring-forming carbon atoms, where a case where at least one selected from among Y₁, Y₅, Y₆ and Y₁₀ is a substituted or unsubstituted alkyl group of 1 to 20 carbon atoms may be excluded. In Formula 1, R₁ to R₁₀ may be each independently a hydrogen atom, a deuterium atom or represented by Formula 2, or combined with an adjacent group to form a ring, where at least three among R₁ to R₅, or at least three among R₆ to R₁₀ may be each independently represented by Formula 2. In this case, a case where R₁ and R₅ are all hydrogen atoms, and R₂ to R₄ are all unsubstituted phenyl groups, and a case where R₆ and R₁₀ are all hydrogen atoms, and R₇ to R₉ are all unsubstituted phenyl groups may be excluded.

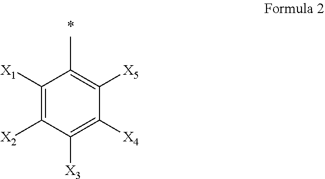

In Formula 2, X₁ to X₅ are each independently a hydrogen atom, a deuterium atom, a halogen atom, a substituted or unsubstituted boron group, a substituted or unsubstituted amine group, a substituted or unsubstituted oxygroup, a substituted or unsubstituted thio group, a substituted or unsubstituted alkyl group of 1 to 20 carbon atoms, or a substituted or unsubstituted aryl group of 6 to 30 ring-forming carbon atoms, or combined with an adjacent group to form a ring.

In one or more embodiments, the first compound represented by Formula 1 may be represented by Formula 3.

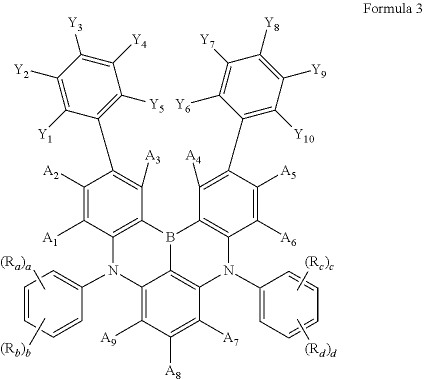

In Formula 3, Rₐ and R_{c} are each independently represented by Formula 2, R_{b} and R_{d} are each independently a hydrogen atom or a deuterium atom, “a” and “c” are each independently an integer of 3 to 5, “b” and “d” are each independently an integer of 0 to 2, and A₁ to A₉, and Y₁ to Y₁₀ are the same as defined with respect to Formula 1.

In one or more embodiments, the first compound represented by Formula 1 may be represented by Formula 4.

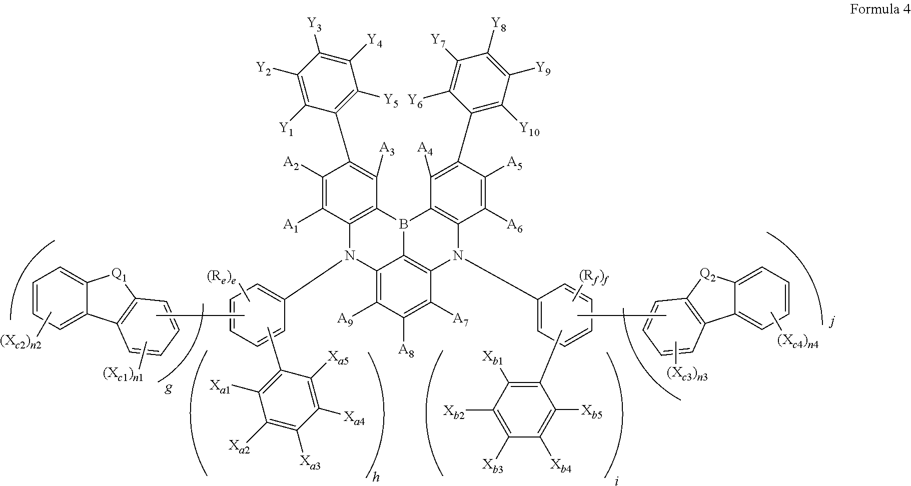

In Formula 4, Q₁ and Q₂ are each independently O, S or NR_{q}, R_{q} is a substituted or unsubstituted aryl group of 3 to 10 ring-forming carbon atoms, Rₑ and R_{f} are each independently a hydrogen atom or a deuterium atom. In Formula 4, Xₐ₁ to Xₐ₅, X_{b1} to X_{b5}, and X_{c1} to X_{c4} are each independently a hydrogen atom, a deuterium atom, a substituted or unsubstituted alkyl group of 1 to 20 carbon atoms, or a substituted or unsubstituted aryl group of 6 to 30 ring-forming carbon atoms. In Formula 4, “e” and “f” are each independently an integer of 0 to 2, “g” and “j” are each independently an integer of 0 or 1, “h” and “i” are each independently an integer of 2 to 5, n1 and n3 are each independently an integer of 0 to 3, and n2 and n4 are each independently an integer of 0 to 4. In one or more embodiments, in Formula 4, A₁ to A₉, and Y₁ to Y₁₀ are the same as defined with respect to Formula 1.

In one or more embodiments, the first compound represented by Formula 1 may be represented by any one selected from among Formula 5-1 to Formula 5-3.

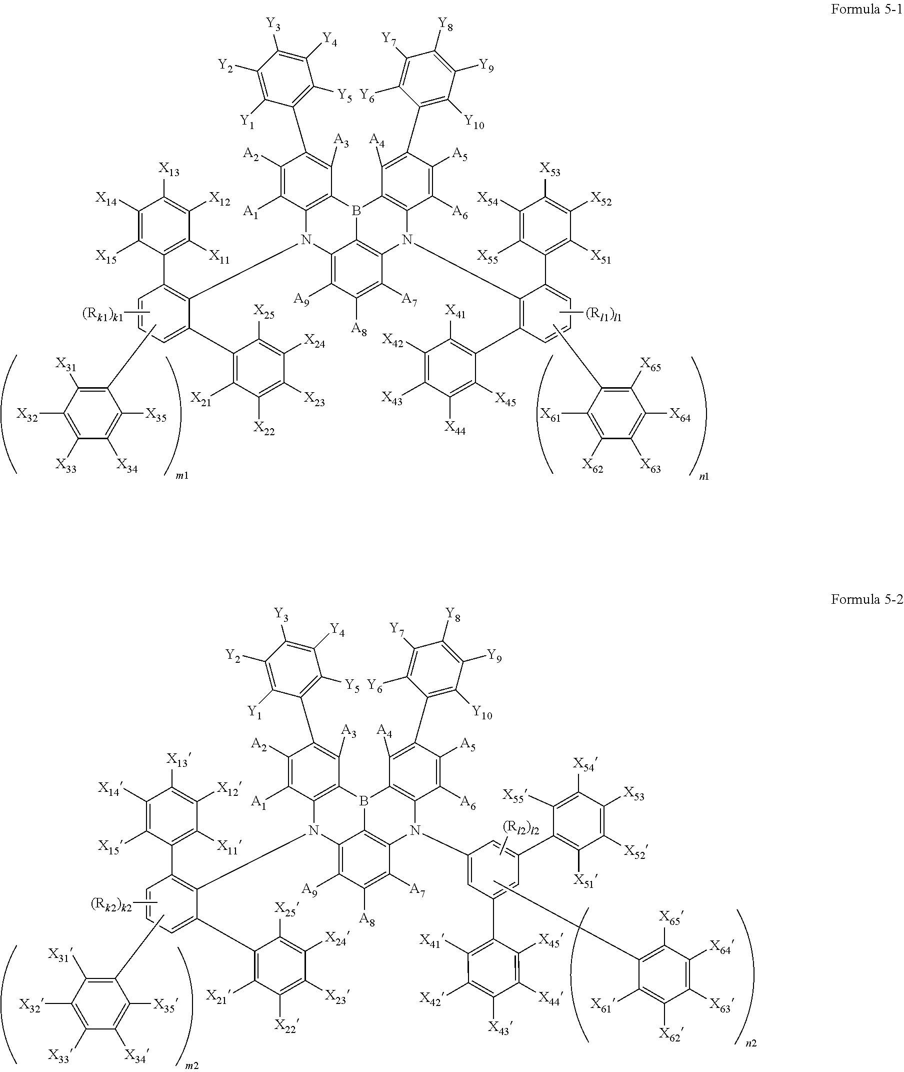

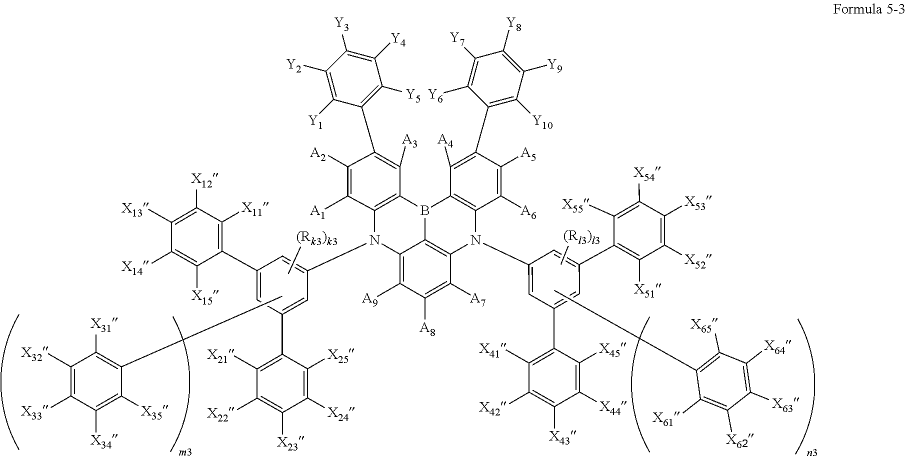

In Formula 5-1 to Formula 5-3, Rₖ₁, Rₖ₂, Rₖ₃, Rₗ₁, Rₗ₂, and Rₗ₃ may each independently be a hydrogen atom, or a deuterium atom, X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X₆₅′, X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle. In Formula 5-1 to Formula 5-3, k1 to k3, and 11 to 13 are each independently an integer of 0 to 2, and m1 to m3, and n1 to n3 are each independently an integer of 1 to 3. In Formula 5-1 to Formula 5-3, A₁ to A₉, and Y₁ to Y₁₀ are the same as defined with respect to Formula 1.

A polycyclic compound according to one or more embodiments of the present disclosure may be represented by Formula 1.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 is a plan view showing a display device according to one or more embodiments;

FIG. 2 is a cross-sectional view of a display device according to one or more embodiments;

FIG. 3 is a cross-sectional view schematically showing a light emitting element according to one or more embodiments;

FIG. 4 is a cross-sectional view schematically showing a light emitting element according to one or more embodiments;

FIG. 5 is a cross-sectional view schematically showing a light emitting element according to one or more embodiments;

FIG. 6 is a cross-sectional view schematically showing a light emitting element according to one or more embodiments;

FIG. 7 is a cross-sectional view of a display device according to one or more embodiments;

FIG. 8 is a cross-sectional view of a display device according to one or more embodiments;

FIG. 9 is a cross-sectional view showing a display device according to one or more embodiments; and

FIG. 10 is a cross-sectional view showing a display device according to one or more embodiments.

### DETAILED DESCRIPTION

The subject matter of the present disclosure may have various modifications and may be embodied in different forms, and example embodiments will be explained in more detail with reference to the accompany drawings. The subject matter of the present disclosure may, however, be embodied in different forms and should not be construed as limited to the embodiments set forth herein. Rather, the present disclosure is intended to encompass all modifications, equivalents, and substituents included in the spirit and technical scope of the appended claims, an equivalents thereof.

Like reference numerals refer to like elements throughout. In the drawings, the dimensions of structures may be exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the spirit and scope of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part, or intervening layers may also be present. On the contrary, when a layer, a film, a region, a plate, etc. is referred to as being “under” or “below” another part, it can be “directly under” the other part, or intervening layers may also be present. Also, when an element is referred to as being “on” another element, it can be under the other element.

In the description, the term “substituted or unsubstituted” corresponds to substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the example substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may mean a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentane, two ethyl groups may be interpreted as “adjacent groups” to each other. In addition, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic type (or kind). The carbon number of the alkyl group may be 1 to 50, 1 to 30, 1 to 20, 1 to 10, or 1 to 6. Examples of the alkyl group may include methyl group, ethyl group, n-propyl group, isopropyl group, n-butyl group, s-butyl group, t-butyl group, i-butyl group, 2-ethylbutyl group, 3,3-dimethylbutyl group, n-pentyl group, i-pentyl group, neopentyl group, t-pentyl group, cyclopentyl group, 1-methylpentyl group, 3-methylpentyl group, 2-ethylpentyl group, 4-methyl-2-pentyl group, n-hexyl group, 1-methylhexyl group, 2-ethylhexyl group, 2-butylhexyl group, cyclohexyl group, 4-methylcyclohexyl group, 4-t-butylcyclohexyl group, n-heptyl group, 1-methylheptyl group, 2,2-dimethylheptyl group, 2-ethylheptyl group, 2-butylheptyl group, n-octyl group, t-octyl group, 2-ethyloctyl group, 2-butyloctyl group, 2-hexyloctyl group, 3,7-dimethyloctyl group, cyclooctyl group, n-nonyl group, n-decyl group, adamantyl group, 2-ethyldecyl group, 2-butyldecyl group, 2-hexyldecyl group, 2-octyldecyl group, n-undecyl group, n-dodecyl group, 2-ethyldodecyl group, 2-butyldodecyl group, 2-hexyldodecyl group, 2-octyldodecyl group, n-tridecyl group, n-tetradecyl group, n-pentadecyl group, n-hexadecyl group, 2-ethylhexadecyl group, 2-butylhexadecyl group, 2-hexylhexadecyl group, 2-octylhexadecyl group, n-heptadecyl group, n-octadecyl group, n-nonadecyl group, n-eicosyl group, 2-ethyleicosyl group, 2-butyleicosyl group, 2-hexyleicosyl group, 2-octyleicosyl group, n-henicosyl group, n-docosyl group, n-tricosyl group, n-tetracosyl group, n-pentacosyl group, n-hexacosyl group, n-heptacosyl group, n-octacosyl group, n-nonacosyl group, n-triacontyl group, etc., without limitation.

In the description, a cycloalkyl group may mean a ring-type alkyl group. The carbon number of the cycloalkyl group may be 3 to 50, 3 to 30, 3 to 20, or 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the description, an alkenyl group means a hydrocarbon group including one or more carbon double bonds in the middle or at the terminal of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl group, a styrenyl group, a styrylvinyl group, etc., without limitation.

In the description, an alkynyl group means a hydrocarbon group including one or more carbon triple bonds in the middle or at the terminal of an alkyl group having a carbon number of 2 or more. The alkynyl group may be a linear chain or a branched chain. The carbon number is not specifically limited, but may be 2 to 30, 2 to 20, or 2 to 10. Examples of the alkynyl group include an ethynyl group, a propynyl group, etc., without limitation.

In the description, a hydrocarbon ring group means an optional functional group or substituent derived from an aliphatic hydrocarbon ring. The hydrocarbon ring group may be a saturated hydrocarbon ring group of 5 to 20 ring-forming carbon atoms.

In the description, an aryl group means an optional functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a fluorenyl group may be substituted, and two substituents may be combined with each other to form a spiro structure. Examples of a substituted fluorenyl group are as follows, but one or more embodiments of the present disclosure are not limited thereto.

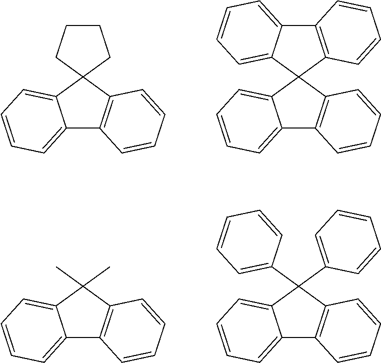

In the description, a heterocyclic group means an optional functional group or substituent derived from a ring including one or more among B, O, N, P, Si, Se, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle. If the heterocyclic group includes two or more heteroatoms, two or more heteroatoms may be the same or different.

In the description, an aliphatic heterocyclic group may include one or more among B, O, N, P, Si, Se, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more among B, O, N, P, Si, Se, and S as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may include thiophene group, furan group, pyrrole group, imidazole group, pyridine group, bipyridine group, pyrimidine group, triazine group, acridyl group, pyridazine group, pyrazinyl group, quinoline group, quinazoline group, quinoxaline group, phenoxazine group, phthalazine group, pyrido pyrimidine group, pyrido pyrazine group, pyrazino pyrazine group, isoquinoline group, indole group, carbazole group, N-arylcarbazole group, N-heteroarylcarbazole group, N-alkylcarbazole group, benzoxazole group, benzimidazole group, benzothiazole group, benzocarbazole group, benzothiophene group, dibenzothiophene group, thienothiophene group, benzofuran group, phenanthroline group, thiazole group, isooxazole group, oxazole group, oxadiazole group, thiadiazole group, phenothiazine group, dibenzosilole group, dibenzofuran group, etc., without limitation.

In the description, the same explanation of the above-described aryl group may be applied to an arylene group except that the arylene group is a divalent group. The same explanation of the above-described heteroaryl group may be applied to a heteroarylene group except that the heteroarylene group is a divalent group.

In the description, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the carbon number of an amino group is not specifically limited, but may be 1 to 30. The amino group may include an alkyl amino group, an aryl amino group, or a heteroaryl amino group. Examples of the amino group include a methylamino group, a dimethylamino group, a phenylamino group, a diphenylamino group, a naphthylamino group, a 9-methyl-anthracenylamino group, etc., without limitation.

In the description, the carbon number of a carbonyl group is not specifically limited, but the carbon number may be 1 to 40, 1 to 30, or 1 to 20. For example, the carbonyl group may have the structures below, but is not limited thereto.

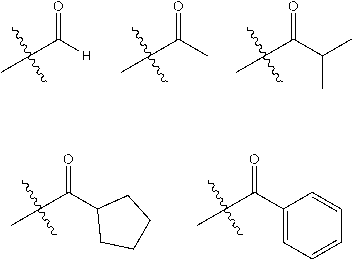

In the description, a sulfinyl group may mean the above-defined alkyl group or aryl group which is combined with an —S(═O)—, and a sulfonyl group may mean the above-defined alkyl group or aryl group which is combined with an —S(═O)₂—. The carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may mean the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may mean the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. The carbon number of the aryl oxy group is not specifically limited, but may be, for example, 6 to 30, 6 to 20, or 6 to 15. Examples of the oxy group may include methoxy, ethoxy, n-propoxy, isopropoxy, butoxy, pentyloxy, hexyloxy, octyloxy, nonyloxy, decyloxy, benzyloxy, etc. However, one or more embodiments of the present disclosure are not limited thereto.

In the description, a thioxy group may include an alkyl thioxy group and an aryl thioxy group. Examples of the alkyl thioxy group may include a methylthioxy group, an ethylthioxy group, a tert-butylthioxy group, a hexylthioxy group, an octylthioxy group, or the like, and examples of the aryl thioxy group may include a phenylthioxy group, a 2-methylphenylthioxy group, a 4-tert-butylphenylthioxy group, or the like, without limitation.

In the description, a boron group may mean the above-defined alkyl group or aryl group, combined with a boron atom. The boron group includes an alkyl boron group and an aryl boron group. Examples of the boron group include a dimethylboron group, a diethylboron group, a t-butylmethylboron group, a diphenylboron group, a phenylboron group, etc., without limitation.

In the description, the carbon number of an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, alkyl groups in an alkylthio group, alkylsulfoxy group, alkylaryl group, alkylamino group, alkylboron group, alkyl silyl group, alkyl amine group, alkyl thioxy group may be the same as the examples of the above-described alkyl group.

In the description, aryl groups in an aryloxy group, arylthio group, arylsulfoxy group, aryl amino group, arylboron group, aryl silyl group, aryl amine group, aryl thioxy group may be the same as the examples of the above-described aryl group.

In the description, a direct linkage may mean a single bond.

In the description,

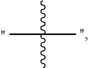

or “-*” means a position to be connected.

Hereinafter, embodiments of the present disclosure will be explained referring to the drawings.

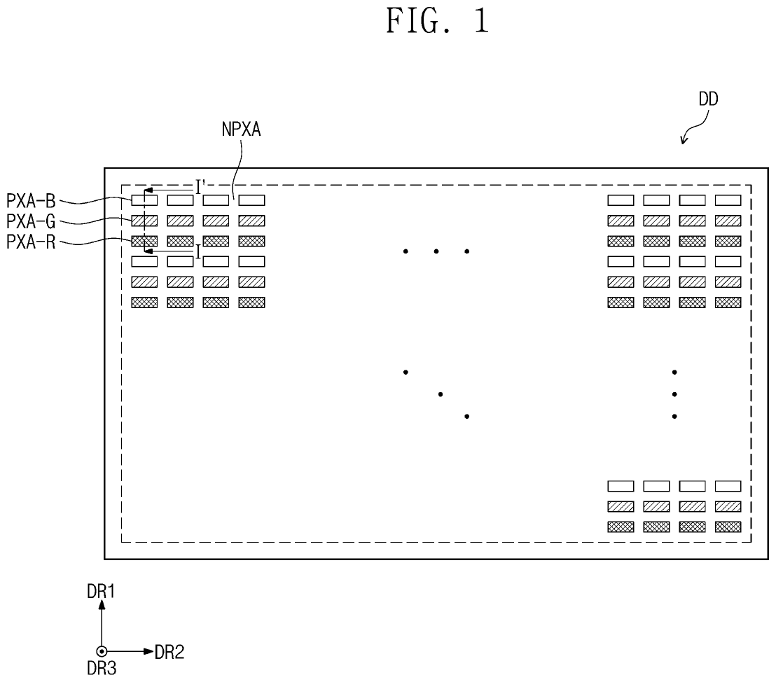

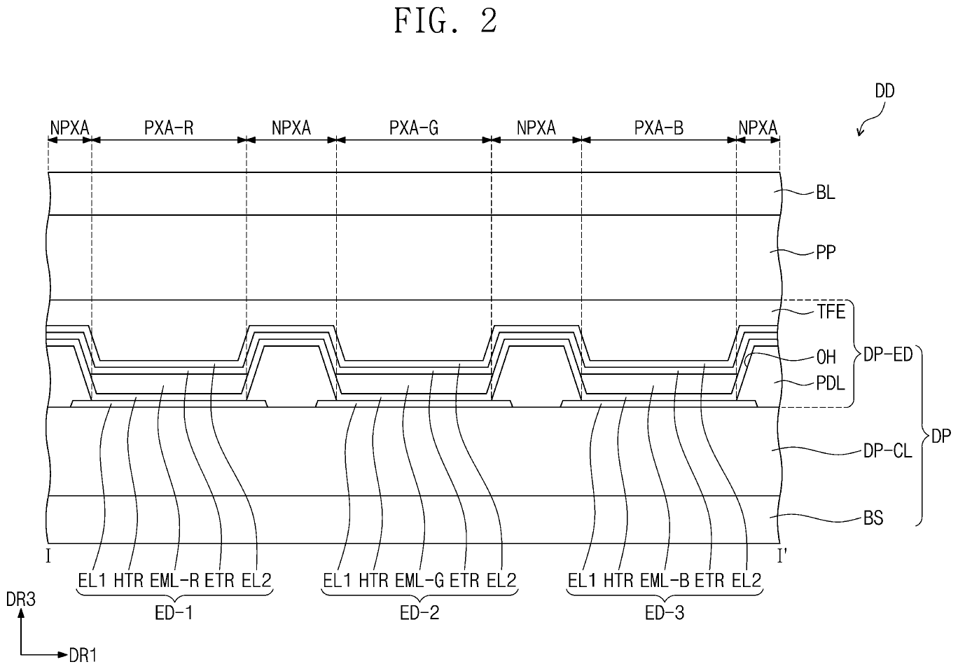

FIG. 1 is a plan view showing one or more embodiments of a display device DD. FIG. 2 is a cross-sectional view of a display device DD of one or more embodiments. FIG. 2 is a cross-sectional view showing a part corresponding to line I-I′ of FIG. 1.

The display device DD includes a display panel DP and an optical layer PP on the display panel DP. The display panel DP may include light emitting elements ED-1, ED-2 and ED-3. The display device DD includes a plurality of light emitting elements ED-1, ED-2 and ED-3. The optical layer PP may be on the display panel DP and control reflected light by external light at the display panel DP. The optical layer PP may include, for example, a polarization layer and/or a color filter layer. The optical layer PP may be omitted in the display device DD of one or more embodiments.

A base substrate BL may be on the optical layer PP. The optical layer PP may be on a base surface of the base substrate BL. The base substrate BL may be a glass substrate, a metal substrate, a plastic substrate, etc. However, one or more embodiments of the present disclosure are not limited thereto, and the base substrate BL may be an inorganic layer, an organic layer or a composite material layer. In addition, different from the drawings, the base substrate BL may be omitted in one or more embodiments.

The display device DD according to one or more embodiments may further include a filling layer. The filling layer may be between a display element layer DP-ED and a base substrate BL. The filling layer may be an organic layer. The filling layer may include at least one selected from among an acrylic-based resin, a silicon-based resin and an epoxy-based resin.

The display panel DP may include a base layer BS, a circuit layer DP-CL provided on the base layer BS and a display element layer DP-ED. The display element layer DP-ED may include a pixel definition layer PDL, light emitting elements ED-1, ED-2 and ED-3 in the pixel definition layer PDL, and an encapsulating layer TFE on the light emitting elements ED-1, ED-2 and ED-3.

The display element layer DP-ED may be on a base surface of the base layer BS. The base layer BS may be a glass substrate, a metal substrate, a plastic substrate, etc. However, one or more embodiments of the present disclosure are not limited thereto, and the base layer BS may be an inorganic layer, an organic layer or a composite material layer.

In one or more embodiments, the circuit layer DP-CL is on the base layer BS, and the circuit layer DP-CL may include a plurality of transistors. Each of the transistors may include a control electrode, an input electrode, and an output electrode. For example, the circuit layer DP-CL may include switching transistors and driving transistors for driving the light emitting elements ED-1, ED-2 and ED-3 of the display element layer DP-ED.

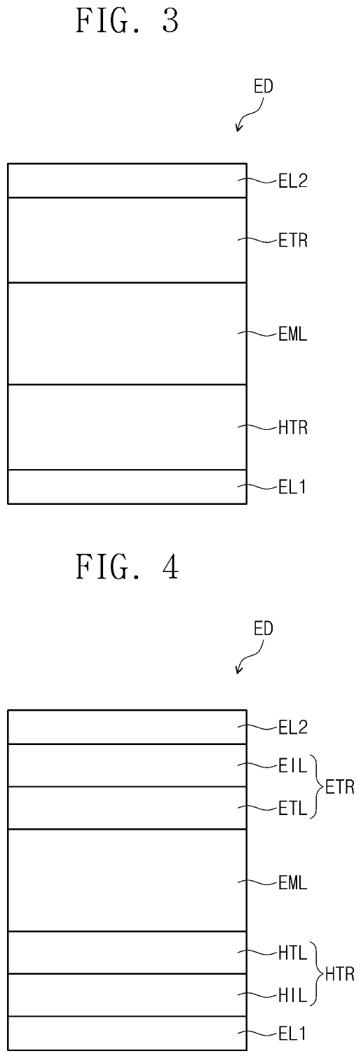

Light emitting elements ED-1, ED-2 and ED-3 may have the structures of the light emitting elements ED of embodiments according to FIG. 3 to FIG. 6, which will be further explained herein below. Each of the light emitting elements ED-1, ED-2 and ED-3 may include a first electrode EL1, a hole transport region HTR, emission layers EML-R, EML-G and EML-B, an electron transport region ETR, and a second electrode EL2.

In FIG. 2, shown is one or more embodiments where the emission layers EML-R, EML-G and EML-B of light emitting elements ED-1, ED-2 and ED-3 are in opening portions OH defined in a pixel definition layer PDL, and a hole transport region HTR, an electron transport region ETR and a second electrode EL2 are provided as common layers in all light emitting elements ED-1, ED-2 and ED-3. However, one or more embodiments of the present disclosure are not limited thereto. Different from FIG. 2, in one or more embodiments, the hole transport region HTR and the electron transport region ETR may be patterned and provided in the opening portions OH defined in the pixel definition layer PDL. For example, in one or more embodiments, the hole transport region HTR, the emission layers EML-R, EML-G and EML-B, and the electron transport region ETR of the light emitting elements ED-1, ED-2 and ED-3 may be patterned by an ink jet printing method and provided.

An encapsulating layer TFE may cover the light emitting elements ED-1, ED-2 and ED-3. The encapsulating layer TFE may encapsulate the display element layer DP-ED. The encapsulating layer TFE may be a thin film encapsulating layer. The encapsulating layer TFE may be one layer or a stacked layer of a plurality of layers. The encapsulating layer TFE includes at least one insulating layer. The encapsulating layer TFE according to one or more embodiments may include at least one inorganic layer (hereinafter, encapsulating inorganic layer). In addition, the encapsulating layer TFE according to one or more embodiments may include at least one organic layer (hereinafter, encapsulating organic layer) and at least one encapsulating inorganic layer.

The encapsulating inorganic layer protects the display element layer DP-ED from moisture/oxygen, and the encapsulating organic layer protects the display element layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic-based compound, an epoxy-based compound, etc. The encapsulating organic layer may include a photopolymerizable organic material, without specific limitation.

The encapsulating layer TFE may be on the second electrode EL2 and may fill the opening portion OH.

Referring to FIG. 1 and FIG. 2, the display device DD may include a non-luminous area NPXA and luminous areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane.

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In one or more embodiments of the disclosure, each of the luminous areas PXA-R, PXA-G and PXA-B may correspond to each pixel. The pixel definition layer PDL may divide the light emitting elements ED-1, ED-2 and ED-3. The emission layers EML-R, EML-G and EML-B of the light emitting elements ED-1, ED-2 and ED-3 may be provided and divided in the opening portions OH defined in the pixel definition layer PDL.

The luminous areas PXA-R, PXA-G and PXA-B may be divided into a plurality of groups according to the color of light produced from the light emitting elements ED-1, ED-2 and ED-3. In the display device DD of one or more embodiments, shown in FIG. 1 and FIG. 2, three luminous areas PXA-R, PXA-G and PXA-B emitting red light, green light and blue light are illustrated as one or more embodiments. For example, the display device DD of one or more embodiments may include a red luminous area PXA-R, a green luminous area PXA-G and a blue luminous area PXA-B, which are separated from each other.

In the display device DD according to one or more embodiments, a plurality of light emitting elements ED-1, ED-2 and ED-3 may emit light having different wavelength regions. For example, in one or more embodiments, the display device DD may include a first light emitting element ED-1 emitting red light, a second light emitting element ED-2 emitting green light, and a third light emitting element ED-3 emitting blue light. In one or more embodiments, each of the red luminous area PXA-R, the green luminous area PXA-G, and the blue luminous area PXA-B of the display device DD may correspond to the first light emitting element ED-1, the second light emitting element ED-2, and the third light emitting element ED-3.

However, one or more embodiments of the present disclosure are not limited thereto, and the first to third light emitting elements ED-1, ED-2 and ED-3 may emit light in the same wavelength region, or at least one thereof may emit light in a different wavelength region. For example, all the first to third light emitting elements ED-1, ED-2 and ED-3 may emit blue light.

The luminous areas PXA-R, PXA-G and PXA-B in the display device DD according to one or more embodiments may be arranged in a stripe shape. Referring to FIG. 1, a plurality of red luminous areas PXA-R, a plurality of green luminous areas PXA-G and a plurality of blue luminous areas PXA-B may be arranged along a second directional axis DR2. In addition, the red luminous area PXA-R, the green luminous area PXA-G and the blue luminous area PXA-B may be arranged by turns along a first directional axis DR1. A third directional axis DR3 may be perpendicular to a plane defined by the first directional axis DR1 and the second directional axis DR2.

In FIG. 1 and FIG. 2, the areas of the luminous areas PXA-R, PXA-G and PXA-B are shown similar, but one or more embodiments of the present disclosure are not limited thereto. The areas of the luminous areas PXA-R, PXA-G and PXA-B may be different from each other according to the wavelength region of light emitted. In one or more embodiments, the areas of the luminous areas PXA-R, PXA-G and PXA-B may mean areas on a plane defined by the first directional axis DR1 and the second directional axis DR2.

In one or more embodiments, the arrangement type (or kind) of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in various combinations according to the properties of display quality required for the display device DD. For example, the arrangement type (or kind) of the luminous areas PXA-R, PXA-G and PXA-B may be a PENTILE® arrangement type (or kind, e.g., an RGBG matrix, RGBG structure, or RGBG matrix structure), or a DIAMOND PIXEL™ arrangement type (or kind). PENTILE® is a duly registered trademark of Samsung Display Co., Ltd.

In addition, the areas of the luminous areas PXA-R, PXA-G and PXA-B may be different from each other. For example, in one or more embodiments, the area of the green luminous area PXA-G may be smaller than the area of the blue luminous area PXA-B, but one or more embodiments of the present disclosure are not limited thereto.

In the display device DD of one or more embodiments, shown in FIG. 2, at least one selected from among the first to third light emitting elements ED-1, ED-2 and ED-3 may include the polycyclic compound of one or more embodiments, which will be further explained herein below.

Hereinafter, FIG. 3 to FIG. 6 are cross-sectional views schematically showing light emitting elements ED according to embodiments. The light emitting element ED according to one or more embodiments may include a first electrode EL1, a second electrode EL2 oppositely to the first electrode EL1, and at least one functional layer between the first electrode EL1 and the second electrode EL2. The light emitting element ED of one or more embodiments may include a first compound of one or more embodiments, which will be further explained herein below, in the at least one functional layer. The polycyclic compound of one or more embodiments may be referred to as the first compound in this disclosure.

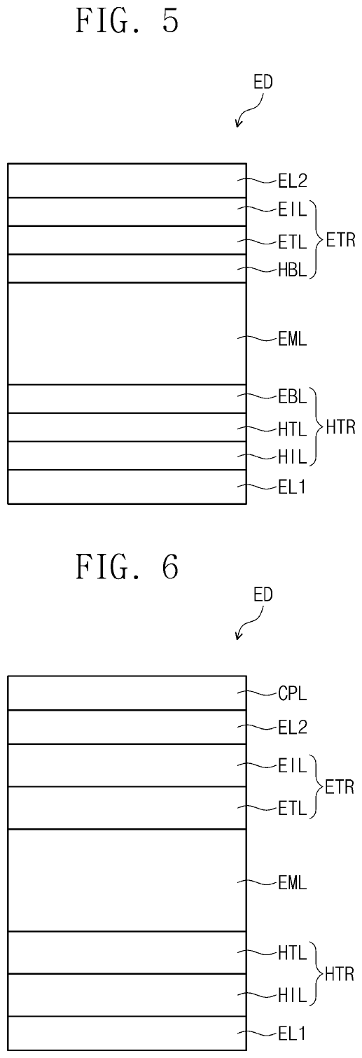

The light emitting element ED may include a hole transport region HTR, an emission layer EML, an electron transport region ETR, and/or the like, stacked in order as the at least one functional layer. Referring to FIG. 3, the light emitting element ED of one or more embodiments may include a first electrode EL1, a hole transport region HTR, an emission layer EML, an electron transport region ETR, and a second electrode EL2, stacked in order. In addition, the light emitting element ED of one or more embodiments may include the polycyclic compound of one or more embodiments, which will be further explained herein below, in an emission layer EML. In the display device DD (FIG. 2) of one or more embodiments, including a plurality of emission regions, the polycyclic compound of one or more embodiments, which will be further explained herein below, may be included in an emission layer EML constituting at least one emission region. When compared with FIG. 3, FIG. 4 shows the cross-sectional view of a light emitting element ED of one or more embodiments, wherein a hole transport region HTR includes a hole injection layer HIL and a hole transport layer HTL, and an electron transport region ETR includes an electron injection layer EIL and an electron transport layer ETL. In addition, when compared with FIG. 3, FIG. 5 shows the cross-sectional view of a light emitting element ED of one or more embodiments, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting element ED of one or more embodiments, including a capping layer CPL on the second electrode EL2.

In the light emitting element ED according to one or more embodiments, the first electrode EL1 has conductivity (e.g., electrical conductivity). The first electrode EL1 may be formed using a metal material, a metal alloy and/or a conductive compound (e.g., an electrically conductive compound). The first electrode EL1 may be an anode or a cathode. However, one or more embodiments of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and/or oxides thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure of a plurality of layers including a reflective layer or a transflective layer formed using the above materials, and a transmissive conductive (e.g., electrically conductive) layer formed using ITO, IZO, ZnO, and/or ITZO. For example, the first electrode EL1 may have a three-layer structure of ITO/Ag/ITO. However, one or more embodiments of the present disclosure are not limited thereto. The first electrode EL1 may include the above-described metal materials, combinations of two or more metal materials selected from the above-described metal materials, and/or oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may have a single layer formed using a single material, a single layer formed using a plurality of different materials, or a multilayer structure including a plurality of layers formed using a plurality of different materials.

The hole transport region HTR may include at least one selected from a hole injection layer HIL, a hole transport layer HTL, a buffer layer or an emission auxiliary layer, and an emission blocking layer EBL. In one or more embodiments, the hole transport region HTR may include a plurality of stacked hole transport layers HTL.

In addition, differently, the hole transport region HTR may have the structure of a single layer of a hole injection layer HIL or a hole transport layer HTL, and may have a structure of a single layer formed using a hole injection material and a hole transport material. In one or more embodiments, the hole transport region HTR may have a structure of a single layer formed using a plurality of different materials, or a structure stacked from the first electrode EL1 of hole injection layer HIL/hole transport layer HTL, hole injection layer HIL/hole transport layer HTL/buffer layer, hole injection layer HIL/buffer layer, or hole transport layer HTL/buffer layer, without limitation.

The thickness of the hole transport region HTR may be, for example, about 50 Å to about 15,000 Å. The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

In a light emitting element ED of one or more embodiments, the hole transport region HTR may include a compound represented by Formula H-1 below.

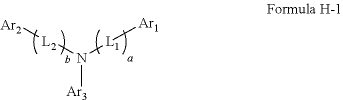

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. In one or more embodiments, if “a” or “b” is an integer of 2 or more, a plurality of L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In addition, in Formula H-1, Ara may be a substituted or unsubstituted aryl group of 6 to 30 ring-forming carbon atoms.

The compound represented by Formula H-1 may be a monoamine compound. Otherwise, the compound represented by Formula H-1 may be a diamine compound in which at least one selected from among Ar₁ to Ar₂ includes an amine group as a substituent. In addition, the compound represented by Formula H-1 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-1 may be represented by any one selected from among the compounds in Compound Group H below. However, the compounds shown in Compound Group H are only illustrations, and the compound represented by Formula H-1 is not limited to the compounds represented in Compound Group H below.

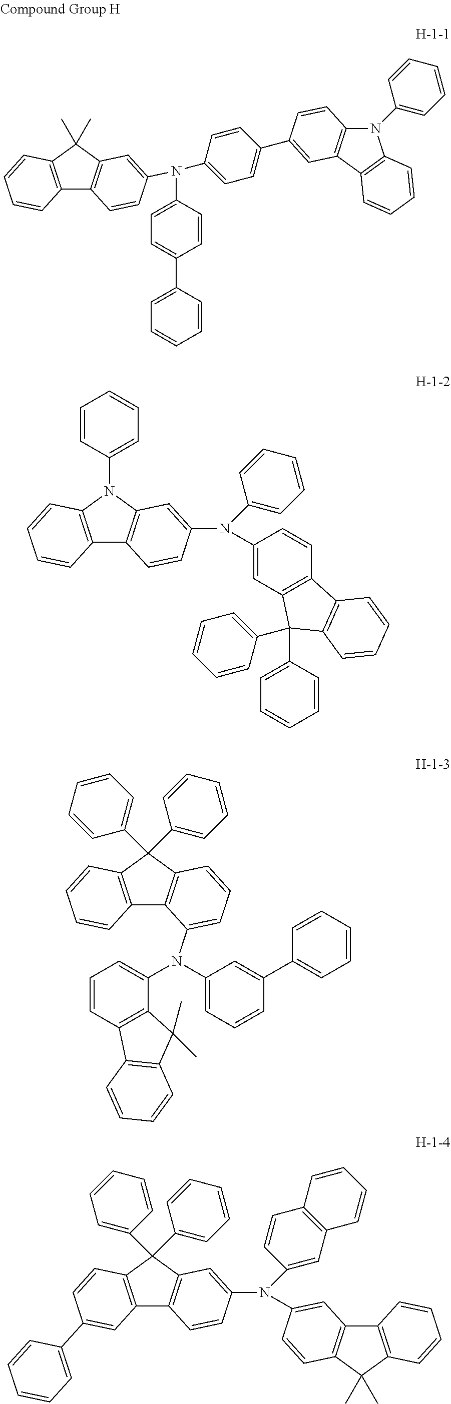 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

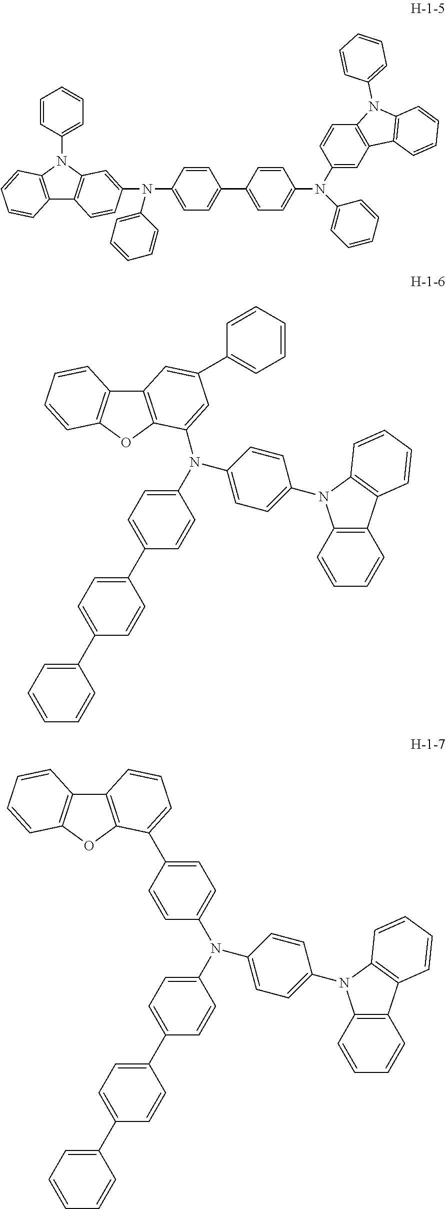 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

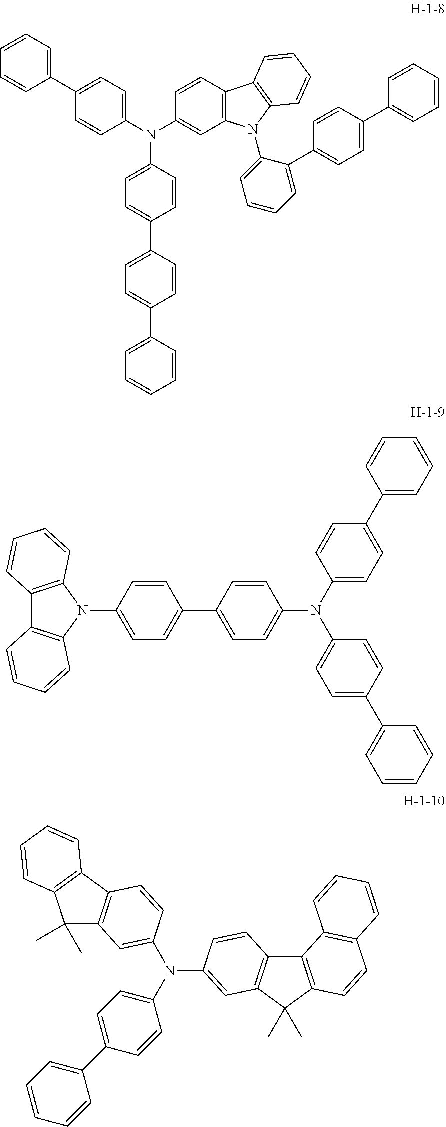 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

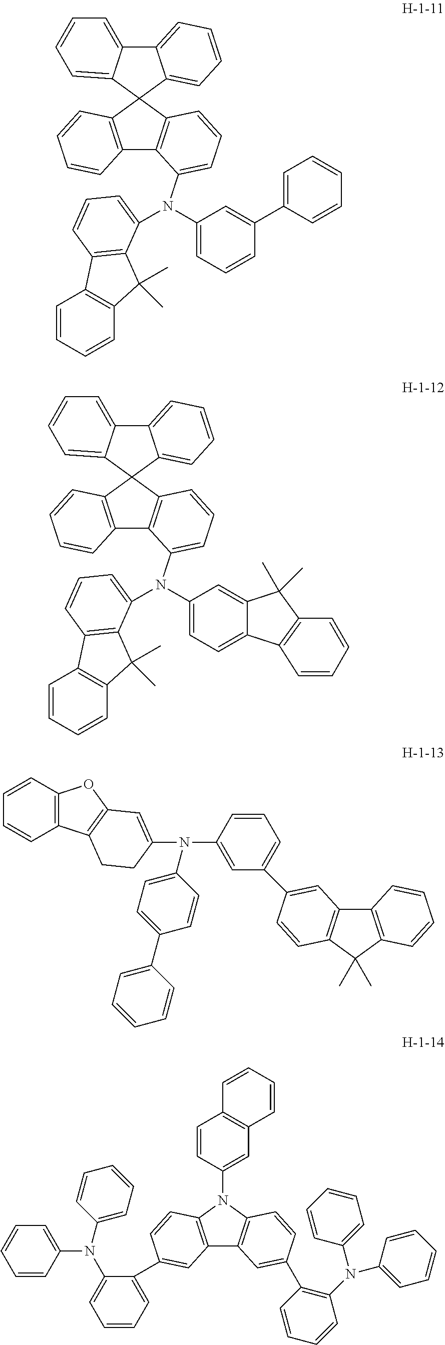

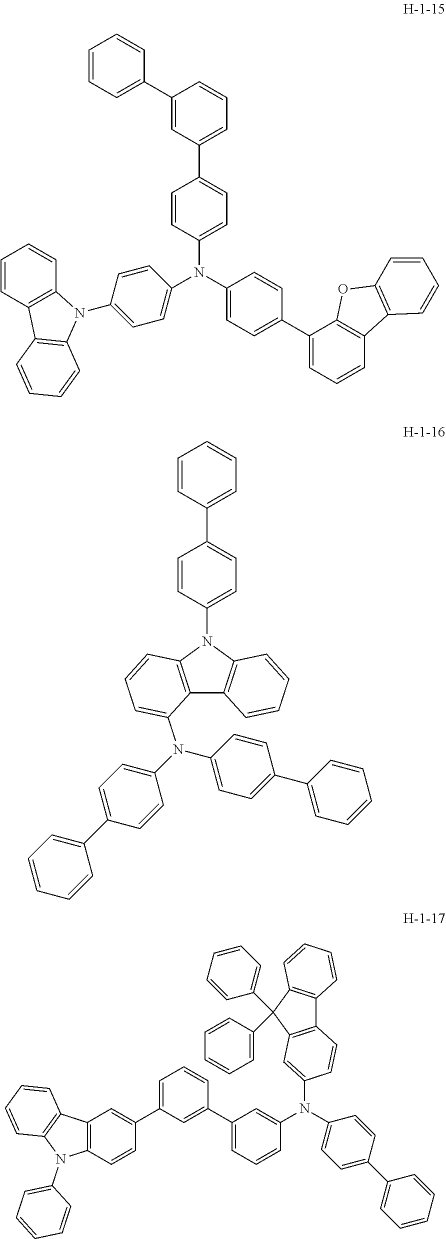 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

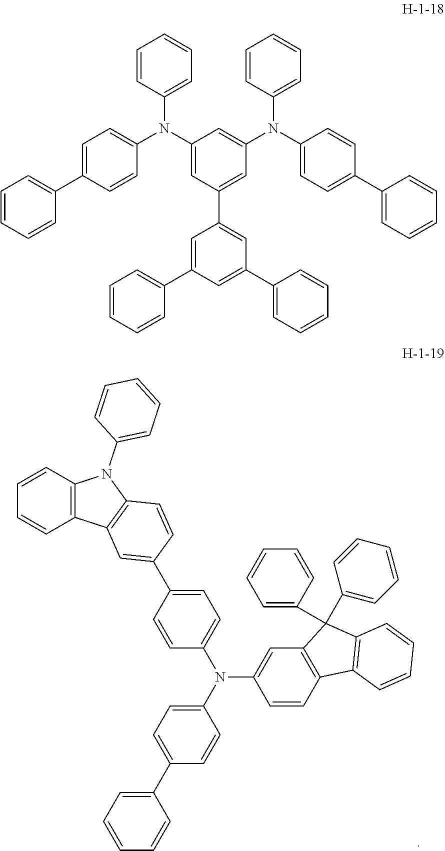

The hole transport region HTR may include a phthalocyanine compound such as copper phthalocyanine, N¹, N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N-(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANT/CSA), polyaniline/poly(4-styrenesulfonate) (PANT/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HAT-CN).

The hole transport region HTR may include carbazole derivatives such as N-phenylcarbazole and/or polyvinylcarbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region HTR in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. In case where the hole transport region HTR includes a hole injection layer HIL, the thickness of the hole injection layer HIL may be, for example, from about 30 Å to about 1,000 Å. In case where the hole transport region HTR includes a hole transport layer HTL, the thickness of the hole transport layer HTL may be from about 30 Å to about 1,000 Å. For example, in case where the hole transport region HTR includes an electron blocking layer EBL, the thickness of the electron blocking layer EBL may be from about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without substantial increase of a driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one selected from metal halide compounds, quinone derivatives, metal oxides, and cyano group-containing compounds, without limitation. For example, the p-dopant may include metal halide compounds such as CuI and/or Rbl, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HAT-CN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a buffer layer, an emission auxiliary layer and an electron blocking layer EBL in addition to the hole injection layer HIL and the hole transport layer HTL. The buffer layer may compensate resonance distance according to the wavelength of light emitted from an emission layer EML and may increase emission efficiency. As materials included in the buffer layer, materials which may be included in the hole transport region HTR may be used. The electron blocking layer EBL is a layer playing the role of blocking the injection of electrons from the electron transport region ETR to the hole transport region HTR. The emission auxiliary layer may improve the charge balance of holes and electrons. If the hole transport region HTR includes an electron blocking layer EBL, the electron blocking layer EBL may include the function as the emission auxiliary layer.

The emission layer EML is provided on the hole transport region HTR. The emission layer EML may have a thickness of, for example, about 100 Å to about 1,000 Å or about 100 Å to about 300 Å. The emission layer EML may have a single layer formed using a single material, a single layer formed using a plurality of different materials, or a multilayer structure having a plurality of layers formed using a plurality of different materials.

In the light emitting element ED of one or more embodiments, the emission layer EML may include a first compound. The first compound corresponds to the polycyclic compound of one or more embodiments. The polycyclic compound of one or more embodiments may include a core part of a fused ring including one boron atom (B) and two nitrogen atoms (N) as ring-forming atoms. In the polycyclic compound of one or more embodiments, the core part may have a fused structure of first to third aromatic rings through one boron atom and two nitrogen atoms. The first to the third aromatic rings may be substituted or unsubstituted benzene rings.

The first aromatic ring and the second aromatic ring may be symmetric to each other with respect to the boron atom in the core part of the fused ring. However, one or more embodiments of the present disclosure are not limited thereto, and the first aromatic ring and the second aromatic ring may be asymmetric to each other with respect to the boron atom in the core part of the fused ring. The third aromatic ring may be connected with the one boron atom and two nitrogen atoms in the core part of the fused ring. In one or more embodiments, benzene rings may be connected with two nitrogen atoms in the core part, respectively. The polycyclic compound of one or more embodiments may introduce a plurality of substituted or unsubstituted phenyl groups in the benzene rings connected with the nitrogen atoms.

The polycyclic compound of according to one or more embodiments of the present disclosure may be represented by Formula 1. In the polycyclic compound of one or more embodiments, represented by Formula 1, a benzene ring with which A₁ to A₃ are connected corresponds to the first aromatic ring, and a benzene ring with which A₄ to A₆ are connected corresponds to the second aromatic ring. In one or more embodiments, a benzene ring with which A₇ to A₉ are connected may correspond to the third aromatic ring.

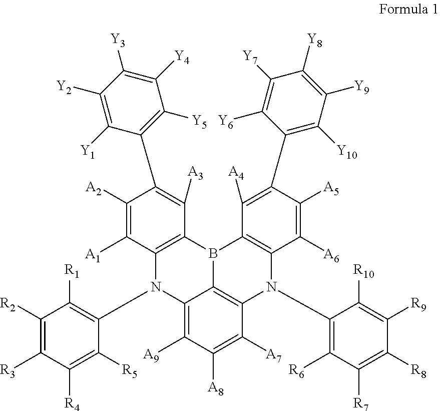

In Formula 1, A₁ to A₉ may be each independently a hydrogen atom, a deuterium atom, a halogen atom, a cyano group, a nitro group, a substituted or unsubstituted boron group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. However, in Formula 1, a case where at least one selected from among A₂ and A₅ is an unsubstituted carbazole group may be excluded.

In one or more embodiments, A₁ to A₉ may be each independently a hydrogen atom, a deuterium atom, a substituted or unsubstituted amine group, a substituted or unsubstituted phenyl group, a substituted or unsubstituted biphenyl group, or a substituted or unsubstituted carbazole group. For example, A₁ to A₇, and A₉ may be each independently a hydrogen atom or a deuterium atom. A₈ may be a hydrogen atom, a deuterium atom, a substituted or unsubstituted amine group, a substituted or unsubstituted t-butyl group, a substituted or unsubstituted phenyl group, a substituted or unsubstituted biphenyl group, or a substituted or unsubstituted carbazole group. However, one or more embodiments of the present disclosure are not limited thereto.

In Formula 1, Y₁ to Y₁₀ may be each independently a hydrogen atom, a deuterium atom, a halogen atom, a substituted or unsubstituted boron group, a substituted or unsubstituted amine group, a substituted or unsubstituted alkyl group of 1 to 20 carbon atoms, or a substituted or unsubstituted aryl group of 6 to 30 ring-forming carbon atoms. However, a case where at least one selected from among Y₁, Y₅, Y₆ and Y₁₀ is a substituted or unsubstituted alkyl group of 1 to 20 carbon atoms may be excluded.

In one or more embodiments, Y₁ to Y₁₀ may be each independently a hydrogen atom, a deuterium atom, a substituted or unsubstituted t-butyl group, or a substituted or unsubstituted phenyl group. For example, Y₁, Y₄, Y₅, Y₆, Y₇, and Y₁₀ may be each independently a hydrogen atom or a deuterium atom. Y₂, Y₃, Y₈, and Y₉ may be each independently a hydrogen atom, a deuterium atom, a substituted or unsubstituted t-butyl group, or a substituted or unsubstituted phenyl group.

In Formula 1, R₁ to R₁₀ may be each independently a hydrogen atom, a deuterium atom, or represented by the following Formula 2. Otherwise, R₁ to R₁₀ may be each independently combined with an adjacent group to form a ring. When R₁ to R₁₀ are combined with adjacent groups to form rings, adjacent R₁ and R₂, R₂ and R₃, R₃ and R₄, or R₄ and R₅ may be combined with each other to form a ring. In addition, adjacent R₆ and R₇, R₇ and R₈, R₈ and R₉, or R₉ and R₁₀ may be combined with each other to a form ring.

In one or more embodiments, at least three among R₁ to R₅, or at least three among R₆ to R₁₀ may be each independently represented by Formula 2. For example, when a benzene ring connected with any one selected from among two nitrogen atoms of the core part and substituted with R₁ to R₅ is referred to as a first benzene ring, and a benzene ring connected with the remaining nitrogen atom and substituted with R₆ to R₁₀ is referred to as a second benzene ring, in the polycyclic compound of one or more embodiments, represented by Formula 1, at least three substituents represented by Formula 2 may be connected with any one selected from among the first benzene ring and the second benzene ring. In addition, in the polycyclic compound of one or more embodiments, represented by Formula 1, at least three substituents represented by Formula 2 may be connected with each of the first benzene ring and the second benzene ring.

In one or more embodiments, a case where R₁ and R₅ are all hydrogen atoms, and R₂ to R₄ are all unsubstituted phenyl groups, and a case where R₆ and R₁₀ are all hydrogen atoms, and R₇ to R₉ are all unsubstituted phenyl groups are excluded. For example, if R₁ and R₅ are all hydrogen atoms, at least one selected from among R₂ to R₄ may be a substituted phenyl group. In addition, if R₆ and R₁₀ are all hydrogen atoms, at least one selected from among R₇ to R₉ may be a substituted phenyl group.

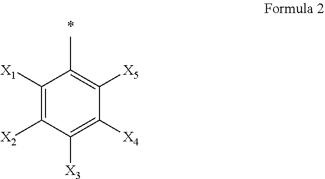

In Formula 2, X₁ to X₅ may be each independently a hydrogen atom, a deuterium atom, a halogen atom, a substituted or unsubstituted boron group, a substituted or unsubstituted amine group, a substituted or unsubstituted oxy group, a substituted or unsubstituted thio group, a substituted or unsubstituted alkyl group of 1 to 20 carbon atoms, or a substituted or unsubstituted aryl group of 6 to 30 ring-forming carbon atoms. Otherwise, X₁ to X₅ may be each independently combined with an adjacent group to form a ring. If X₁ to X₅ are combined with adjacent groups to form rings, adjacent X₁ and X₂, X₂ and X₃, X₃ and X₄, or X₄ and X₅ may be combined with each other to form a ring. For example, X₁ to X₅ may be each independently a hydrogen atom, a deuterium atom, a substituted or unsubstituted methyl group, a substituted or unsubstituted t-butyl group, or a substituted or unsubstituted phenyl group. Otherwise, adjacent X₁ and X₂, X₂ and X₃, X₃ and X₄, or X₄ and X₅ may be combined with each other to form a heterocycle containing a nitrogen atom (N), an oxygen atom (O), or a sulfur atom (S) as a ring-forming atom.

In one or more embodiments, Formula 2 may be represented by any one selected from among X-1 to X-11 below. For example, at least three among the substituents represented by X-1 to X-11 may be combined with at least one selected from among the first and second benzene rings.

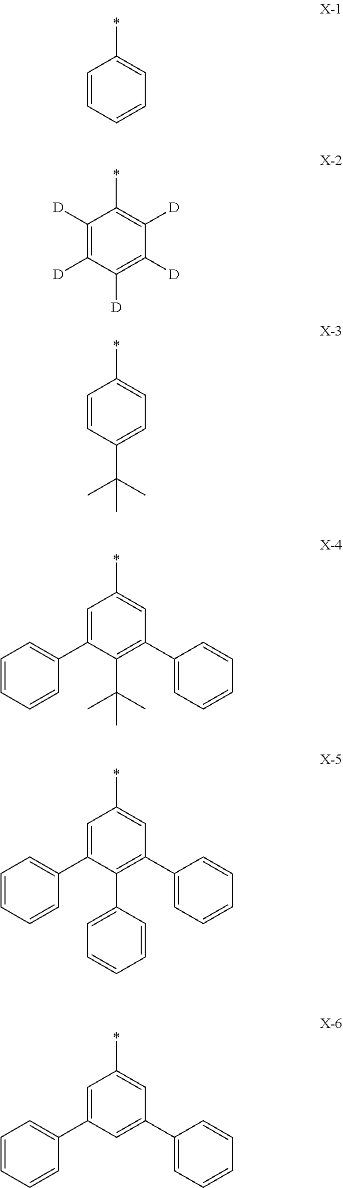

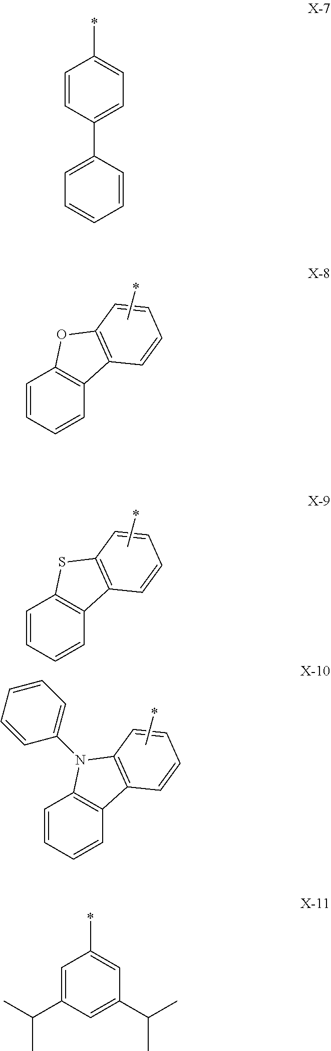

In one or more embodiments, in Formula 1, if R₁ and R₅ are all hydrogen atoms, and R₂ to R₄ are each independently represented by Formula 2, at least one selected from among R₂ to R₄ may exclude a case where X₁ to X₅ are all hydrogen atoms. In addition, if R₆ and R₁₀ are all hydrogen atoms, and R₇ to R₉ are each independently represented by Formula 2, at least one selected from among R₇ to R₉ may exclude a case where X₁ to X₅ are all hydrogen atoms. For example, in Formula 1, a case where R₁ and R₅ are all hydrogen atoms, and R₂ to R₄ are all X-1 may be excluded, and a case where R₆ and R₁₀ are all hydrogen atoms, and R₇ to R₉ are all X-1 may be excluded.

The polycyclic compound of one or more embodiments may include a deuterium atom as a substituent. For example, in the polycyclic compound represented by Formula 1, at least one selected from among A₁ to A₉, Y₁ to Y₁₀, and R₁ to R₁₀ may include a deuterium atom, or a substituent containing a deuterium atom. However, this is an illustration, and one or more embodiments of the present disclosure are not limited thereto.

In one or more embodiments, the polycyclic compound represented by Formula 1 may be represented by Formula 3. Formula 3 illustrates a polycyclic compound in which at least three of the substituent represented by Formula 2 are combined with each of the first and second benzene rings. In Formula 3, the same contents explained referring to Formula 1 may be applied for A₁ to A₉, and Y₁ to Y₁₀.

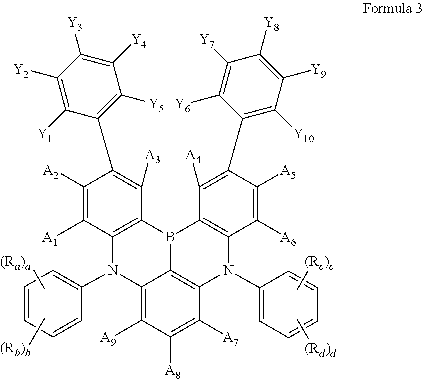

In Formula 3, Rₐ and R_{c} may be each independently represented by Formula 2. R_{b} and R_{d} may be each independently a hydrogen atom or a deuterium atom. For example, in Formula 3, a plurality of substituted or unsubstituted phenyl groups may be connected with each benzene ring connected with the nitrogen atom of the core part.

In Formula 3, “a” and “c” may be each independently an integer of 3 to 5. For example, the polycyclic compound of one or more embodiments may include three, four or five of the substituent represented by Formula 2 in each of the first and second benzene rings.

In Formula 3, “b” and “d” may be each independently an integer of 0 to 2. In one or more embodiments, a case where b is 0, may be the same as a case where b is 2, and two R_{b} are all hydrogen atoms. In addition, a case where d is 0, may be the same as a case where d is 2, and two R_{d} are all hydrogen atoms.

In one or more embodiments, the polycyclic compound of one or more embodiments, represented by Formula 1 may be represented by Formula 4. Formula 4 corresponds to Formula 1 in which R₁ to R₁₀ are embodied. For example, in Formula 1, at least two or more, or at least three or more among positions corresponding to R₁ to R₅ may be substituted or unsubstituted phenyl groups. Any one selected from among positions corresponding to R₁ to R₅ of Formula 1 may be a substituted or unsubstituted dibenzofuranyl group, a substituted or unsubstituted dibenzothiophenyl group, or a substituted or unsubstituted carbazole group. In addition, at least two or more, or at least three or more among positions corresponding to R₆ to R₁₀ may be substituted or unsubstituted phenyl groups. Any one selected from among positions corresponding to R₆ to R₁₀ may be a substituted or unsubstituted dibenzofuranyl group, a substituted or unsubstituted dibenzothiophenyl group, or a substituted or unsubstituted carbazole group. In one or more embodiments, in Formula 4, the same contents explained referring to Formula 1 may be applied for A₁ to A₉, and Y₁ to Y₁₀.

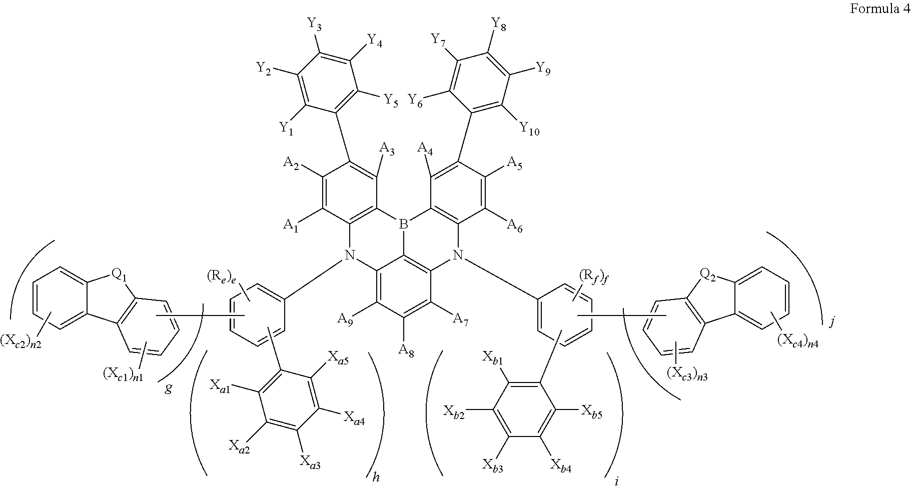

In Formula 4, Q₁ and Q₂ may be each independently 0, S or NR_{q}. For example, both Q₁ and Q₂ may be 0, S or NR_{q}. However, one or more embodiments of the present disclosure are not limited thereto, and Q₁ and Q₂ may be different.

In Formula 4, Rₑ and R_{f} may be each independently a hydrogen atom or a deuterium atom. R_{q} may be a substituted or unsubstituted aryl group of 3 to 10 ring-forming carbon atoms. For example, R_{q} may be a substituted or unsubstituted phenyl group, but one or more embodiments of the present disclosure are not limited thereto.

In Formula 4, Xₐ₁ to Xₐ₅, X_{b1} to X_{b5}, and X_{c1} to X_{c4} may be each independently a hydrogen atom, a deuterium atom, a substituted or unsubstituted alkyl group of 1 to 20 carbon atoms, or a substituted or unsubstituted aryl group of 6 to 30 ring-forming carbon atoms. For example, Xₐ₁ to Xₐ₅, X_{b1} to X_{b5}, and X_{c1} to X_{c4} may be each independently a hydrogen atom, a deuterium atom, a substituted or unsubstituted methyl group, a substituted or unsubstituted t-butyl group, or a substituted or unsubstituted phenyl group.

In Formula 4, “e” and “f” may be each independently an integer of 0 to 2. If “e” and “f” are 2, a plurality of Rₑ and R_{f} may be all the same, or at least one may be different from the remainder. A case where “e” and “f” are 0, may be the same as a case where “e” and “f” are 2, and R e and R_{f} are hydrogen atoms. If “e” and “f” are 0, the polycyclic compound of one or more embodiments may be unsubstituted with Rₑ and R_{f}, respectively.

In Formula 4, “g” and “j” may be each independently an integer of 0 or 1. “h” and “i” may be each independently an integer of 2 to 5. For example, the polycyclic compound of one or more embodiments, represented by Formula 4 may include a heterocycle including Q₁ and Q₂ as ring-forming atoms, or may not include a heterocycle including Q₁ and Q₂ as ring-forming atoms. In addition, the polycyclic compound of one or more embodiments, represented by Formula 4 may include at least two substituted or unsubstituted phenyl groups. For example, in Formula 4, if “g” is 0, “h” may be an integer of 3 to 5, and if “j” is 0, “i” may be an integer of 3 to 5. In addition, if “g” is 1, “h” may be an integer of 2 to 5, and if “j” is 1, “i” may be an integer of 2 to 5.

In Formula 4, n1 and n3 may be each independently an integer of 0 to 3. If n1 and n3 are integers of 2 or more, a plurality of X_{c1} and X_{c3} may be all the same, or at least one may be different from the remainder. In one or more embodiments, a case where n1 is 0, may be the same as a case where n1 is 3, and three X_{c1} are all hydrogen atoms. The case where n1 is 0 may be understood as a case of Formula 4 unsubstituted with X_{c1}. In addition, a case where n3 is 0, may be the same as a case where n3 is 3, and three X_{c3} are all hydrogen atoms. The case where n3 is 0 may be understood as a case of Formula 4 unsubstituted with X_{c3}.

In Formula 4, n2 and n4 may be each independently an integer of 0 to 4. If n2 and n4 are integers of 2 or more, a plurality of X_{c2} and X_{c4} may be all the same, or at least one may be different from the remainder. In one or more embodiments, a case where n2 is 0, may be the same as a case where n2 is 4, and four X_{c2} are all hydrogen atoms. The case where n2 is 0 may be understood as a case of Formula 4 unsubstituted with X_{c2}. In addition, a case where n4 is 0, may be the same as a case where n4 is 4, and four X_{c4} are all hydrogen atoms. The case where n4 is 0 may be understood as a case of Formula 4 unsubstituted with X_{c4}.

In one or more embodiments, the polycyclic compound of one or more embodiments, represented by Formula 1 may be represented by any one selected from among Formula 5-1 to Formula 5-3. Each of Formula 5-1 to Formula 5-3 correspond to the polycyclic compound represented by Formula 1 in which the bonding position of the substituent represented by Formula 2 is embodied. Formula 5-1 represents a case where the substituents represented by Formula 2 are connected at positions R₁, R₅, R₆ and R₁₀, and at least one selected from among R₂ to R₄ and at least one selected from among R₇ to R₉ are represented by Formula 2. Formula 5-2 represents a case where the substituents represented by Formula 2 are connected at positions R₁, R₅, R₇ and R₉, and at least one selected from among R₂ to R₄ and at least one selected from among R₆, R₈ and R₁₀ are represented by Formula 2. Formula 5-3 represents a case where the substituents represented by Formula 2 are connected at positions R₂, R₄, R₇ and R₉, and at least one selected from among R₁, R₃ and R₅ and at least one selected from among R₆, R₈ and R₁₀ are represented by Formula 2. In one or more embodiments, in Formula 5-1 to Formula 5-3, the same contents explained referring to Formula 1 may be applied for A₁ to A₉, and Y₁ to Y₁₀.

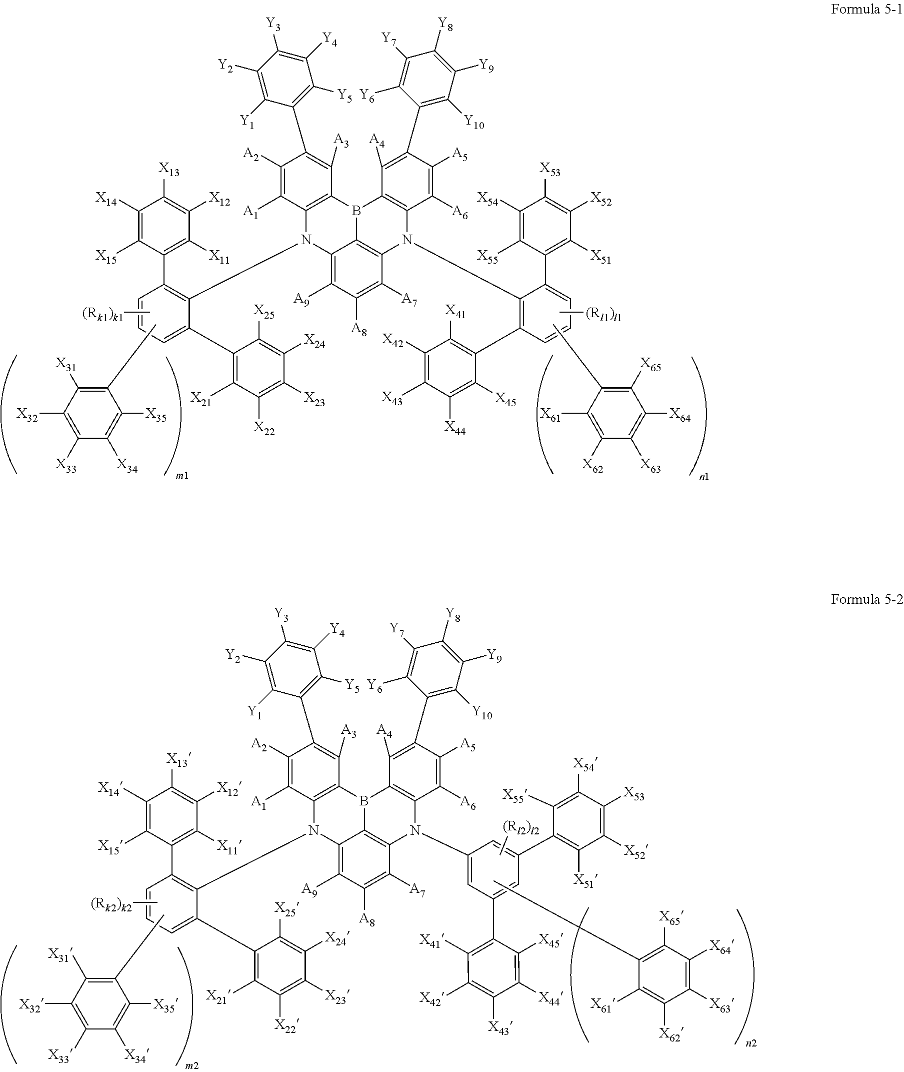

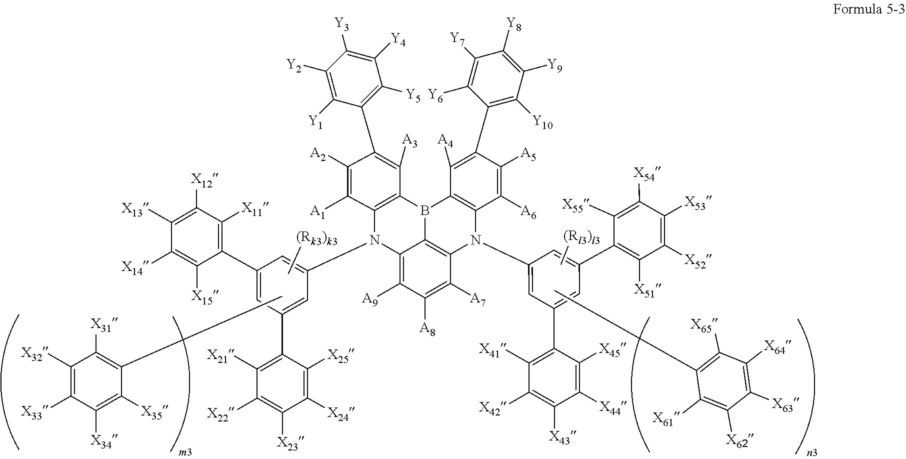

In Formula 5-1 to Formula 5-3, Rₖ₁, Rₖ₂, Rₖ₃, Rₗ₁, Rₗ₂, and Rₗ₃ may be each independently a hydrogen atom, or a deuterium atom. k1 to k3, and 11 to 13 may be each independently an integer of 0 to 2. If k1 to k3, and 11 to 13 are integers of 2 or more, a plurality of Rₖ₁, Rₖ₂, Rₖ₃, Rₗ₁, Rₗ₂ and Rₗ₃ may be all the same, or at least one may be different from the remainder. In one or more embodiments, a case where k1 to k3, and 11 to 13 are 0, may be the same as a case where k1 to k3, and 11 to 13 are 2, and Rₖ₁, Rₖ₂, Rₖ₃, Rₗ₁, R₁₂ and R₁₃ are hydrogen atoms, respectively. The case where k1 to k3, and 11 to 13 are 0, may be understood as Formula 5-1 to Formula 5-3, unsubstituted with Rₖ₁, Rₖ₂, Rₖ₃, Rₗ₁, R₁₂ and Rₗ₃, respectively.

In Formula 5-1 to Formula 5-3, X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X₆₅′, X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ may be each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle. For example, X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X_{65′,} X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ may be each independently a hydrogen atom, a deuterium atom, a substituted or unsubstituted methyl group, a substituted or unsubstituted t-butyl group, or a substituted or unsubstituted phenyl group. In addition, X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X₆₅′, X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ may be each independently combined with an adjacent group to form a heterocycle containing a nitrogen atom (N), an oxygen atom (0) or a sulfur atom (S) as a ring-forming atom.

In Formula 5-1 to Formula 5-3, m1 to m3, and n1 to n3 may be each independently an integer of 1 to 3. For example, when m1 to m3, and n1 to n3 are each integers of 2 or more, the substituents in parentheses may be the same or different.

In one or more embodiments, the polycyclic compound represented by Formula 5-1 is represented by any one selected from among Formula 5-1-1 to Formula 5-1-4. Formula 5-1-1 to Formula 5-1-4 illustrate the polycyclic compound of one or more embodiments in which a substituent corresponding to the substituent represented by Formula 2 is bonded to a set or specific position. In Formula 5-1-1 to Formula 5-1-4, the same contents explained referring to Formula 1 and Formula 5-1 may be applied for A₁ to A₉, Y₁ to Y₁₀, X₁₁ to X₁₅, X₂₁ to X₂₅, X₄₁ to X₄₅, and X₅₁ to X₅₅.

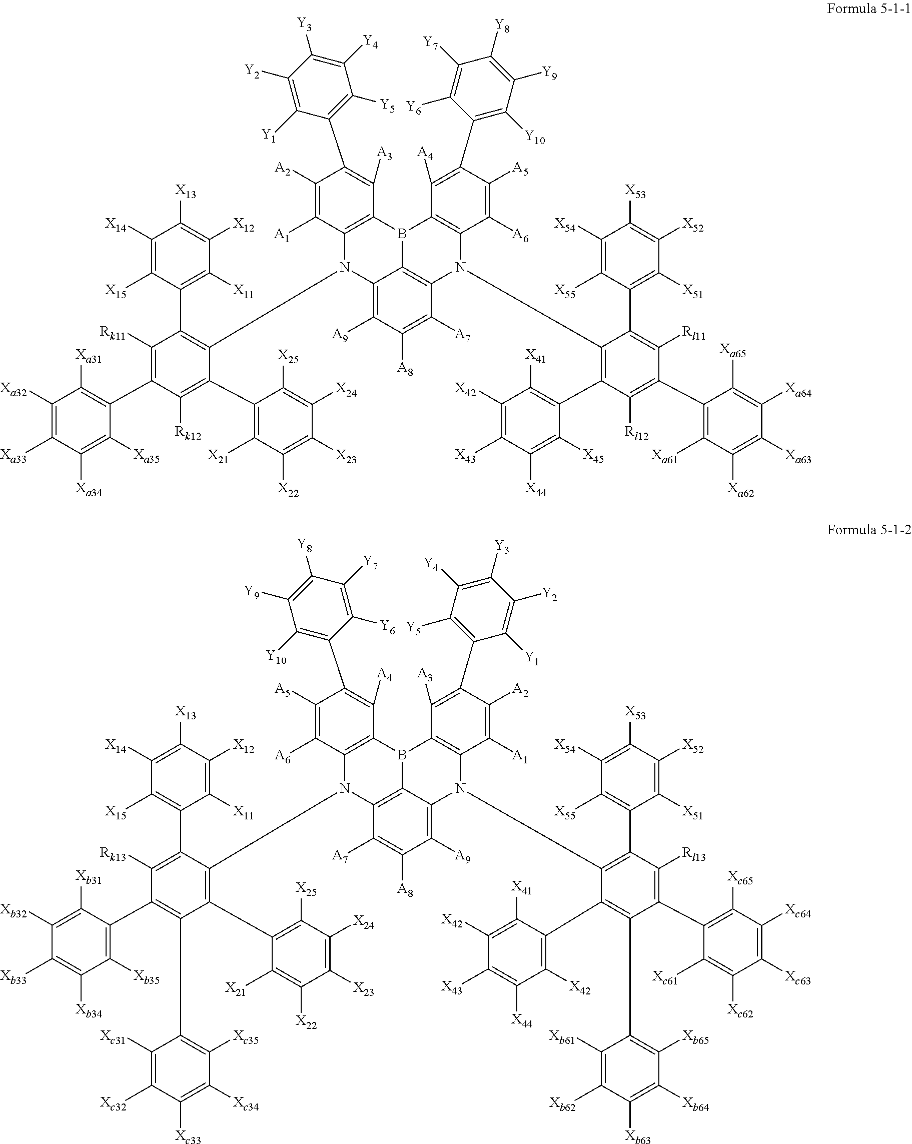

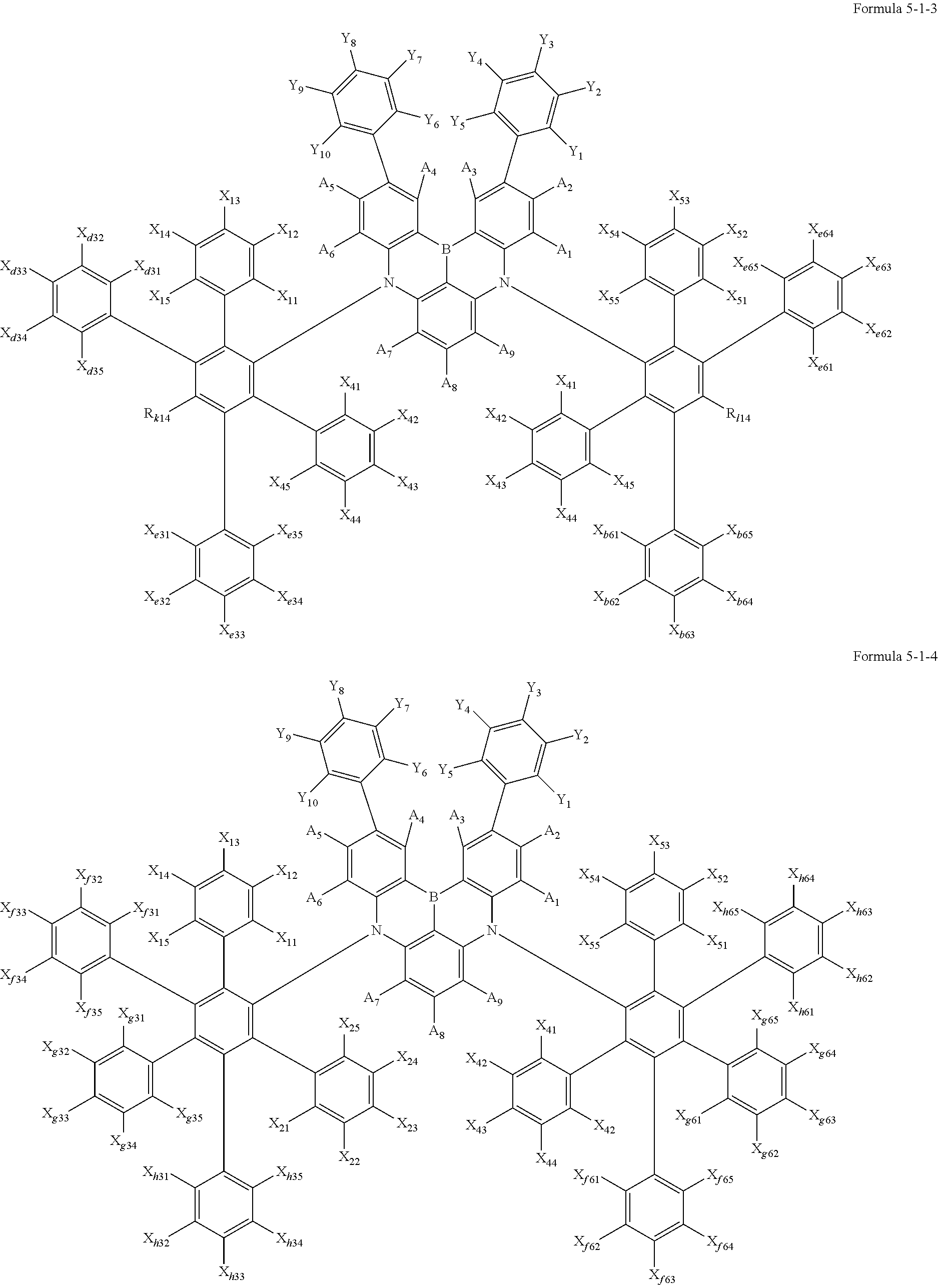

In Formula 5-1-1 to Formula 5-1-4, Rₖ₁₁ to Rₖ₁₄, and Rₗ₁₁ to Rₗ₁₄ may be each independently a hydrogen atom or a deuterium atom.

In Formula 5-1-1 to Formula 5-1-4, Xₐ₃₁ to Xₐ₃₅, X_{b31} to X_{b35}, X_{c31} to X_{c35}, X_{d31} to X_{d35}, Xₑ₃₁ to Xₑ₃₅, X_{f31} to X_{f35}, X_{g31} to X_{g35}, Xₕ₃₁ to Xₕ₃₅, Xₐ₆₁ to Xₐ₆₅, X_{b61} to X_{b65}, X_{c61} to X_{c65}, X_{d61} to X_{d65}, Xₑ₆₁ to Xₑ₆₅, X_{f61} to X_{f65}, X_{g61} to X_{g65}, and Xₕ₆₁ to Xₕ₆₅ may be each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle. For example, Xₐ₃₁ to Xₐ₃₅, X_{b31} to X_{b35}, X_{c31} to X_{c35}, X_{d31} to X_{d35}, Xₑ₃₁ to Xₑ₃₅, X_{f31} to X_{f35}, X_{g31} to X_{g35}, Xₕ₃₁ to Xₕ₃₅, Xₐ₆₁ to Xₐ₆₅, X_{b61} to X_{b65}, X_{c61} to X_{c65}, X_{d61} to X_{d65}, Xₑ₆₁ to Xₑ₆₅, X_{f61} to X_{f65}, X_{g61} to X_{g65}, and Xₕ₆₁ to Xₕ₆₅ may be each independently a hydrogen atom, a deuterium atom, a substituted or unsubstituted methyl group, a substituted or unsubstituted t-butyl group, or a substituted or unsubstituted phenyl group. In addition, Xₐ₃₁ to Xₐ₃₅, X_{b31} to X_{b35}, X_{c31} to X_{c35}, X_{d31} to X_{d35}, Xₑ₃₁ to Xₑ₃₅, X_{f31} to X_{f35}, X_{g31} to X_{g35}, Xₕ₃₁ to Xₕ₃₅, Xₐ₆₁ to Xₐ₆₅, X_{b61} to X_{b65}, X_{c61} to X_{c65}, X_{d61} to X_{d65}, Xₑ₆₁ to Xₑ₆₅, X_{f61} to X_{f65}, X_{g61} to X_{g65}, and Xₕ₆₁ to Xₕ₆₅ may be combined with an adjacent group to form a heterocycle. The heterocycle may include a nitrogen atom (N), an oxygen atom (O) or a sulfur atom (S) as a ring-forming atom, but one or more embodiments of the present disclosure are not limited thereto.

In one or more embodiments, the polycyclic compound represented by Formula 5-2 may be represented by Formula 5-2-1. In Formula 5-2-1, the same contents explained referring to Formula 1 and Formula 5-2 may be applied for A₁ to A₉, Y₁ to Y₁₀, X₁₁′ to X₁₅′, X₂₁′ to X₂₅′, X₄₁′ to X₄₅′, and X₅₁′ to X₅₅′.

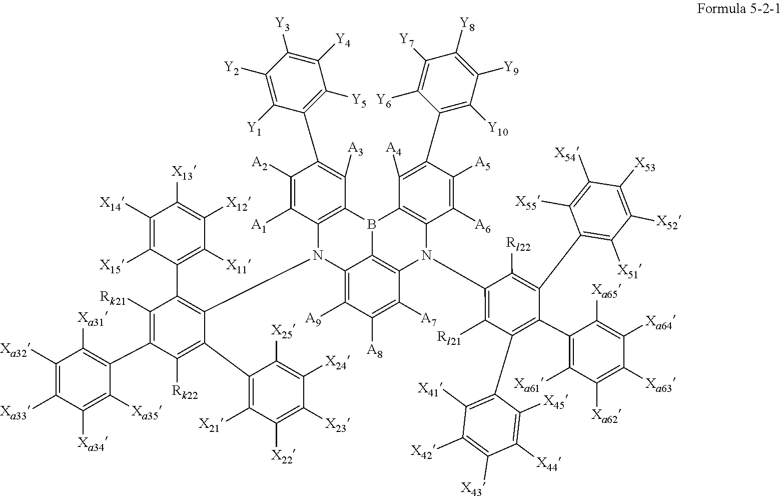

In Formula 5-2-1, Rₖ₂₁, Rₖ₂₂, Rₗ₂₁ and Rₗ₂₂ may be each independently a hydrogen atom or a deuterium atom. Xₐ₃₁′ to Xₐ₃₅′, and X a 61′ to Xₐ₆₅′ may be each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle. For example, Xₐ₃₁′ to Xₐ₃₅′, and X a 61′ to Xₐ₆₅′ may be each independently a hydrogen atom, a deuterium atom, a substituted or unsubstituted t-butyl group or a substituted or unsubstituted phenyl group. In addition, Xₐ₃₁′ to Xₐ₃₅′, and Xₐ₆₁′ to Xₐ₆₅′ may be combined with adjacent group to form a heterocycle containing a nitrogen atom (N), an oxygen atom (O) or a sulfur atom (S) as a ring-forming atom.

In one or more embodiments, the polycyclic compound represented by Formula 5-3 may be represented by Formula 5-3-1 or Formula 5-3-2. In Formula 5-3-1 and Formula 5-3-2, the same contents explained referring to Formula 1 and Formula 5-3 may be applied for A₁ to A₉, Y₁ to Y₁₀, X₁₁″ to X₁₅″, X₂₁″ to X₂₅″, X₄₁″ to X₄₅″, and X₅₁″ to X₅₅″.

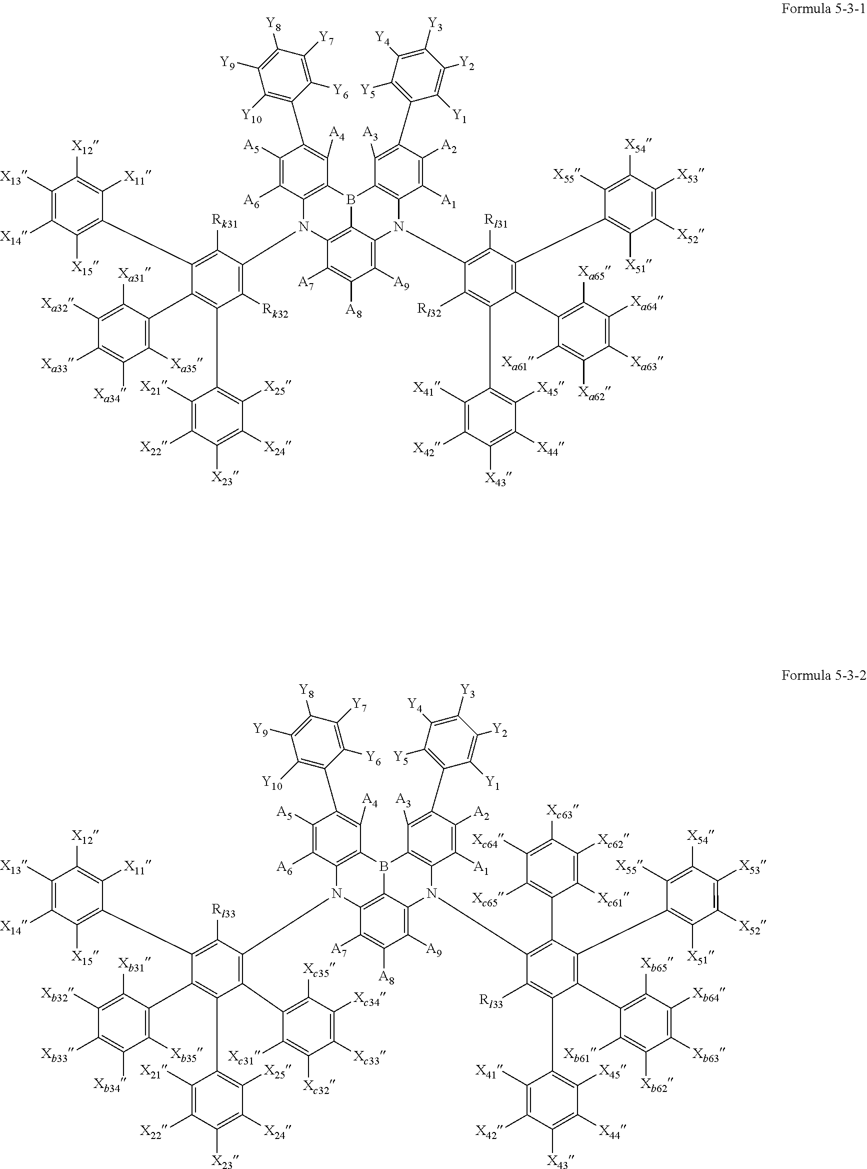

In Formula 5-3-1 and Formula 5-3-2, Rₖ₃₁, Rₖ₃₂, Rₖ₃₃, Rₗ₃₁, Rₗ₃₂ and Rₗ₃₃ may be each independently a hydrogen atom or a deuterium atom. Xₐ₃₁″ to Xₐ₃₅″, X_{b31}″ to X_{b35}″, X_{c31}″ to X_{c35}″, Xₐ₆₁″ to Xₐ₆₅″, X_{b61}″ to X_{b65}″ and X_{c61}″ to X_{c65}″ may be each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a ring. For example, Xₐ₃₁″ to Xₐ₃₅″, X_{b31}″ to X_{b35}″, X_{c31}″ to X_{c35}″, Xₐ₆₁″ to Xₐ₆₅″, X_{b61}″ to X_{b65}″ and X_{c61}″ to X_{c65}″ may be each independently a hydrogen atom, a deuterium atom, a substituted or unsubstituted t-butyl group or a substituted or unsubstituted phenyl group. In addition, Xₐ₃₁″ to Xₐ₃₅″, X_{b31}″ to X_{b35}″, X_{c31}″ to X_{c35}″, Xₐ₆₁″ to Xₐ₆₅″, X_{b61}″ to X_{b65}″ and X_{c61}″ to X_{c65}″ may be combined with adjacent group to form a heterocycle containing a nitrogen atom (N), an oxygen atom (0) or a sulfur atom (S) as a ring-forming atom.

The polycyclic compound of one or more embodiments may be represented by any one selected from among the compounds in Compound Group 1. The light emitting element ED of one or more embodiments may include at least one selected from among the compounds of Compound Group 1. In Compound Group 1, “D” is a deuterium atom.

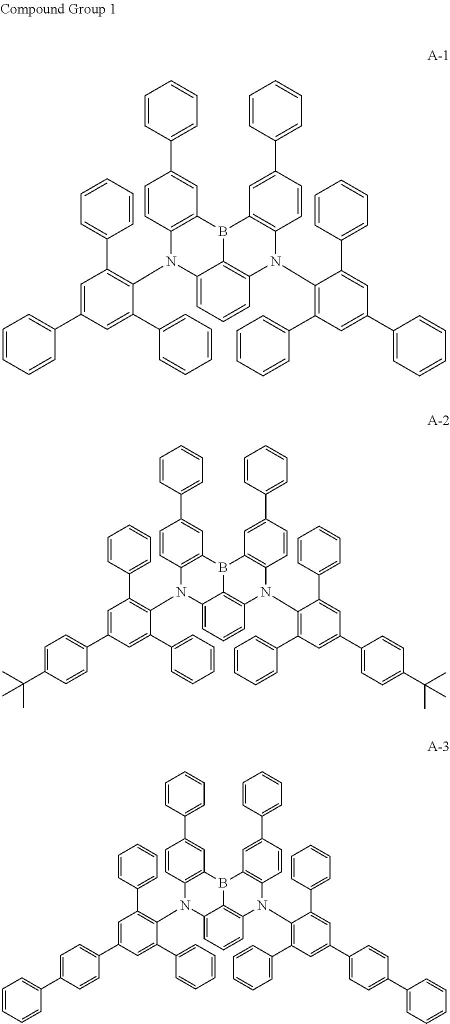 [SMILES: c1ccc(-c2ccc3c(c2)B2c4cc(-c5ccccc5)ccc4N(c4c(-c5ccccc5)cc(-c5ccccc5)cc4-c4ccccc4)c4cccc(c42)N3c2c(-c3ccccc3)cc(-c3ccccc3)cc2-c2ccccc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cccc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cccc4c65)c(-c4ccccc4)c3)cc2)cc1]

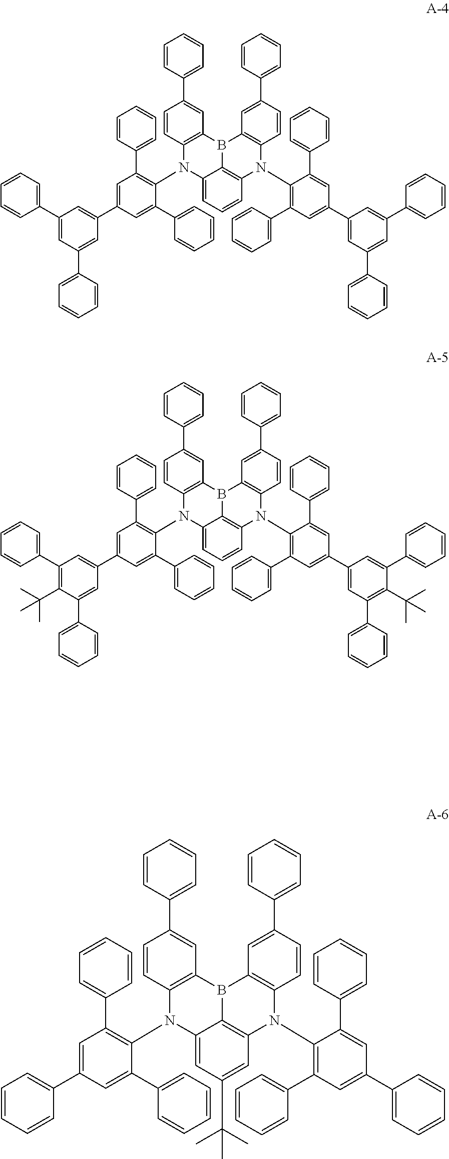

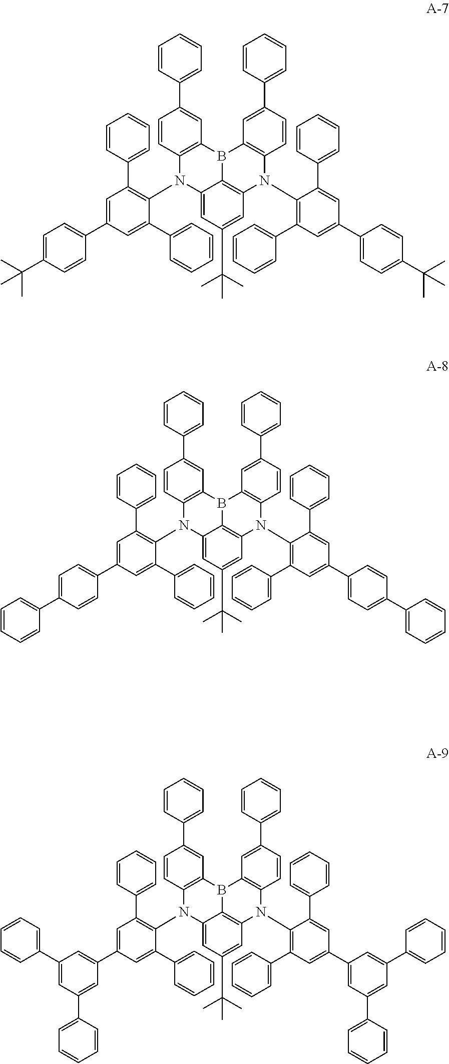

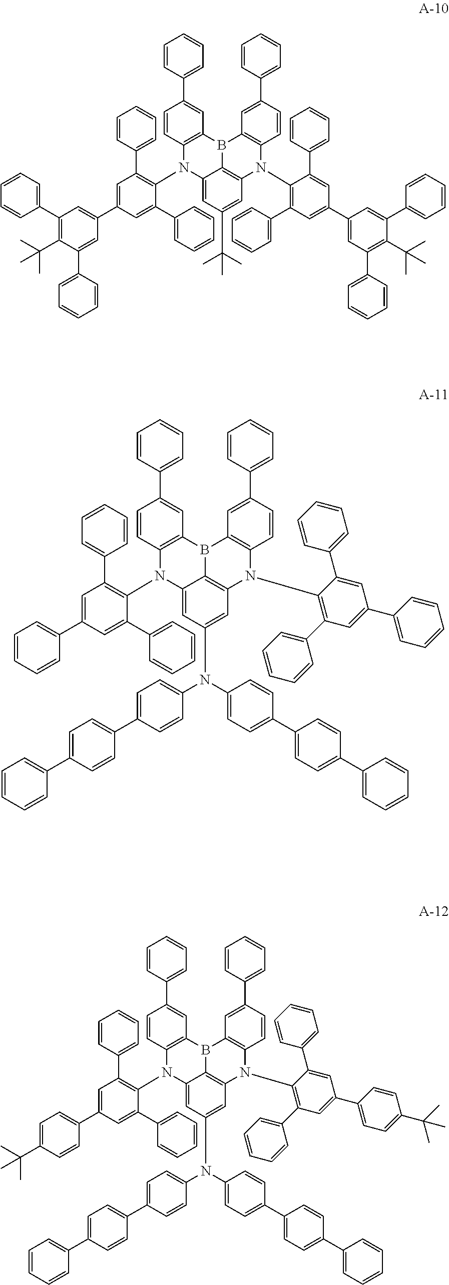

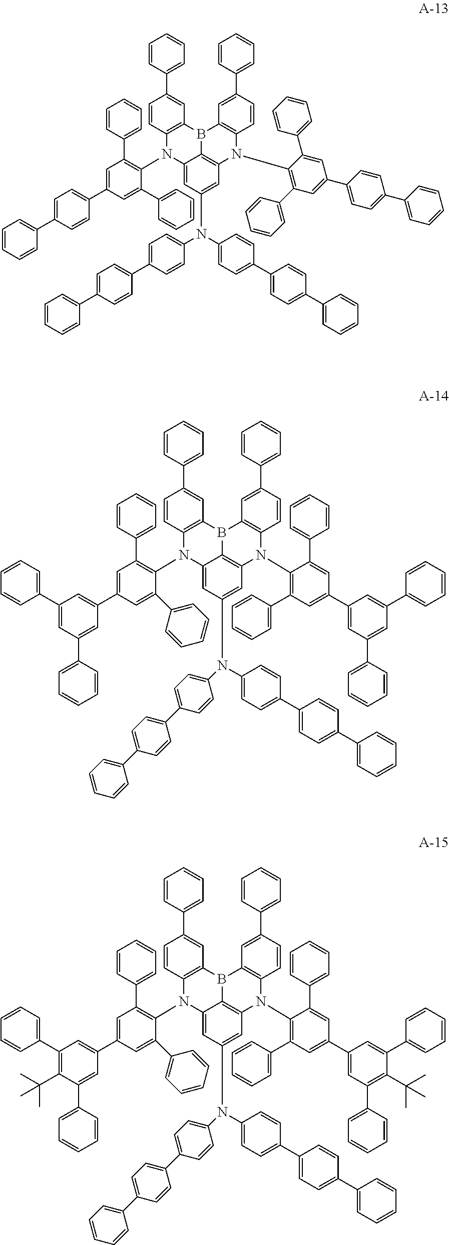

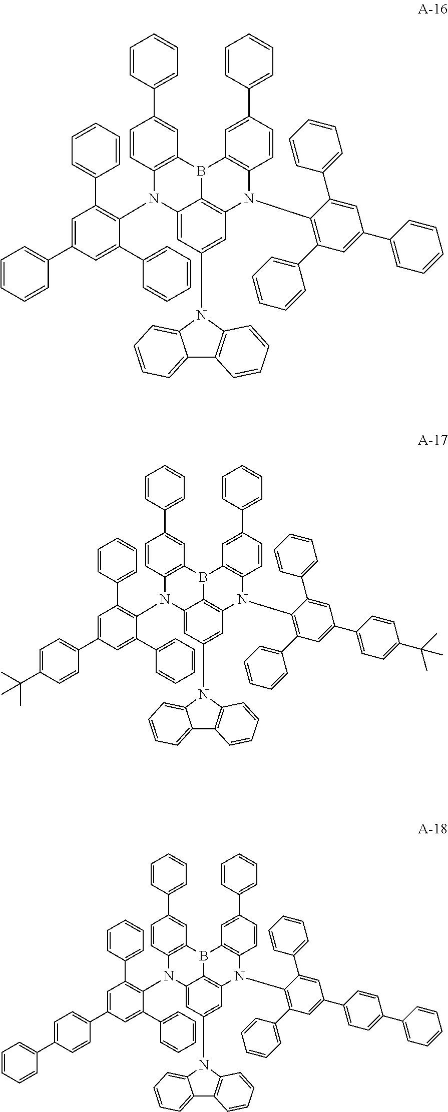

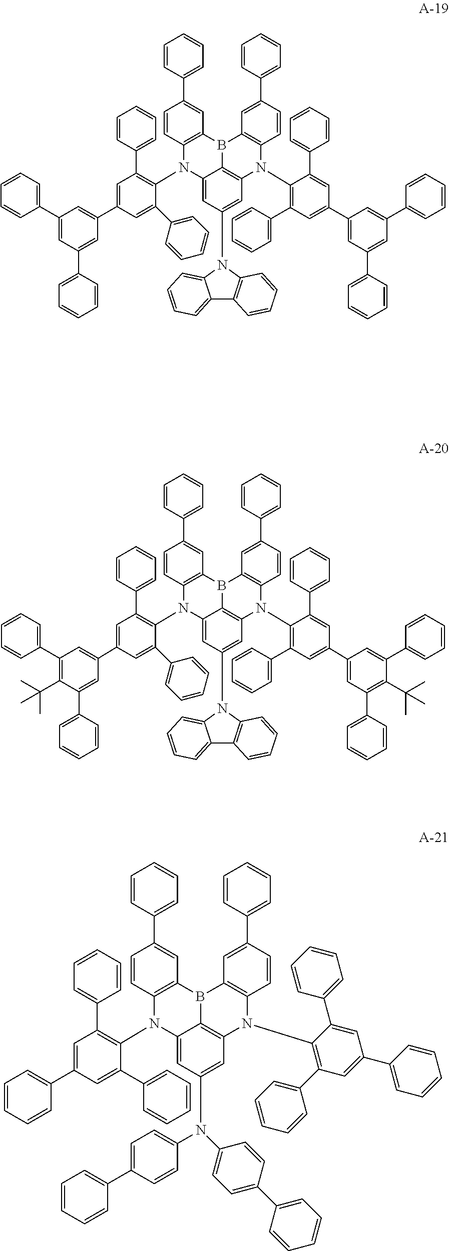

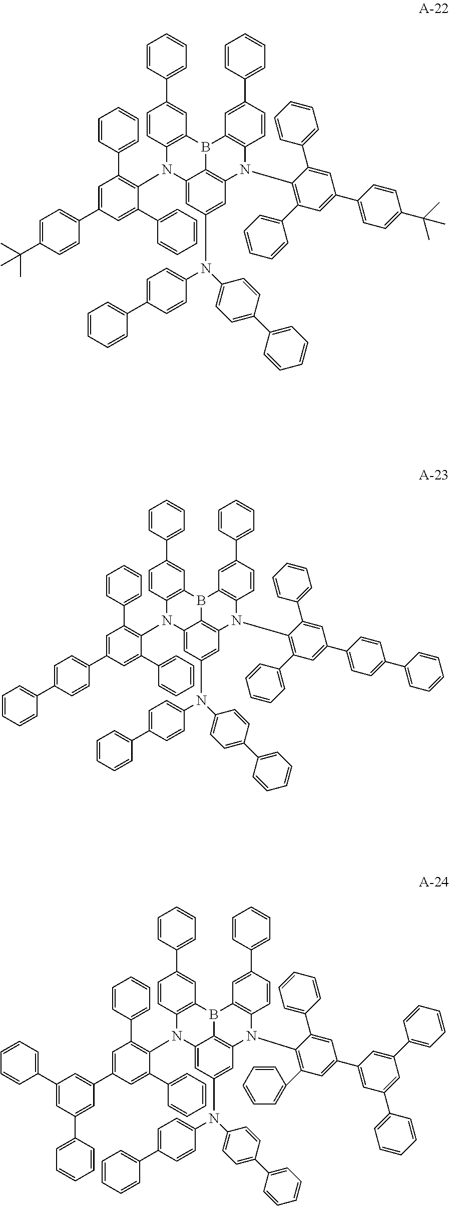

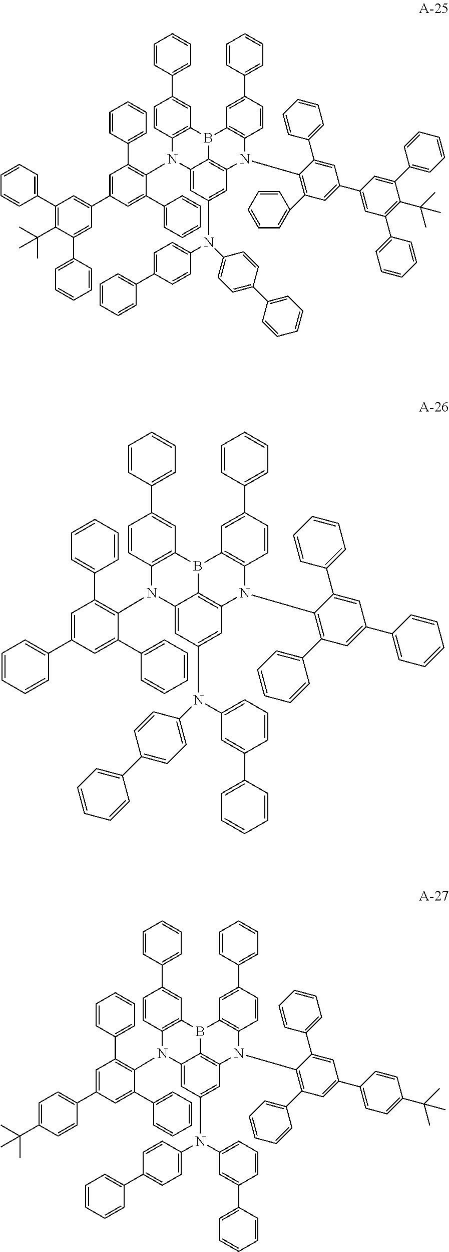

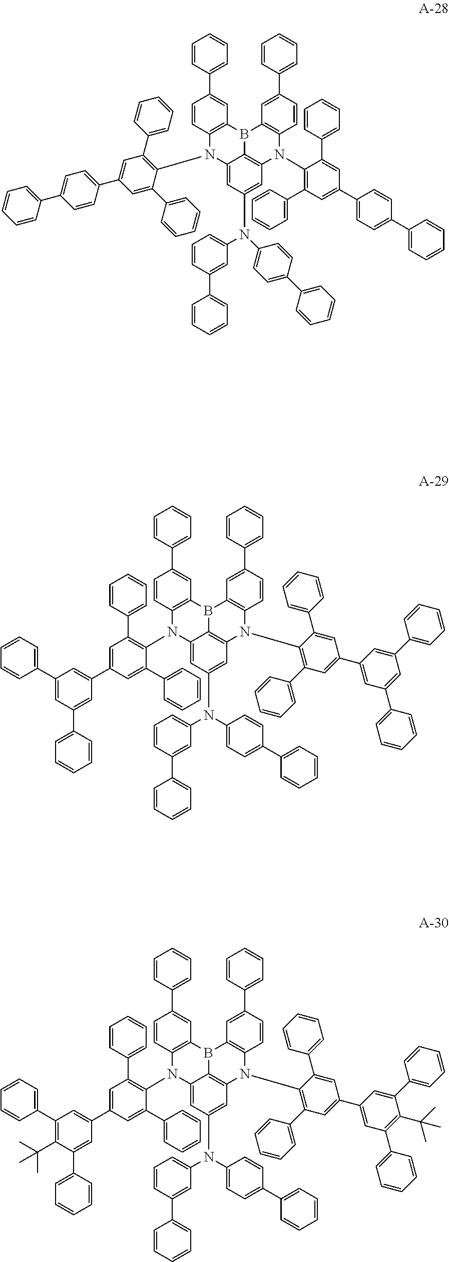

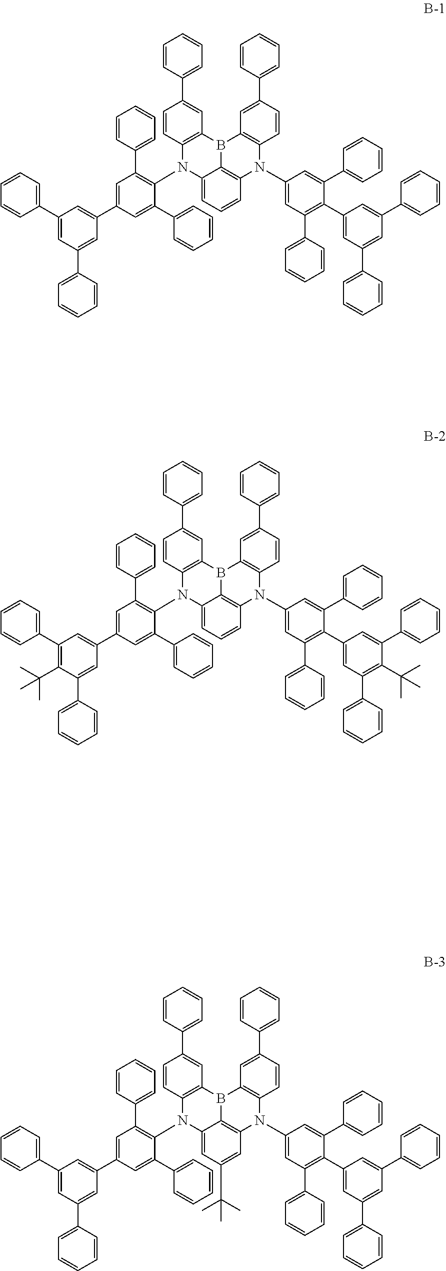

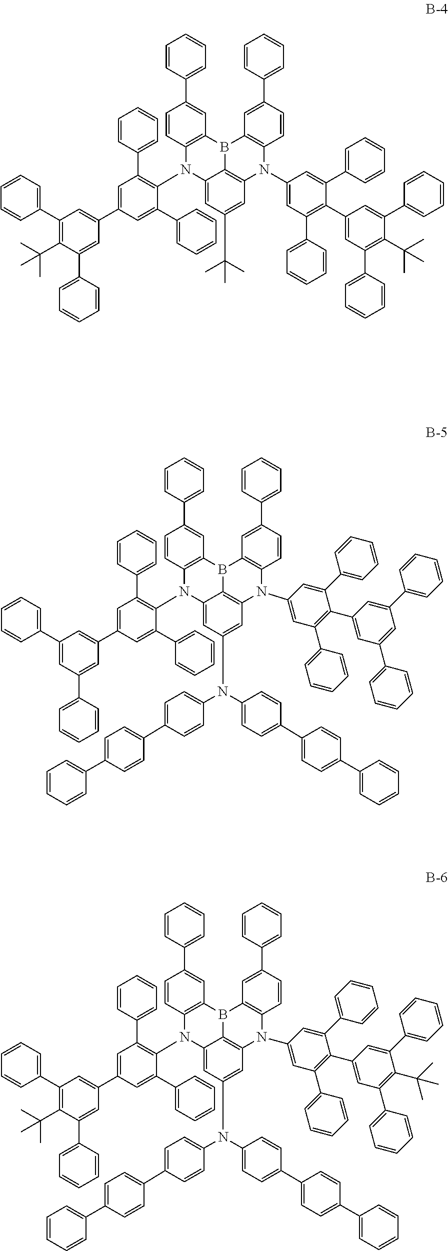

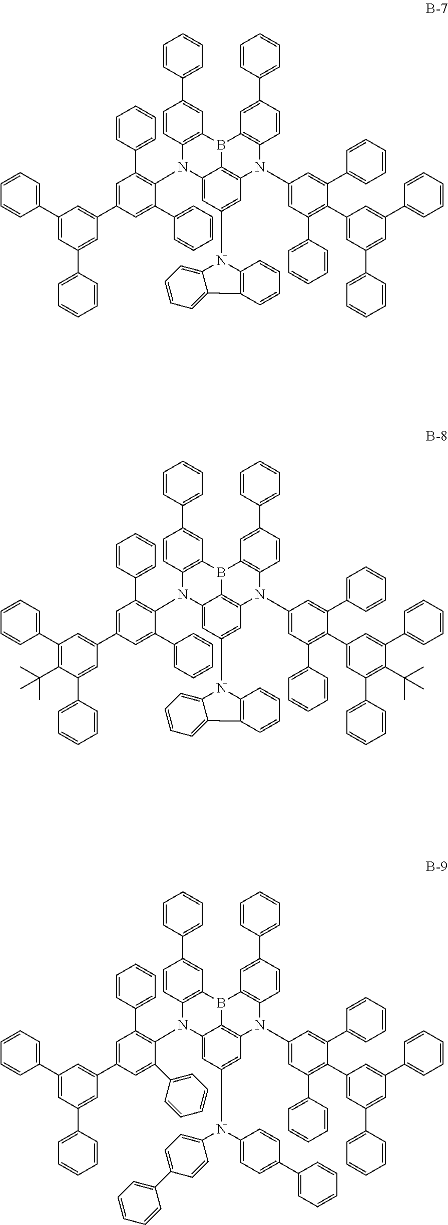

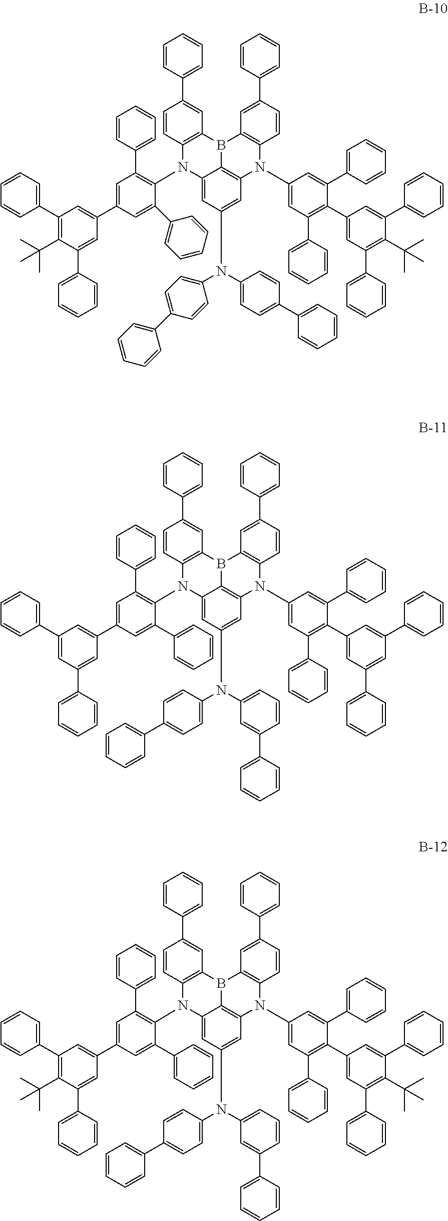

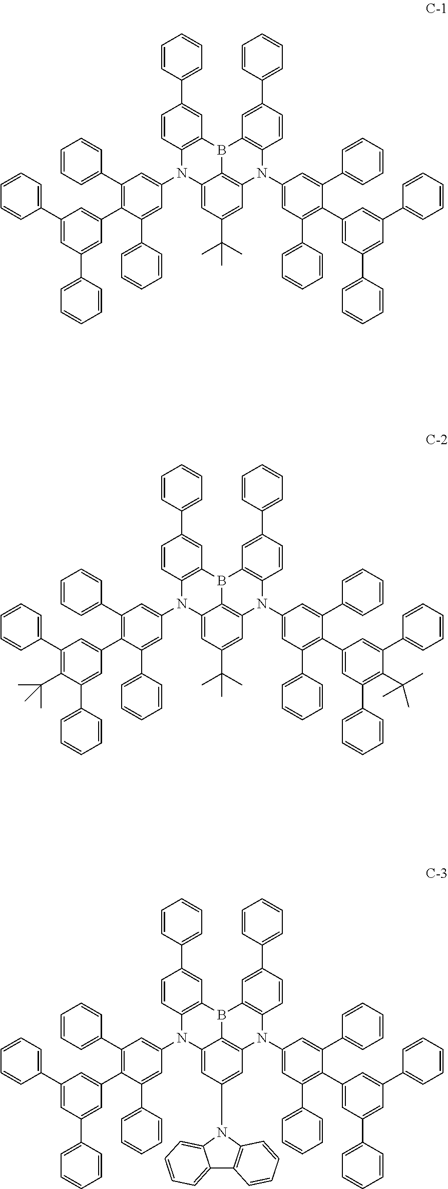

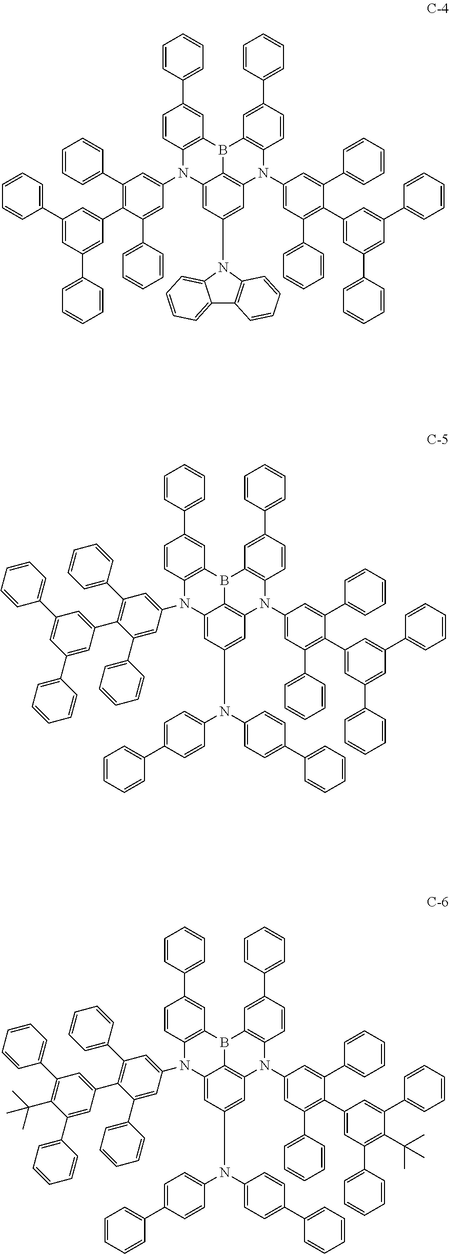

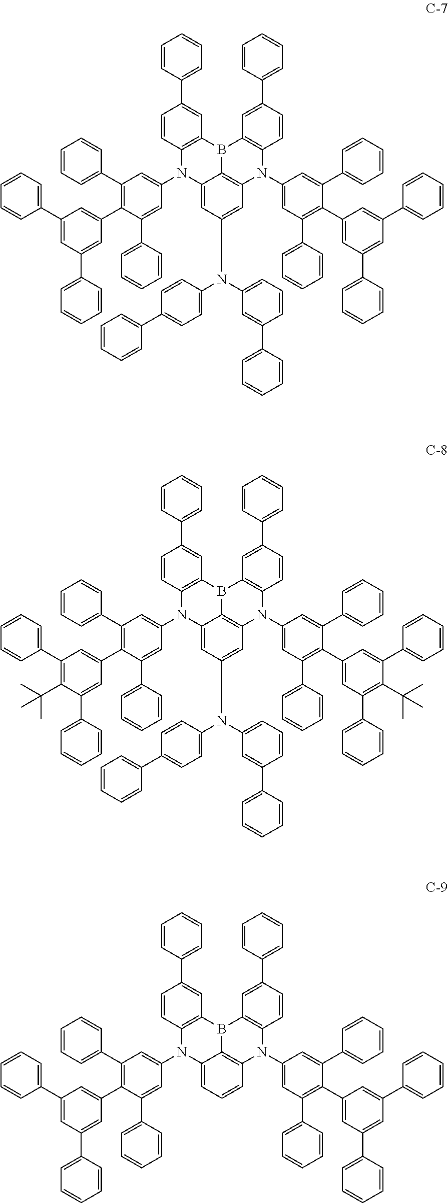

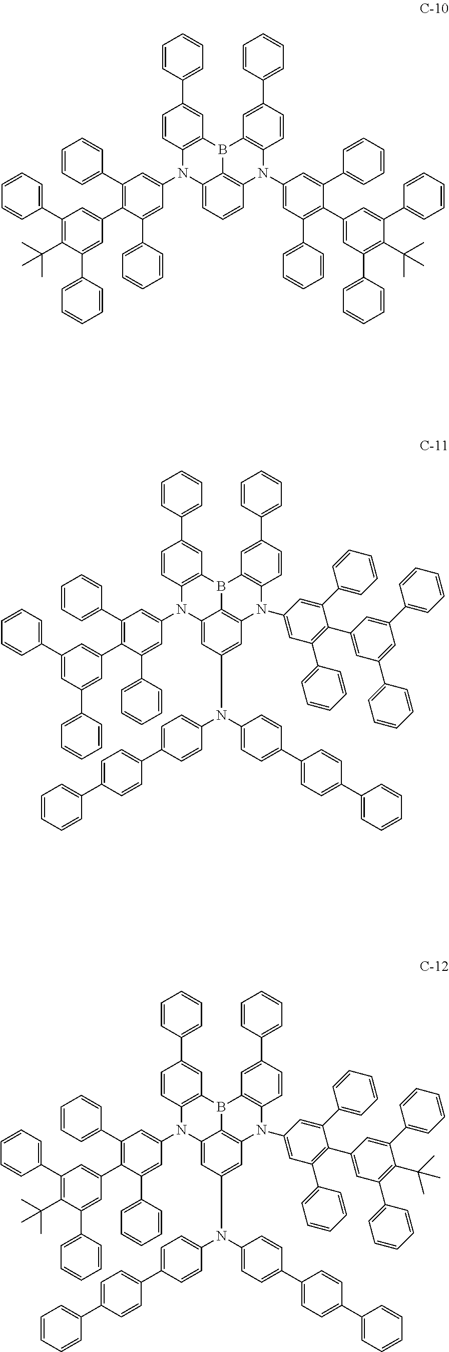

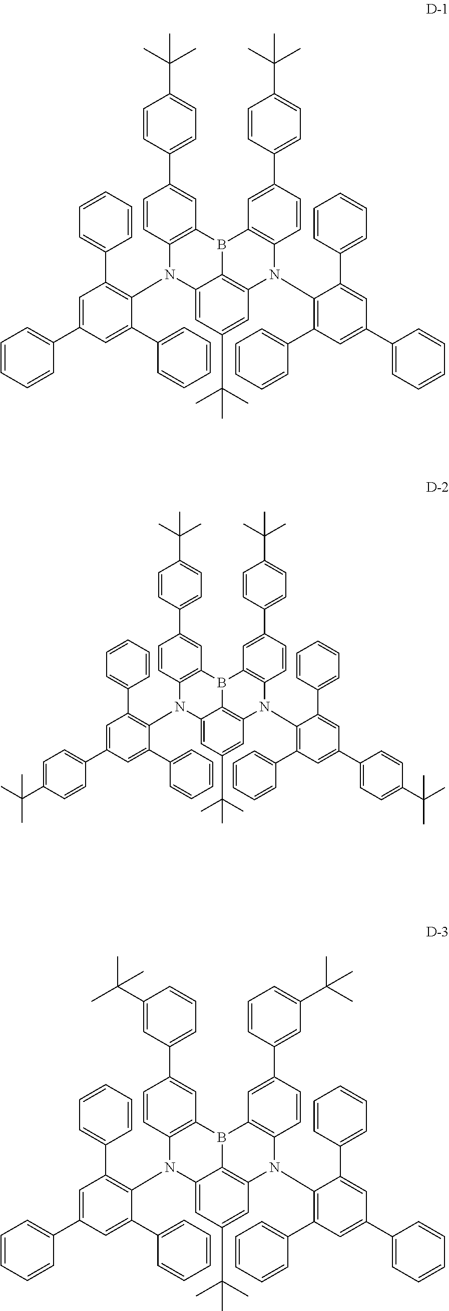

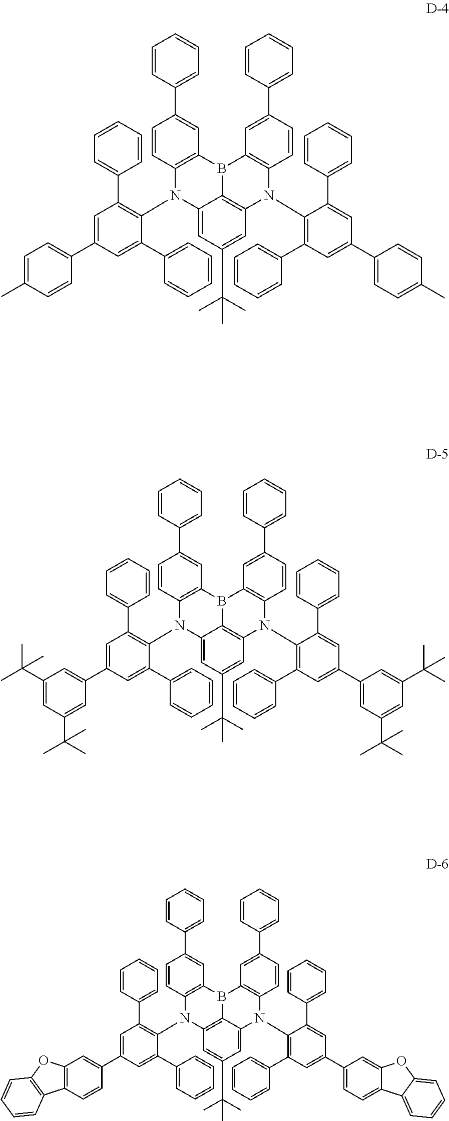

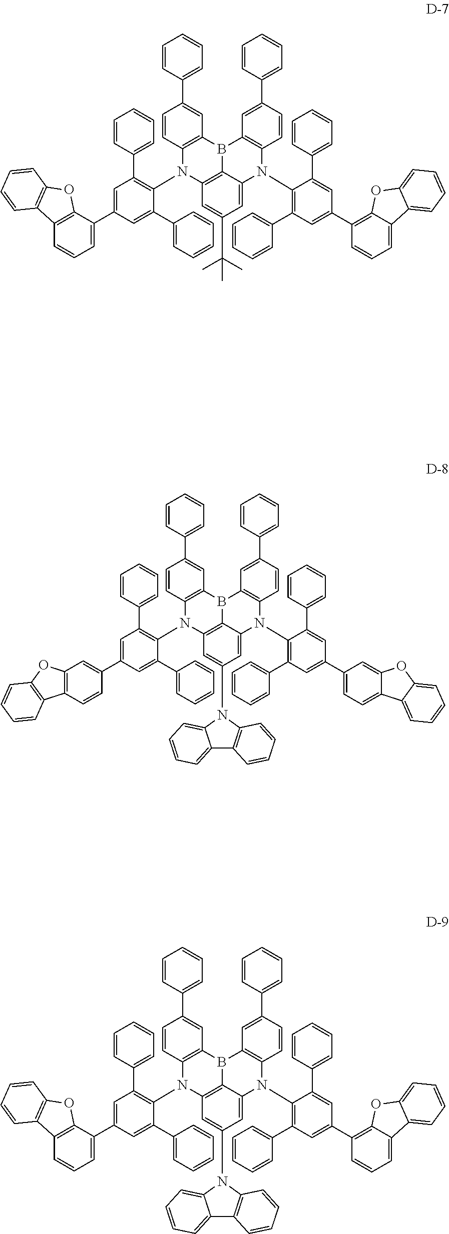

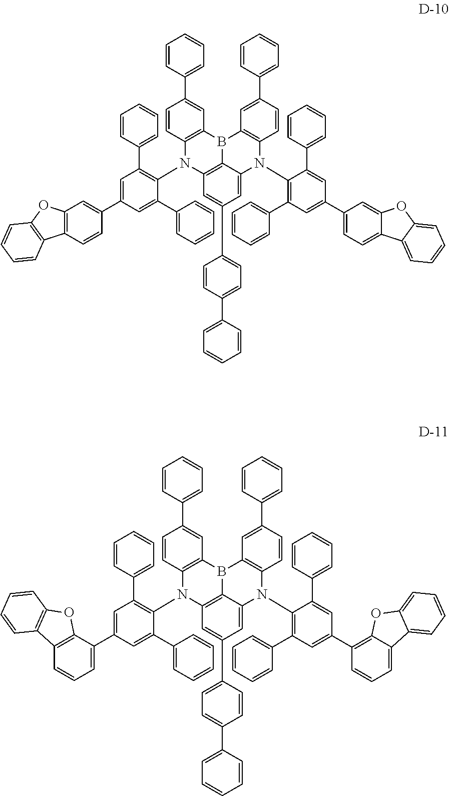 [SMILES: c1ccc(-c2ccc(-c3cc4c5c(c3)N(c3c(-c6ccccc6)cc(-c6ccc7c(c6)oc6ccccc67)cc3-c3ccccc3)c3ccc(-c6ccccc6)cc3B5c3cc(-c5ccccc5)ccc3N4c3c(-c4ccccc4)cc(-c4ccc5c(c4)oc4ccccc45)cc3-c3ccccc3)cc2)cc1 ; c1ccc(-c2ccc(-c3cc4c5c(c3)N(c3c(-c6ccccc6)cc(-c6cccc7c6oc6ccccc67)cc3-c3ccccc3)c3ccc(-c6ccccc6)cc3B5c3cc(-c5ccccc5)ccc3N4c3c(-c4ccccc4)cc(-c4cccc5c4oc4ccccc45)cc3-c3ccccc3)cc2)cc1]

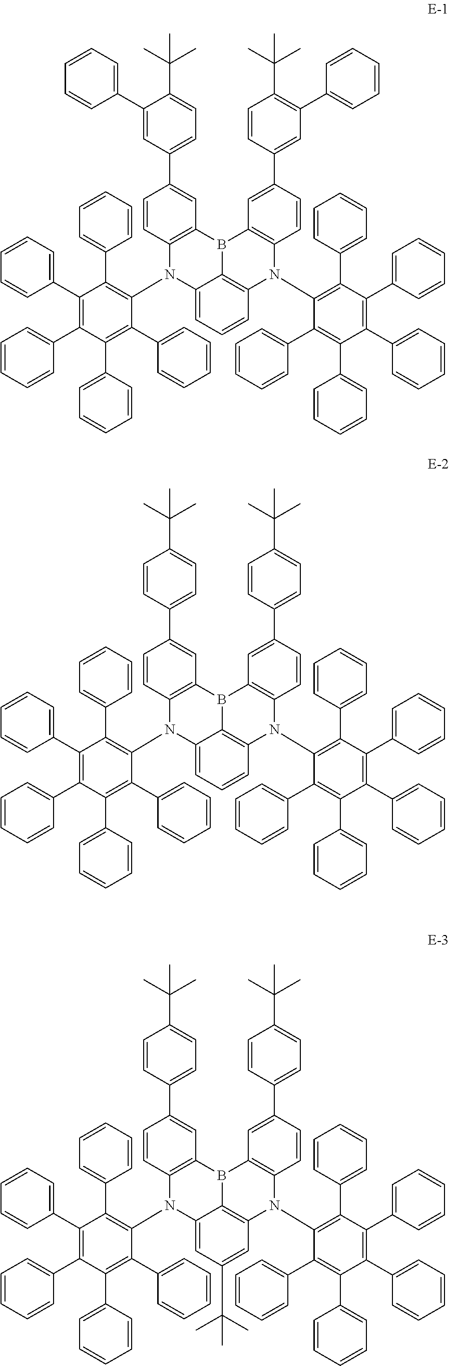

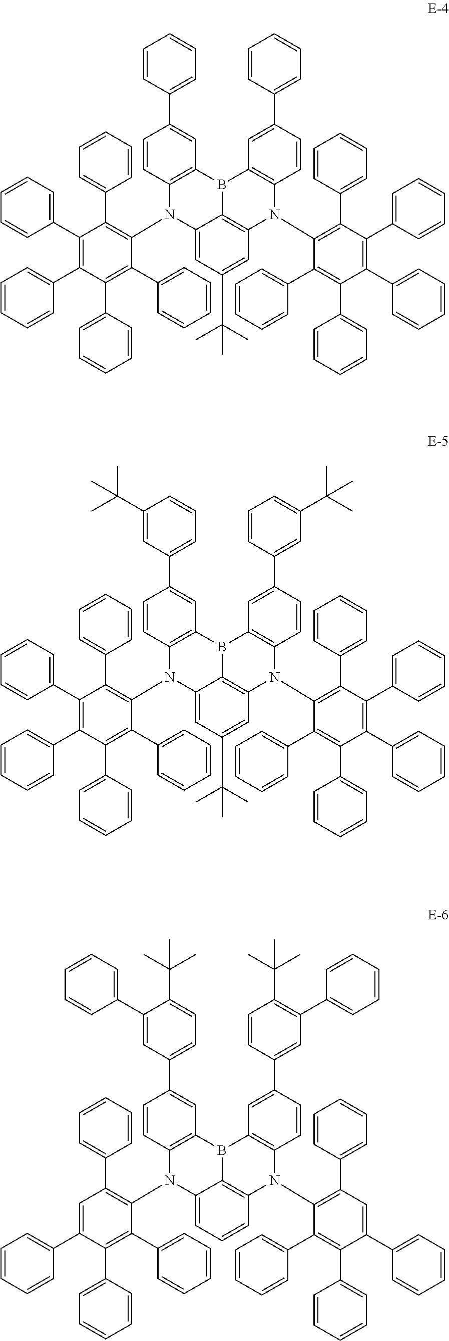

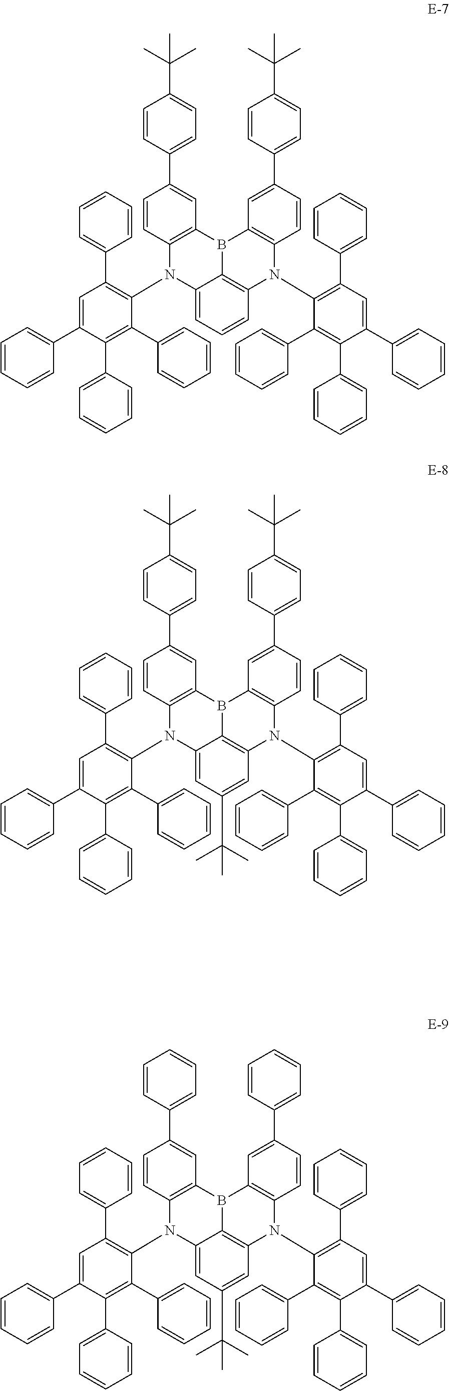

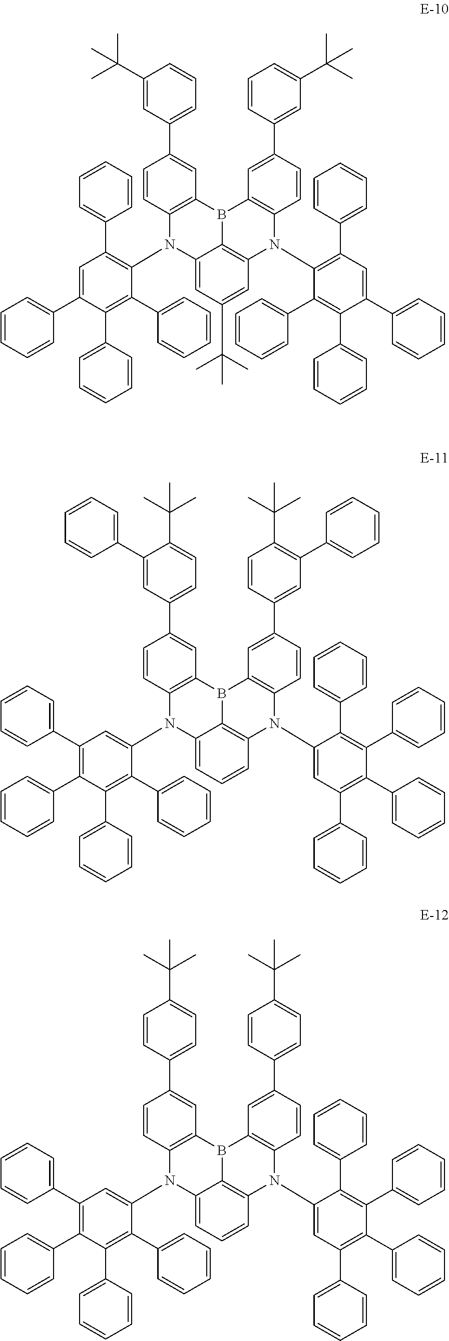

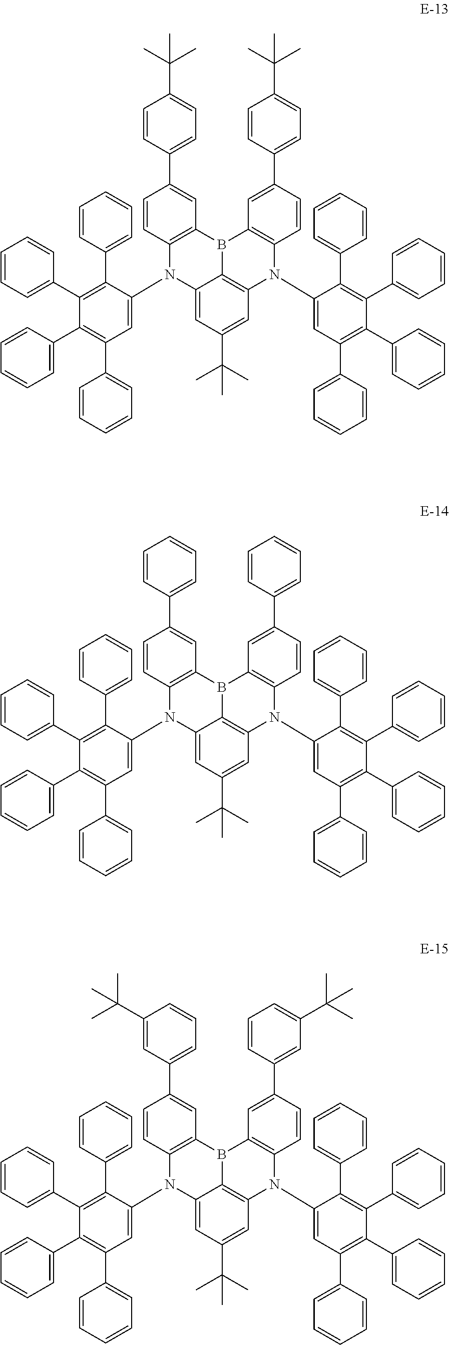

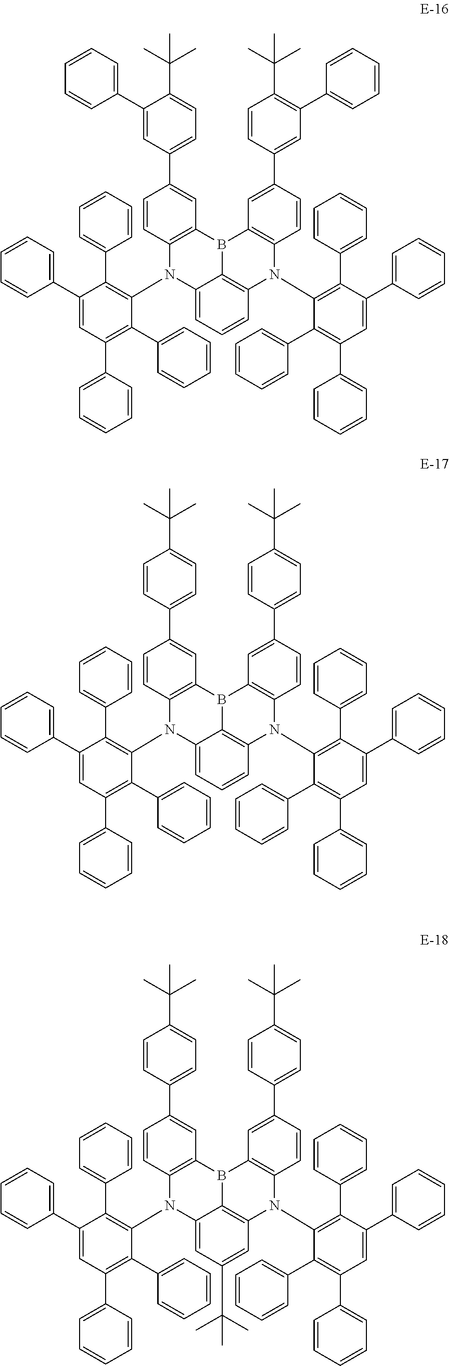

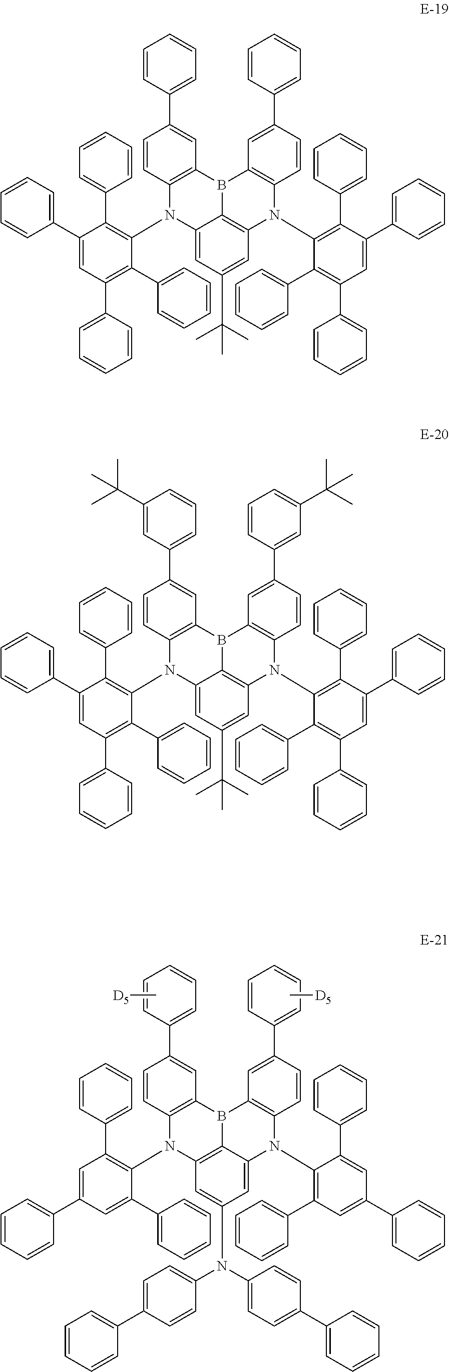

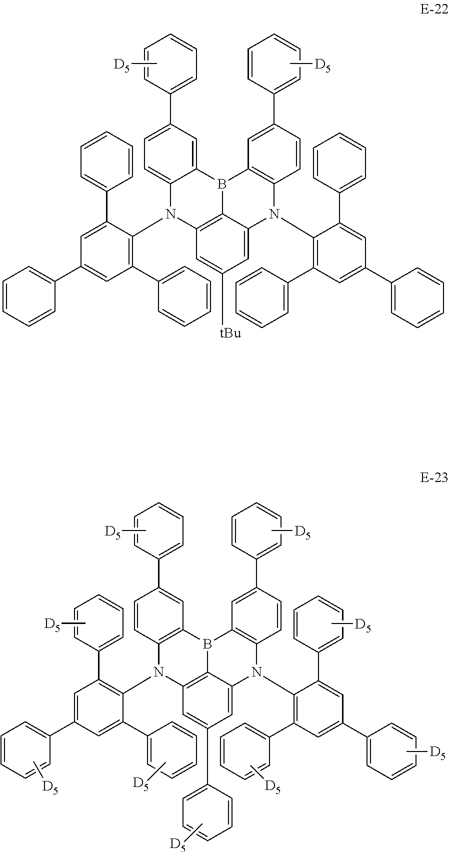

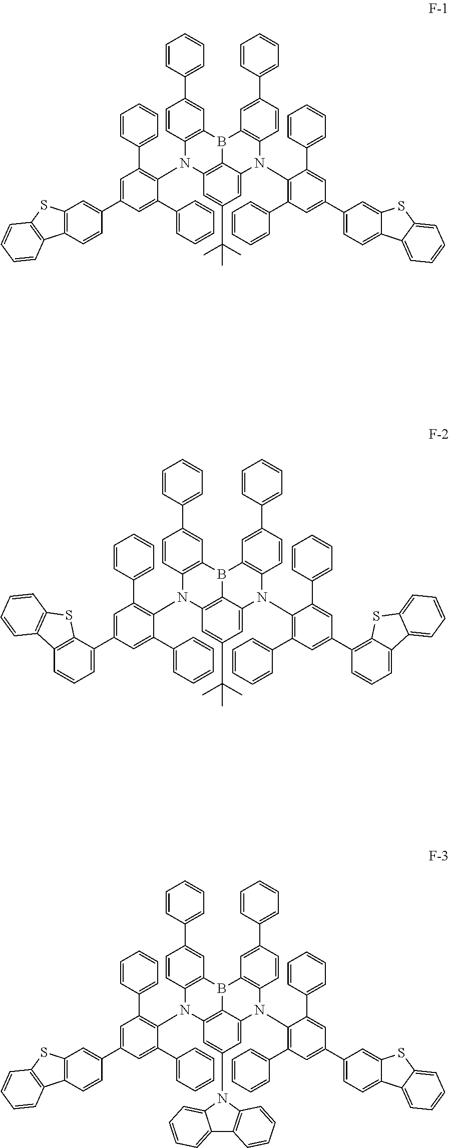

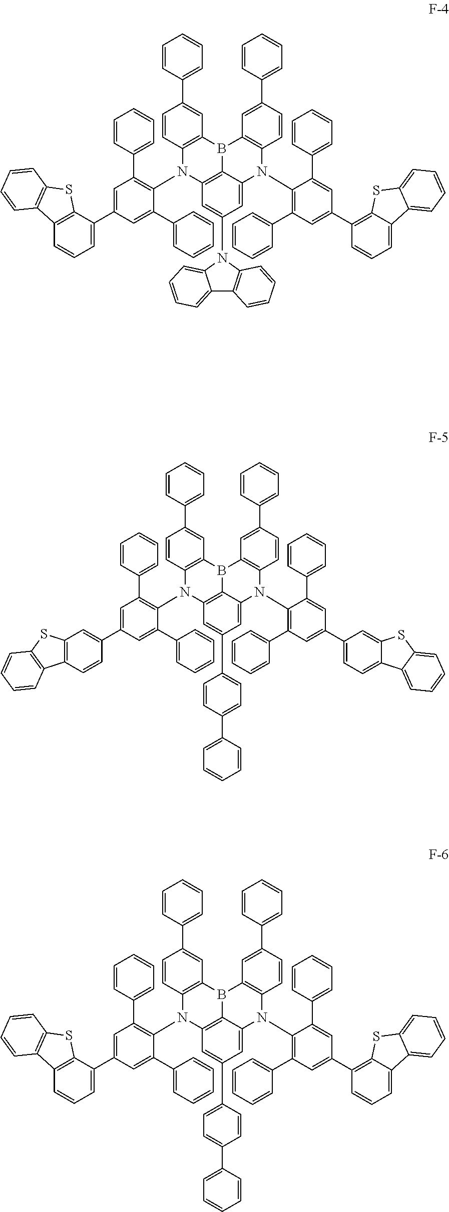

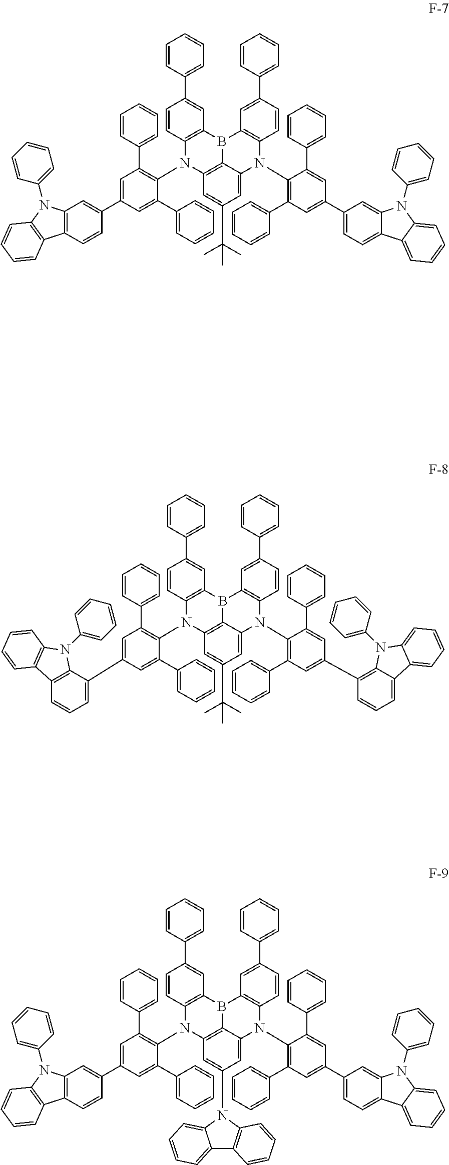

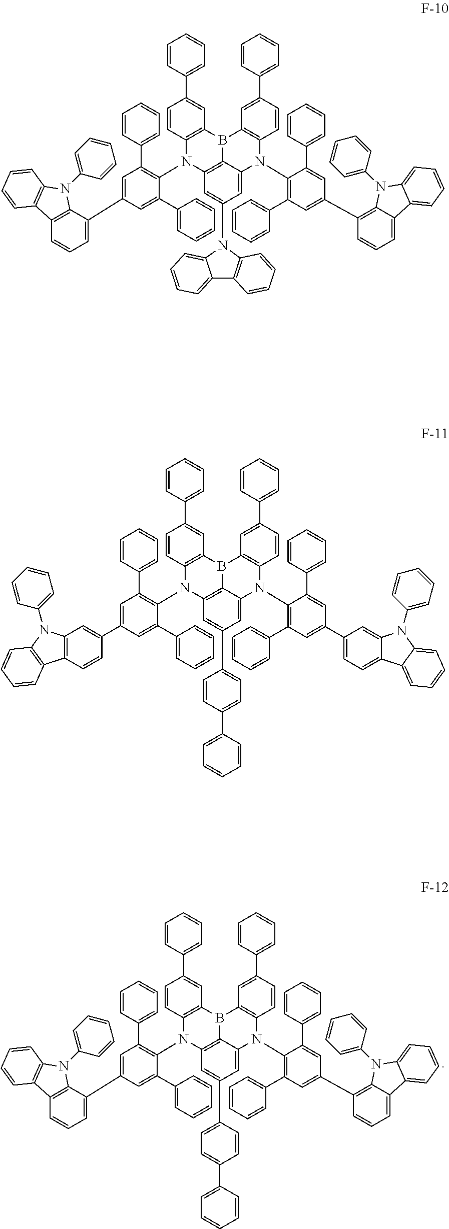

The polycyclic compound of one or more embodiments may include a fused ring core part including one boron atom and two nitrogen atoms as ring-forming atoms, and may include a plurality of substituted or unsubstituted phenyl groups in first and second benzene rings connected with the nitrogen atoms of the core part. In the polycyclic compound of one or more embodiments, a plurality of substituted or unsubstituted phenyl groups may be connected with the first benzene ring or the second benzene ring, or with both the first and second benzene rings. In one or more embodiments of the present disclosure, a plurality of substituted or unsubstituted phenyl groups may include substituents of a dibenzoheterole skeleton such as a substituted or unsubstituted dibenzofuranyl group, a substituted or unsubstituted dibenzothiophenyl group or a substituted or unsubstituted carbazole group.

The polycyclic compound of one or more embodiments introduces a plurality of substituted or unsubstituted phenyl groups in each benzene ring connected with the nitrogen atom of the core part to improve resonance stability, and sterically protect the boron atom of the core part to contribute to the improvement of the emission efficiency and lifetime of a light emitting element, if applied as a light-emitting material.

In one or more embodiments, an emission layer EML may include a host and a dopant. The polycyclic compound of one or more embodiments may be used as the dopant material of the emission layer EML. The polycyclic compound of one or more embodiments may be a thermally activated delayed fluorescence light-emitting material. The polycyclic compound of one or more embodiments may be used as a thermally activated delayed fluorescence (TADF) dopant. For example, in the light emitting element ED of one or more embodiments, the emission layer EML may include at least one selected from among the polycyclic compounds represented in Compound Group 1 as a thermally activated delayed fluorescence dopant. However, the use of the polycyclic compound of one or more embodiments is not limited thereto.

The polycyclic compound of one or more embodiments, represented by Formula 1 may be a light-emitting material having a central emission wavelength in a wavelength region of about 430 nm to about 490 nm. In one or more embodiments, the polycyclic compound of one or more embodiments may emit blue light. The polycyclic compound of one or more embodiments may be a thermally activated delayed fluorescence (TADF) dopant. The emission layer EML may include at least one selected from among the polycyclic compounds represented in Compound Group 1 as a thermally activated delayed fluorescence dopant.

In one or more embodiments, the emission layer EML includes a first compound that is the polycyclic compound of one or more embodiments, and may further include at least one selected from among second to fourth compounds. For example, the emission layer EML may include a first compound, a second compound and a third compound. In the emission layer EML, the second compound and the third compound may form exciplex, and energy transfer from the exciplex to the first compound may occur to emit light. In addition, the emission layer EML may include the first compound, the second compound, the third compound and the fourth compound. In the emission layer EML, the second compound and the third compound may form exciplex, and energy transfer from the exciplex to the fourth compound may occur to emit light. In one or more embodiments, the fourth compound may be referred to as a phosphorescence sensitizer. The fourth compound may emit phosphorescence or transfer energy to the first compound as an auxiliary dopant. However, the function of the suggested compounds is illustration, and one or more embodiments of the present disclosure are not limited thereto.

In the light emitting element ED of one or more embodiments, the emission layer EML may include the first compound that emits delayed fluorescence, the second compound and the third compound, that are two different hosts, and the fourth compound including an organometallic complex, concurrently (e.g., simultaneously), and may show excellent emission efficiency properties.

In one or more embodiments, the second compound may include a substituted or unsubstituted carbazole. The third compound may include a hexagonal ring including at least one nitrogen atom as a ring-forming atom. The fourth compound may be an organometallic complex compound. The fourth compound may be an organometallic complex compound including platinum (Pt) as a central metal. For example, the second compound may be represented by Formula HT, and the third compound may be represented by Formula ET. The fourth compound includes platinum (Pt) as a central metal atom and may be represented by Formula PS.

In one or more embodiments, the second compound may be used as a hole transport host material in an emission layer EML.

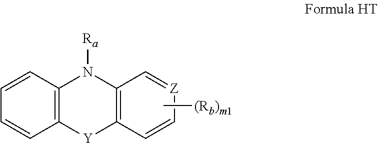

In Formula HT, m1 may be an integer of 0 to 7. If m1 is an integer of 2 or more, a plurality of R_{b} may be all the same, or at least one may be different. Rₐ and R_{b} may be each independently a hydrogen atom, a deuterium atom, a cyano group, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, Rₐ may be a substituted phenyl group, an unsubstituted dibenzofuran group, or a substituted fluorenyl group. R_{b} may be a hydrogen atom, a deuterium atom, a substituted or unsubstituted phenyl group, a substituted or unsubstituted carbazole group, or a substituted fluorenyl group. In addition, adjacent two R_{b} may be combined with each other to form a substituted or unsubstituted heterocycle.

In Formula HT, Y may be a direct linkage, CR_{y1}R_{y2}, or SiR_{y3}R_{y4}. For example, if Y is the direct linkage, the second compound represented by Formula HT may include a carbazole skeleton. R_{y1} to R_{y4} may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms. For example, R_{y1} to R_{y4} may be each independently a methyl group or a phenyl group.

In Formula HT, Z may be CR_{z} or a nitrogen atom (N). For example, if Y is the direct linkage, and Z is a carbon atom, Formula HT may include a carbazole skeleton. In addition, if Y is the direct linkage, and Z is a nitrogen atom, Formula HT may include a pyridoindole skeleton. R_{z} may be a hydrogen atom or a deuterium atom.

The second compound may be represented by any one selected from among the compounds in Compound Group 2. The light emitting element ED of one or more embodiments may include any one selected from among the compounds in Compound Group 2. In Compound Group 2, “D” is a deuterium atom.

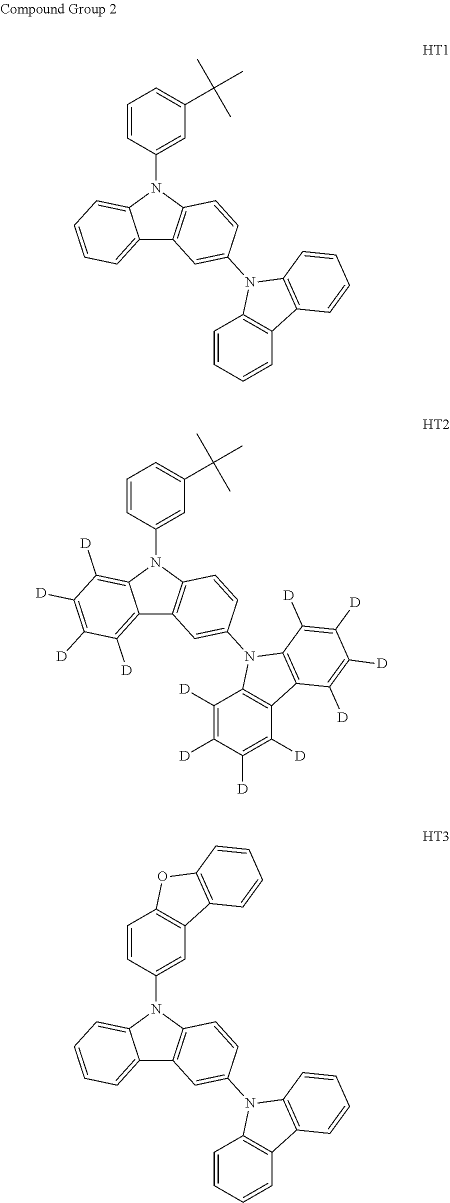 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

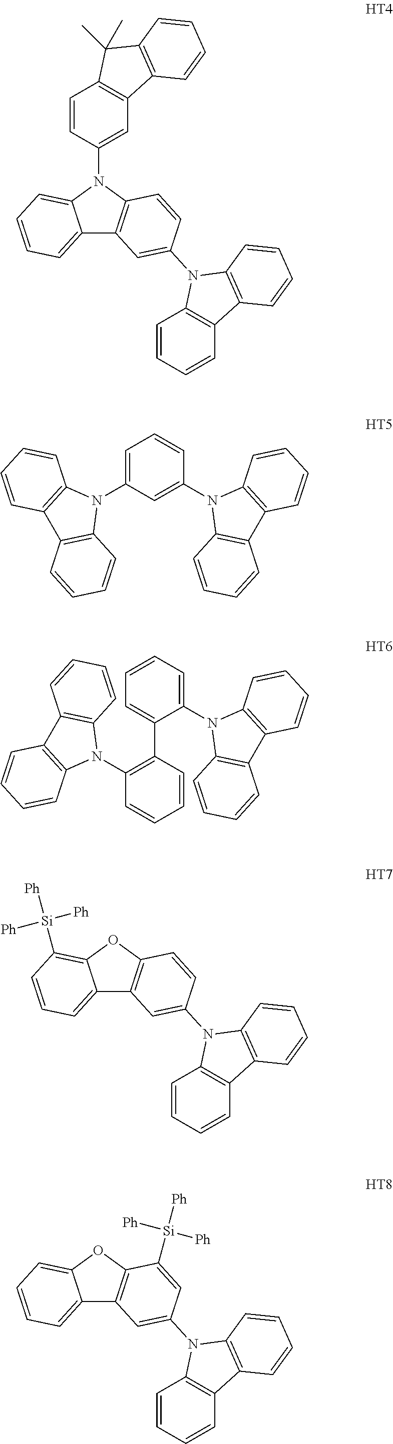 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

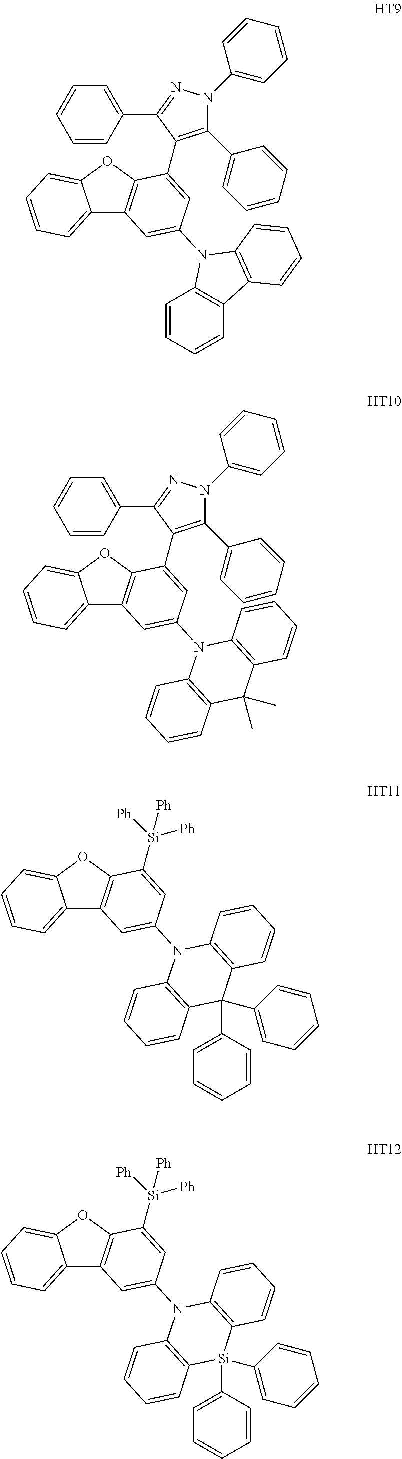 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

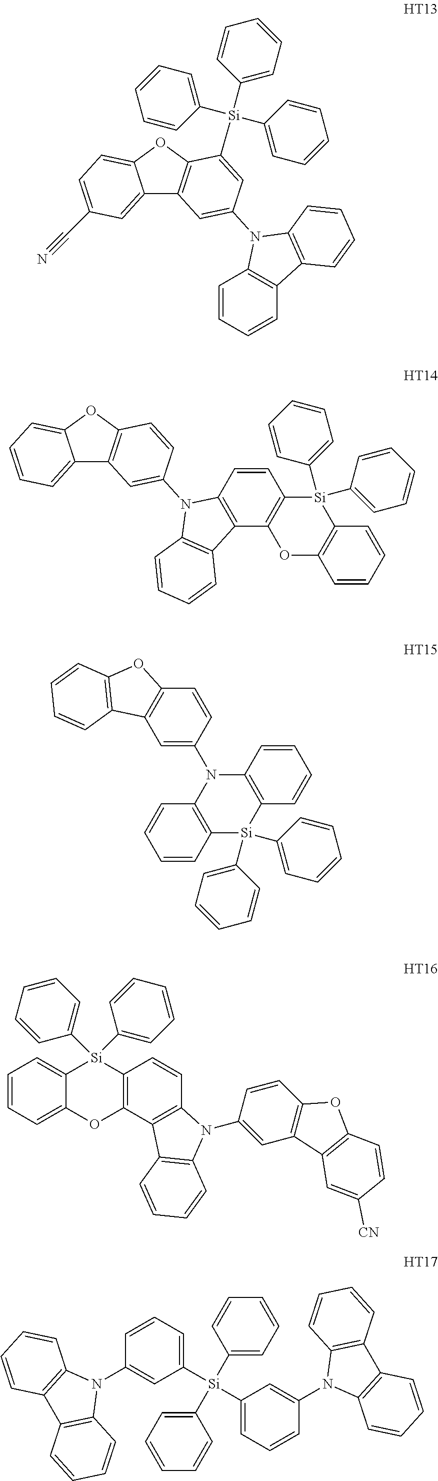 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

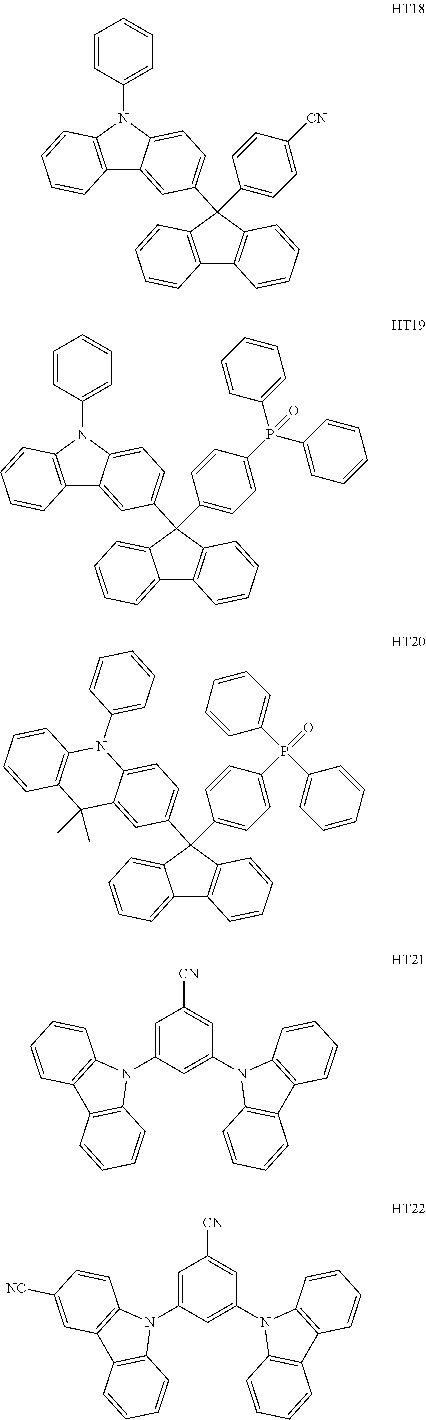 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

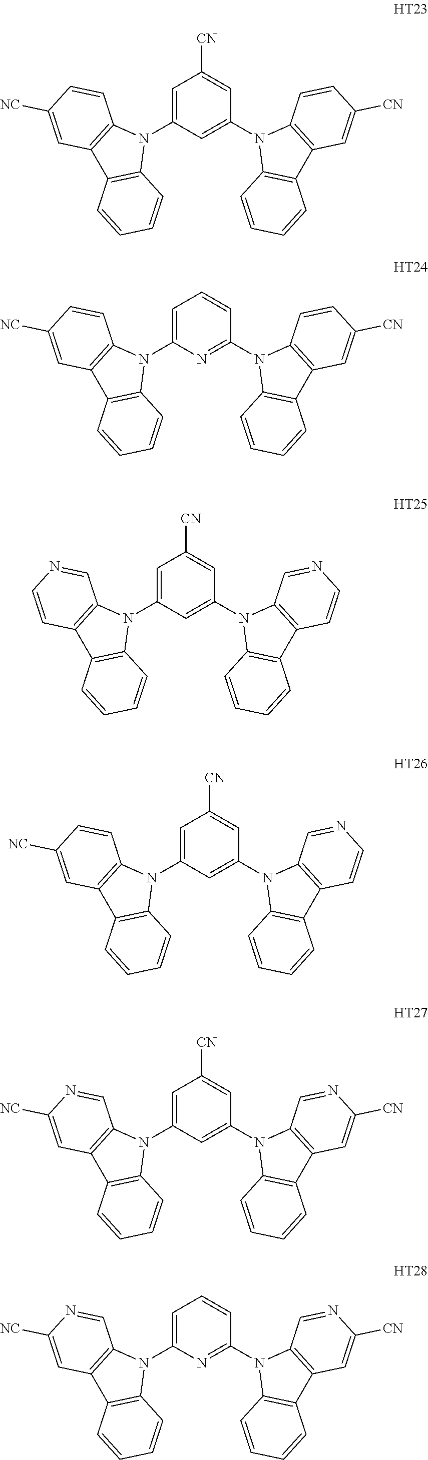 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

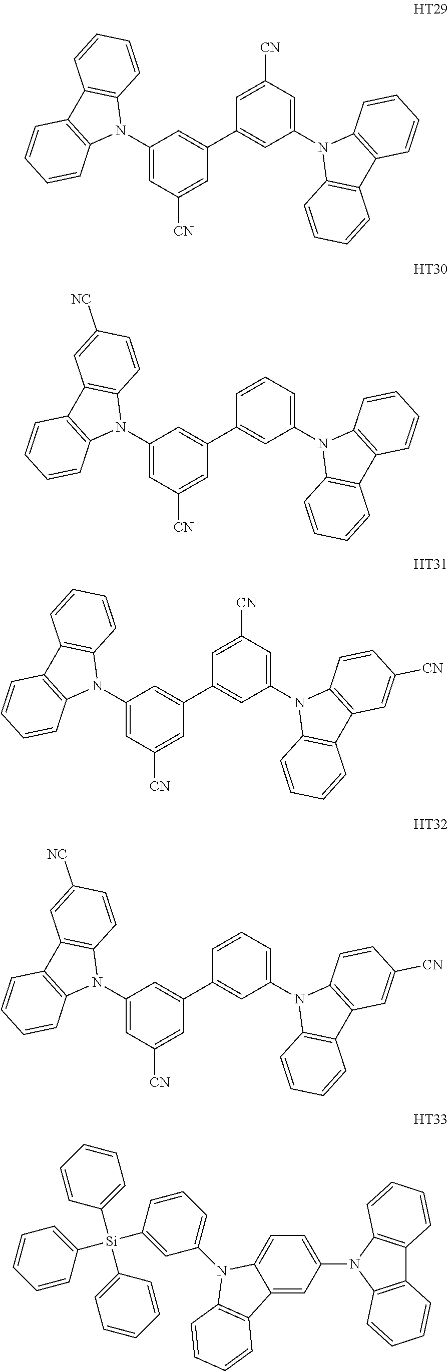 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cc(C#N)cc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

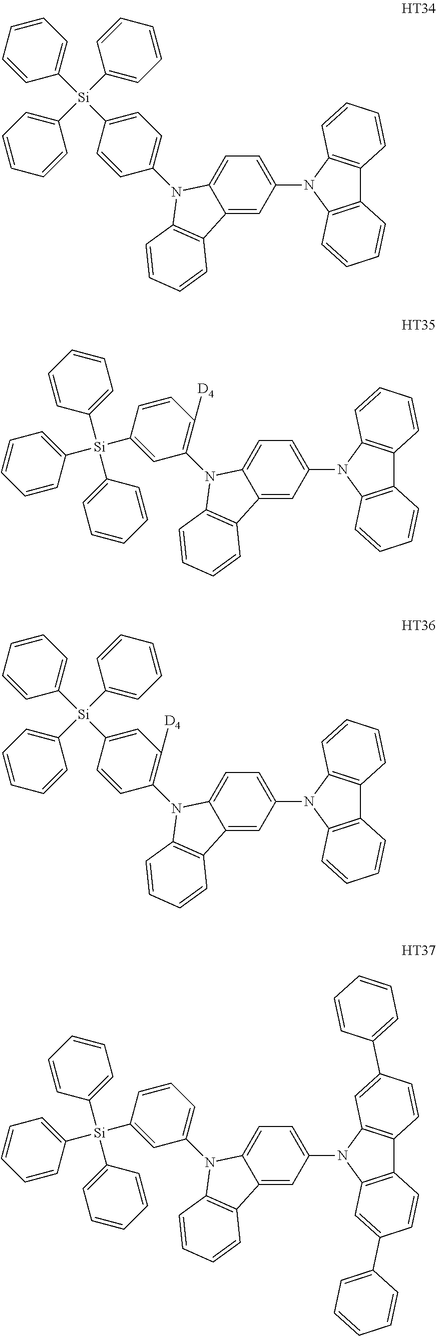

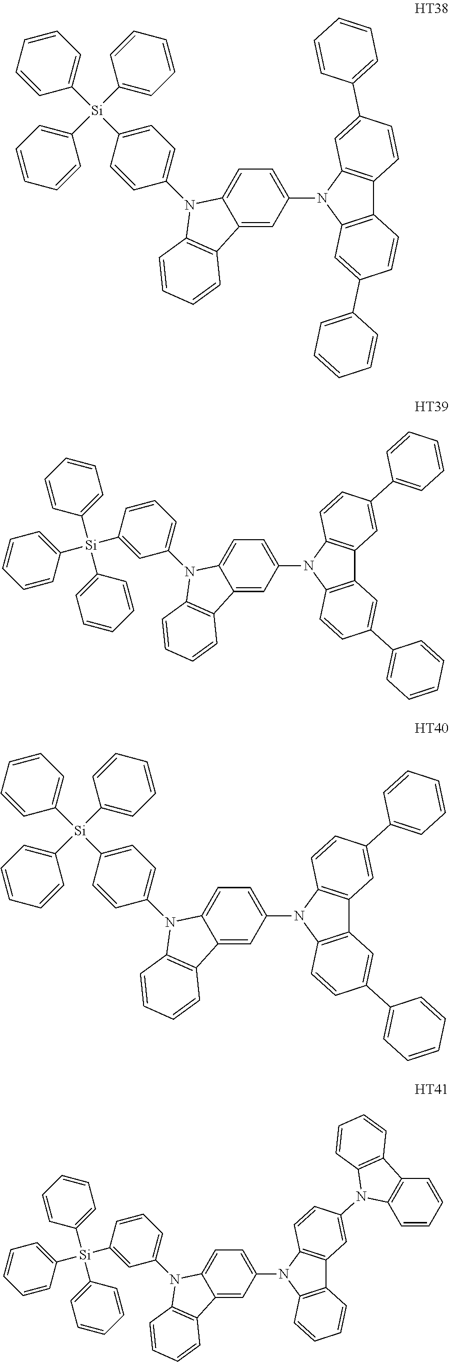 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

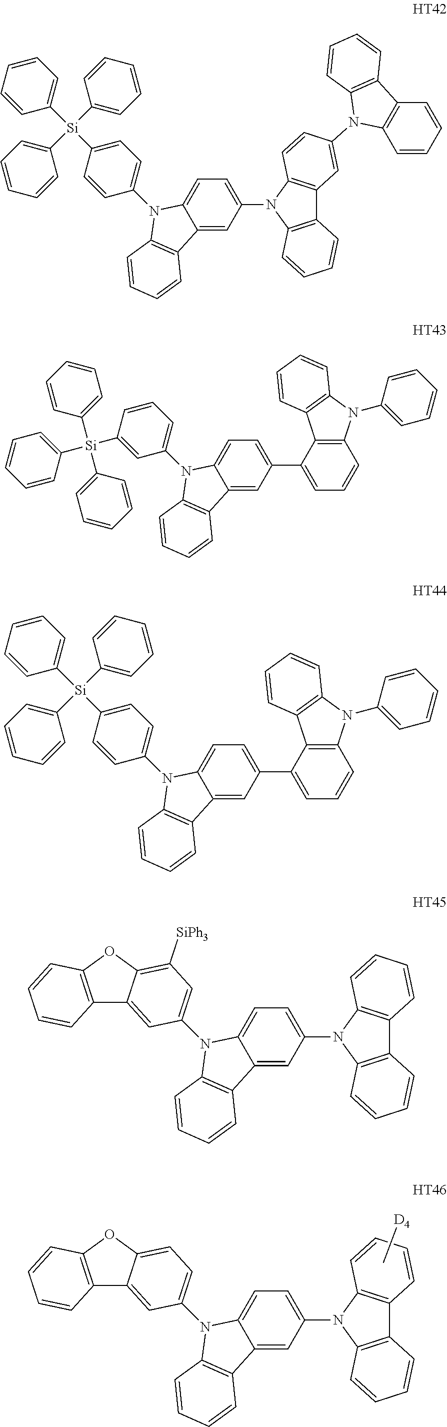

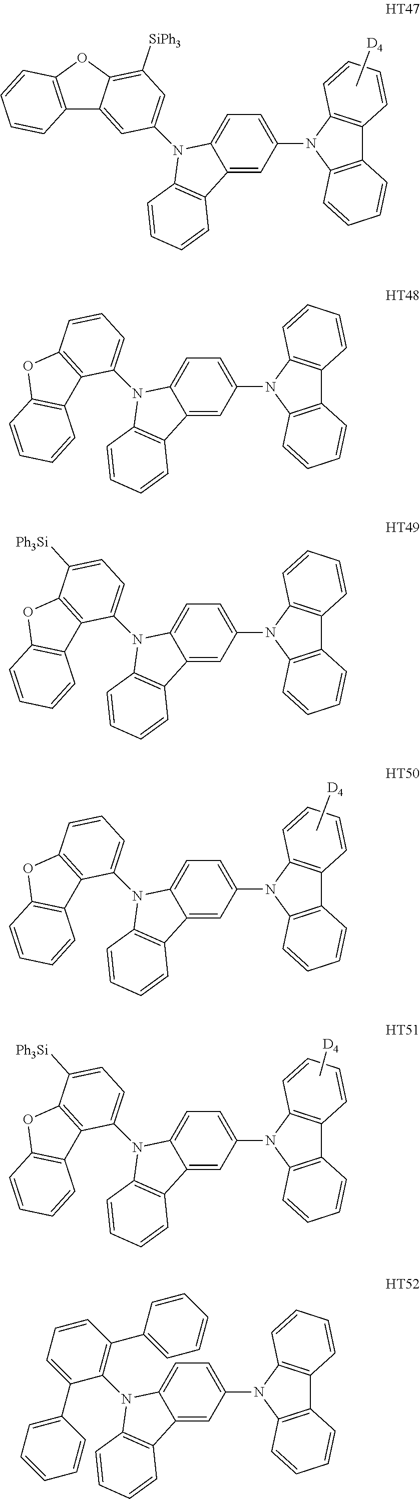

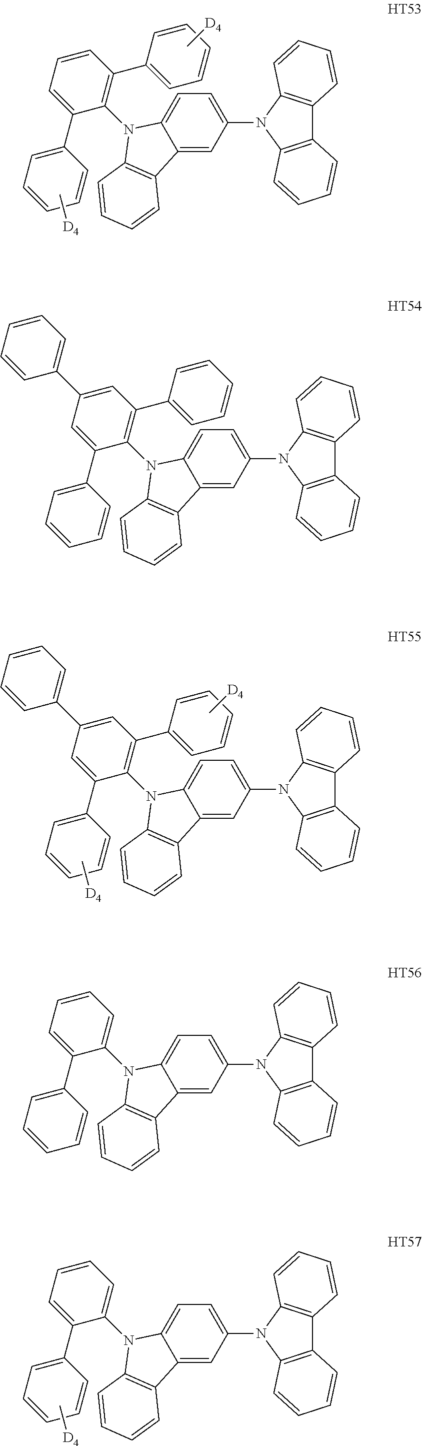

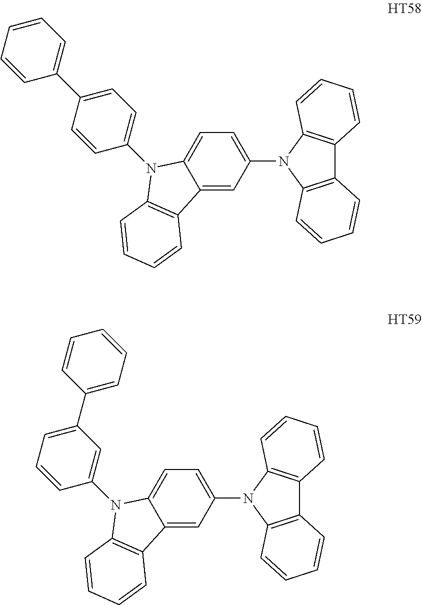 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In one or more embodiments, the emission layer EML may include a third compound represented by Formula ET below. For example, the third compound may be used as an electron transport host material in the emission layer EML.

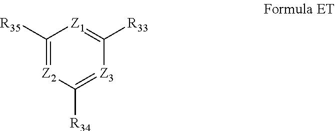

In Formula ET, Z₁ to Z₃ may be each independently N or CR₃₆, and at least one selected from among Z₁ to Z₃ may be N. For example, Z₁ to Z₃ may be all N. In addition, any two selected from among Z₁ to Z₃ may be N, and the remainder may be CR₃₆. Any one selected from among Z₁ to Z₃ may be N, and the remainder may be CR₃₆.

In Formula ET, R₃₃ to R₃₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring. For example, R₃₃ to R₃₆ may be each independently a substituted or unsubstituted phenyl group, or a substituted or unsubstituted carbazole group. However, one or more embodiments of the present disclosure are not limited thereto.

In one or more embodiments, the third compound represented by Formula 3 may be represented by any one selected from among the compounds in Compound Group 3. The emission layer EML may include at least one selected from among the compounds represented in Compound Group 3 as an electron transport host material. In Compound Group 3, “D” is a deuterium atom.

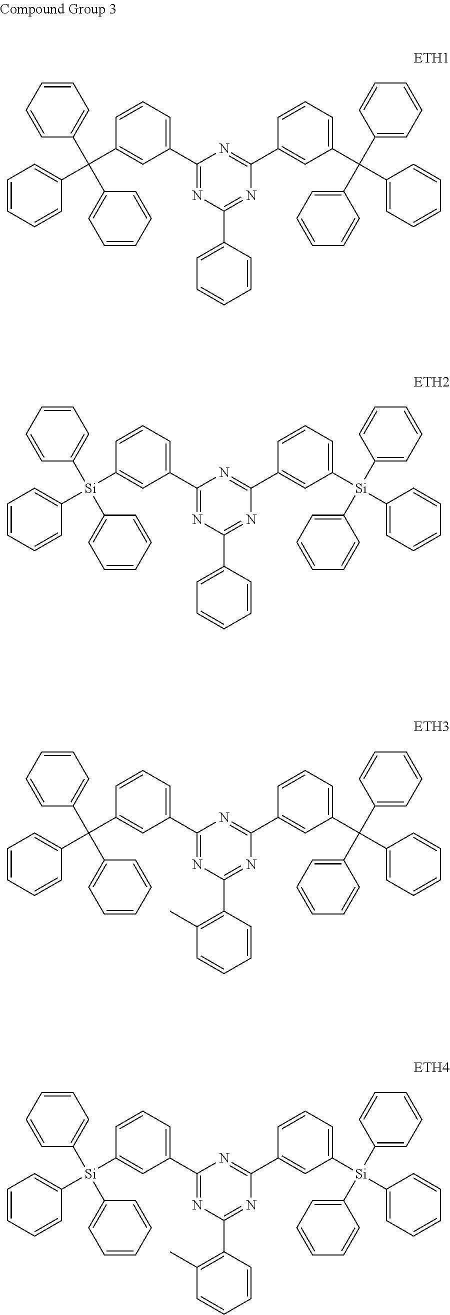 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

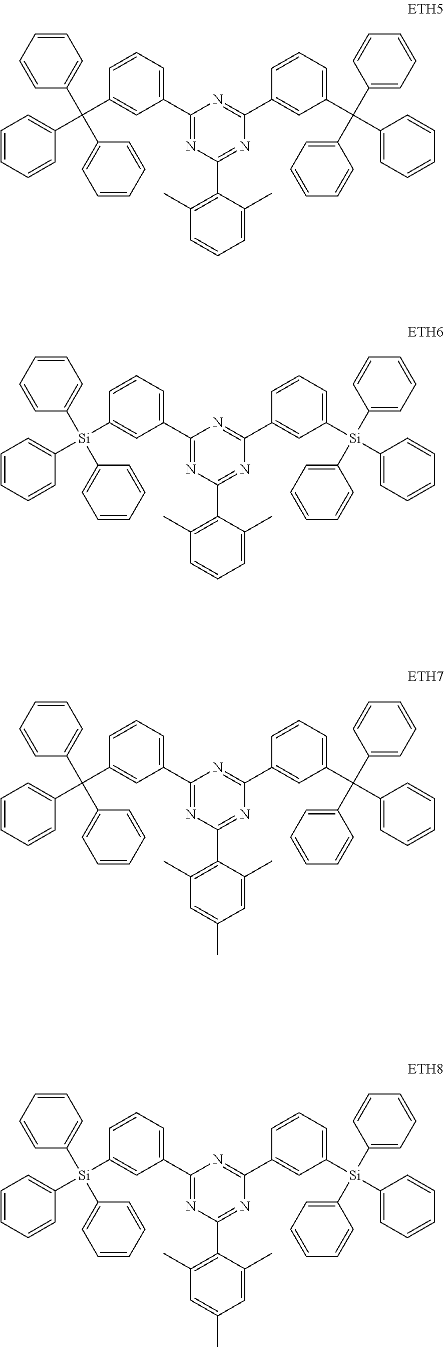 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

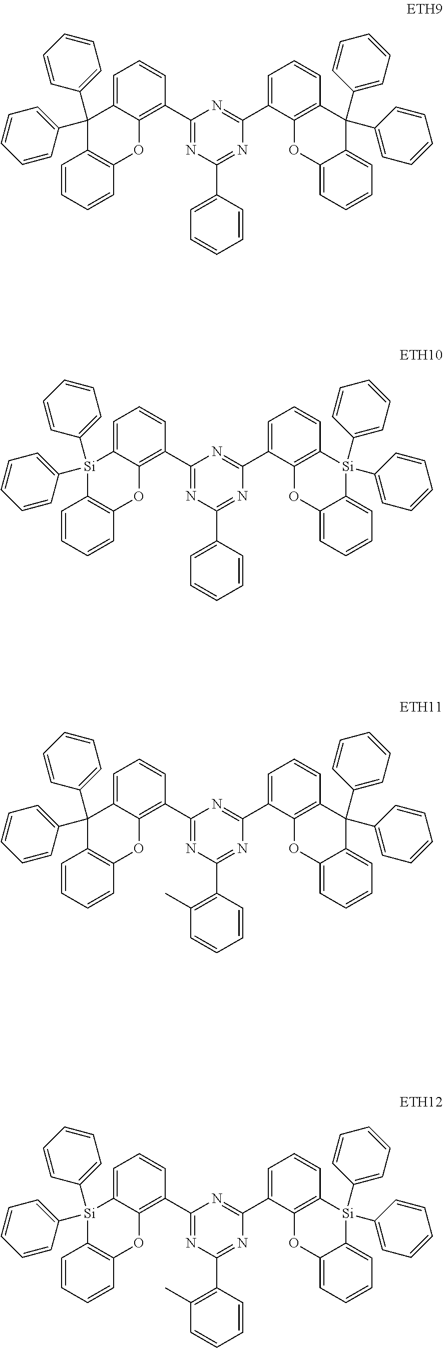 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

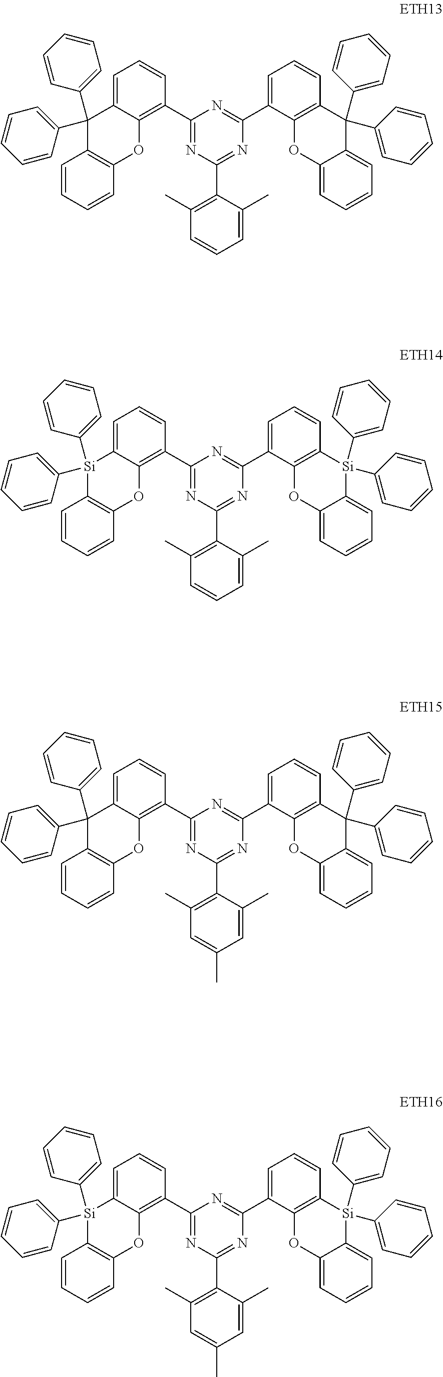 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

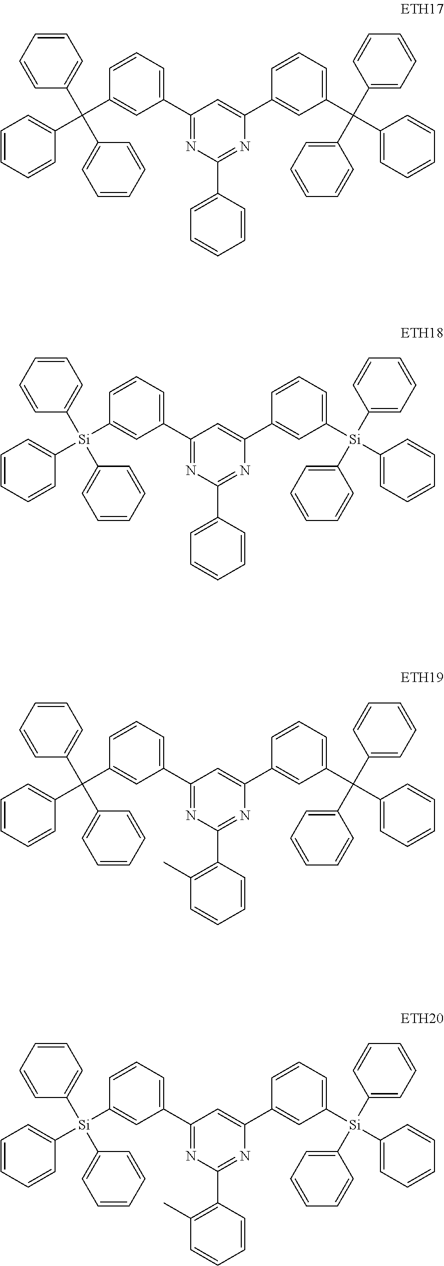 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

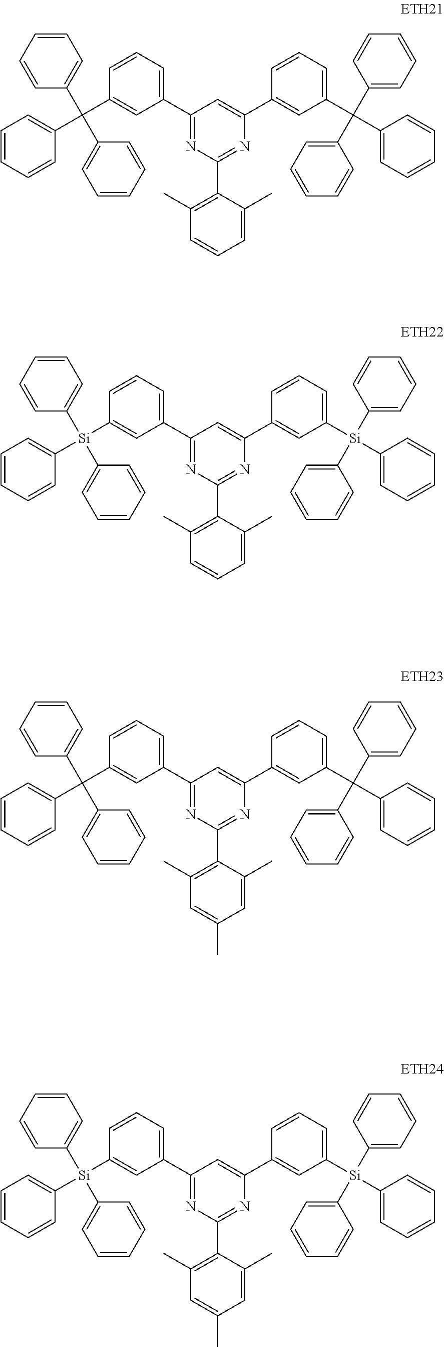 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

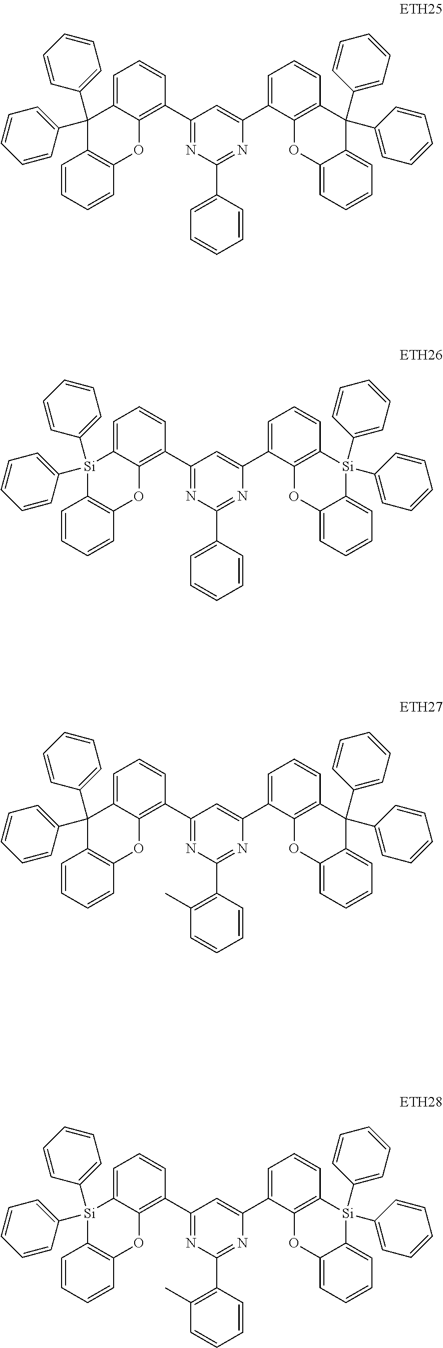 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

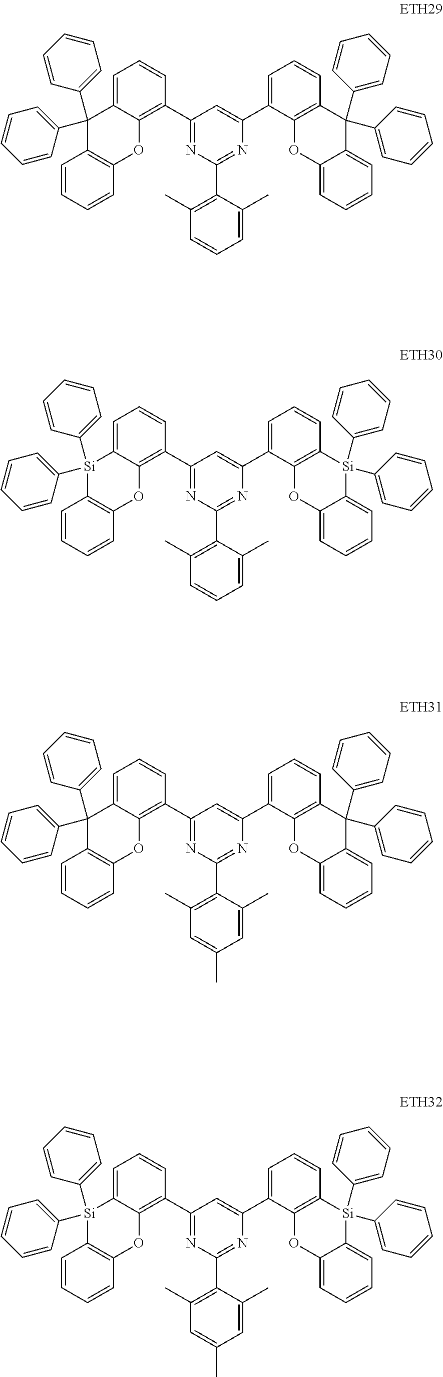 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

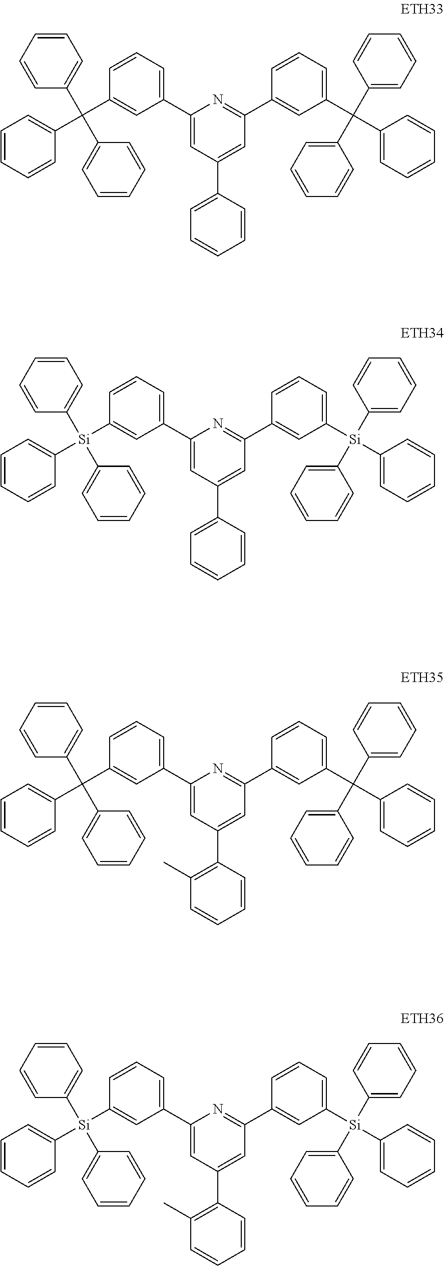 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

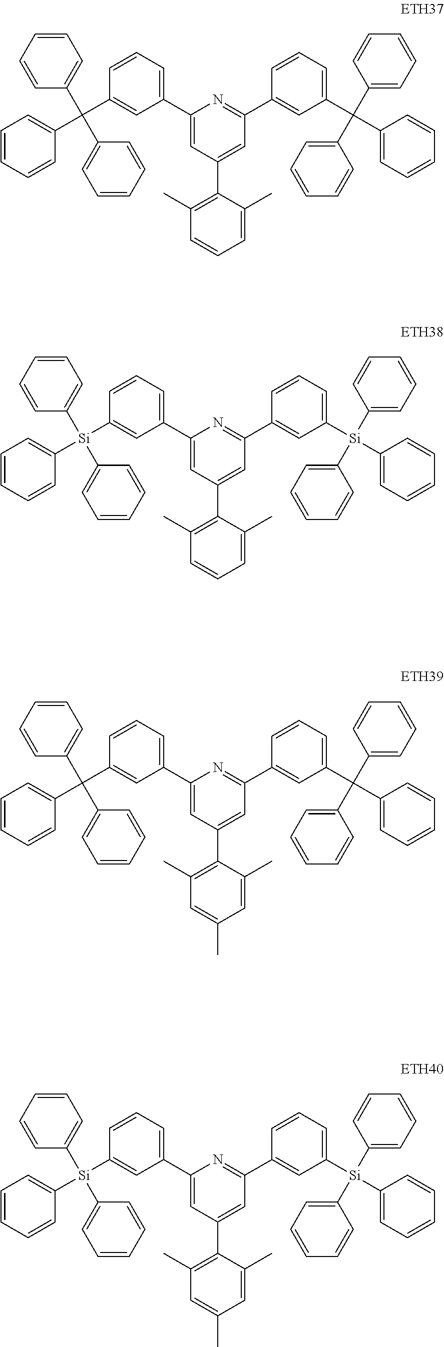 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

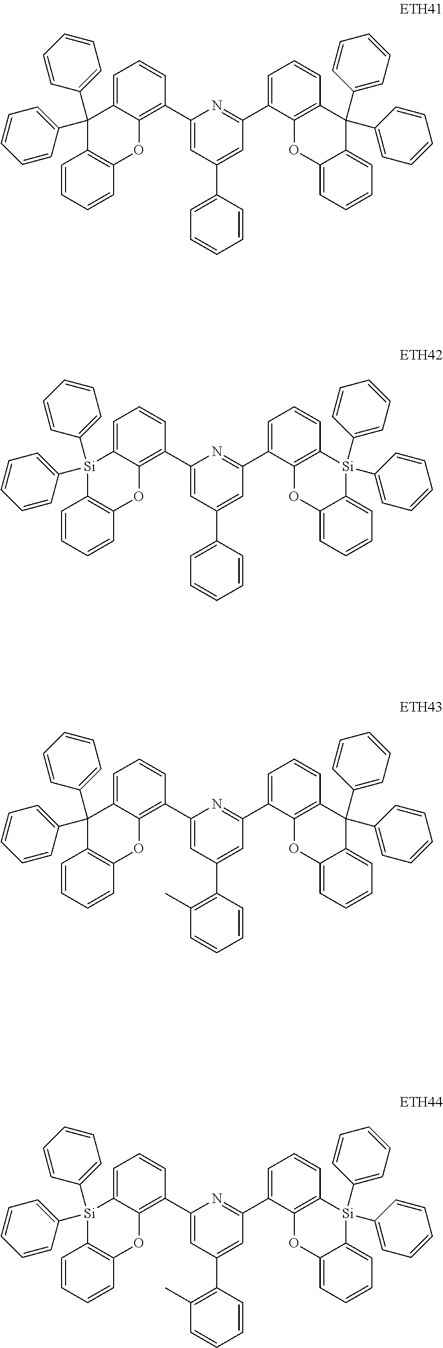 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

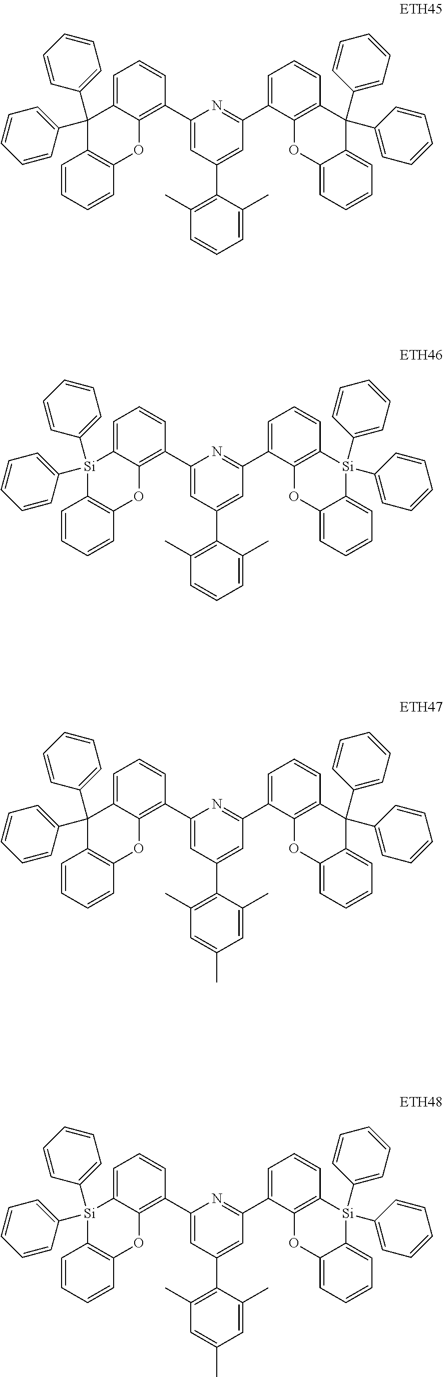 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

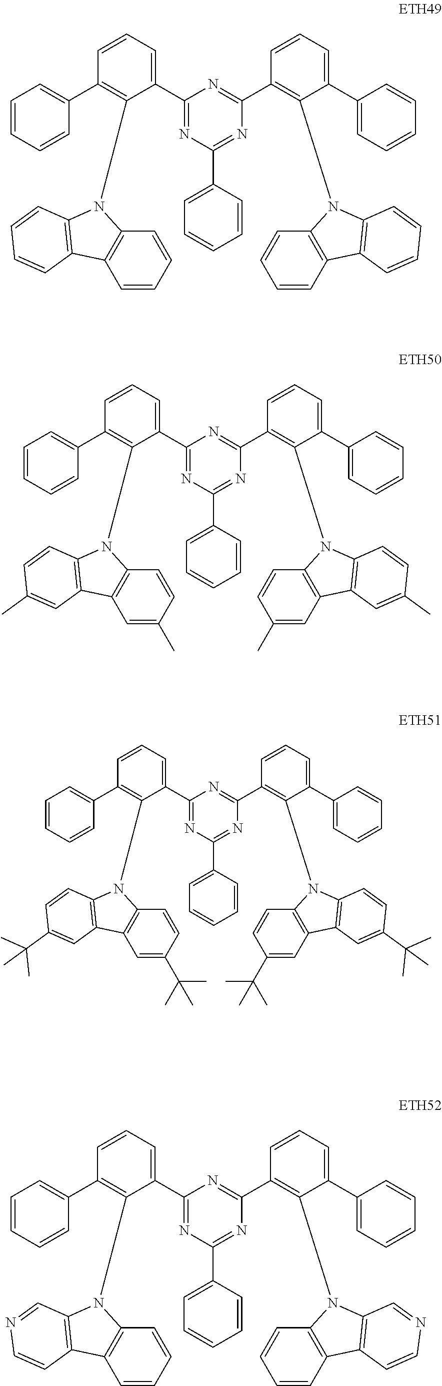

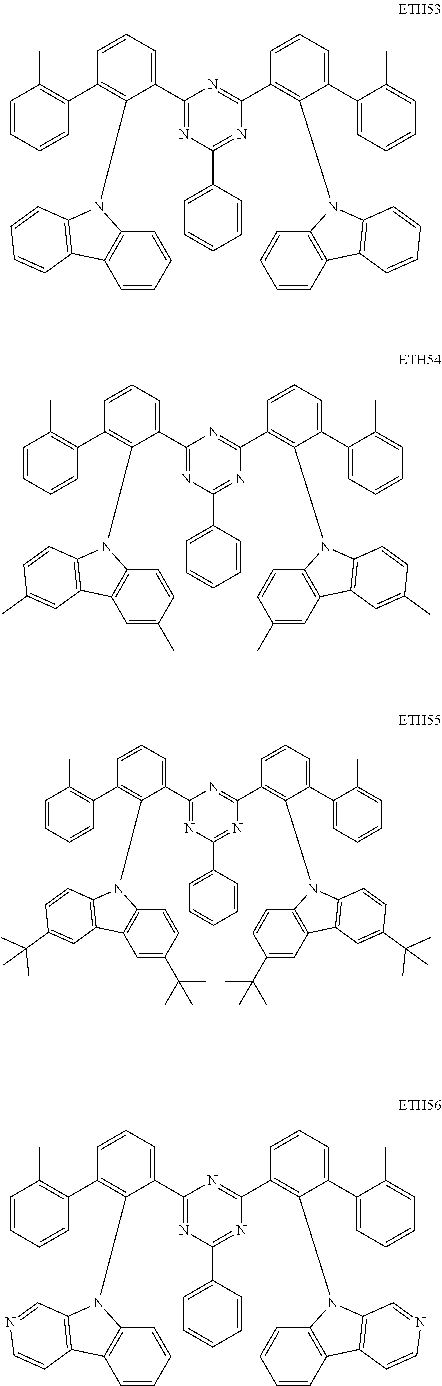

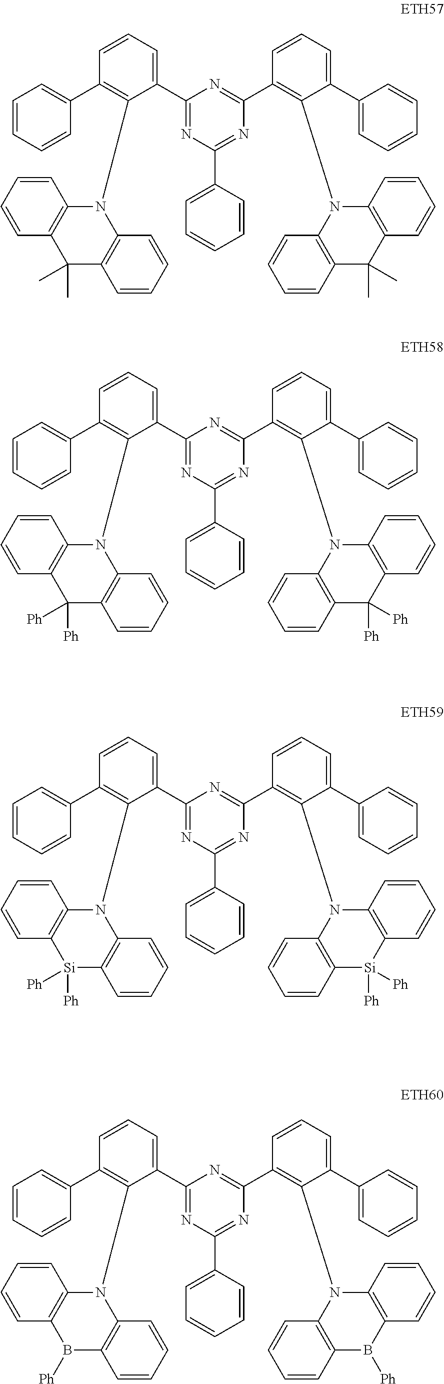

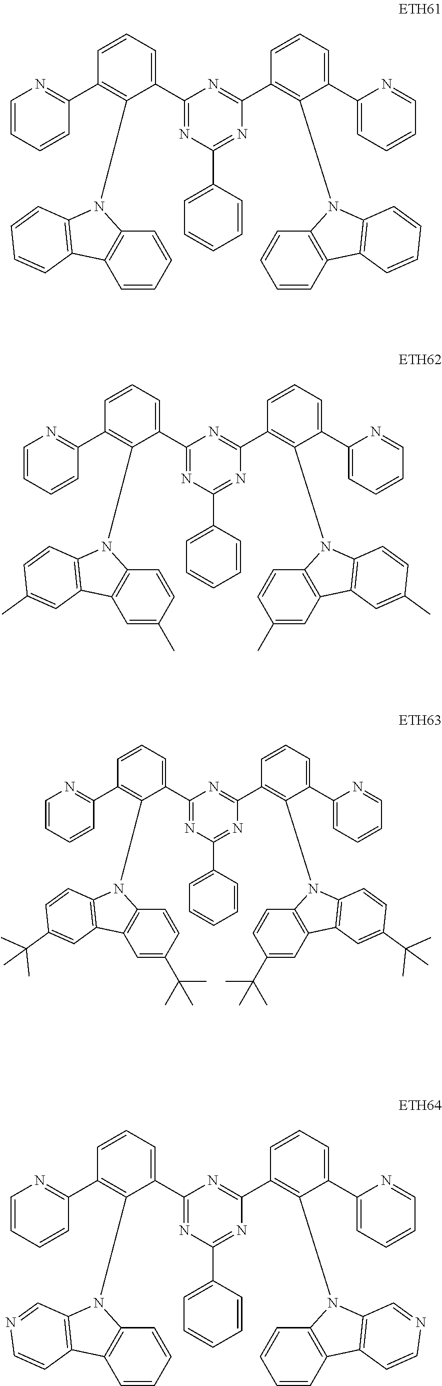

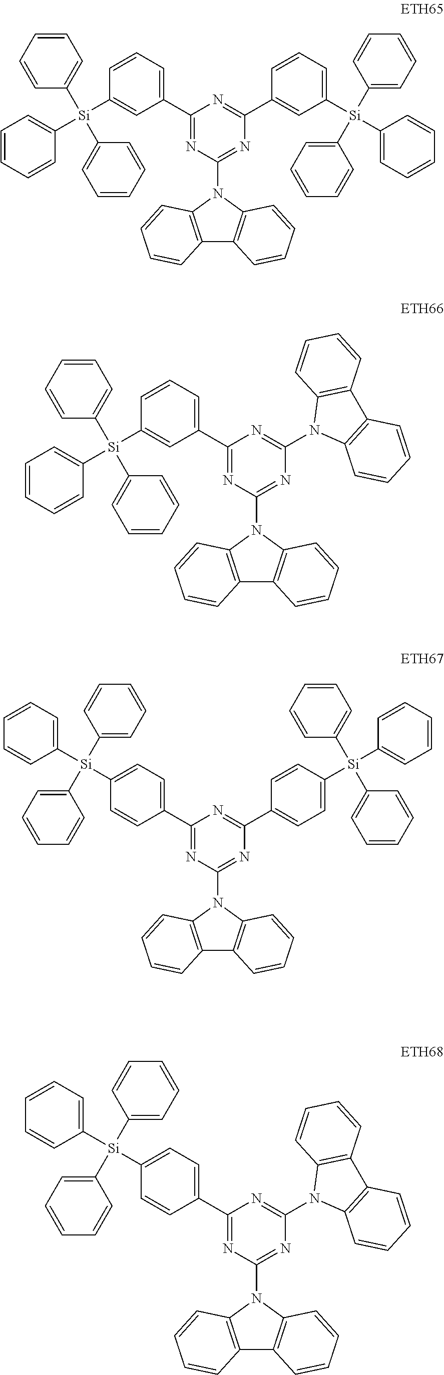 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

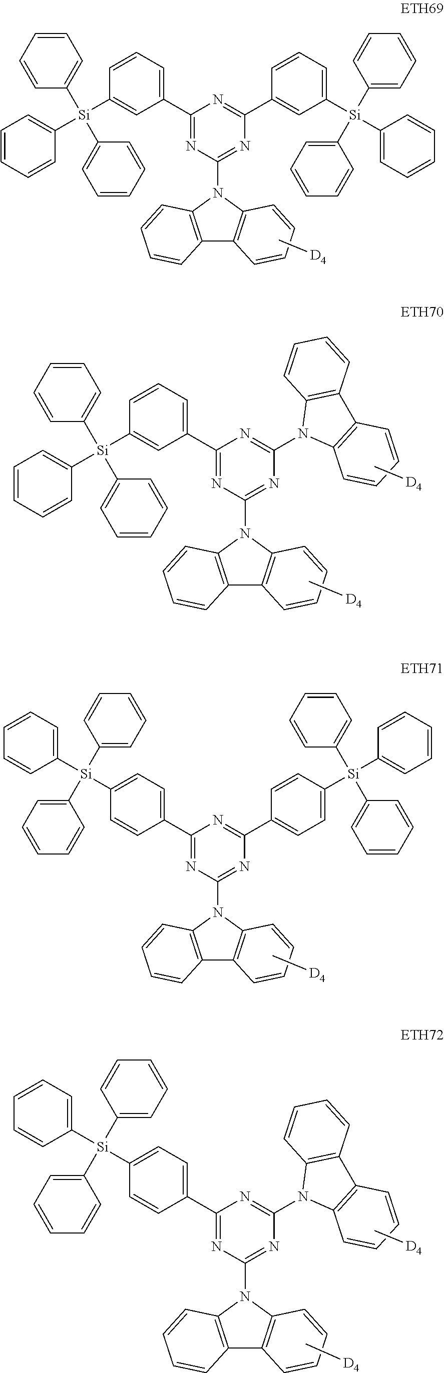

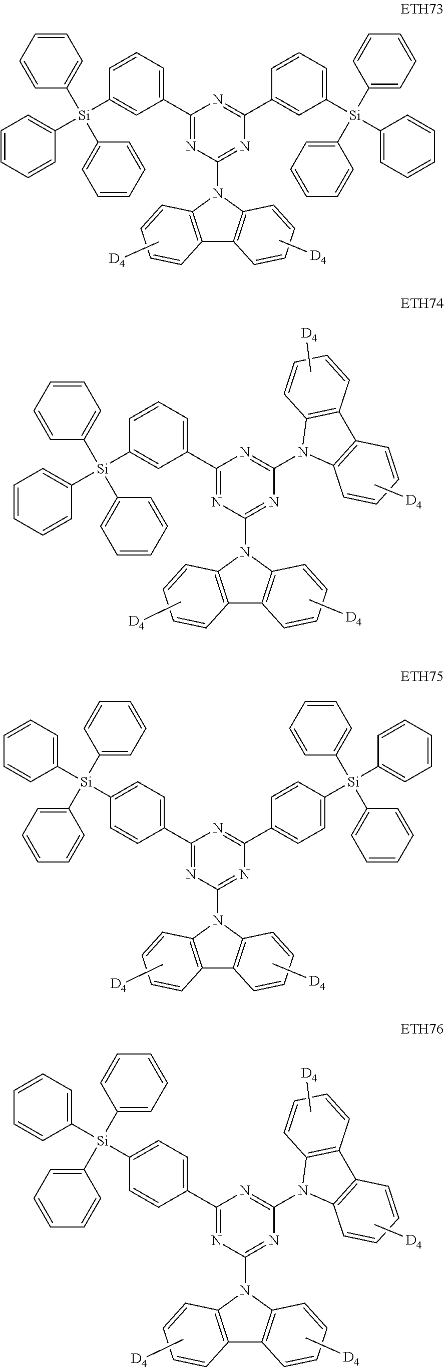

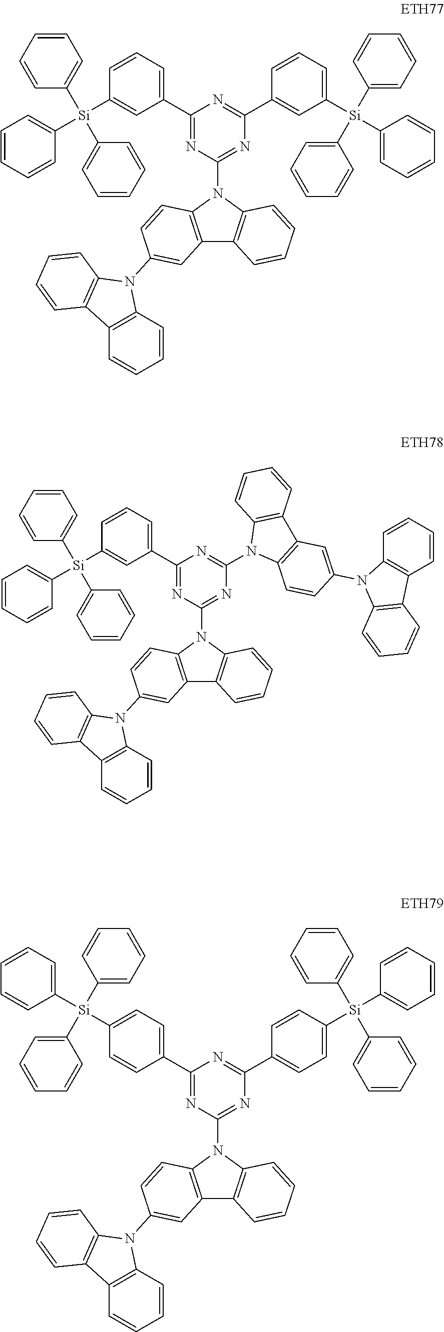 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

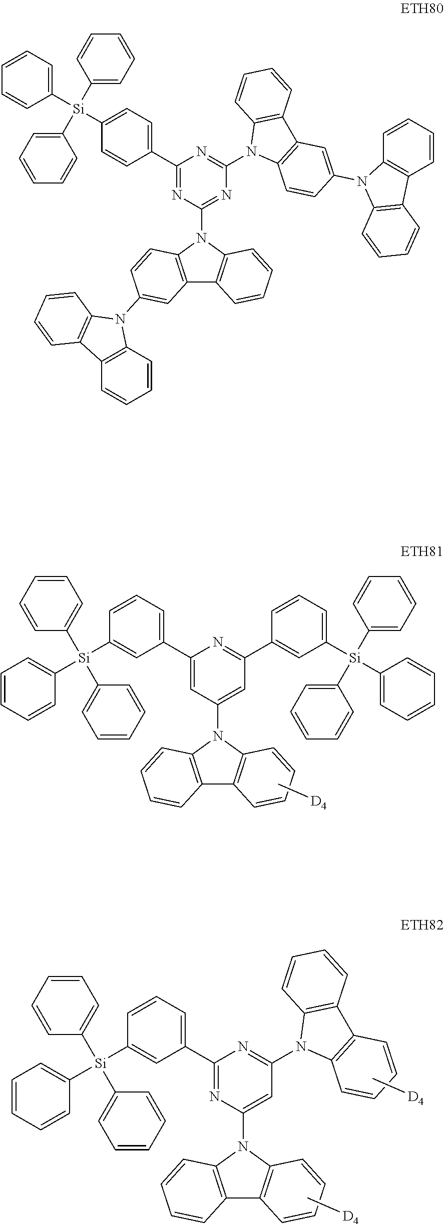

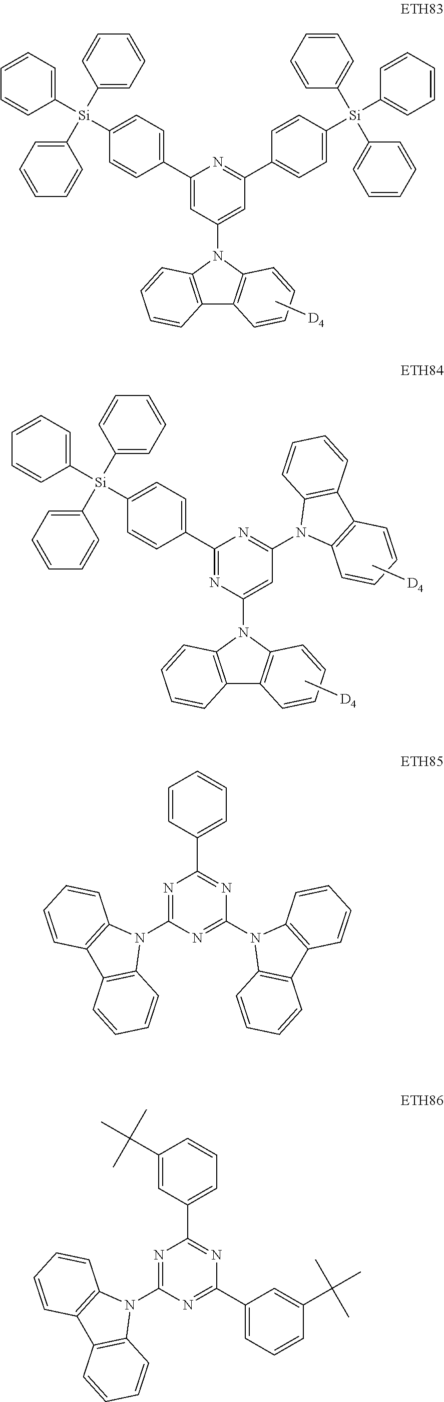

For example, the emission layer EML may include the second compound and the third compound, and the second compound and the third compound may form exciplex. In the emission layer EML, exciplex may be formed by a hole transport host and an electron transport host. In this case, the triplet energy level of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 eV to about 3.0 eV. In addition, the triplet energy level of the exciplex may be a value smaller than the energy gap of each host material. The exciplex may have a triplet energy level of about 3.0 eV or less, that is the energy gap between the hole transport host and the electron transport host.

In one or more embodiments, the emission layer EML may include a fourth compound represented by Formula PS below. For example, the fourth compound may be used as a phosphorescence sensitizer of the emission layer EML. Energy may transfer from the fourth compound to the first compound to emit light.

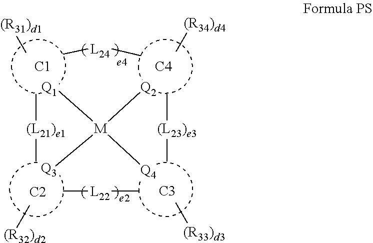

In Formula PS, M may be platinum (Pt). Q₁ to Q₄ may be each independently C or N. C1 to C4 may be each independently a substituted or unsubstituted hydrocarbon ring of 5 to 30 ring-forming carbon atoms, or a substituted or unsubstituted heterocycle of 2 to 30 ring-forming carbon atoms.

e1 to e4 may be each independently 0 or 1, and L₂₁ to L₂₄ may be each independently a direct linkage,

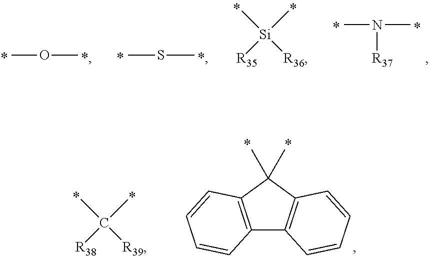

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms.

d1 to d4 may be each independently an integer of 0 or 4. If d1 is an integer of 2 or more, a plurality of R₃₁ may be the same, or at least one may be different. If d2 is an integer of 2 or more, a plurality of R₃₂ may be the same, or at least one may be different. If d3 is an integer of 2 or more, a plurality of R₃₃ may be the same, or at least one may be different. If d4 is an integer of 2 or more, a plurality of R₃₄ may be the same, or at least one may be different.

R₃₁ to R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

The fourth compound may be represented by any one selected from among the compounds in Compound Group 4. The light emitting element ED of one or more embodiments may include any one selected from among the compounds in Compound Group 4.

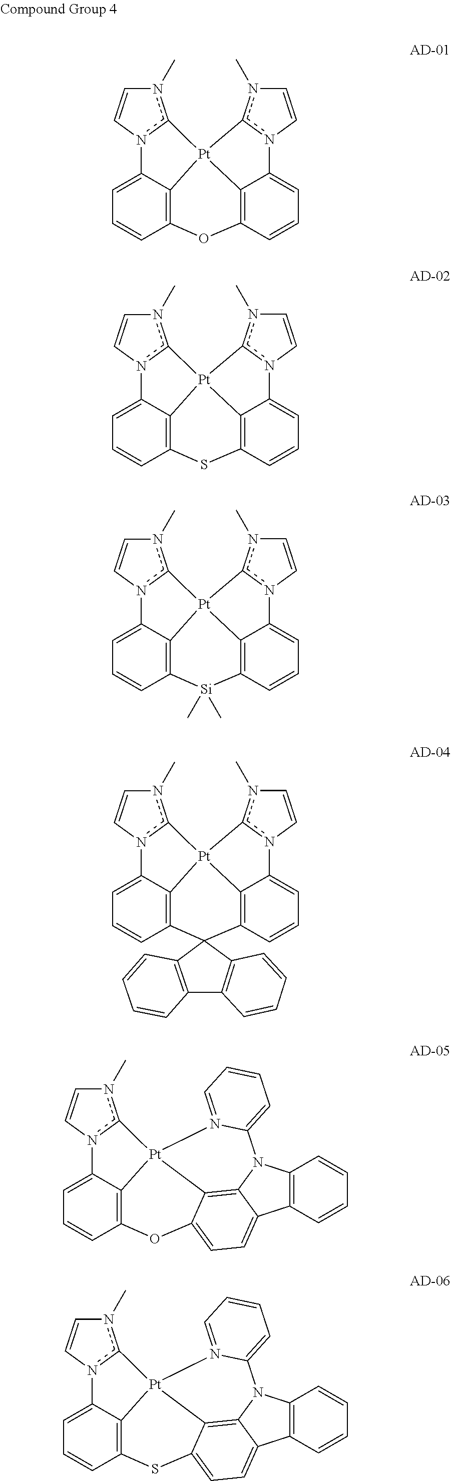

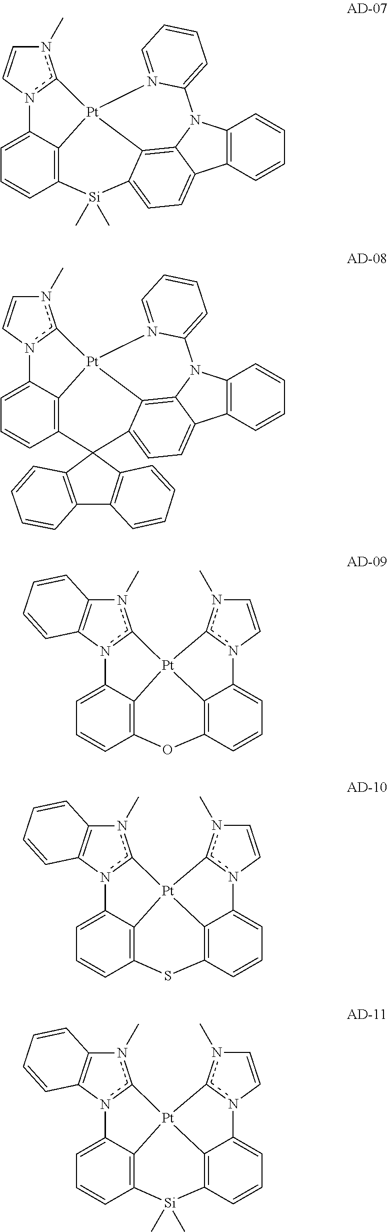

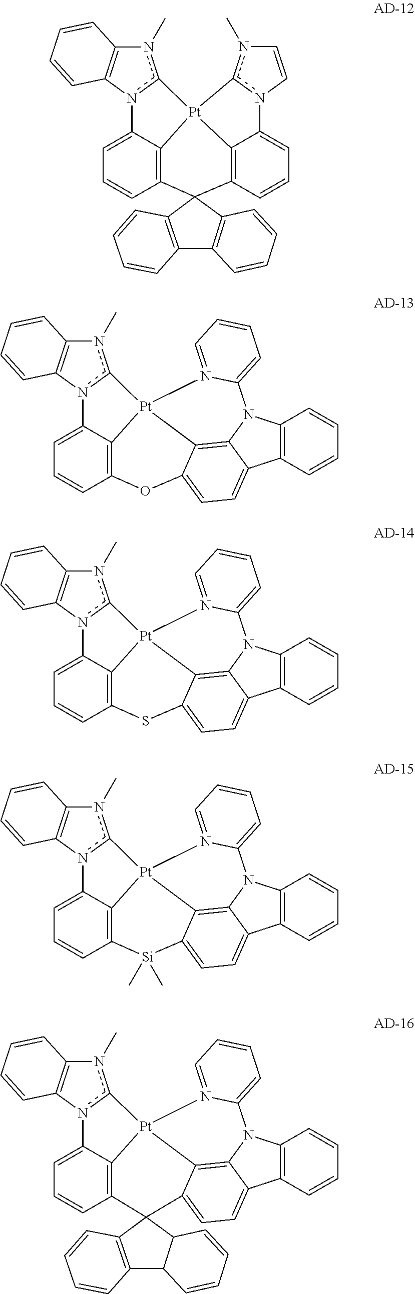

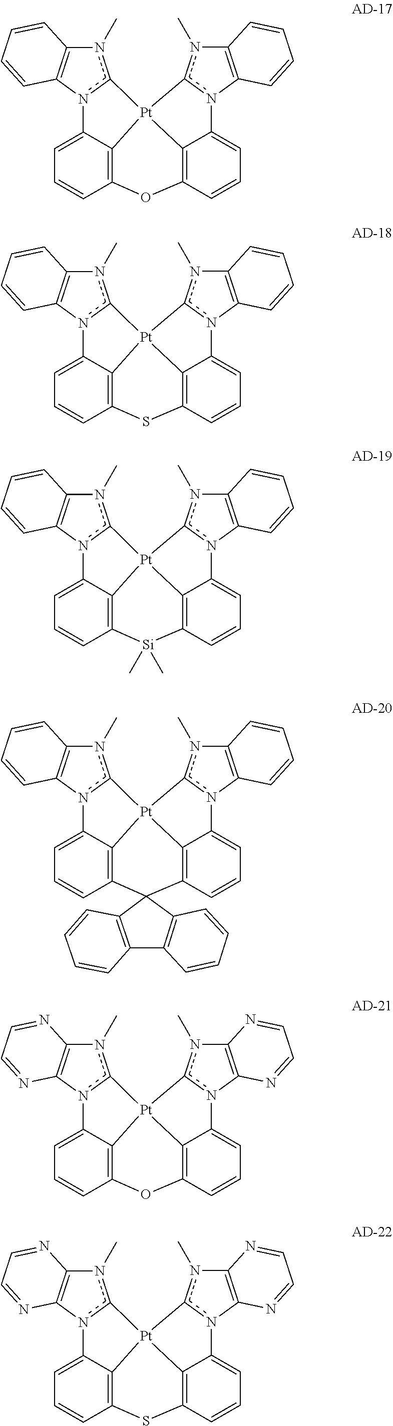

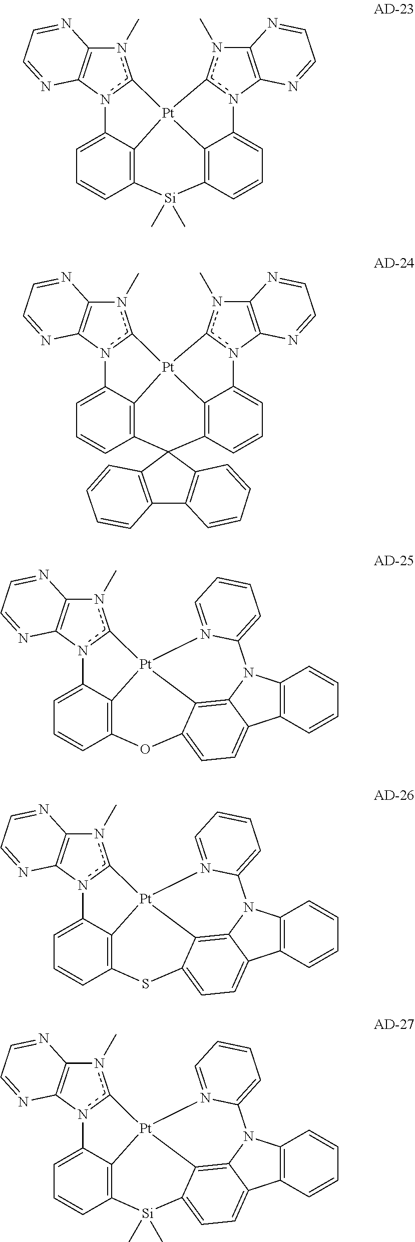

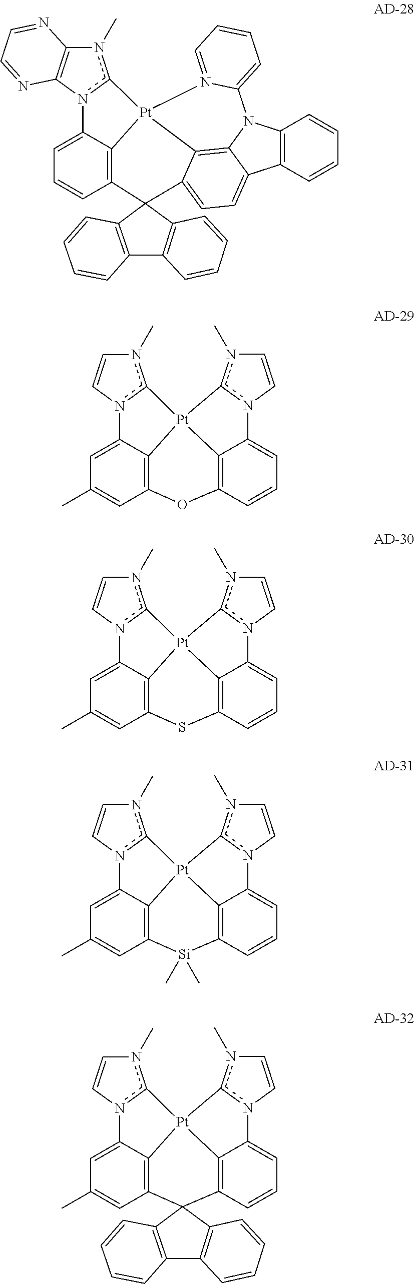

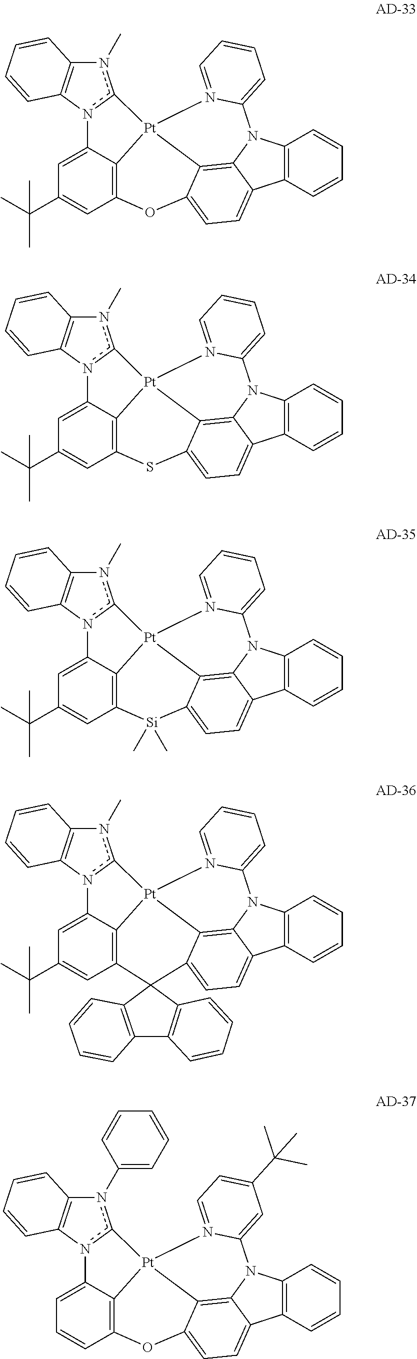

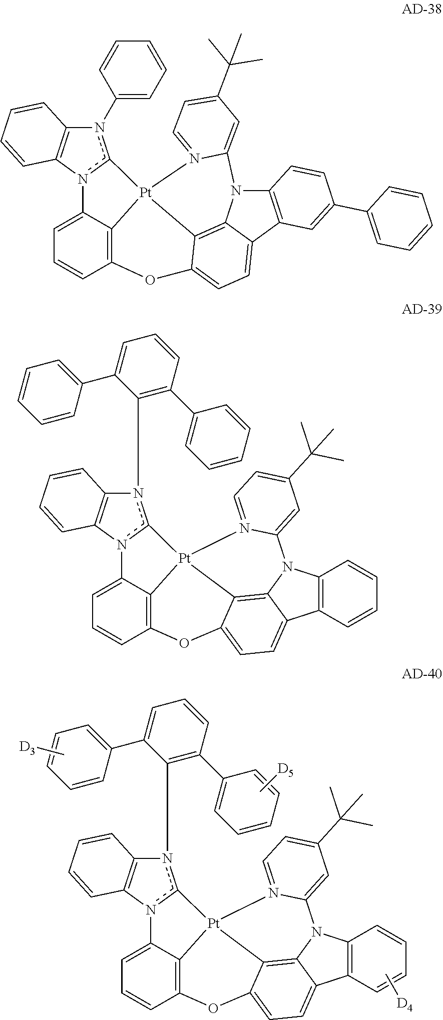

In one or more embodiments, the light emitting element ED of one or more embodiments may include a plurality of emission layers EML. The plurality of emission layers EML may be provided by stacking in order. For example, a light emitting element ED including a plurality of emission layers EML may emit white light. The light emitting element ED including a plurality of emission layers EML may be a light emitting element of a tandem structure. If the light emitting element ED includes a plurality of emission layers EML, at least one emission layer EML may include the first compound represented by Formula 1 of one or more embodiments. In addition, if the light emitting element ED includes a plurality of emission layers EML, at least one emission layer EML may include all of the first compound, second compound, third compound and fourth compound as described above.

In the light emitting element ED of one or more embodiments, if the emission layer EML includes all of the first compound, the second compound and the third compound, the amount of the first compound may be about 0.5 wt % to about 5 wt % based on the total weight of the first compound, the second compound and the third compound. However, one or more embodiments of the present disclosure are not limited thereto. If the amount of the first compound satisfies the above-described ratio, energy transfer from the second compound and the third compound to the first compound may increase, and accordingly, emission efficiency and element life may increase.

In the emission layer EML, the total amount of the second compound and the third compound may be the remaining amount excluding the amount of the first compound. For example, in the emission layer EML, the total amount of the second compound and the third compound may be about 65 wt % to about 95 wt % based on the total weight of the first compound, the second compound and the third compound.

In the total amount of the second compound and the third compound, the weight ratio of the second compound and the third compound may be about 3:7 to about 7:3.

If the total amount of the second compound and the third compound satisfies the above-described ratio, charge balance properties in the emission layer EML may be improved, and emission efficiency and element life may be improved. If the total amount of the second compound and the third compound deviates from the above-described ratio range, charge balance in the emission layer EML may be broken, emission efficiency may be degraded, and the element may be easily deteriorated.

If the first compound, the second compound and the third compound included in the emission layer EML satisfy the range of the amount ratio, excellent emission efficiency and long lifetime may be achieved.

If the emission layer EML includes the fourth compound, the amount of the fourth compound may be about 4 wt % to 30 wt % based on the total weight of the first compound, the second compound, the third compound and the fourth compound in the emission layer EML. However, an embodiment of the inventive concept is not limited thereto. If the amount of the fourth compound satisfies the above-described amount, energy transfer from a host to the first compound that is a light emitting dopant may increase, and emission ratio may be improved. Accordingly, the emission efficiency of the emission layer EML may be improved. If the amount ratio of the first compound, the second compound, the third compound and the fourth compound, included in the emission layer EML satisfies the above-described amount ratio, excellent emission efficiency and long lifetime may be achieved.

In one or more embodiments, the emission layer EML may further include materials for an emission layer EML in addition to the suggested first to fourth compounds. In the light emitting element ED of one or more embodiments, the emission layer EML may include anthracene derivatives, pyrene derivatives, fluoranthene derivatives, chrysene derivatives, dihydrobenzanthracene derivatives, and/or triphenylene derivatives. For example, the emission layer EML may include anthracene derivatives and/or pyrene derivatives.

In the light emitting elements ED of embodiments, shown in FIG. 3 to FIG. 6, the emission layer EML may include a compound represented by Formula E-1 below. The compound represented by Formula E-1 below may be used as a fluorescence host material.

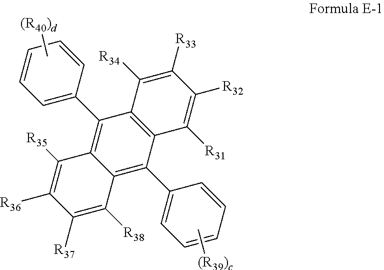

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In one or more embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may be each independently an integer of 0 to 5.

Formula E-1 may be represented by any one selected from among Compound E1 to Compound E19 below.

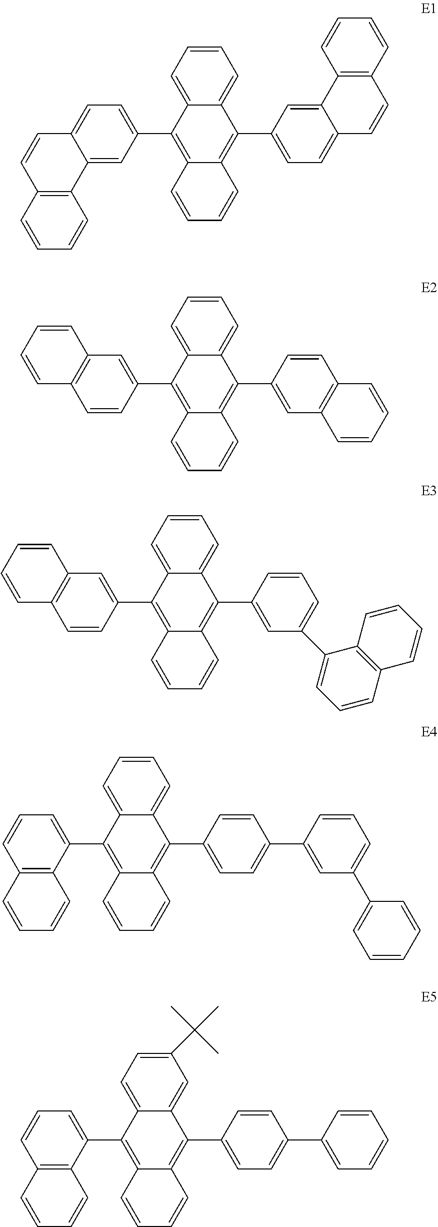

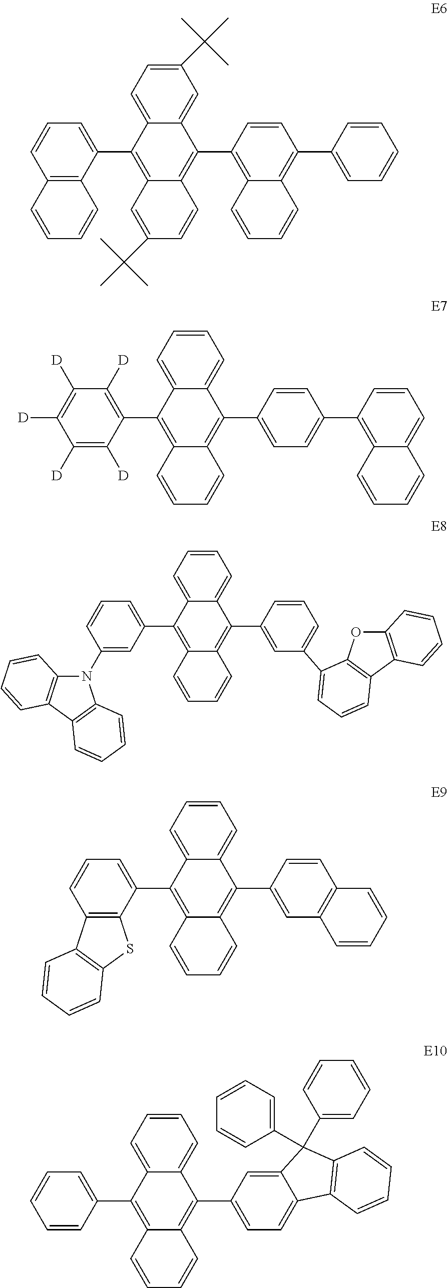

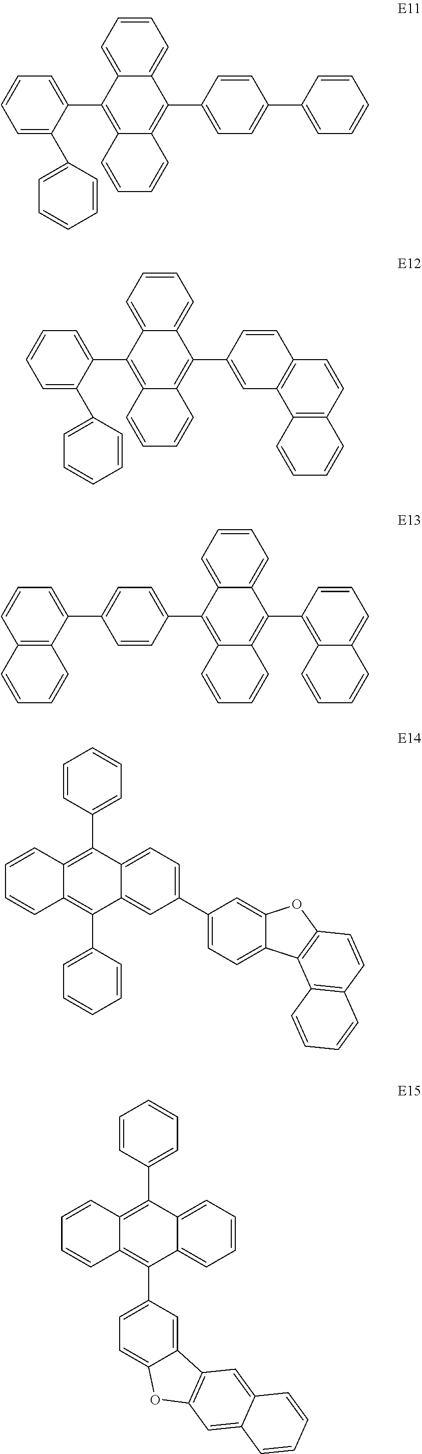

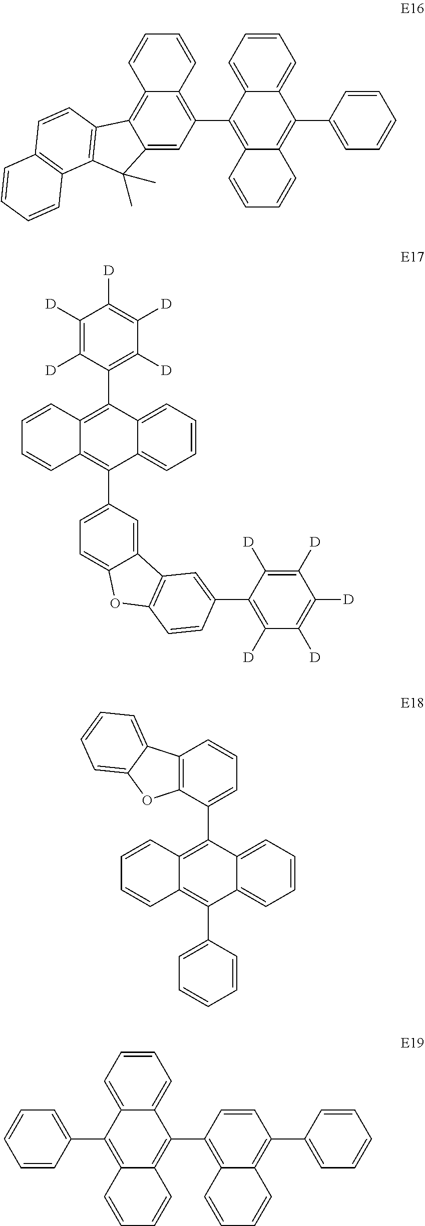

In one or more embodiments, the emission layer EML may include a compound represented by Formula E-2a or Formula E-2b. The compound represented by Formula E-2a or Formula E-2b may be used as a phosphorescence host material.

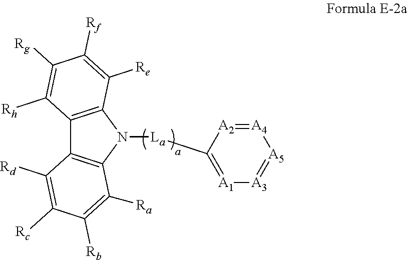

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if “a” is an integer of 2 or more, a plurality of Lₐ may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In one or more embodiments, in Formula E-2a, two or three selected from A₁ to A₅ may be N, and the remainder may be CRᵢ.

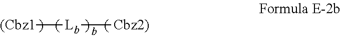

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2 below. However, the compounds shown in Compound Group E-2 below are only illustrations, and the compound represented by Formula E-2a or Formula E-2b is not limited to the compounds represented in Compound Group E-2 below.

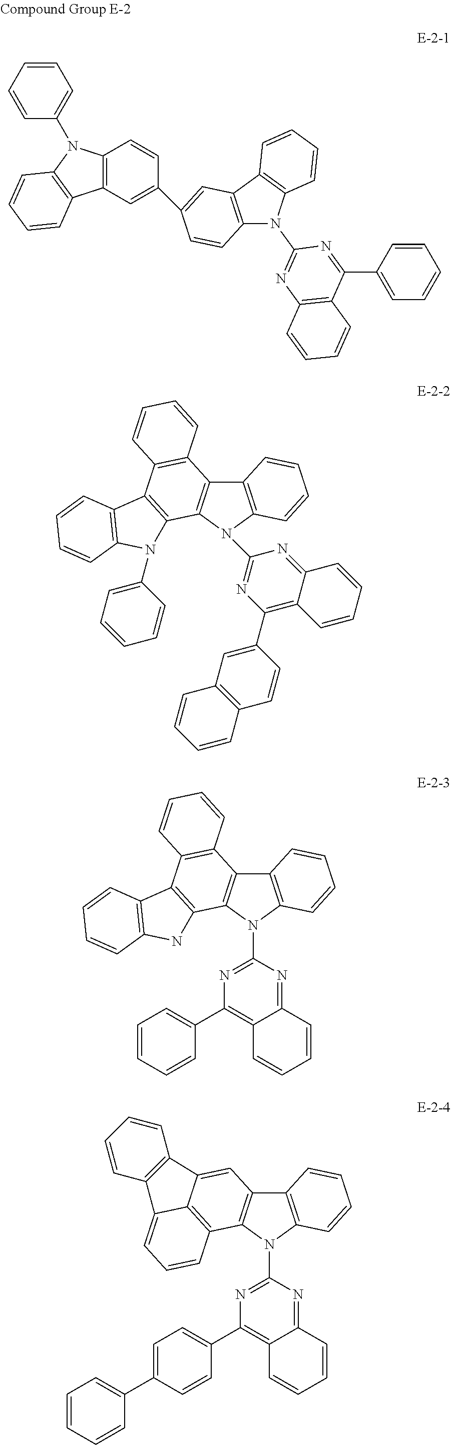

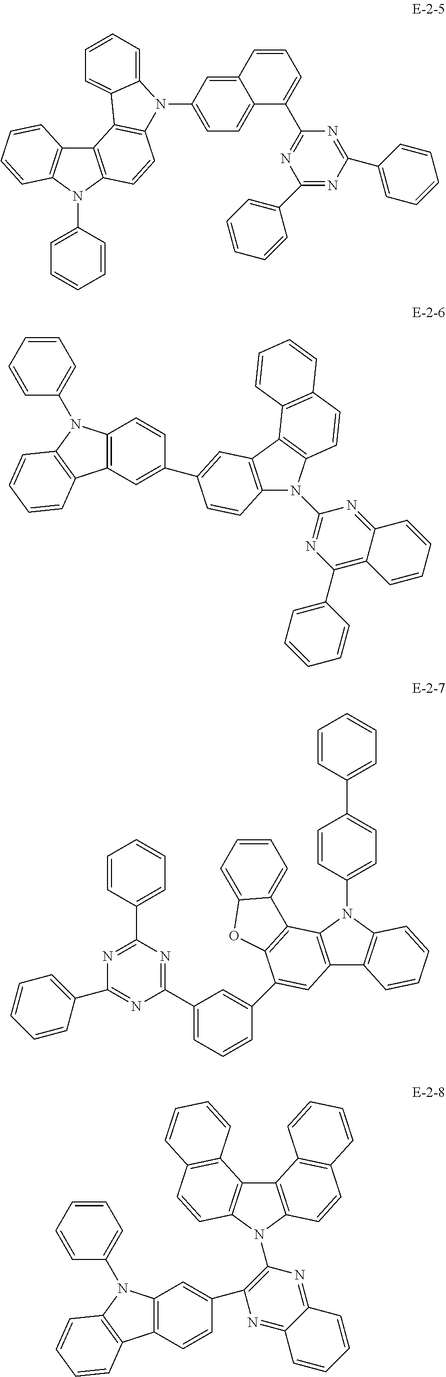 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

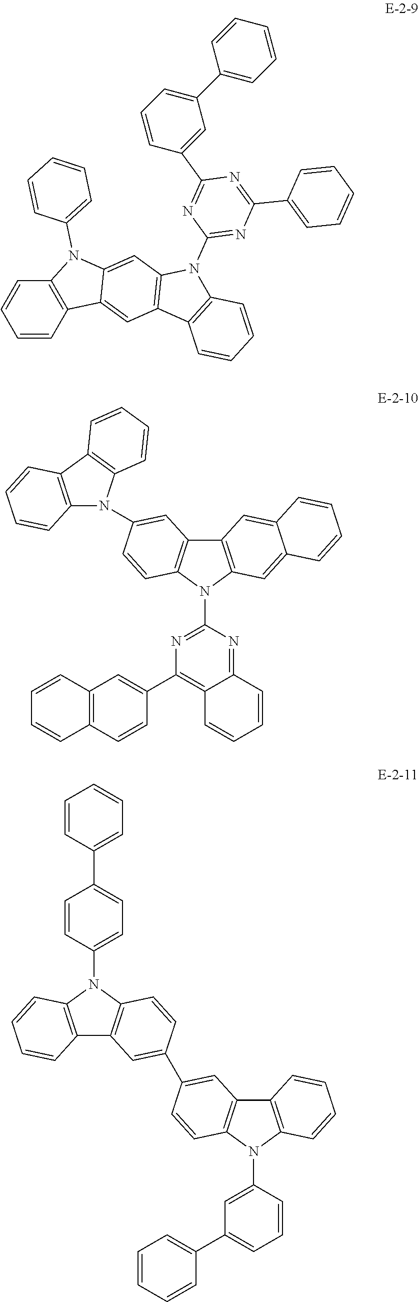 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

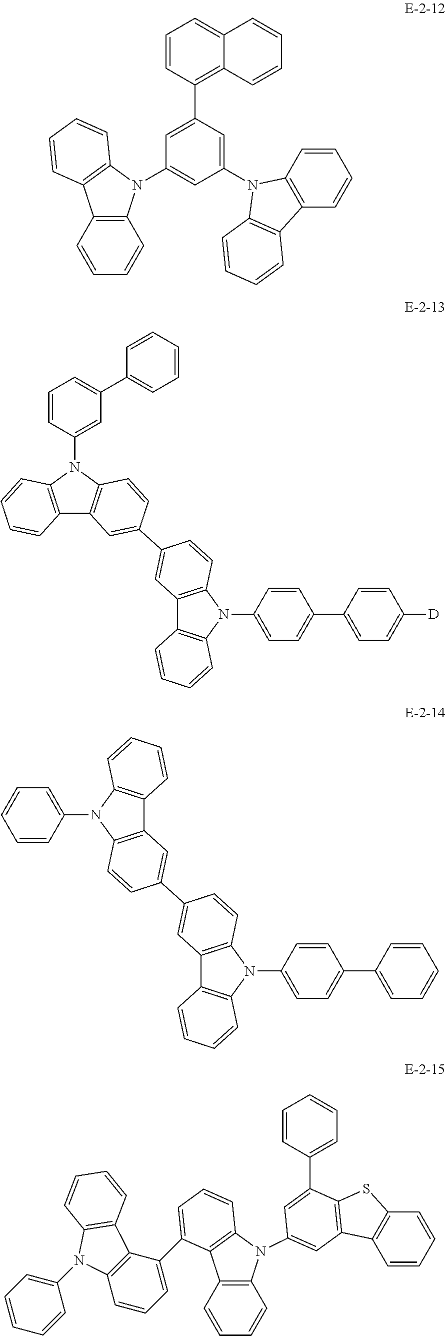 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

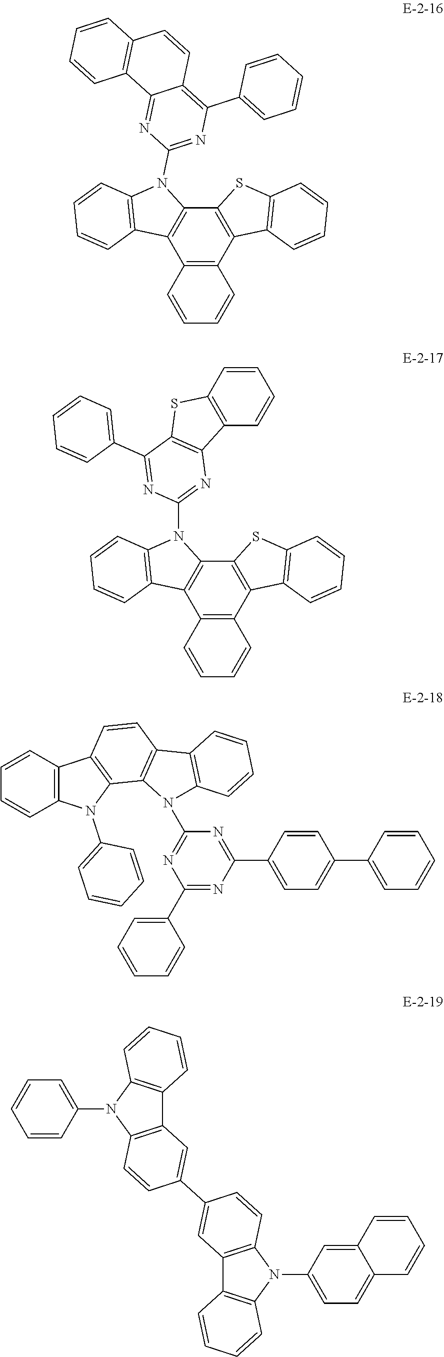

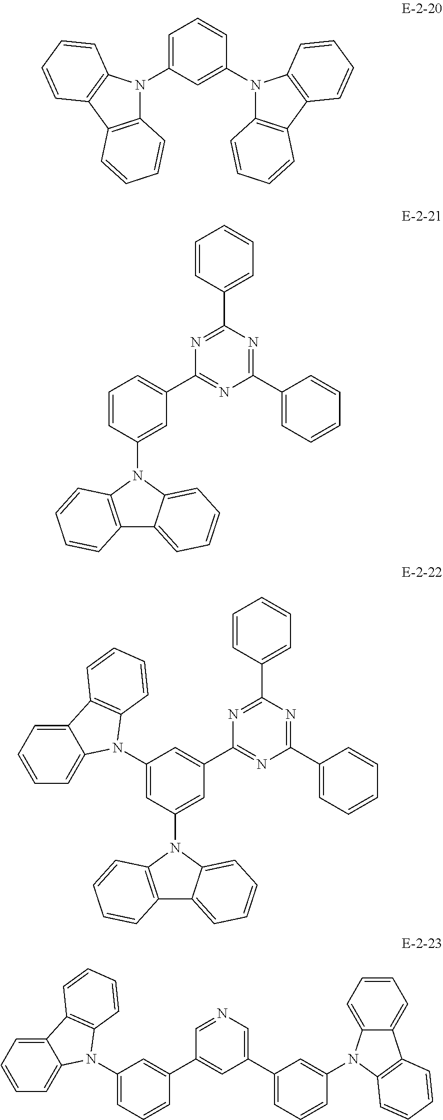 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

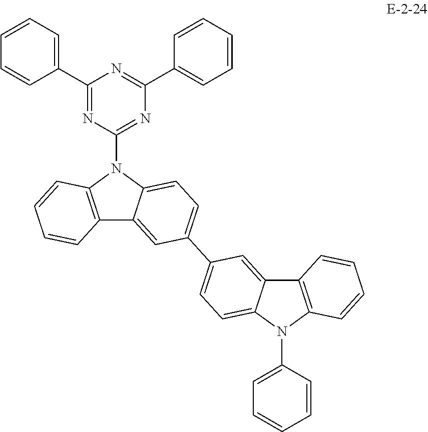 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material generally used in the art as a host material. For example, the emission layer EML may include as a host material, at least one selected from bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 3,3′-di(9H-carbazol-9-yl)-1,1′-biphenyl (mCBP), 4,4′-bis(N-carbazolyI)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl) triphenylamine (TCTA), and 1,3,5-tris(1-phenyl-1H-benzo[d]imidazole-2-yl)benzene (TPBi). However, one or more embodiments of the present disclosure are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a below. The compound represented by Formula M-a may be used as a phosphorescence dopant material. In addition, in one or more embodiments, the compound represented by Formula M-a may be used as an auxiliary dopant material.

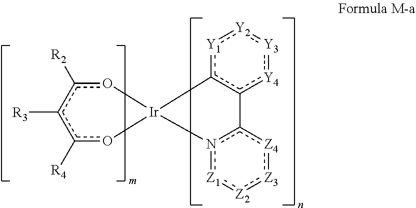

In Formula M-a, Y₁ to Y₄, and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be represented by any one selected from among Compounds M-a1 to M-a25 below. However, Compounds M-a1 to M-a25 below are illustrations, and the compound represented by Formula M-a is not limited to the compounds represented by Compounds M-a1 to M-a25 below.

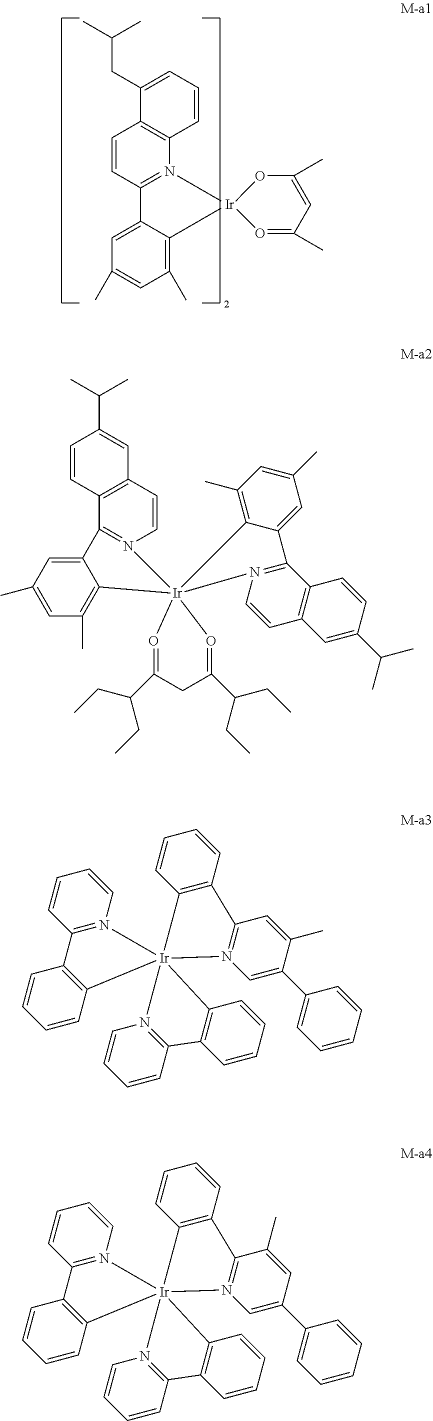

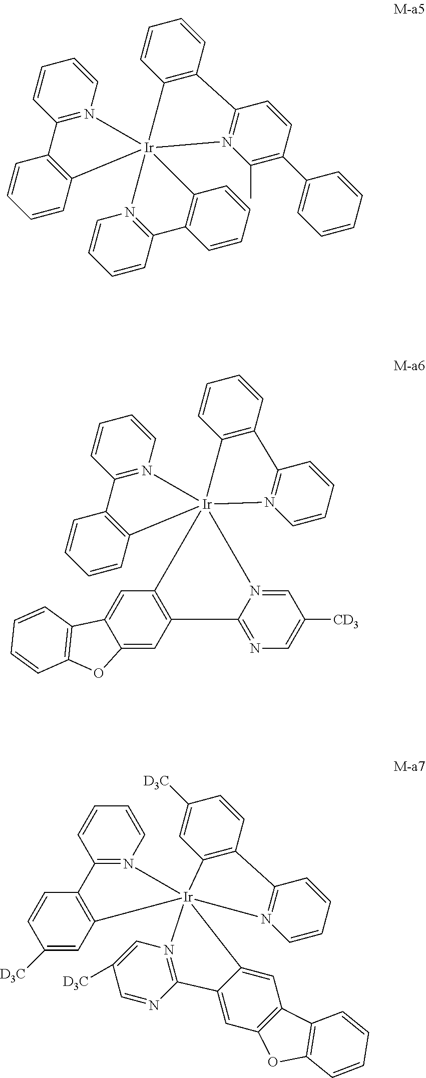

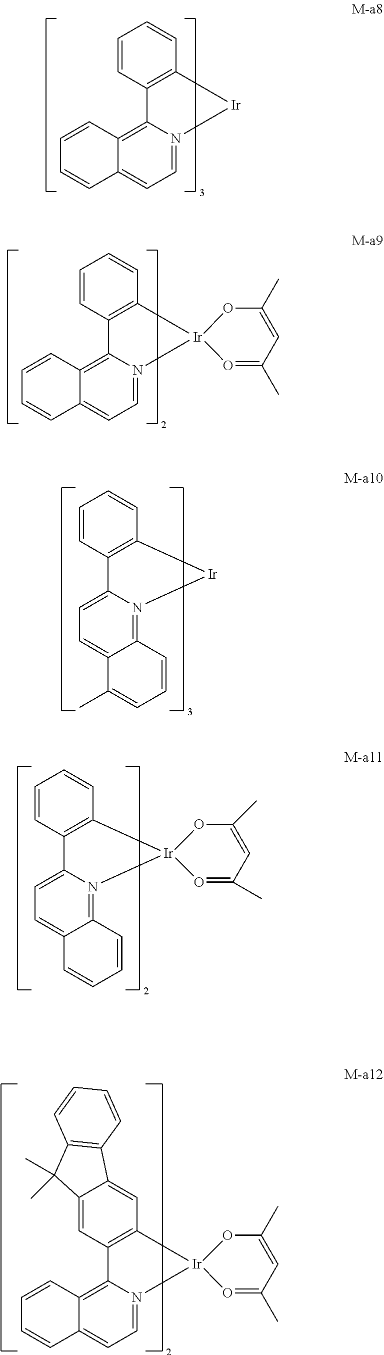

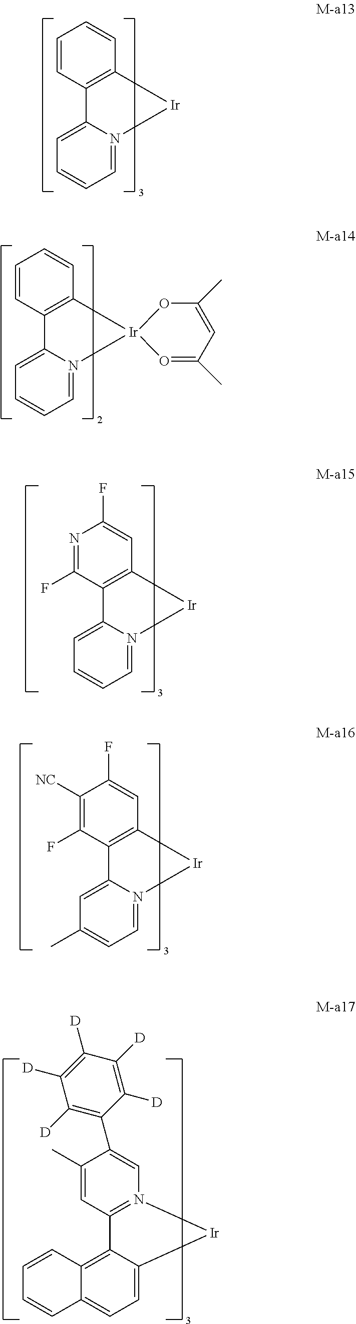

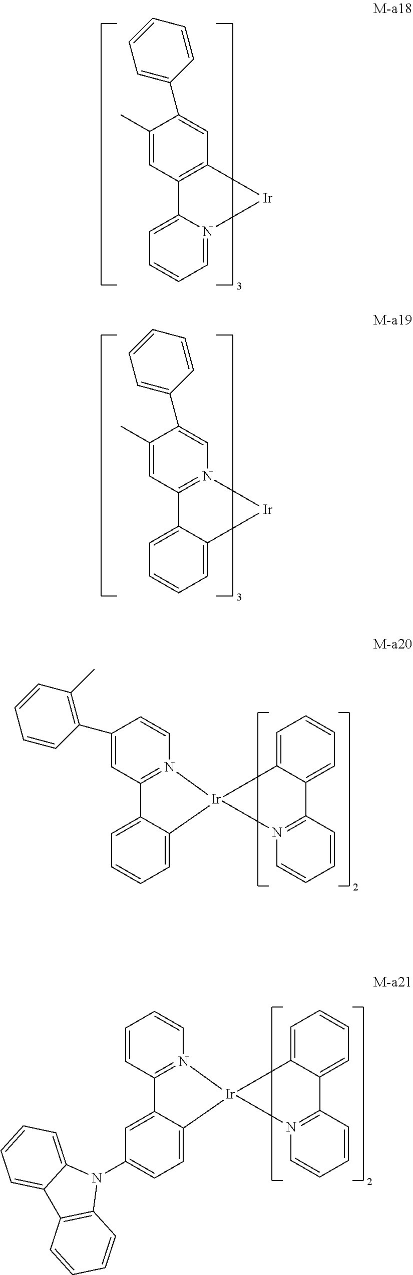

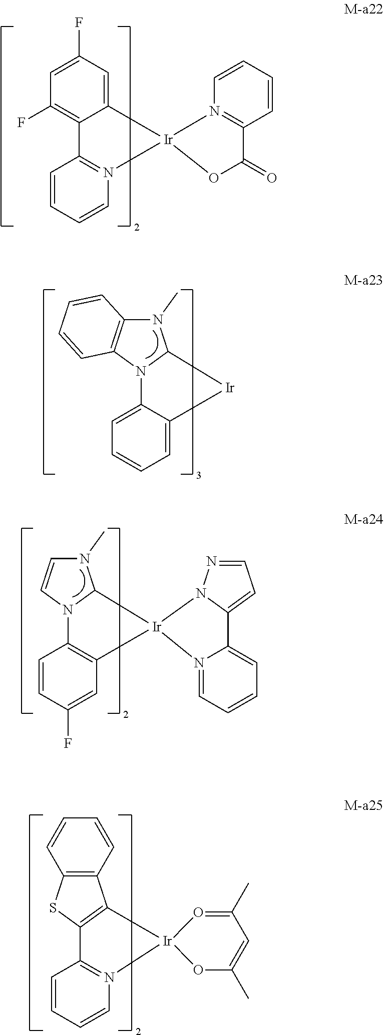

Compound M-a1 and Compound M-a2 may be used as red dopant materials, and Compound M-a3 to Compound M-a7 may be used as green dopant materials.

The emission layer EML may include any one selected from among Formula F-a to Formula F-c below. The compounds represented by Formula F-a to Formula F-c below may be used as fluorescence dopant materials.

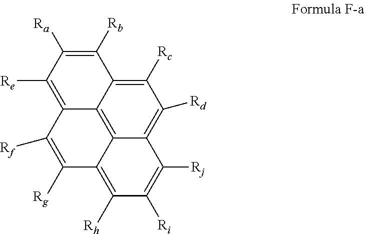

In Formula F-a, two selected from Rₐ to Rⱼ may be each independently substituted with *—NAr₁Ar₂. The remainder not substituted with *—NAr₁Ar₂ among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

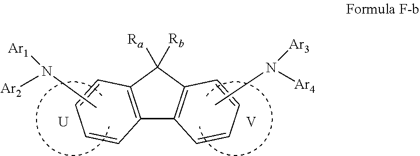

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may be each independently 0 or 1. For example, in Formula F-b, if the number of U or V is 1, one ring forms a fused ring at the designated part by U or V, and if the number of U or V is 0, a ring is not present at the designated part by U or V. In one or more embodiments, if the number of U is 0, and the number of V is 1, or if the number of U is 1, and the number of V is 0, a fused ring having the fluorene core of Formula F-b may be a ring compound with four rings. In addition, if the number of both U and V is 0, the fused ring of Formula F-b may be a ring compound with three rings. In addition, if the number of both U and V is 1, a fused ring having the fluorene core of Formula F-b may be a ring compound with five rings.

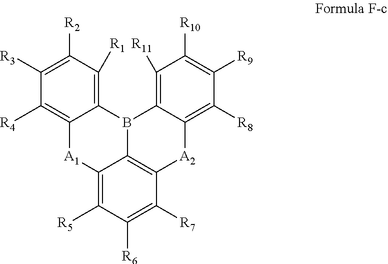

In Formula F-c, A₁ and A₂ may be each independently 0, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ are each independently NRₘ, A₁ may be combined with R₄ or R₅ to form a ring. In addition, A₂ may be combined with R₇ or R₈ to form a ring.

In one or more embodiments, the emission layer EML may include any suitable dopant material generally used in the art. In one or more embodiments, the emission layer EML may include styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layer EML may further include any suitable phosphorescence dopant material generally used in the art. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb), and/or thulium (Tm). In one or more embodiments, bis(4,6-difluorophenylpyridinato-N,C2′)picolinato iridium(III) (Flrpic), bis(2,4-difluorophenylpyridinato)-tetrakis(1-pyrazolyl)borate iridium(III) (Flr6), and/or platinum octaethyl porphyrin (PtOEP) may be used as the phosphorescence dopant. However, one or more embodiments of the present disclosure are not limited thereto.

The emission layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, and In₂Se₃, a ternary compound such as InGaS₃, and InGaSe₃, or optional combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and CuInGaS₂.

The III-V group compound may be selected from the group consisting of a binary compound selected from the group consisting of GaN, GaP, GaAs, GaSb, AlN, AlP, AIAs, AlSb, InN, InP, InAs, InSb, and mixtures thereof, a ternary compound selected from the group consisting of GaNP, GaNAs, GaNSb, GaPAs, GaPSb, AINP, AINAs, AINSb, AIPAs, AIPSb, InGaP, InAIP, InNP, InNAs, InNSb, InPAs, InPSb, and mixtures thereof, and a quaternary compound selected from the group consisting of GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, and mixtures thereof. In one or more embodiments, the III-V group compound may further include a II group metal. For example, InZnP, etc. may be selected as a III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound or the quaternary compound may be present at uniform (e.g., substantially uniform) concentration in a particle or may be present at a partially different concentration distribution state in the same particle. In addition, a core/shell structure in which one quantum dot wraps another quantum dot may be possible. The interface of the core and the shell may have a concentration gradient in which the concentration of an element present in the shell is decreased along a direction toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal and/or non-metal oxide, a semiconductor compound, or combinations thereof.

For example, the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but one or more embodiments of the present disclosure are not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but one or more embodiments of the present disclosure are not limited thereto.

The quantum dot may have a full width of half maximum (FWHM) of emission wavelength spectrum of about 45 nm or less, about 40 nm or less, or, for example, about 30 nm or less. Within this range, color purity and/or color reproducibility may be improved. In addition, light emitted via such quantum dot is emitted in all (e.g., substantially all) directions, and light view angle properties may be improved.

In addition, the shape of the quantum dot may be generally used shapes in the art, without specific limitation. In one or more embodiments, the shape of spherical, pyramidal, multi-arm, and/or cubic nanoparticle, nanotube, nanowire, nanofiber, nanoplate particle, etc. may be used.

The quantum dot may control the color of light emitted according to the particle size, and accordingly, the quantum dot may have various suitable emission colors such as blue, red and green.

In the light emitting elements ED of embodiments, as shown in FIG. 3 to FIG. 6, the electron transport region ETR is provided on the emission layer EML. The electron transport region ETR may include at least one selected from an hole blocking layer HBL, an electron transport layer ETL, and an electron injection layer EIL. However, one or more embodiments of the present disclosure are not limited thereto.

The electron transport region ETR may have a single layer formed using a single material, a single layer formed using a plurality of different materials, or a multilayer structure having a plurality of layers formed using a plurality of different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure formed using a plurality of different materials, or a structure stacked from the emission layer EML of electron transport layer ETL/electron injection layer EIL, hole blocking layer HBL/electron transport layer ETL/electron injection layer EIL, electron transport layer ETL/buffer layer/electron injection layer EIL, and/or the like, without limitation. The thickness of the electron transport region ETR may be, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1 below.

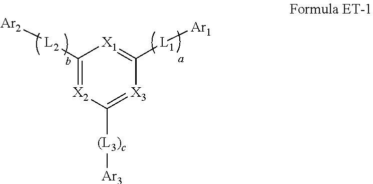

In Formula ET-1, at least one selected from among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ara may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (^{t}Bu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), and/or mixtures thereof, without limitation.

The electron transport region ETR may include at least one selected from among Compounds ET1 to ET36 below.

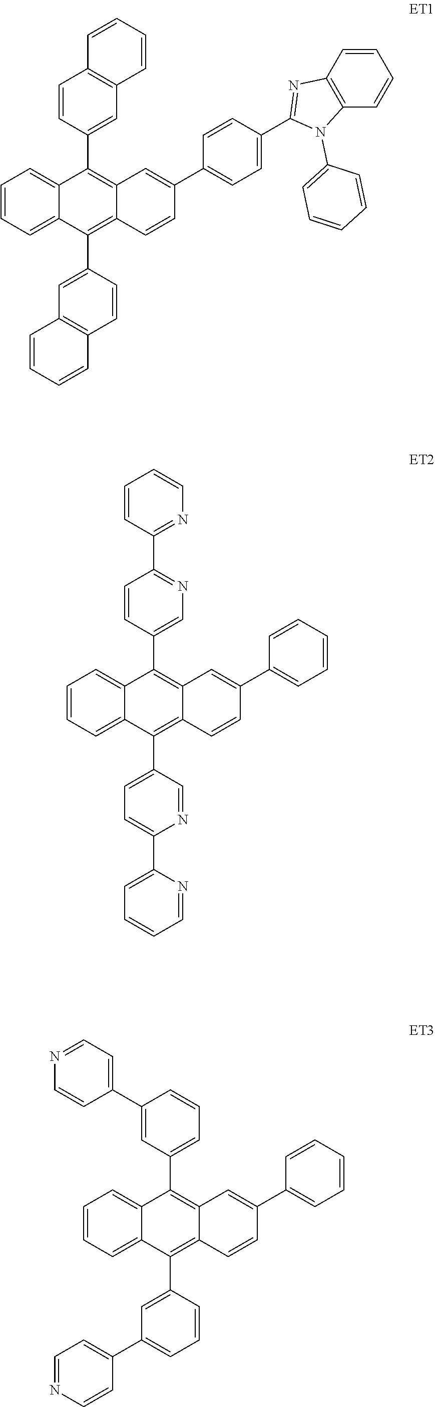 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

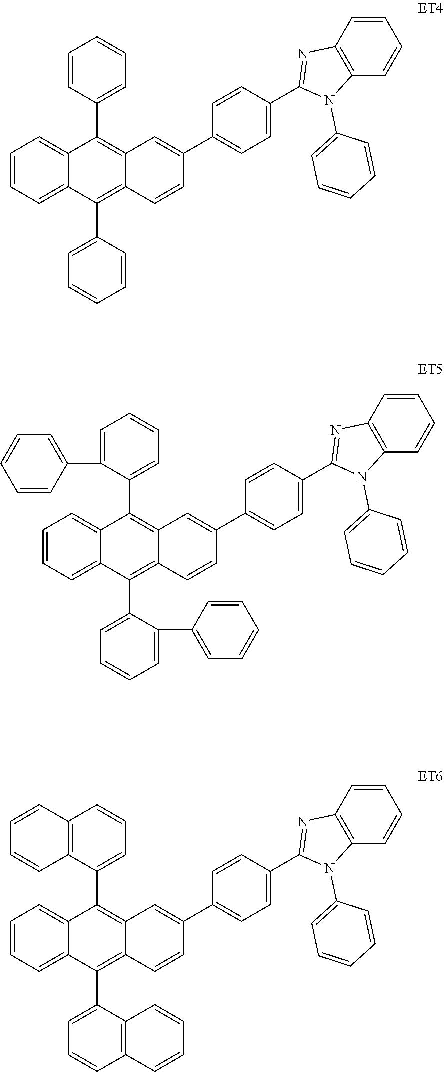 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

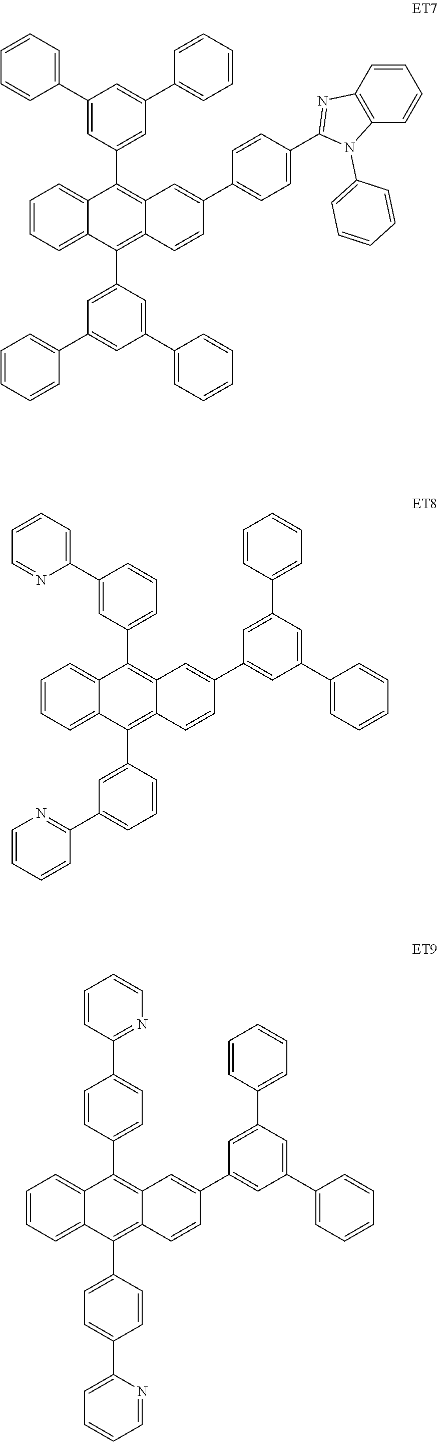 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

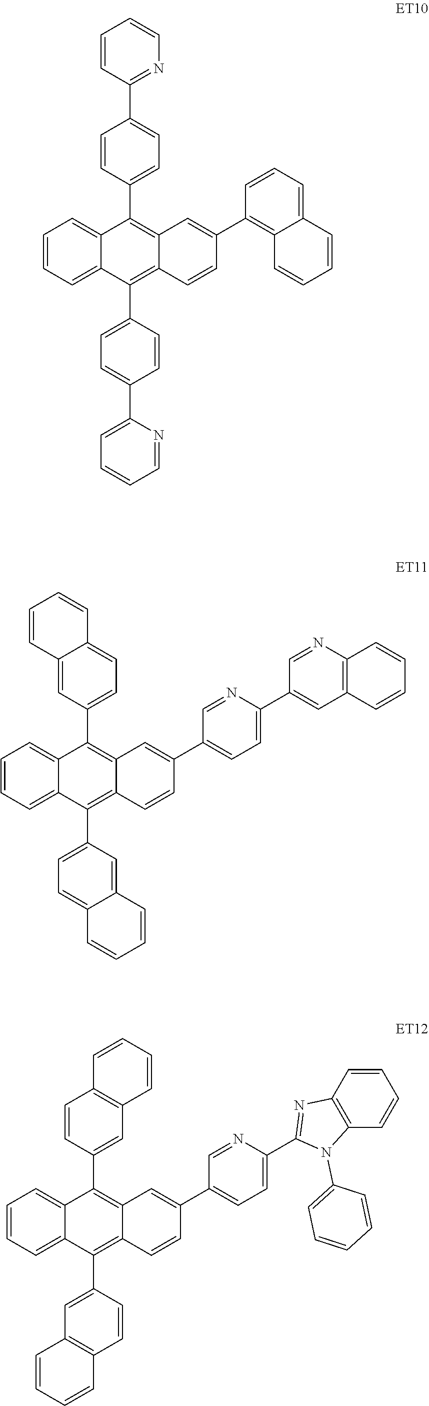 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cn3)nc3ccccc32)cc1]

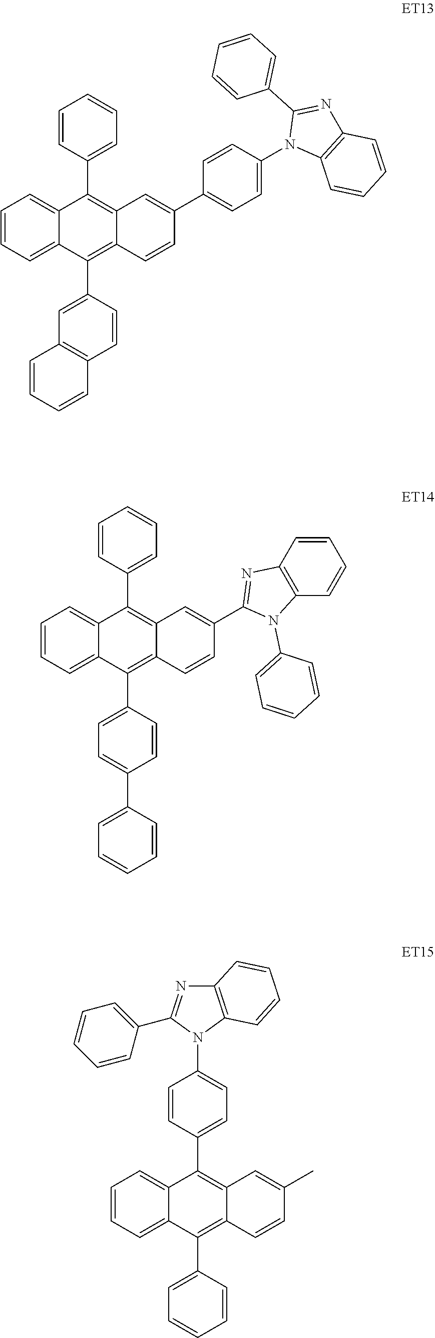 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

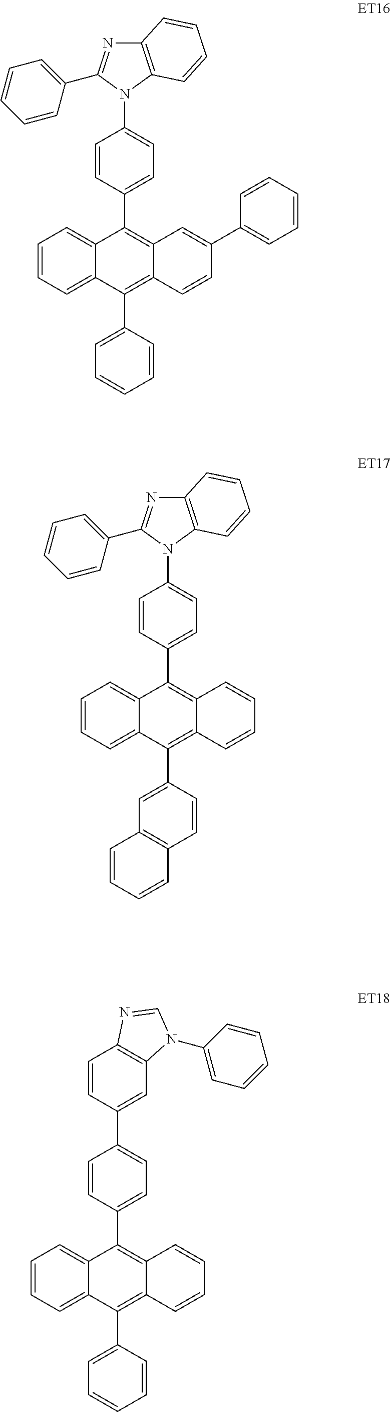 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; c1ccc(-c2c3ccccc3c(-c3ccc(-c4ccc5ncn(-c6ccccc6)c5c4)cc3)c3ccccc23)cc1]

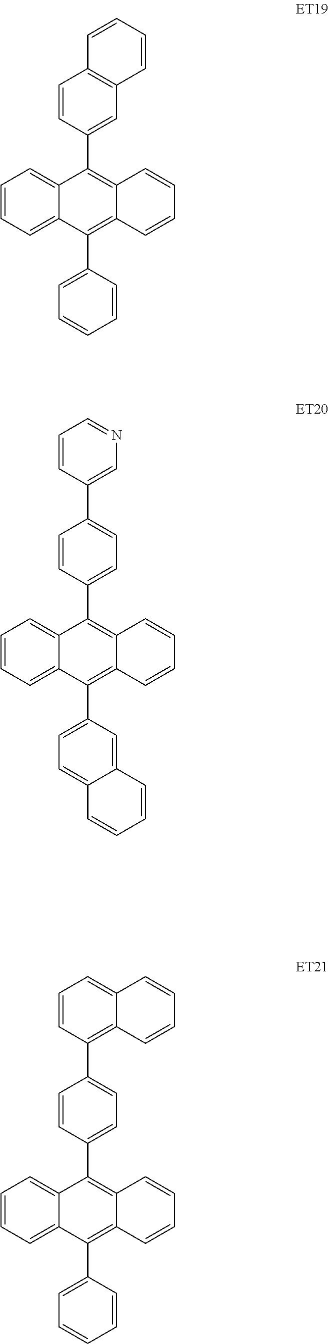

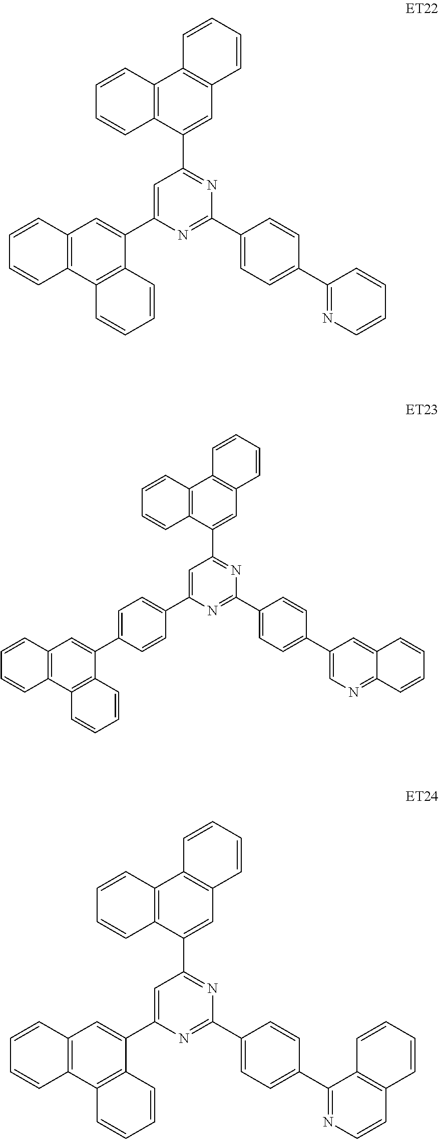 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

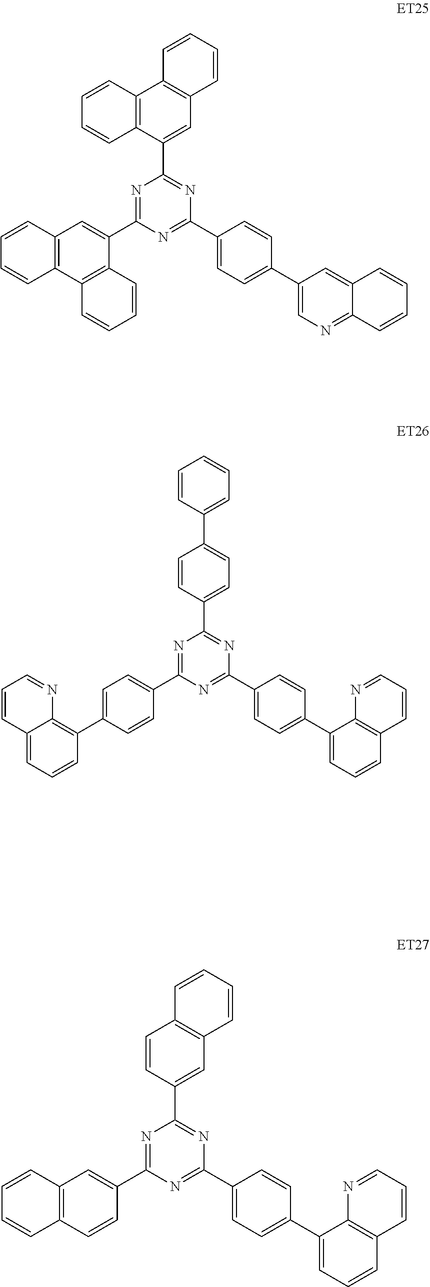 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

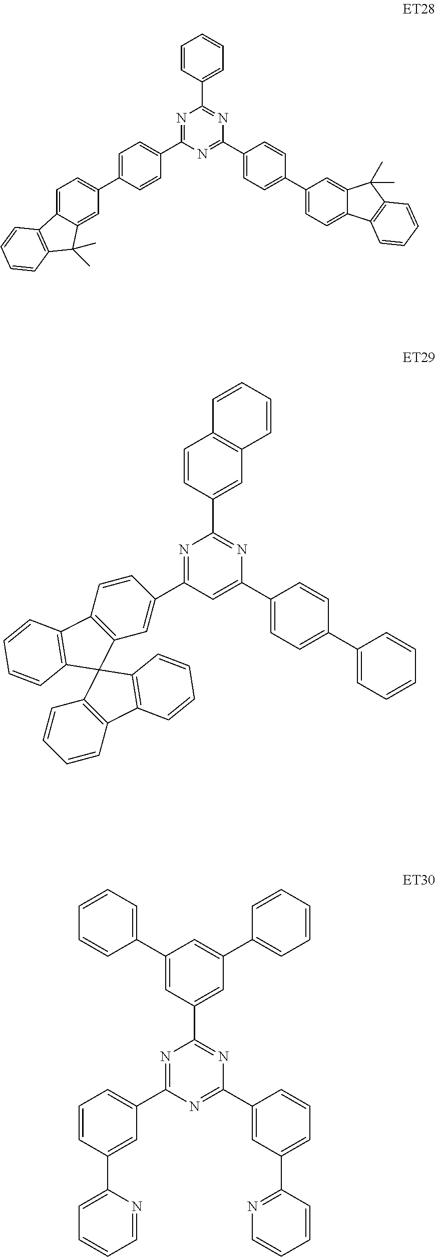 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

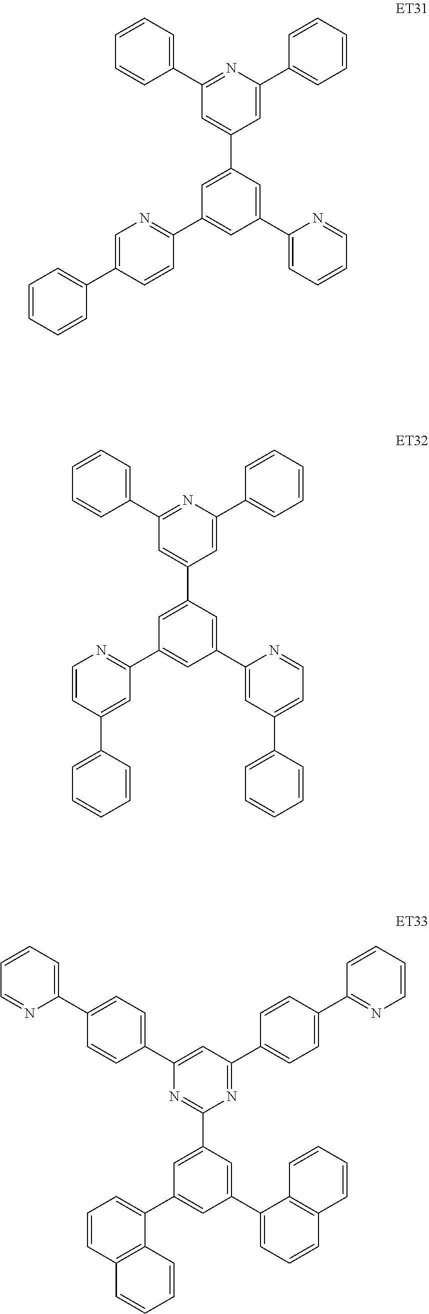 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

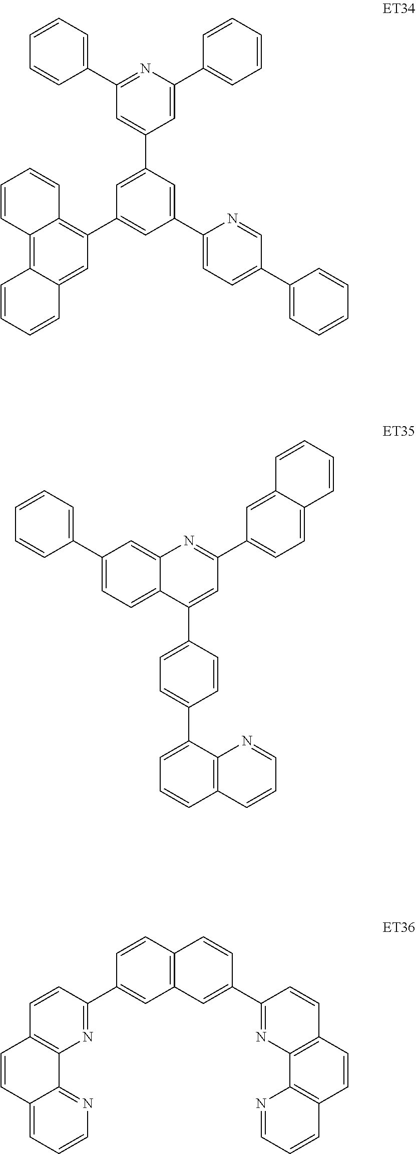 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport region ETR may include a metal halide such as LiF, NaCl, CsF, RbCl, Rbl, CuI and/or KI, a metal in lanthanoides such as Yb, and/or a co-depositing material of the metal halide and the metal in lanthanoides. For example, the electron transport region ETR may include KI:Yb, RbI:Yb, LiF:Yb, etc., as the co-depositing material. In one or more embodiments, the electron transport region ETR may use a metal oxide such as Li₂O and/or BaO, and/or 8-hydroxy-lithium quinolate (Liq). However, one or more embodiments of the present disclosure are not limited thereto. The electron transport region ETR also may be formed using a mixture material of an electron transport material and an insulating organo metal salt. The organo metal salt may be a material having an energy band gap of about 4 eV or more. In one or embodiments, the organo metal salt may include, for example, metal acetates, metal benzoates, metal acetoacetates, metal acetylacetonates, and/or metal stearates.

The electron transport region ETR may include at least one selected from 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the aforementioned materials. However, one or more embodiments of the present disclosure are not limited thereto.

The electron transport region ETR may include the compounds of the electron transport region ETR in at least one selected from among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies the above-described range, suitable or satisfactory electron transport properties may be obtained without substantial increase of a driving voltage. If the electron transport region ETR includes the electron injection layer EIL, the thickness of the electron injection layer EIL may be from about 1 Å to about 100 Å, and from about 3 Å to about 90 Å. If the thickness of the electron injection layer EIL satisfies the above described range, suitable or satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but one or more embodiments of the present disclosure are not limited thereto. For example, if the first electrode EL1 is an anode, the second cathode EL2 may be a cathode, and if the first electrode EL1 is a cathode, the second electrode EL2 may be an anode. The second electrode EL2 may include at least one selected among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and/or oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, Yb, W, compounds including thereof, and/or mixtures thereof (for example, AgMg, AgYb, and/or MgYb). Otherwise, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In one or more embodiments, the second electrode EL2 may be connected with an auxiliary electrode. If the second electrode EL2 is connected with the auxiliary electrode, the resistance of the second electrode EL2 may decrease.

In one or more embodiments, a capping layer CPL may be further on the second electrode EL2 in the light emitting element ED of one or more embodiments. The capping layer CPL may include a multilayer or a single layer.

In one or more embodiments, the capping layer CPL may be an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., and/or includes an epoxy resin, and/or acrylate such as methacrylate. In addition, a capping layer CPL may include at least one selected from among Compounds P1 to P5 below, but one or more embodiments of the present disclosure are not limited thereto.

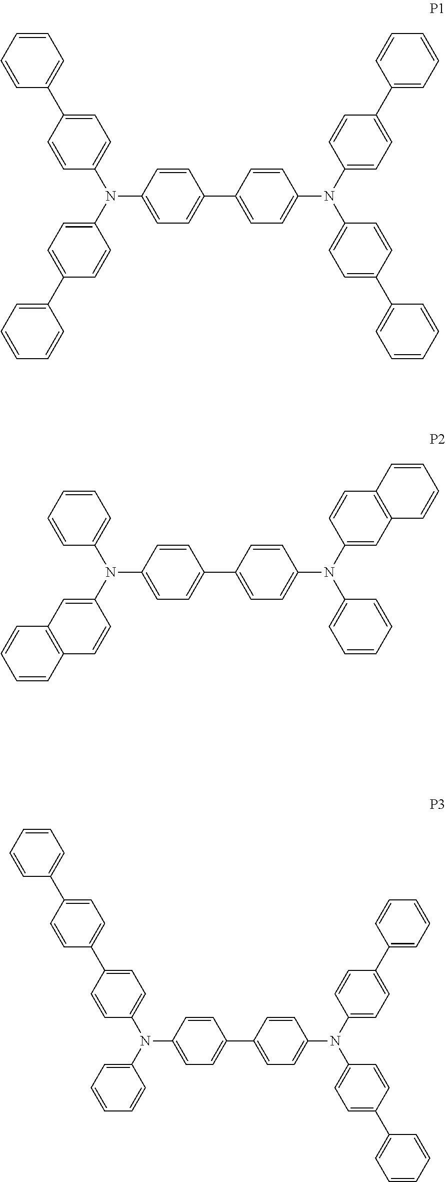 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

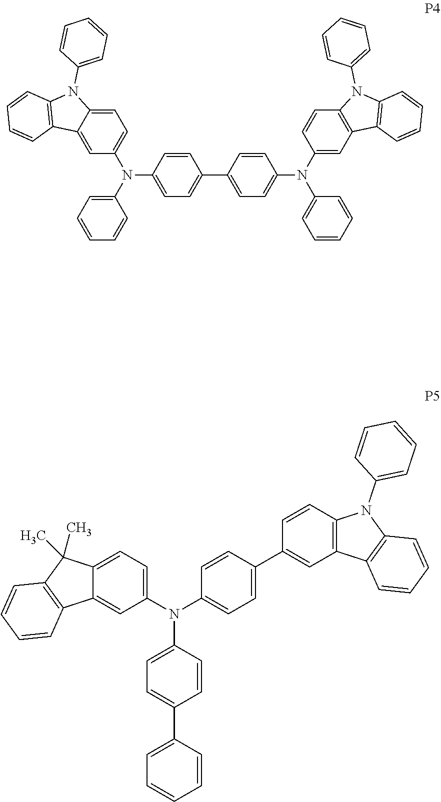 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL with respect to light in a wavelength range of about 550 nm to about 660 nm may be about 1.6 or more.

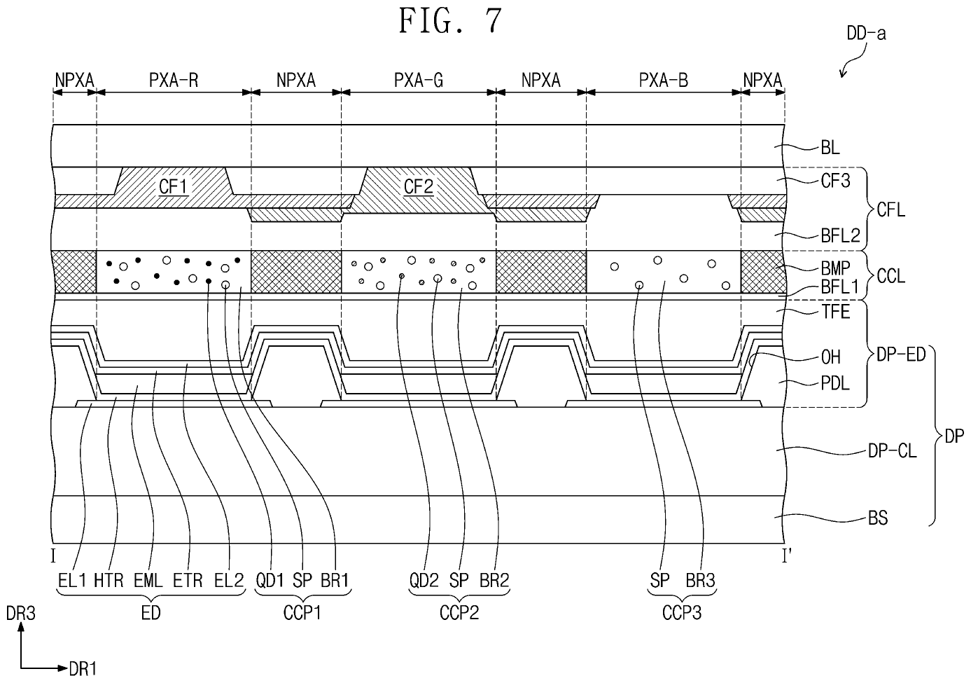

FIG. 7 to FIG. 10 are cross-sectional views of display devices according to embodiments. In the explanation on the display devices of embodiments, referring to FIG. 7 to FIG. 10, the overlapping parts with the explanation on FIG. 1 to FIG. 6 will not be explained again here, and the different features will be explained chiefly.

Referring to FIG. 7, a display device DD-a according to one or more embodiments may include a display panel DP including a display element layer DP-ED, a light controlling layer CCL on the display panel DP, and a color filter layer CFL.

In one or more embodiments shown in FIG. 7, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. the same structures of the light emitting elements of FIG. 3 to FIG. 6 may be applied to the structure of the light emitting element ED shown in FIG. 7.

The emission layer EML of the light emitting element ED included in the display device DD-a according to one or more embodiments may include the polycyclic compound of one or more embodiments.

Referring to FIG. 7, the emission layer EML may be in an opening part OH defined in a pixel definition layer PDL. For example, the emission layer EML divided by the pixel definition layer PDL and correspondingly provided to each of luminous areas PXA-R, PXA-G and PXA-B may emit light in the same wavelength region. In the display device DD-a of one or more embodiments, the emission layer EML may emit blue light. In one or more embodiments, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot and/or a phosphor. The light converter may transform the wavelength of light provided and then emit. For example, the light controlling layer CCL may be a layer including a quantum dot and/or a layer including a phosphor.

The light controlling layer CCL may include a plurality of light controlling parts CCP1, CCP2 and CCP3. The light controlling parts CCP1, CCP2 and CCP3 may be separated from one another.

Referring to FIG. 7, a partition pattern BMP may be between the separated light controlling parts CCP1, CCP2 and CCP3, but one or more embodiments of the present disclosure are not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting element ED into second color light, a second light controlling part CCP2 including a second quantum dot QD2 converting first color light into third color light, and a third light controlling part CCP3 transmitting first color light.

In one or more embodiments, the first light controlling part CCP1 may provide red light which is the second color light, and the second light controlling part CCP2 may provide green light which is the third color light. The third light controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described above may be applied.

In addition, the light controlling layer CCL may further include a scatterer SP (e.g., a light scatterer SP). The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2 and BR3 are mediums in which the quantum dots QD1 and QD2 and the scatterer SP are dispersed, and may be composed of various suitable resin compositions which may be generally referred to as a binder. For example, the base resins BR1, BR2 and BR3 may be acrylic-based resins, urethane-based resins, silicone-based resins, epoxy-based resins, etc. The base resins BR1, BR2 and BR3 may be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, will be referred to as “humidity/oxygen”). The barrier layer BFL1 may be on the light controlling parts CCP1, CCP2 and CCP3 to block the exposure of the light controlling parts CCP1, CCP2 and CCP3 to humidity/oxygen. In one or more embodiments, the barrier layer BFL1 may cover the light controlling parts CCP1, CCP2 and CCP3. In addition, the barrier layer BFL2 may be provided between the light controlling parts CCP1, CCP2 and CCP3 and filters CF1, CF2 and CF3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride and/or a metal thin film securing light transmittance. In one or more embodiments, the barrier layers BFL1 and BFL2 may further include an organic layer. The barrier layers BFL1 and BFL2 may be composed of a single layer of a plurality of layers.

In the display device DD-a of one or more embodiments, the color filter layer CFL may be on the light controlling layer CCL. For example, the color filter layer CFL may be directly on the light controlling layer CCL. In this case, the barrier layer BFL2 may be omitted.

The color filter layer CFL may include filters CF1, CF2 and CF3. The color filter layer CFL may include a first filter CF1 that transmits a second color light, a second filter CF2 that transmits a third color light, and a third filter CF3 that transmits a first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. One or more embodiments of the present disclosure, however, are not limited thereto, and the third filter CF3 may not include the pigment or dye. The third filter CF3 may include a polymer photosensitive resin and not include a pigment or dye. The third filter CF3 may be transparent. The third filter CF3 may be formed using a transparent photosensitive resin.

In addition, in one or more embodiments, the first filter CF1 and the second filter CF2 may be yellow filters. The first filter CF1 and the second filter CF2 may be provided in one body without distinction. Each of the first to third filters CF1, CF2 and CF3 may correspond to each of a red luminous area PXA-R, green luminous area PXA-G, and blue luminous area PXA-B.

In one or more embodiments, the color filter layer CFL may include a light blocking part. The color filter layer CFL may include the light blocking part so as to overlap with the boundaries of the neighboring filters CF1, CF2 and CF3. The light blocking part may be a black matrix. The light blocking part may be formed by including an organic light blocking material and/or an inorganic light blocking material, including a black pigment and/or black dye. The light blocking part may divide the boundaries among adjacent filters CF1, CF2 and CF3. In addition, in one or more embodiments, the light blocking part may be formed as a blue filter.

A base substrate BL may be on the color filter layer CFL. The light controlling layer CCL, etc. may be on a base surface of the base substrate BL. The base substrate BL may be a glass substrate, a metal substrate, a plastic substrate, etc. However, one or more embodiments of the present disclosure are not limited thereto, and the base substrate BL may be an inorganic layer, an organic layer or a composite material layer. In addition, different from the drawing, the base substrate BL may be omitted in one or more embodiments.

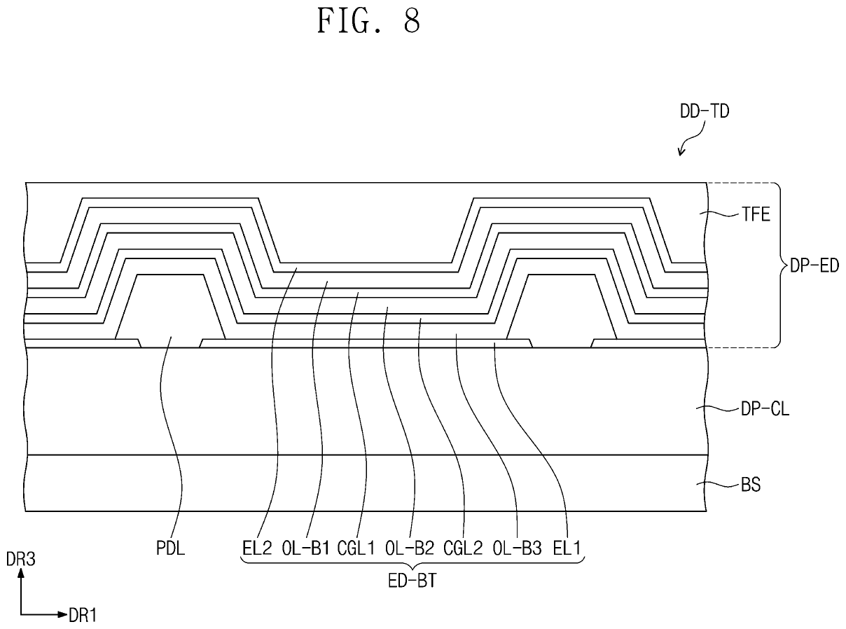

FIG. 8 is a cross-sectional view showing a portion of the display device according to one or more embodiments. FIG. 8 illustrates another embodiment of a part corresponding to the display panel DP of FIG. 7. In a display device DD-TD of one or more embodiments, the light emitting element ED-BT may include a plurality of light emitting structures OL-B1, OL-B2 and OL-B3. The light emitting element ED-BT may include a first electrode EL1 and a second electrode EL2 opposite to each other, and the plurality of light emitting structures OL-B1, OL-B2 and OL-B3 stacked in order in a thickness direction and provided between the first electrode EL1 and the second electrode EL2. At least one selected from among the light emitting structures OL-B1, OL-B2 and OL-B3 may include the above-explained polycyclic compound of one or more embodiments. Each of the light emitting structures OL-B1, OL-B2 and OL-B3 may include an emission layer EML (FIG. 7), a hole transport region HTR (FIG. 7) and an electron transport region ETR (FIG. 7) with the emission layer EML therebetween.

In one or more embodiments, the light emitting element ED-BT included in the display device DD-TD of one or more embodiments may be a light emitting element of a tandem structure including a plurality of emission layers EML.

In one or more embodiments shown in FIG. 8, light emitted from each of the light emitting structures OL-B1, OL-B2 and OL-B3 may be all blue light. However, one or more embodiments of the present disclosure are not limited thereto, and the wavelength regions of light emitted from the light emitting structures OL-B1, OL-B2 and OL-B3 may be different from each other. For example, the light emitting element ED-BT including the plurality of light emitting structures OL-B1, OL-B2 and OL-B3 emitting light in different wavelength regions may emit white light.

Charge generating layers CGL1 and CGL2 may be respectively between neighboring light emitting structures OL-B1, OL-B2 and OL-B3. The charge generating layers CGL1 and CGL2 may include a p-type charge generating layer and/or an n-type charge generating layer.

In at least one selected from among the light emitting structures OL-B1, OL-B2 and OL-B3, included in the display device DD-TD of one or more embodiments, the polycyclic compound of one or more embodiments may be included. In one or more embodiments, at least one selected from among a plurality of emission layers included in the light emitting element ED-BT, the polycyclic compound of one or more embodiments may be included.

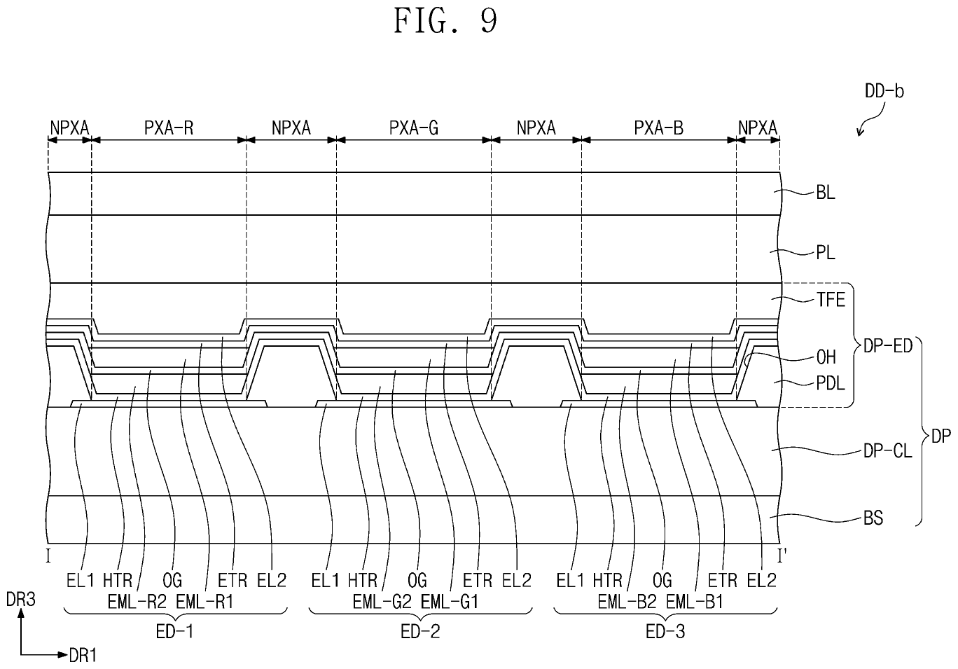

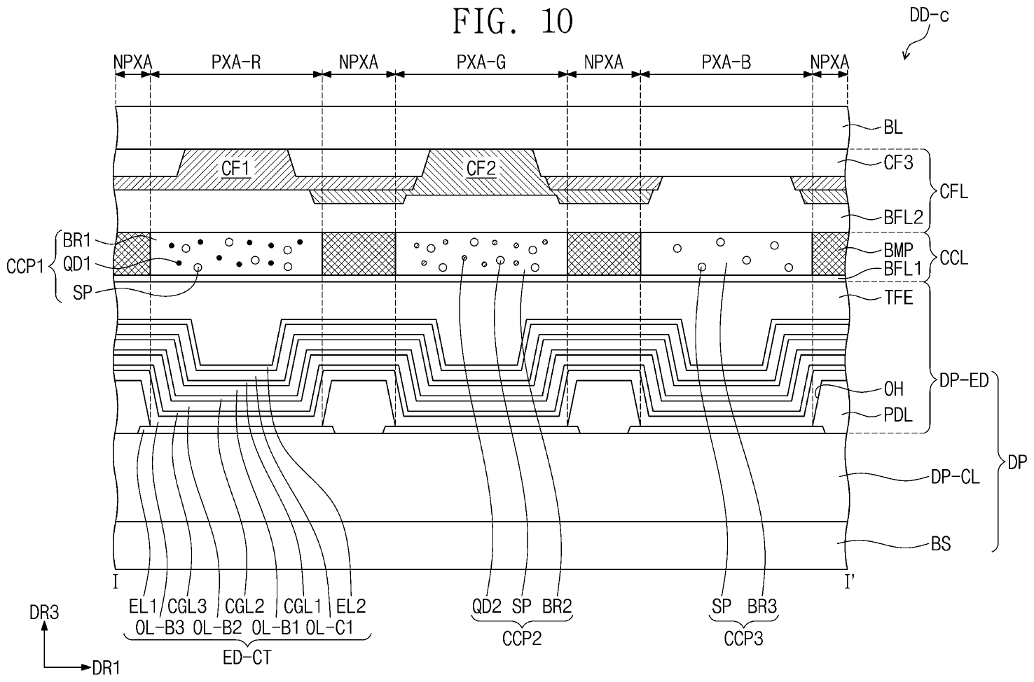

Referring to FIG. 9, a display device DD-b according to one or more embodiments may include light emitting elements ED-1, ED-2 and ED-3, formed by stacking two emission layers. Compared to the display device DD of one or more embodiments, shown in FIG. 2, one or more embodiments shown in FIG. 9 is different in that first to third light emitting elements ED-1, ED-2 and ED-3 include two emission layers stacked in a thickness direction, each. In the first to third light emitting elements ED-1, ED-2 and ED-3, two emission layers may emit light in the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generating layer. For example, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, one or more embodiments of the present disclosure are not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be between the electron transport region ETR and the emission auxiliary part OG. The second red emission layer EML-R2, the second green emission layer EML-G2 and the second blue emission layer EML-B2 may be between the emission auxiliary part OG and the hole transport region TTR.

In one or more embodiments, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

In one or more embodiments, an optical auxiliary layer PL may be on a display element layer DP-ED. The optical auxiliary layer PL may include a polarization layer. The optical auxiliary layer PL may be on a display panel DP and may control reflected light at the display panel DP by external light. Different from the drawings, the optical auxiliary layer PL may be omitted from the display device DD-b according to one or more embodiments.

At least one emission layer included in the display device DD-b of one or more embodiments, shown in FIG. 9, may include the polycyclic compound of one or more embodiments. For example, in one or more embodiments, at least one selected from among the first blue emission layer EML-B1 and the second blue emission layer EML-B2 may include the polycyclic compound of one or more embodiments.

Different from FIG. 8 and FIG. 9, a display device DD-c in FIG. 10 is shown to include four light emitting structures OL-B1, OL-B2, OL-B3 and OL-C1. A light emitting element ED-CT may include a first electrode EL1 and a second electrode EL2 opposite to each other, and first to fourth light emitting structures OL-B1, OL-B2, OL-B3 and OL-C1 stacked in order in a thickness direction between the first electrode EL1 and the second electrode EL2. Charge generating layers CGL1, CGL2 and CGL3 may be respectively between the first to fourth light emitting structures OL-B1, OL-B2, OL-B3 and OL-C1. Among the four light emitting structures, the first to third light emitting structures OL-B1, OL-B2 and OL-B3 may emit blue light, and the fourth light emitting structure OL-C1 may emit green light. However, one or more embodiments of the present disclosure are not limited thereto, and the first to fourth light emitting structures OL-B1, OL-B2, OL-B3 and OL-C1 may emit different wavelengths of light.

Charge generating layers CGL1, CGL2 and CGL3 among neighboring light emitting structures OL-B1, OL-B2, OL-B3 and OL-C1 may include a p-type charge generating layer and/or an n-type charge generating layer.

In at least one selected from among the light emitting structures OL-B1, OL-B2, OL-B3 and OL-C1, included in the display device DD-c of one or more embodiments, the polycyclic compound of one or more embodiments may be included. For example, in one or more embodiments, at least one selected from among the light emitting structures OL-B1, OL-B2, OL-B3 may include the polycyclic compound of one or more embodiments.

The light emitting element ED according to one or more embodiments of the present disclosure may include the polycyclic compound of one or more embodiments in at least one functional layer between the first electrode EL1 and the second electrode EL2 to show excellent emission efficiency and improved life characteristics. For example, the polycyclic compound of one or more embodiments may be included in the emission layer EML of the light emitting element ED of one or more embodiments, and the light emitting element of one or more embodiments may show long-life characteristics concurrently (e.g., simultaneously).

Hereinafter, referring to embodiments and comparative embodiments, the polycyclic compound according to one or more embodiments and the light emitting element according to one or more embodiments of the present disclosure will be explained in more detail. In addition, the embodiments below are illustrations to assist the understanding of the subject matter of the present disclosure, but the scope of the present disclosure is not limited thereto.

### Examples

### 1. Synthesis of Polycyclic Compounds

First, the synthetic method of the polycyclic compound according to one or more embodiments will be explained in more detail by illustrating the synthetic methods of Compound A-6, Compound A-16, Compound A-21 and Compound C-1. In addition, the synthetic methods of the polycyclic compounds explained hereinafter are embodiments, and the synthetic method of the polycyclic compound according to one or more embodiments of the present disclosure are not limited to the embodiments below.

### (1) Synthesis of Compound A-6

Compound A-6 according to one or more embodiments may be synthesized, for example, by Reaction 1 below.

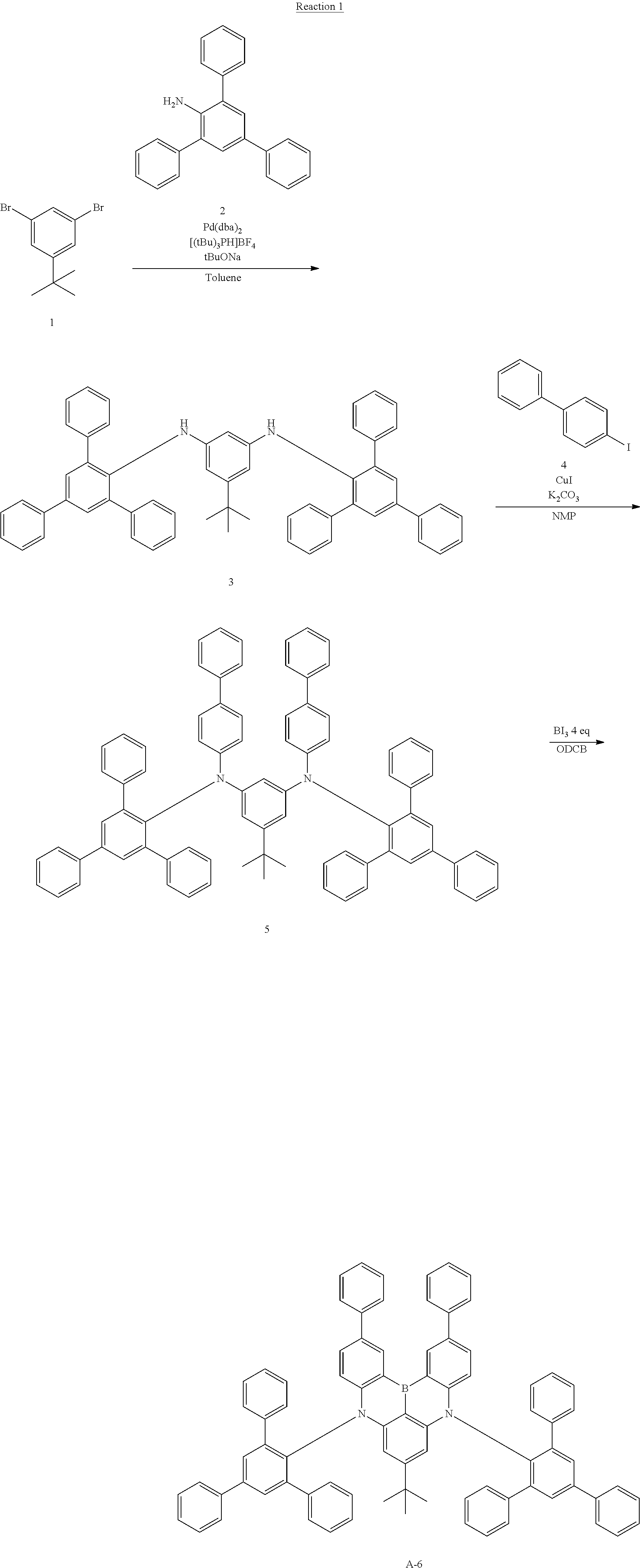

To a three-necked flask, Intermediate 1 (200 mmol), Intermediate 2 (400 mmol), Pd(dba)₂ (20 mmol), [(tBu)₃PH]BF₄ (40 mmol), and tBuONa (500 mmol) were added, and argon (Ar) substitution was performed. Then, 1000 ml of toluene was added and stirred at about 100° C. for about 8 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (182 mmol, yield 91%). Through measuring fast atom bombardment mass spectrometry (FABMS) of the purified product thus obtained, a molecular weight of 773 was confirmed, and Intermediate 3 was confirmed.

Then, to a three-necked flask, Intermediate 3 (182 mmol), Intermediate 4 (1820 mmol), K₂CO₃ (1274 mmol), and CuI (218 mmol) were added, argon (Ar) substitution was performed, and 50 ml of NMP (N-methylpyrrolidone) was added for dissolution, followed by stirring at about 200° C. for about 71 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (155 mmol, yield 85%). Through measuring the FABMS of the purified product thus obtained, a molecular weight of 1077 was confirmed, and Intermediate 5 was confirmed.

Then, to a three-necked flask, Intermediate 5 (155 mmol) was added, Ar substitution was performed, 200 ml of ODCB (o-dichlorobenzene) was added for dissolution, and Bl₃ (619 mmol) was added, followed by stirring at about 190° C. for about 5 hours. The resultant reaction solution was dispersed and washed using a large amount of acetonitrile, and a solid was recovered through filtering. The crude product thus obtained was purified by silica gel column chromatography (hexane/dichloromethane mixture solvent) and recrystallization (ethanol/toluene mixture solvent) to obtain a yellow solid (46 mmol, yield 30%). Through measuring the FABMS of the purified product thus obtained, a molecular weight of 1085 was confirmed, and Compound A-6 was confirmed.

### (2) Synthesis of Compound A-16

Compound A-16 according to one or more embodiments may be synthesized, for example, by Reaction 2 below.

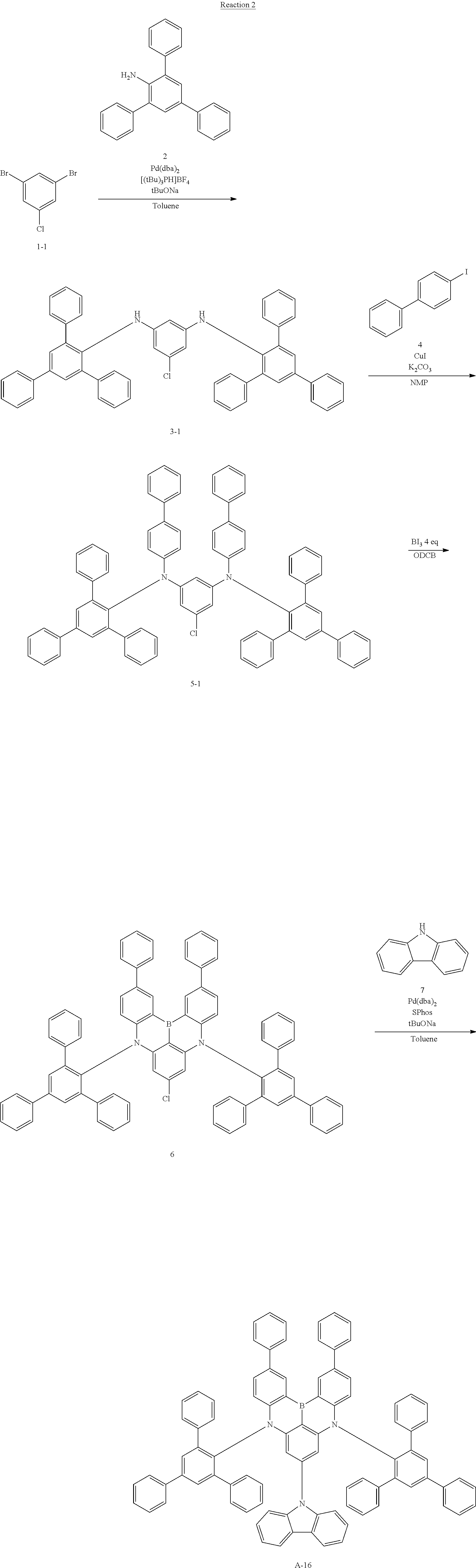

To a three-necked flask, Intermediate 1-1 (200 mmol), Intermediate 2 (420 mmol), Pd(dba)₂ (20 mmol), [(tBu)₃PH]BF₄ (40 mmol), and tBuONa (500 mmol) were added, and Ar substitution was performed. Then, 1000 ml of toluene was added and stirred at about 60° C. for about 12 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (168 mmol, yield 84%). Through measuring FABMS of the purified product thus obtained, a molecular weight of 751 was confirmed, and Intermediate 3-1 was confirmed.

Then, to a three-necked flask, Intermediate 3-1 (168 mmol), Intermediate 4 (1680 mmol), K₂CO₃ (1176 mmol), and CuI (202 mmol) were added, Ar substitution was performed, and 100 ml of NMP was added for dissolution, followed by stirring at about 200° C. for about 80 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (151 mmol, yield 90%). Through measuring the FABMS of the purified product thus obtained, a molecular weight of 1055 was confirmed, and Intermediate 5-1 was confirmed.

Then, to a three-necked flask, Intermediate 5-1 (151 mmol) was added, Ar substitution was performed, 200 ml of ODCB was added for dissolution, and Bl₃ (605 mmol) was added, followed by stirring at about 190° C. for about 2 hours. The resultant reaction solution was dispersed and washed using a large amount of acetonitrile, and a solid was recovered through filtering. The crude product thus obtained was purified by silica gel column chromatography (hexane/dichloromethane mixture solvent) and recrystallization (ethanol/toluene mixture solvent) to obtain a yellow solid (53 mmol, yield 35%). Through measuring the FABMS of the purified product thus obtained, a molecular weight of 1063 was confirmed, and Intermediate 6 was confirmed.

Then, to a three-necked flask, Intermediate 6 (53 mmol), Intermediate 7 (79 mmol), Pd(dba)₂ (5 mmol), SPhos (2-dicyclohexylphosphino-2′,6′-dimethoxybiphenyl) (11 mmol), and tBuONa (106 mmol) were added, Ar substitution was performed, and 100 ml of toluene was added, followed by stirring at about 100° C. for about 5 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a yellow solid (30 mmol, yield 56%). Through measuring the FABMS of the purified product thus obtained, a molecular weight of 1194 was confirmed, and Compound A-6 was confirmed.

### (3) Synthesis of Compound A-21

Compound A-21 according to one or more embodiments may be synthesized, for example, by Reaction 3 below.

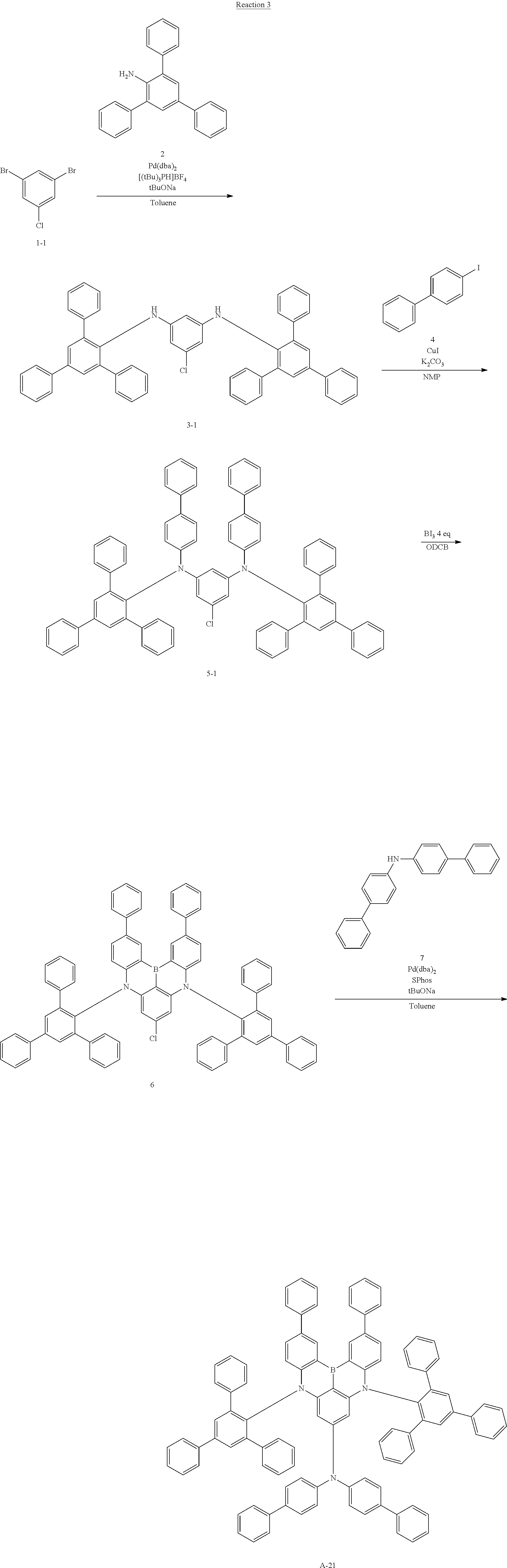

To a three-necked flask, Intermediate 1-1 (200 mmol), Intermediate 2 (420 mmol), Pd(dba)₂ (20 mmol), [(tBu)₃PH]BF₄ (40 mmol), and tBuONa (500 mmol) were added, and Ar substitution was performed. Then, 1000 ml of toluene was added and stirring was performed at about 60° C. for about 12 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (168 mmol, yield 84%). Through measuring the FABMS of the purified product thus obtained, a molecular weight of 751 was confirmed, and Intermediate 3-1 was confirmed.

Then, to a three-necked flask, Intermediate 3-1 (168 mmol), Intermediate 4 (1680 mmol), K₂CO₃ (1176 mmol), and CuI (202 mmol) were added, Ar substitution was performed, and 100 ml of NMP was added for dissolution, followed by stirring at about 200° C. for about 80 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (151 mmol, yield 90%). Through measuring the FABMS of the purified product thus obtained, a molecular weight of 1055 was confirmed, and Intermediate 5-1 was confirmed.

Then, to a three-necked flask, Intermediate 5-1 (151 mmol) was added, Ar substitution was performed, 200 ml of ODCB was added for dissolution, and Bl₃ (605 mmol) was added, followed by stirring at about 190° C. for about 2 hours. The resultant reaction solution was dispersed and washed using a large amount of acetonitrile, and a solid was recovered through filtering. The crude product thus obtained was purified by silica gel column chromatography (hexane/dichloromethane mixture solvent) and recrystallization (ethanol/toluene mixture solvent) to obtain a yellow solid (53 mmol, yield 35%). Through measuring the FABMS of the purified product thus obtained, a molecular weight of 1063 was confirmed, and Intermediate 6 was confirmed.

Then, to a three-necked flask, Intermediate 6 (53 mmol), Intermediate 7 (79 mmol), Pd(dba)₂ (5 mmol), SPhos (11 mmol), and tBuONa (106 mmol) were added, Ar substitution was performed, and 100 ml of toluene was added, followed by stirring at about 100° C. for about 5 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a yellow solid (38 mmol, yield 72%). Through measuring the FABMS of the purified product thus obtained, a molecular weight of 1348 was confirmed, and Compound A-21 was confirmed.

### (4) Synthesis of Compound C-1

Compound C-1 according to one or more embodiments may be synthesized, for example, by Reaction 4-1 and Reaction 4-2 below.

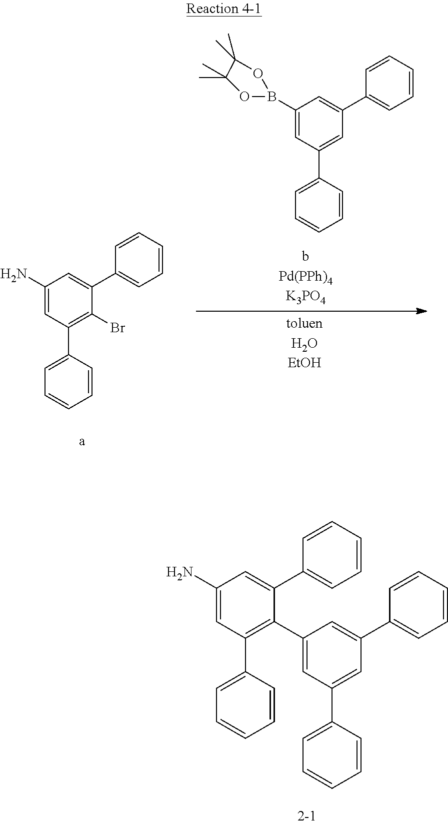 [SMILES: CC1(C)OB(c2cc(-c3ccccc3)cc(-c3ccccc3)c2)OC1(C)C ; Nc1cc(-c2ccccc2)c(Br)c(-c2ccccc2)c1 ; Nc1cc(-c2ccccc2)c(-c2cc(-c3ccccc3)cc(-c3ccccc3)c2)c(-c2ccccc2)c1]

1) To a three-necked flask, Intermediate a (300 mmol), Intermediate b (300 mmol), Pd(PPh)₄ (30 mmol), and K₃PO₄ (600 mmol) were added, and Ar substitution was performed. Then, 1000 ml of toluene was added and stirring was performed at about 100° C. for about 3 hours. EtOH (ethanol, 100 mL) and water (H₂O, 100 mL) was added to the resultant reaction system and mixed, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (248 mmol, yield 83%). Through measuring the FABMS of the purified product thus obtained, a molecular weight of 474 was confirmed, and Intermediate 2-1 was confirmed.

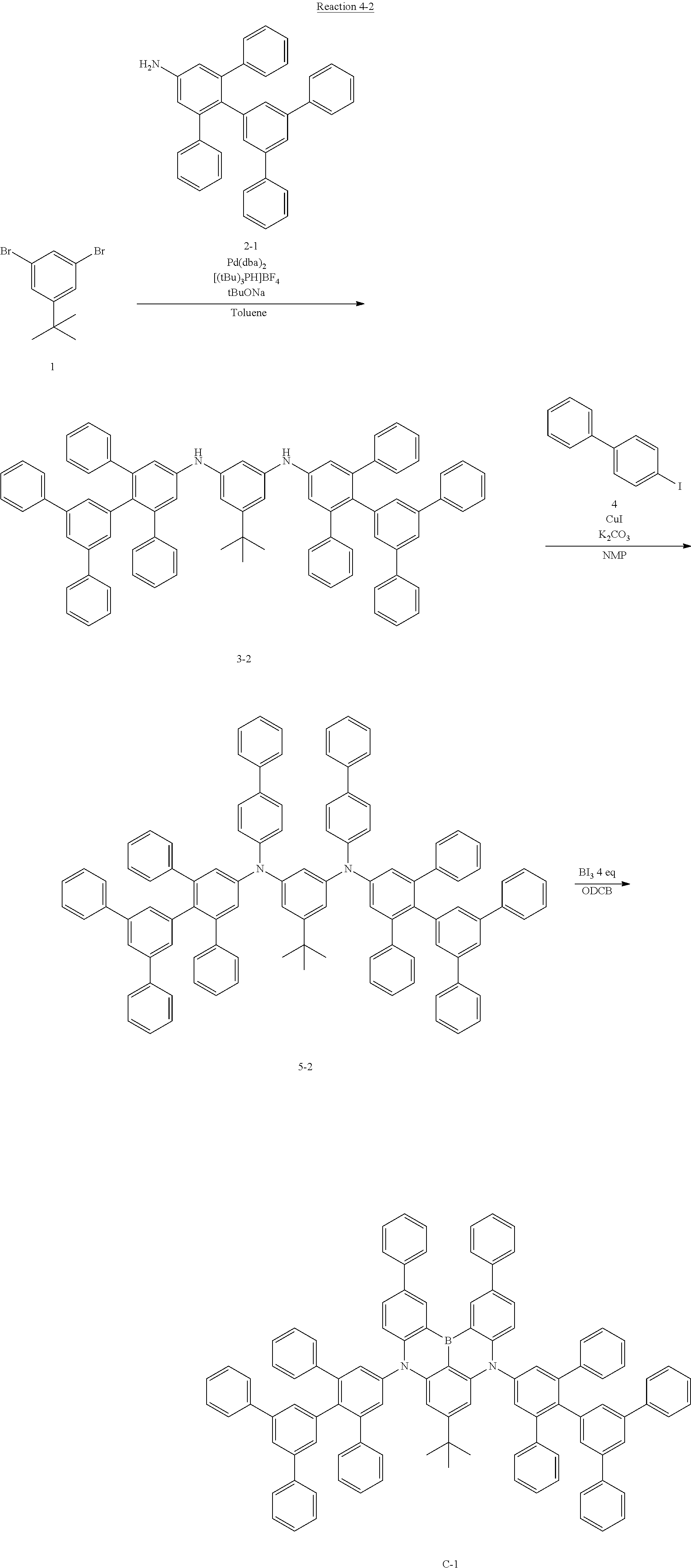

2) To a three-necked flask, Intermediate 1 (200 mmol), Intermediate 2-1 (420 mmol), Pd(dba)₂ (20 mmol), [(tBu)₃PH]BF₄ (40 mmol), and tBuONa (500 mmol) were added, and Ar substitution was performed. Then, 1000 ml of toluene was added and stirring was performed at about 100° C. for about 8 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (168 mmol, yield 84%). Through measuring the FABMS of the purified product thus obtained, a molecular weight of 1077 was confirmed, and Intermediate 3-2 was confirmed.

Then, to a three-necked flask, Intermediate 3-2 (168 mmol), Intermediate 4 (1680 mmol), K₂CO₃ (1176 mmol), and CuI (185 mmol) were added, Ar substitution was performed, and 20 ml of NMP was added for dissolution, followed by stirring at about 200° C. for about 58 hours. Water was added to the resultant reaction system, an organic layer was extracted using toluene and dried over magnesium sulfate, and the solvent was removed utilizing distillation. The crude product thus obtained was purified by silica gel column chromatography (hexane/toluene mixture solvent) and recrystallization (ethanol/toluene mixture solvent) to obtain a white solid (145 mmol, yield 86%). Through measuring the FABMS of the purified product thus obtained, a molecular weight of 1382 was confirmed, and Intermediate 5-2 was confirmed.

Then, to a three-necked flask, Intermediate 5-2 (145 mmol) was added, Ar substitution was performed, 50 ml of ODCB was added for dissolution, and Bl₃ (290 mmol) was added, followed by stirring at about 190° C. for about 2 hours. The resultant reaction solution was dispersed and washed using a large amount of acetonitrile, and a solid was recovered through filtering. The crude product thus obtained was purified by silica gel column chromatography (hexane/dichloromethane mixture solvent) and recrystallization (ethanol/toluene mixture solvent) to obtain a yellow solid (46 mmol, yield 32%). Through measuring the FABMS of the purified product thus obtained, a molecular weight of 1340 was confirmed, and Compound C-1 was confirmed.

### 2. Evaluation of Fluorescence Emission Properties of Polycyclic Compounds

In the evaluation of emission properties of the polycyclic compounds of embodiments and Comparative Compounds, emission wavelength was measured using HITACHI F-7000, and fluorescence quantum yield was measured using Hamamatsu Photonics Q-PLAY. In this case, the Example Compounds and Comparative Compounds were dissolved in a toluene solvent (10 μM) for measurement.

### Example Compounds

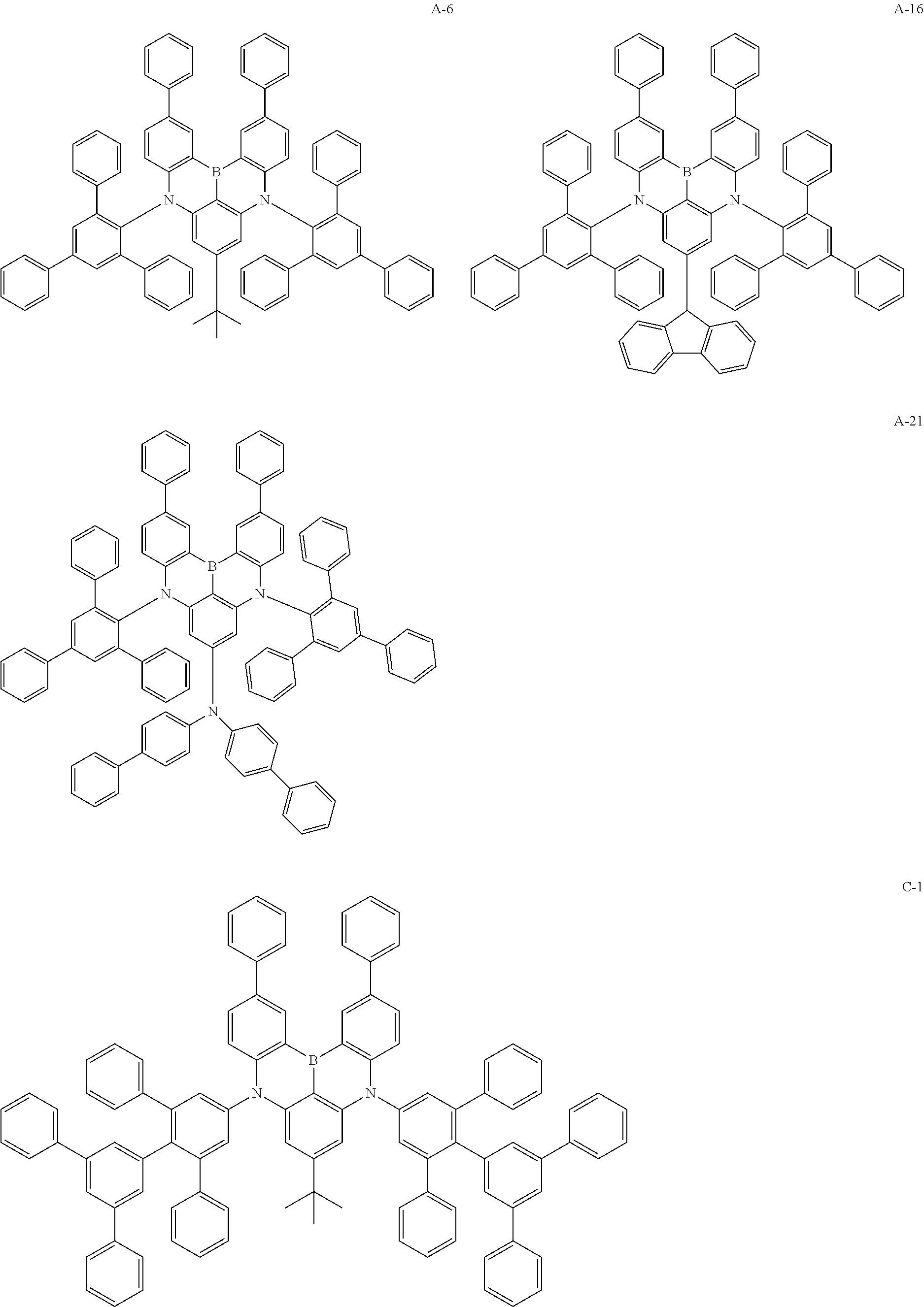

### Comparative Compounds

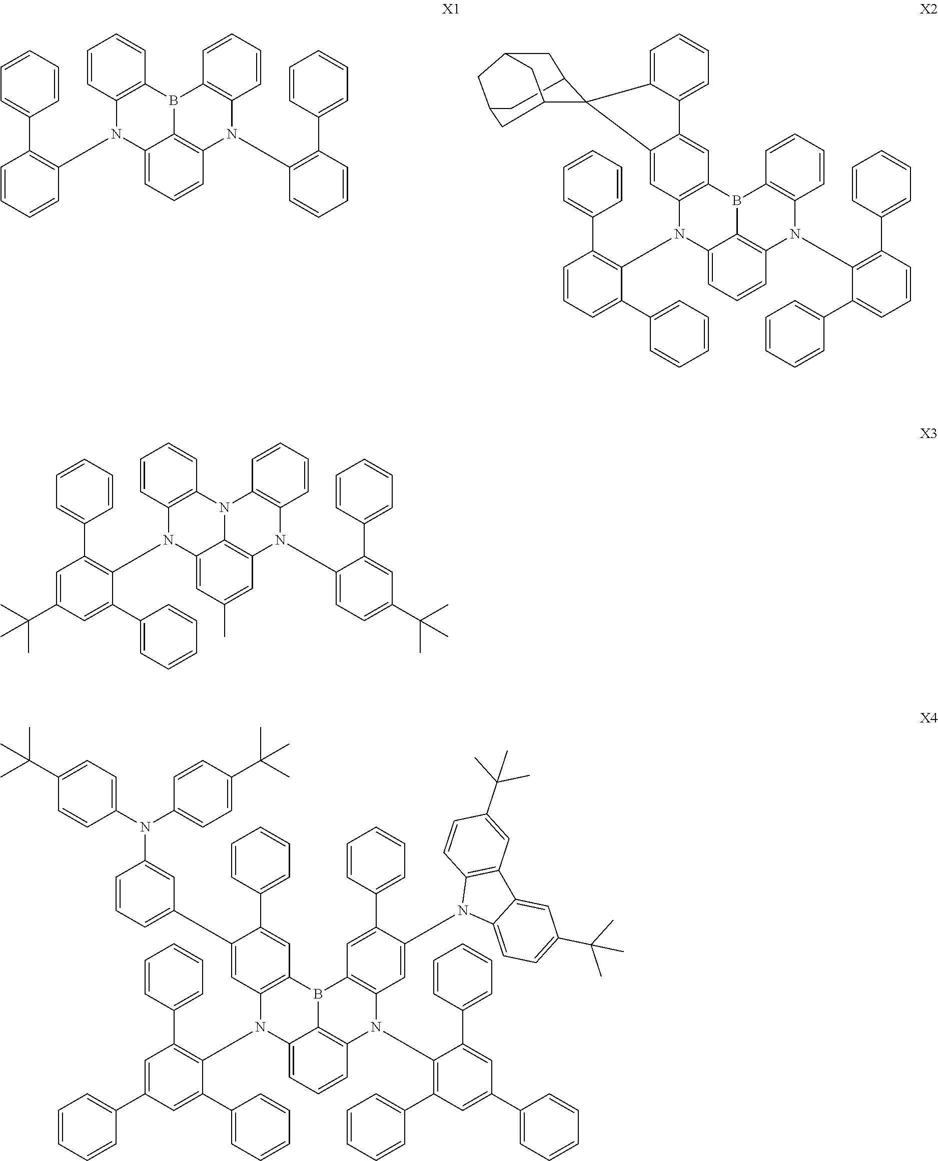

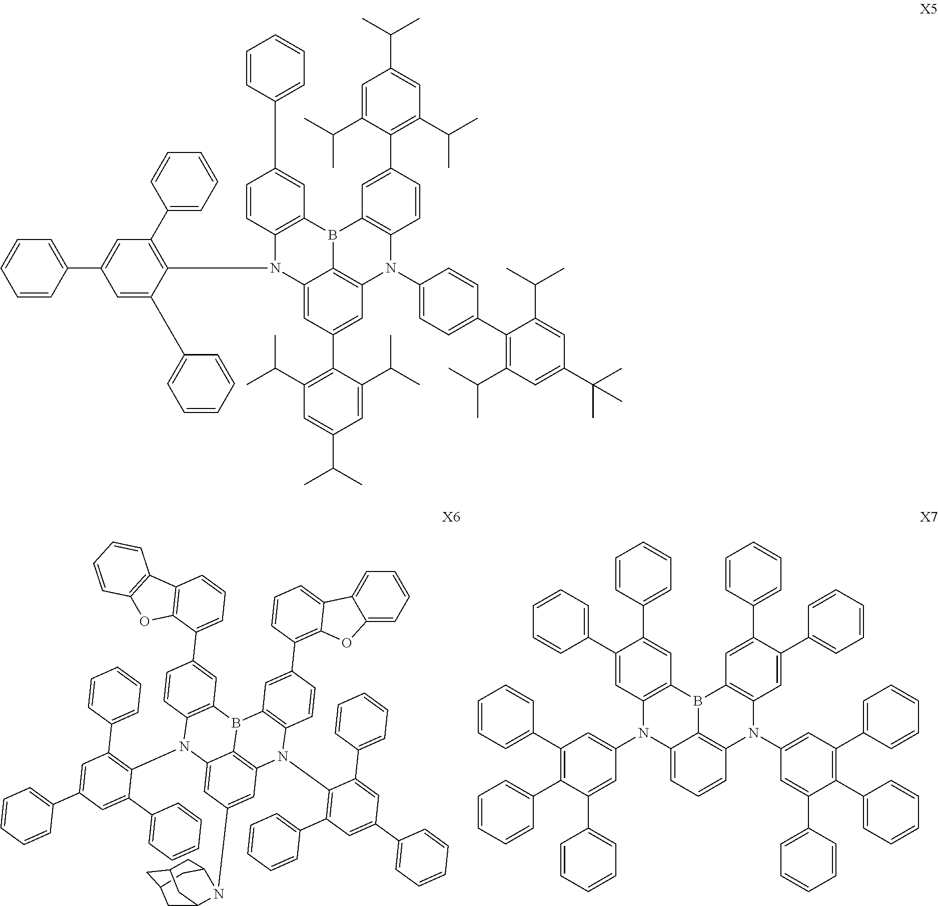

TABLE 1

| | | Fluorescence quantum |
|---|---|---|
| Compound | λmax/nm | yield/% |
| Example Compound A-6 | 464 | 95 |
| Example Compound A-16 | 457 | 70 |
| Example Compound A-21 | 458 | 80 |
| Example Compound C-1 | 466 | 90 |
| Comparative Compound X1 | 456 | 80 |
| Comparative Compound X2 | 462 | 80 |
| Comparative Compound X3 | 460 | 65 |
| Comparative Compound X4 | 467 | 70 |
| Comparative Compound X5 | 458 | 70 |
| Comparative Compound X6 | 452 | 90 |
| Comparative Compound X7 | 470 | 90 |

Referring to the results of Table 1, Example Compound A-6, Example Compound A-16, Example Compound A-21, and Example Compound C-1 emitted light in a wavelength region of about 450 nm to about 470 nm. The fluorescence quantum yield was measured as a value of about 70% to about 95%, and the Example Compounds were found to be suitable for the use as light-emitting materials.

### 3. Manufacture and Evaluation of Light Emitting Elements

Light emitting elements including the polycyclic compounds of embodiments or the Comparative Compounds in an emission layer were manufactured by a method below. Light emitting elements of Example 1 to Example 4 were manufactured using Compounds A-6, A-16, A-21 and C-1, which are the polycyclic compounds of embodiments as the dopant materials of an emission layer. Light emitting elements of Comparative Example 1 to Comparative Example 7 were manufactured using Comparative Compound X₁ to Comparative Compound X₇ as the dopant materials of an emission layer.

### (1) Manufacture of Light Emitting Element

A first electrode with a thickness of about 1500 Å was formed using ITO, washed using ultrapure water, and treated with UV-ozone for about 10 minutes. Then, on the first electrode, a hole injection layer with a thickness of about 100 Å was formed using dipyrazino[2,3-f: 2′,3′-h] quinoxaline-2,3,6,7,10,11-hexacarbonitrile (HAT-CN), and on the hole injection layer, a hole transport layer with a thickness of about 400 Å was formed using N,N′-Di(1-naphthyl)-N,N′-diphenyl-(1,1′-biphenyl)-4,4′-diamine (NPD or α-NPB).

On hole transport layer, an electron blocking layer having a thickness of about 50 Å was formed using 3,3′-Di(9H-carbazol-9-yl)-1,1′-biphenyl (mCBP), and an emission layer of a mixture of the Example Compound or Comparative Compound with mCBP in a ratio of about 1:99 was formed. In this case, the thickness of the emission layer was about 300 Å. On the emission layer, an electron transport layer with a thickness of about 300 Å was formed 1,3,5-tris(1-phenyl-1H-benzo[d]imidazole-2-yl)benzene (TPBi), and on the electron transport layer, an electron injection layer with a thickness of about 5 Å was formed using Liq. Then, on the electron injection layer, a second electrode having a thickness of about 1000 Å was formed using aluminum (Al). All layers were formed by a deposition method under a vacuum atmosphere.

The compounds used for the manufacture of the light emitting elements of the Examples and Comparative Examples are shown below. The materials below were used for the manufacture of the light emitting elements after performing sublimation purification.

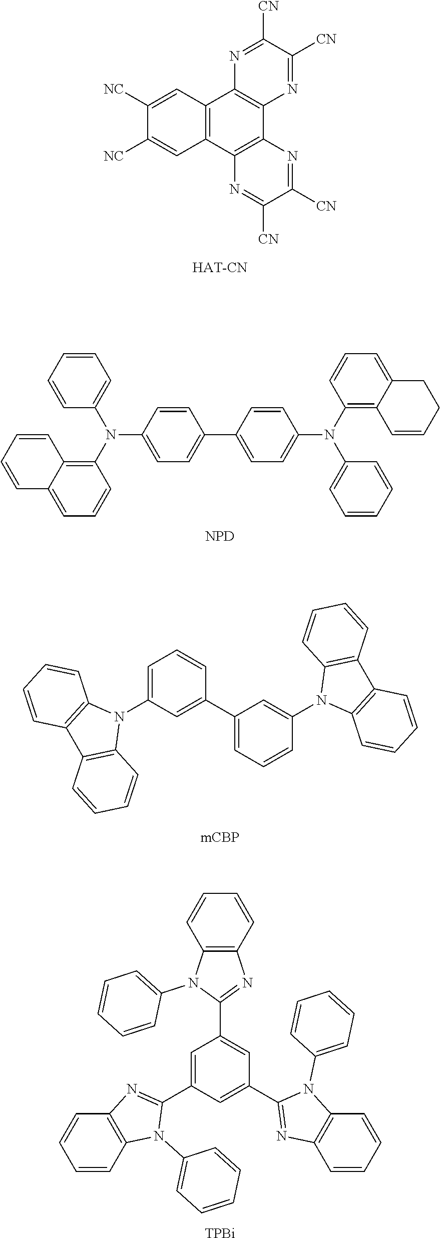

### (2) Evaluation of Properties of Light Emitting Elements

The properties of the light emitting elements of Example 1 to Example 4, and Comparative Example 1 to Comparative Example 7 were evaluated, and the results are shown in Table 2. For the evaluation of the light emitting elements, luminance and external quantum efficiency were measured using TOPCON SR-3AR. In Table 2, LT₅₀ is shown as a relative value considering that the half life of Comparative Example 1 is 100%, that is, relative element lifetime (LT₅₀, %).

TABLE 2

| | | | Relative | |
|---|---|---|---|---|
| | | | external | Relative |
| Element | | | emission | element |
| manufacturing | | λmax, | efficiency, | lifetime, |
| example | Dopant | nm | EQEₘₐₓ, % | LT₅₀, % |
| Example 1 | Example | 466 | 20 | 300 |
| | Compound A-6 | | | |
| Example 2 | Example | 459 | 22 | 220 |
| | Compound A-16 | | | |
| Example 3 | Example | 460 | 20 | 230 |
| | Compound A-21 | | | |
| Example 4 | Example | 467 | 17 | 220 |
| | Compound C-1 | | | |
| Comparative | Comparative | 462 | 14 | 100 |
| Example 1 | Compound X1 | | | |
| Comparative | Comparative | 466 | 12 | 90 |
| Example 2 | Compound X2 | | | |
| Comparative | Comparative | 462 | 11 | 110 |
| Example 3 | Compound X3 | | | |
| Comparative | Comparative | 467 | 15 | 130 |
| Example 4 | Compound X4 | | | |
| Comparative | Comparative | 458 | 15 | 100 |
| Example 5 | Compound X5 | | | |
| Comparative | Comparative | 452 | 15 | 120 |
| Example 6 | Compound X6 | | | |
| Comparative | Comparative | 470 | 18 | 160 |
| Example 7 | Compound X7 | | | |

Referring to the results of Table 2, it can be seen that the light emitting elements of the Examples using the polycyclic compounds according to one or more embodiments of the present disclosure showed excellent emission efficiency and markedly improved properties of element life when compared to the light emitting elements of the Comparative Examples.

From the results of Table 2, it can be seen that the polycyclic compound of one or more embodiments introduces a plurality of phenyl groups (substituents represented by Formula 2) in first and second benzene rings connected with the nitrogen atoms of a core part, and sterically protects the boron atom of the core part, and if using the polycyclic compound of one or more embodiments as a light-emitting material, long-life characteristics could be shown.

In contrast to the Comparative Compounds, the Example Compounds used in Examples 1 to 4 introduce at least three of the substituent represented by Formula 2 in first and second benzene rings and may increase the sterically protecting effects of the core part. In this case, the substituent represented by Formula 2 has a suppressed width of an orbital, and has effects of having high triplet energy and suppressing triplet energy transfer in a host. Accordingly, the light emitting elements of Examples 1 to 4 showed improved efficiency in addition to element stability. In addition, when compared to the Comparative Compounds used in Comparative Examples 1 to 3, the Example Compounds used in Examples 1 to 4 introduce the substituent represented by Formula 2 at the para position to the nitrogen atom of the core part, and show improved resonance stability and the stability of the material itself.

On the contrary, in Comparative Compound X4 used in Comparative Example 4, a carbazole group is connected at the para position to the boron atom of the core part, and molecular twist occurred due to steric hindrance, and resonance stability at the para position to the nitrogen atom of the core part was deteriorated, and element lifetime was reduced.

In Comparative Compound X5 used in Comparative Example 5, an alkyl group is connected at the position corresponding to Y₆ and Y₁₀ in the polycyclic compound of one or more embodiments, represented by Formula 1, and molecular twist occurred, and the stability at the connected part with the alkyl group was deteriorated.

Comparative Compound X6 used in Comparative Example 6 showed deteriorated resonance stability and material stability due to a dibenzofuran connected at the para position to the nitrogen atom of the core part.

In one or more embodiments, Example 4 using Example Compound C-1 showed improved life characteristics when compared to Comparative Example 7 using Comparative Compound X7. In the case of Comparative Compound X7, positions corresponding to R₁, R₅, R₆ and R₁₀ of Formula 1 of the present disclosure are all hydrogen atoms, and positions corresponding to R₂ to R₄ and R₇ to R₉ are all unsubstituted phenyl groups. Accordingly, it can be seen that Comparative Compound X7 is insufficient for sterically protecting the boron atom of the core part, and if used as a light-emitting material, element lifetime was deteriorated. On the contrary, in Example Compound C-1, the volume of the substituent represented by Formula 2 increased even further, and intermolecular distance could be increased, and if used as a light-emitting material, the stability of a light emitting element may be improved. Due to the influence of degrading energy transfer efficiency in a host molecule, Example Compound C-1 showed somewhat degraded results of EQEₘₐₓ when compared to Example Compound A-6, Example Compound A-16, and Example Compound A-21.

The light emitting element of one or more embodiments includes the polycyclic compound of one or more embodiments and may show improved life characteristics and high emission efficiency.

The polycyclic compound of one or more embodiments may be used as a light-emitting material for achieving improved properties of a light emitting element including long lifetime and high emission efficiency.

Although example embodiments of the present disclosure have been described, it is understood that the present disclosure should not be limited to these embodiments, but various changes and modifications can be made by one ordinary skilled in the art within the spirit and scope of the present disclosure as hereinafter claimed.

What is claimed is:

1. A light emitting element comprising:
a first electrode;
a second electrode on the first electrode; and
an emission layer between the first electrode and the second electrode,
wherein the emission layer comprises a first compound represented by the following Formula 1: 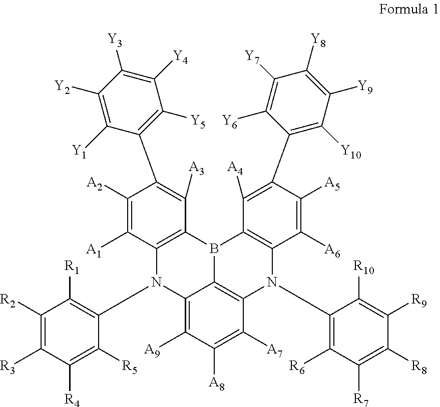
in Formula 1,
A₁ to A₉ are each independently a hydrogen atom, a deuterium atom, a halogen atom, a cyano group, a nitro group, a substituted or unsubstituted boron group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, where a case where at least one selected from among A₂ and A₅ is an unsubstituted carbazole group is excluded,
Y₁ to Y₁₀ are each independently a hydrogen atom, a deuterium atom, a halogen atom, a substituted or unsubstituted boron group, a substituted or unsubstituted amine group, a substituted or unsubstituted alkyl group of 1 to 20 carbon atoms, or a substituted or unsubstituted aryl group of 6 to 30 ring-forming carbon atoms, where a case where at least one selected from among Y₁, Y₅, Y₆ and Y₁₀ is a substituted or unsubstituted alkyl group of 1 to 20 carbon atoms is excluded,
R₁ to R₁₀ are each independently a hydrogen atom, a deuterium atom, or represented by the following Formula 2, or combined with an adjacent group to form a ring, where at least three among R₁ to R₅, or at least three among R₆ to R₁₀ are each independently represented by the following Formula 2, and
a case where R₁ and R₅ are all hydrogen atoms, and R₂ to R₄ are all unsubstituted phenyl groups, and a case where R₆ and R₁₀ are all hydrogen atoms, and R₇ to R₉ are all unsubstituted phenyl groups are excluded: 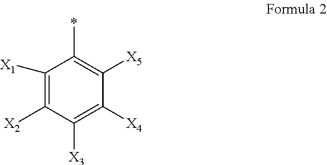
in Formula 2,
X₁ to X₅ are each independently a hydrogen atom, a deuterium atom, a halogen atom, a substituted or unsubstituted boron group, a substituted or unsubstituted amine group, a substituted or unsubstituted oxy group, a substituted or unsubstituted thio group, a substituted or unsubstituted alkyl group of 1 to 20 carbon atoms, or a substituted or unsubstituted aryl group of 6 to 30 ring-forming carbon atoms, or combined with an adjacent group to form a ring.

2. The light emitting element of claim 1, wherein the first compound is represented by the following Formula 3: 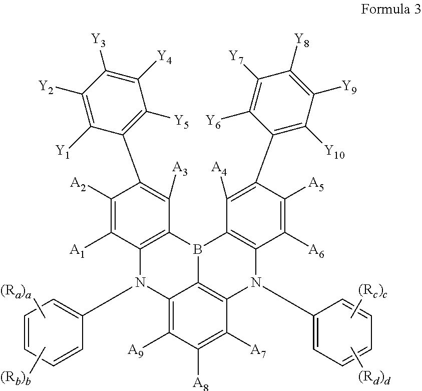
in Formula 3,
Rₐ and R_{c} are each independently represented by Formula 2,
R_{b} and R_{d} are each independently a hydrogen atom or a deuterium atom,
“a” and “c” are each independently an integer of 3 to 5,
“b” and “d” are each independently an integer of 0 to 2, and
A₁ to A₉, and Y₁ to Y₁₀ are the same as defined with respect to Formula 1.

3. The light emitting element of claim 1, wherein the first compound is represented by the following Formula 4: 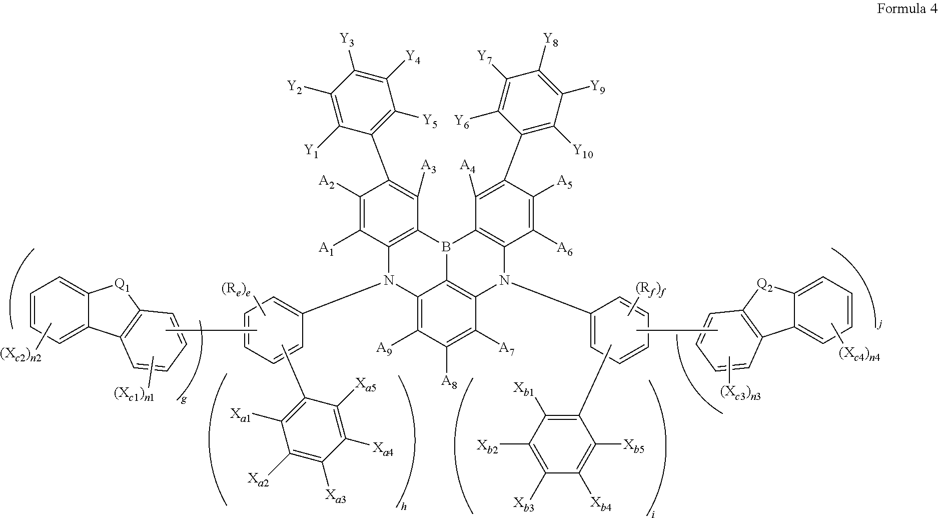
in Formula 4,
Q₁ and Q₂ are each independently O, S or NR_{q},
R_{q} is a substituted or unsubstituted aryl group of 3 to 10 ring-forming carbon atoms,
Rₑ and R_{f} are each independently a hydrogen atom or a deuterium atom,
Xₐ₁ to Xₐ₅, X_{b1} to X_{b5}, and X_{c1} to X_{c4} are each independently a hydrogen atom, a deuterium atom, a substituted or unsubstituted alkyl group of 1 to 20 carbon atoms, or a substituted or unsubstituted aryl group of 6 to 30 ring-forming carbon atoms,
“e” and “f” are each independently an integer of 0 to 2,
“g” and “j” are each independently an integer of 0 or 1,
“h” and “i” are each independently an integer of 2 to 5,
n1 and n3 are each independently an integer of 0 to 3,
n2 and n4 are each independently an integer of 0 to 4, and
A₁ to A₉, and Y₁ to Y₁₀ are the same as defined with respect to Formula 1.

4. The light emitting element of claim 1, wherein the first compound is represented by any one selected from among the following Formula 5-1 to Formula 5-3: 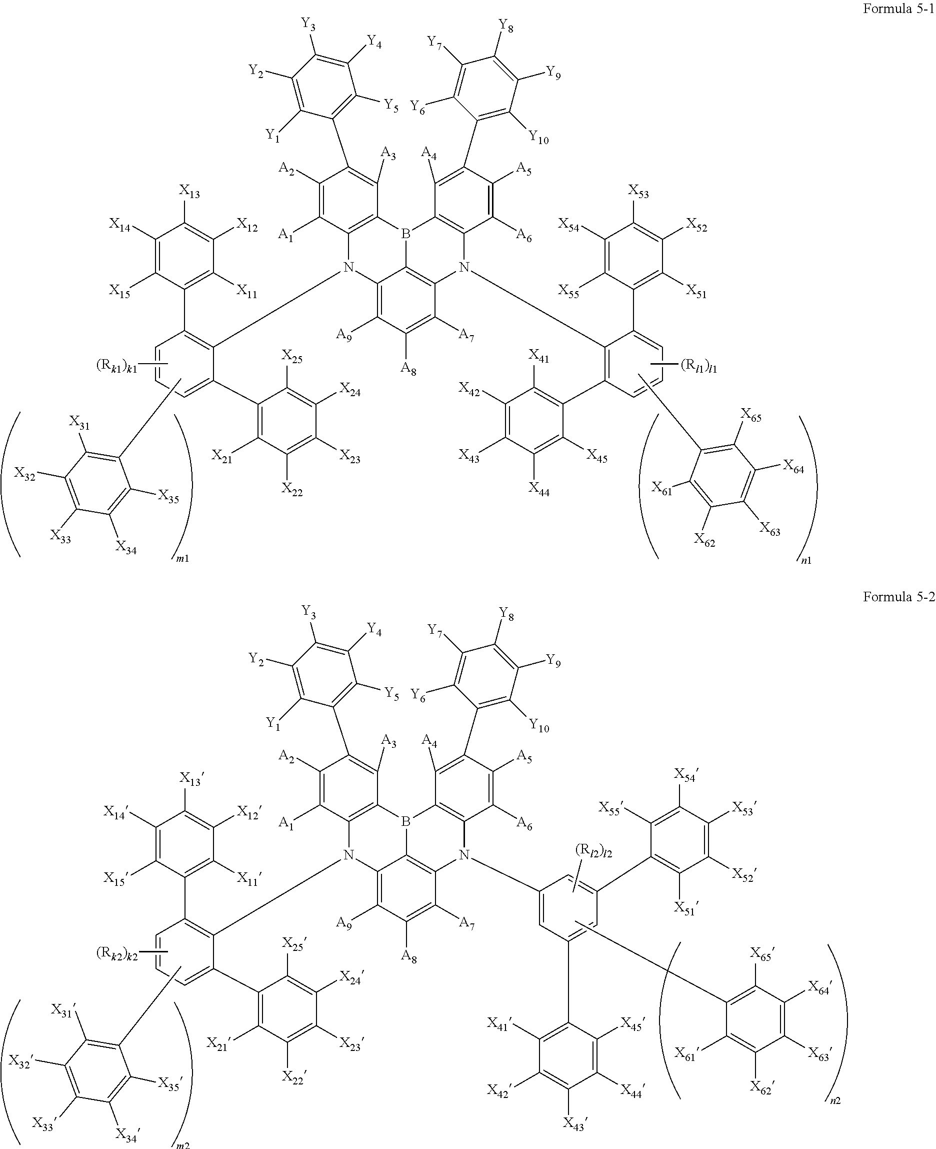 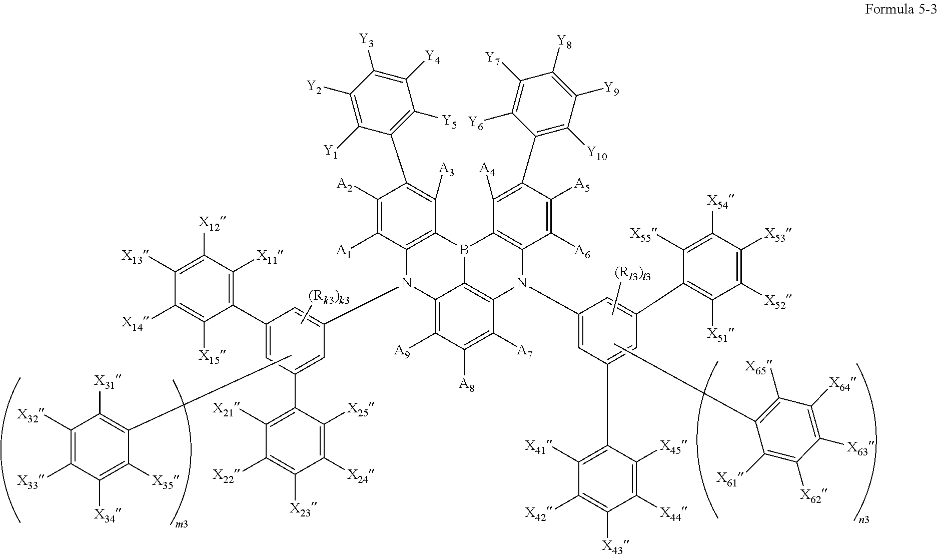
in Formula 5-1 to Formula 5-3,
Rₖ₁, Rₖ₂, Rₖ₃, Rₗ₁, Rₗ₂, and Rₗ₃ are each independently a hydrogen atom, or a deuterium atom,
X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X₆₅′, X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle,
k1 to k3, and 11 to 13 are each independently an integer of 0 to 2,
m1 to m3, and n1 to n3 are each independently an integer of 1 to 3, and
A₁ to A₉, and Y₁ to Y₁₀ are the same as defined with respect to Formula 1.

5. The light emitting element of claim 4, wherein the first compound represented by Formula 5-1 is represented by any one selected from among the following Formula 5-1-1 to Formula 5-1-4: 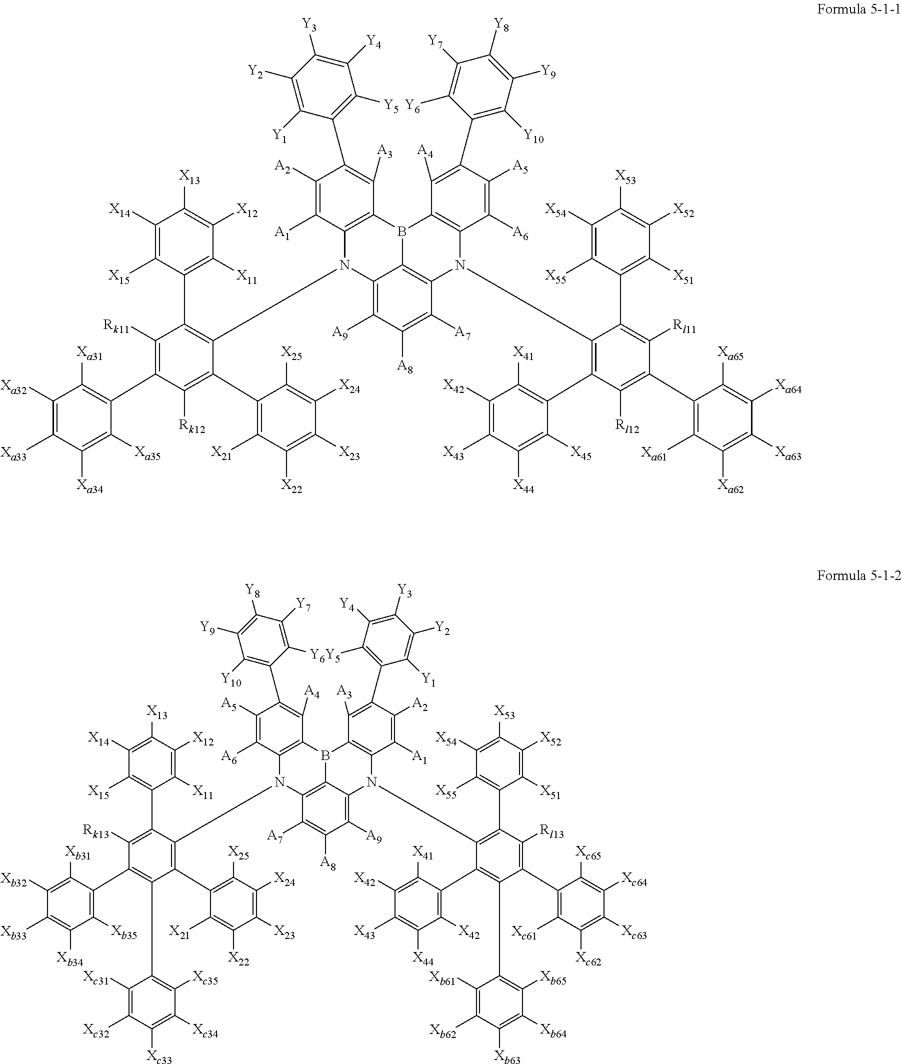 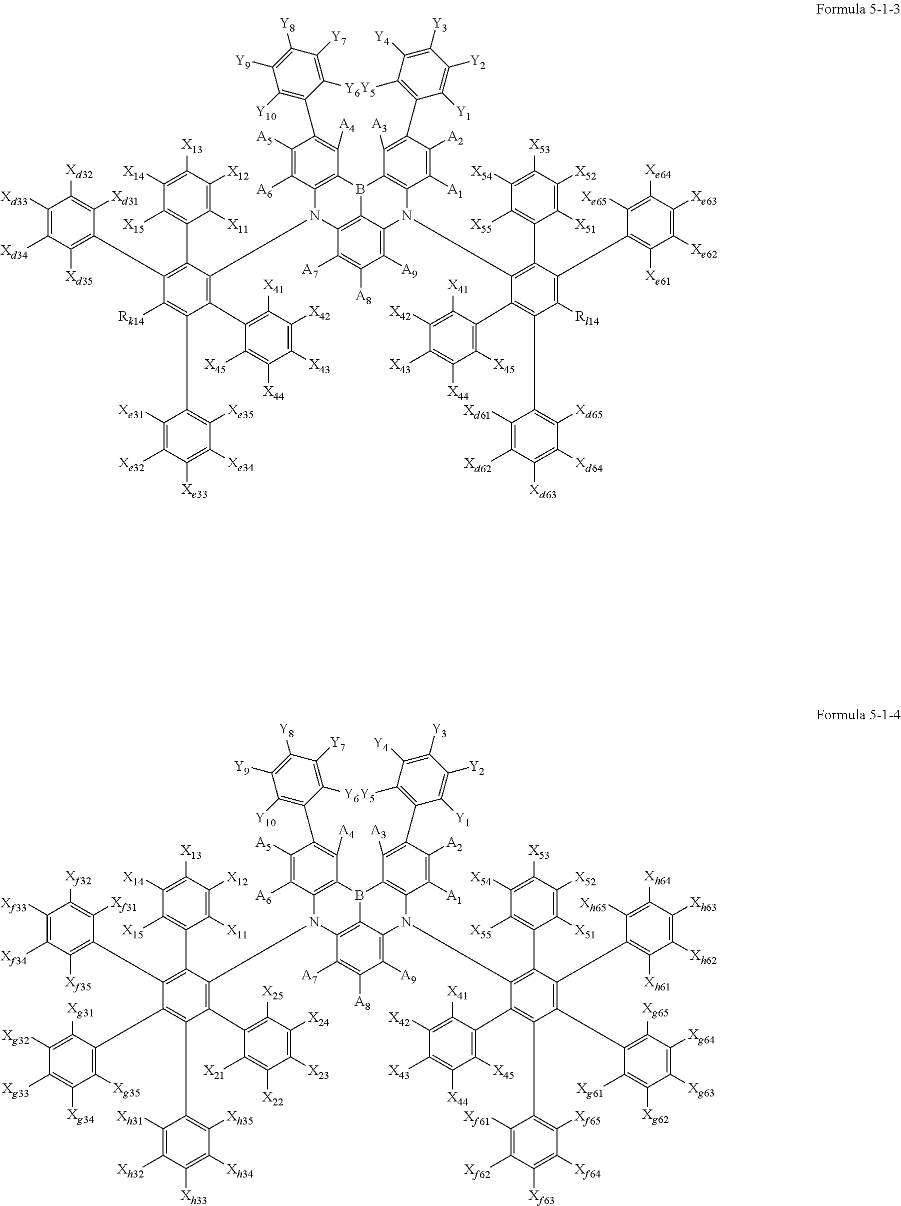
in Formula 5-1-1 to Formula 5-1-4,
Rₖ₁₁ to Rₖ₁₄, and Rₗ₁₁ to Rₗ₁₄ are each independently a hydrogen atom or a deuterium atom, and
Xₐ₃₁ to Xₐ₃₅, X_{b31} to X_{b35}, X_{c31} to X_{c35}, X_{d31} to X_{d35}, Xₑ₃₁ to Xₑ₃₅, X_{f31} to X_{f35}, X_{g31} to X_{g35}, Xₕ₃₁ to Xₕ₃₅, Xₐ₆₁ to Xₐ₆₅, X_{b61} to X_{b65}, X_{c61} to X_{c65}, X_{d61} to X_{d65}, Xₑ₆₁ to Xₑ₆₅, X_{f61} to X_{f65}, X_{g61} to X_{g65}, and Xₕ₆₁ to Xₕ₆₅ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle, and
A₁ to A₉, Y₁ to Y₁₀, X₁₁ to X₁₅, X₂₁ to X₂₅, X₄₁ to X₄₅, and X₅₁ to X₅₅ are the same as defined with respect to Formula 1 and Formula 5-1.

6. The light emitting element of claim 4, wherein the first compound represented by Formula 5-2 is represented by the following Formula 5-2-1: 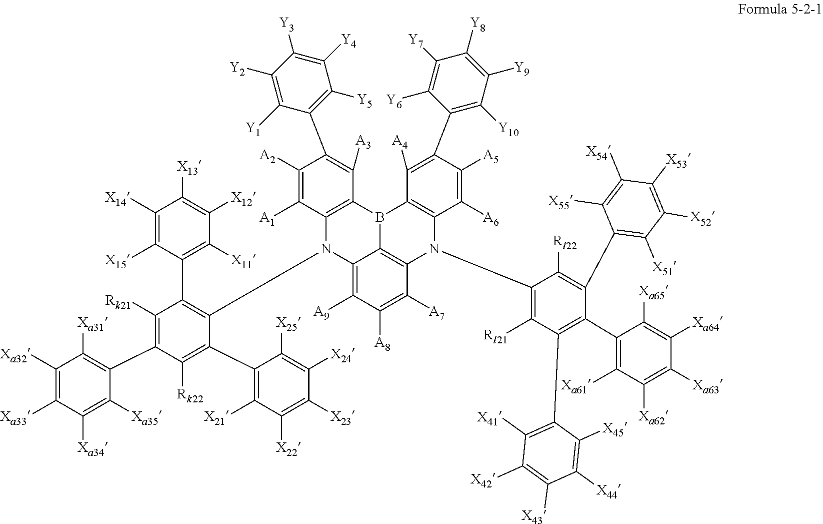
in Formula 5-2-1,
Rₖ₂₁, Rₖ₂₂, Rₗ₂₁ and Rₗ₂₂ are each independently a hydrogen atom or a deuterium atom,
Xₐ₃₁′ to Xₐ₃₅′, and Xₐ₆₁′ to Xₐ₆₅′ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle, and
A₁ to A₉, Y₁ to Y₁₀, X₁₁′ to X₁₅′, X₂₁′ to X₂₅′, X₄₁′ to X₄₅′, and X₅₁′ to X₅₅′ are the same as defined with respect to Formula 1 and Formula 5-2.

7. The light emitting element of claim 4, wherein the first compound represented by Formula 5-3 is represented by the following Formula 5-3-1 or Formula 5-3-2: 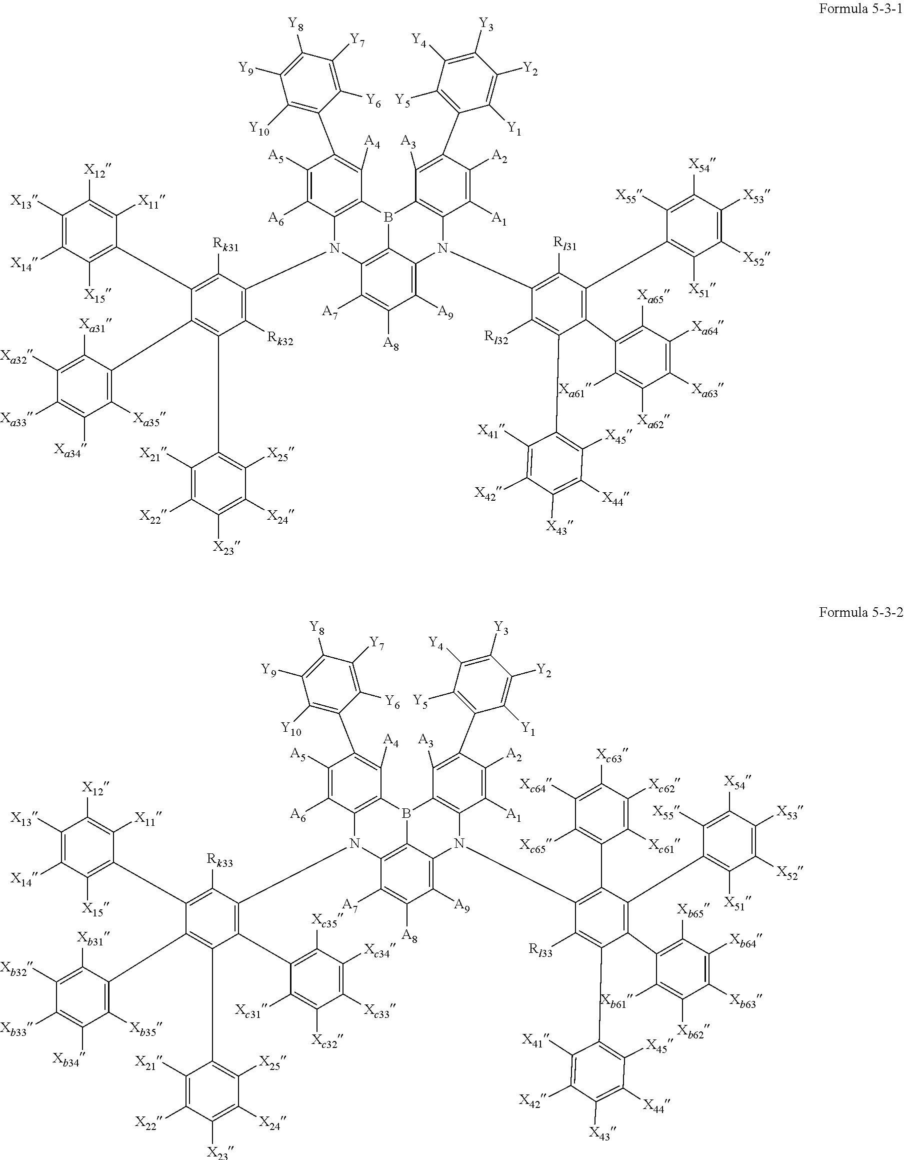
in Formula 5-3-1 and Formula 5-3-2,
Rₖ₃₁, Rₖ₃₂, Rₖ₃₃, Rₗ₃₁, Rₗ₃₂ and Rₗ₃₃ are each independently a hydrogen atom or a deuterium atom,
Xₐ₃₁″ to Xₐ₃₅″, X_{b31}″ to X_{b35}″, X_{c31}″ to X_{c35}″, Xₐ₆₁″ to Xₐ₆₅″, X_{b61}″ to X_{b65}″ and X_{c61}″ to X_{c65}″ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a ring,
A₁ to A₉, Y₁ to Y₁₀, X₁₁″ to X₁₅″, X₂₁″ to X₂₅″, X₄₁″ to X₄₅″, and X₅₁″ to X₅₅″ are the same as defined with respect to Formula 1 and Formula 5-3.

8. The light emitting element of claim 1, wherein:
A₁ to A₇, and A₉ are each independently a hydrogen atom or a deuterium atom, and
A₈ is a hydrogen atom, a deuterium atom, a substituted or unsubstituted amine group, a substituted or unsubstituted t-butyl group, a substituted or unsubstituted phenyl group, a substituted or unsubstituted biphenyl group, or a substituted or unsubstituted carbazole group.

9. The light emitting element of claim 1, wherein Formula 2 is represented by any one selected from among the following X-1 to X-11:

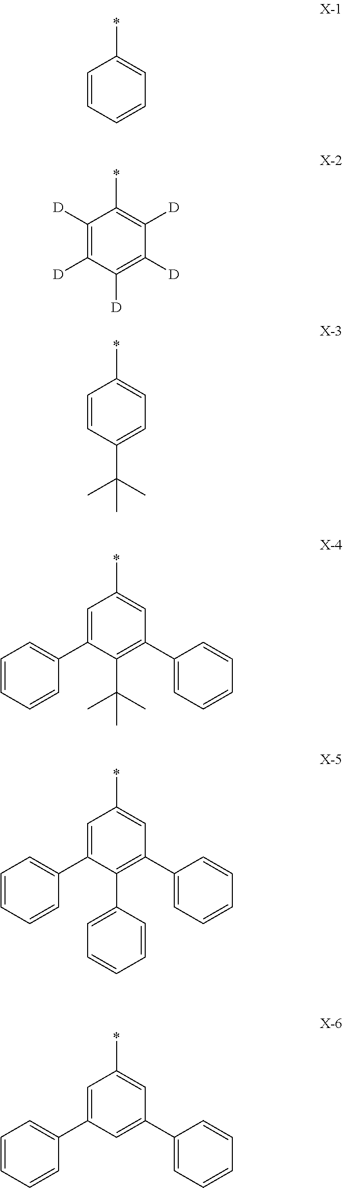

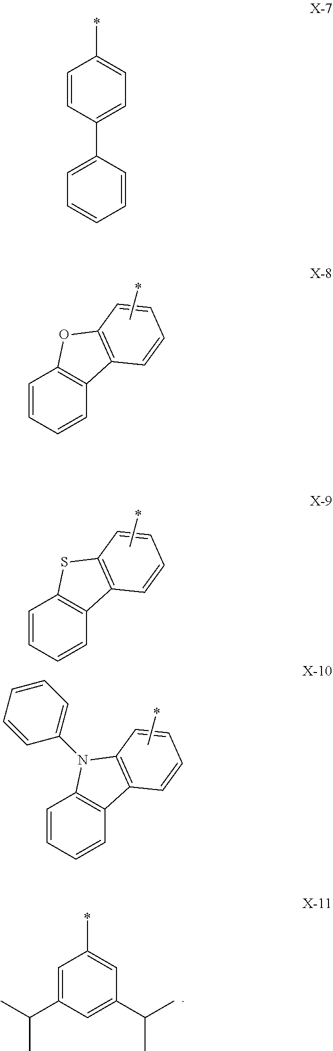

10. The light emitting element of claim 1, wherein the emission layer emits delayed fluorescence.

11. The light emitting element of claim 1, wherein at least one selected from among A₁ to A₉, Y₁ to Y₁₀, and R₁ to R₁₀ comprises a deuterium atom, or a substituent comprising a deuterium atom.

12. The light emitting element of claim 1, wherein the first compound comprises any one selected from among compounds in the following Compound Group 1:

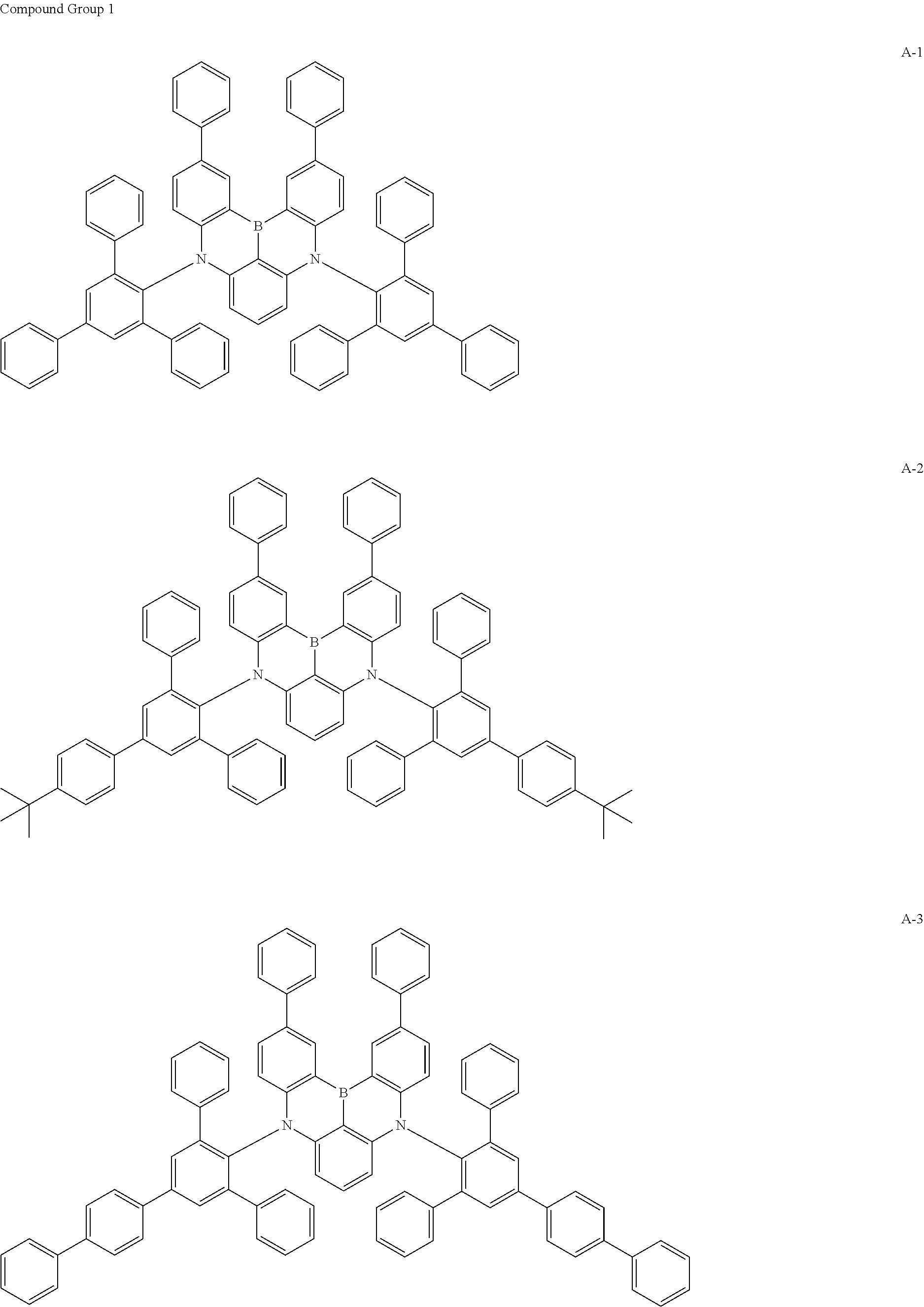 [SMILES: c1ccc(-c2ccc3c(c2)B2c4cc(-c5ccccc5)ccc4N(c4c(-c5ccccc5)cc(-c5ccccc5)cc4-c4ccccc4)c4cccc(c42)N3c2c(-c3ccccc3)cc(-c3ccccc3)cc2-c2ccccc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cccc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cccc4c65)c(-c4ccccc4)c3)cc2)cc1]

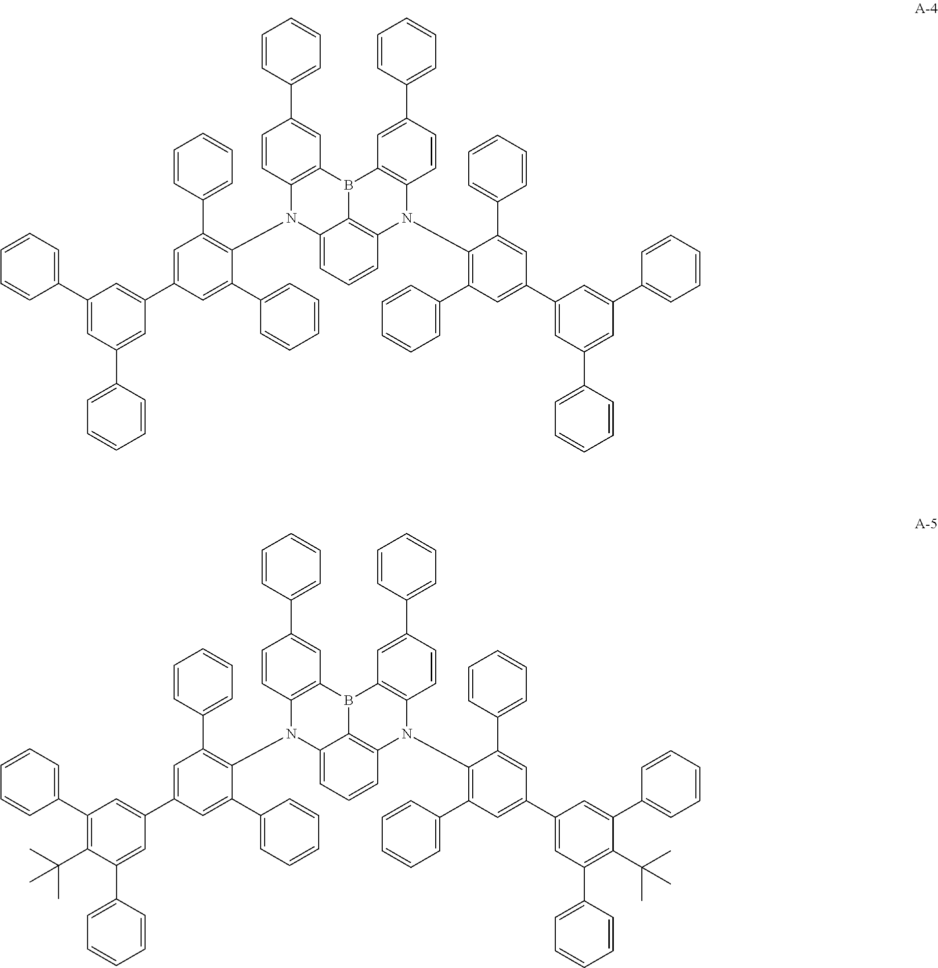 [SMILES: c1ccc(-c2cc(-c3ccccc3)cc(-c3cc(-c4ccccc4)c(N4c5ccc(-c6ccccc6)cc5B5c6cc(-c7ccccc7)ccc6N(c6c(-c7ccccc7)cc(-c7cc(-c8ccccc8)cc(-c8ccccc8)c7)cc6-c6ccccc6)c6cccc4c65)c(-c4ccccc4)c3)c2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cccc3c54)c(-c3ccccc3)c2)cc1-c1ccccc1]

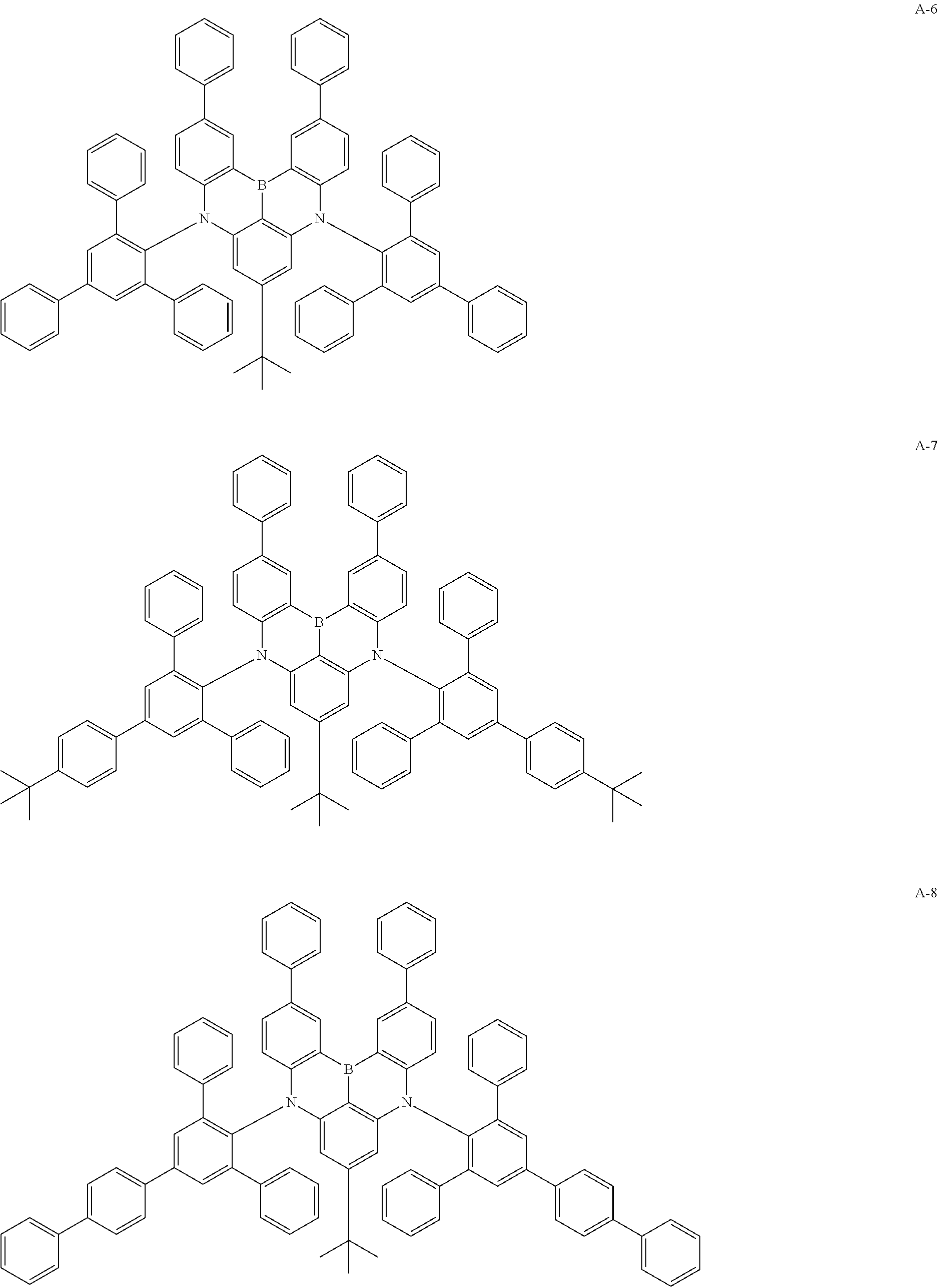 [SMILES: CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(C(C)(C)C)cc3c54)c(-c3ccccc3)c2)cc1 ; CC(C)(C)c1cc2c3c(c1)N(c1c(-c4ccccc4)cc(-c4ccc(-c5ccccc5)cc4)cc1-c1ccccc1)c1ccc(-c4ccccc4)cc1B3c1cc(-c3ccccc3)ccc1N2c1c(-c2ccccc2)cc(-c2ccc(-c3ccccc3)cc2)cc1-c1ccccc1]

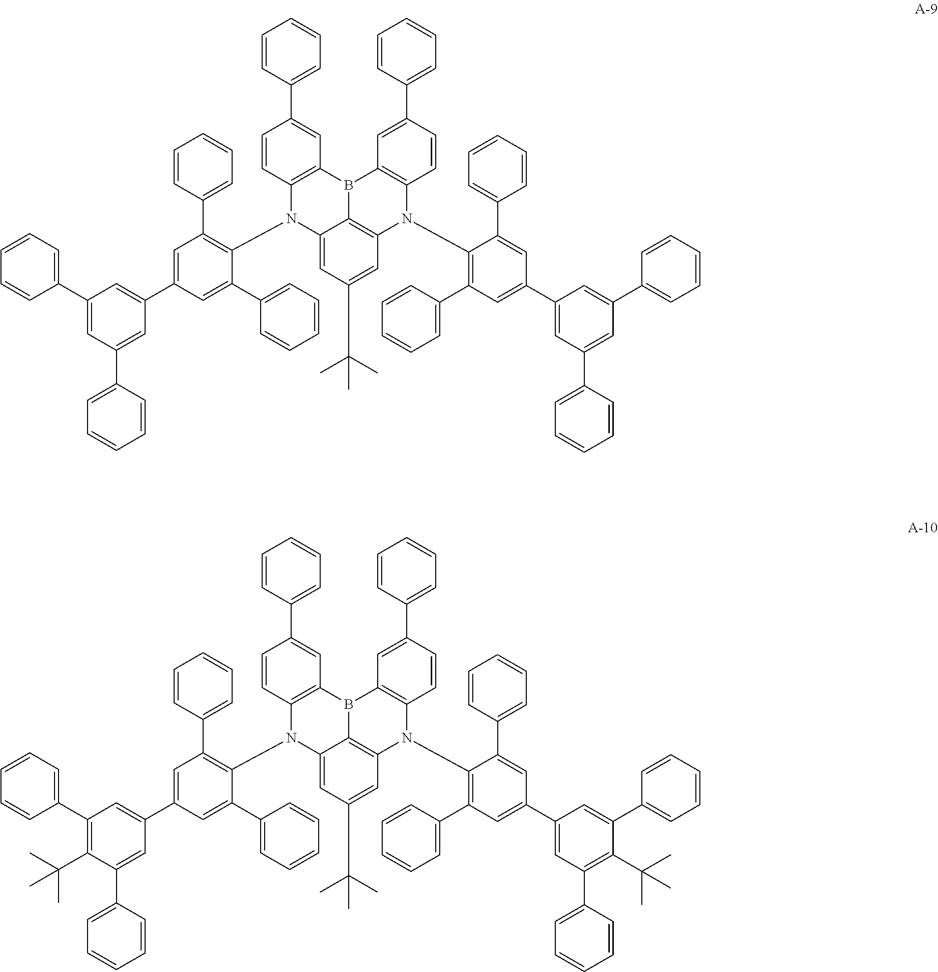 [SMILES: CC(C)(C)c1cc2c3c(c1)N(c1c(-c4ccccc4)cc(-c4cc(-c5ccccc5)cc(-c5ccccc5)c4)cc1-c1ccccc1)c1ccc(-c4ccccc4)cc1B3c1cc(-c3ccccc3)ccc1N2c1c(-c2ccccc2)cc(-c2cc(-c3ccccc3)cc(-c3ccccc3)c2)cc1-c1ccccc1 ; CC(C)(C)c1cc2c3c(c1)N(c1c(-c4ccccc4)cc(-c4cc(-c5ccccc5)c(C(C)(C)C)c(-c5ccccc5)c4)cc1-c1ccccc1)c1ccc(-c4ccccc4)cc1B3c1cc(-c3ccccc3)ccc1N2c1c(-c2ccccc2)cc(-c2cc(-c3ccccc3)c(C(C)(C)C)c(-c3ccccc3)c2)cc1-c1ccccc1]

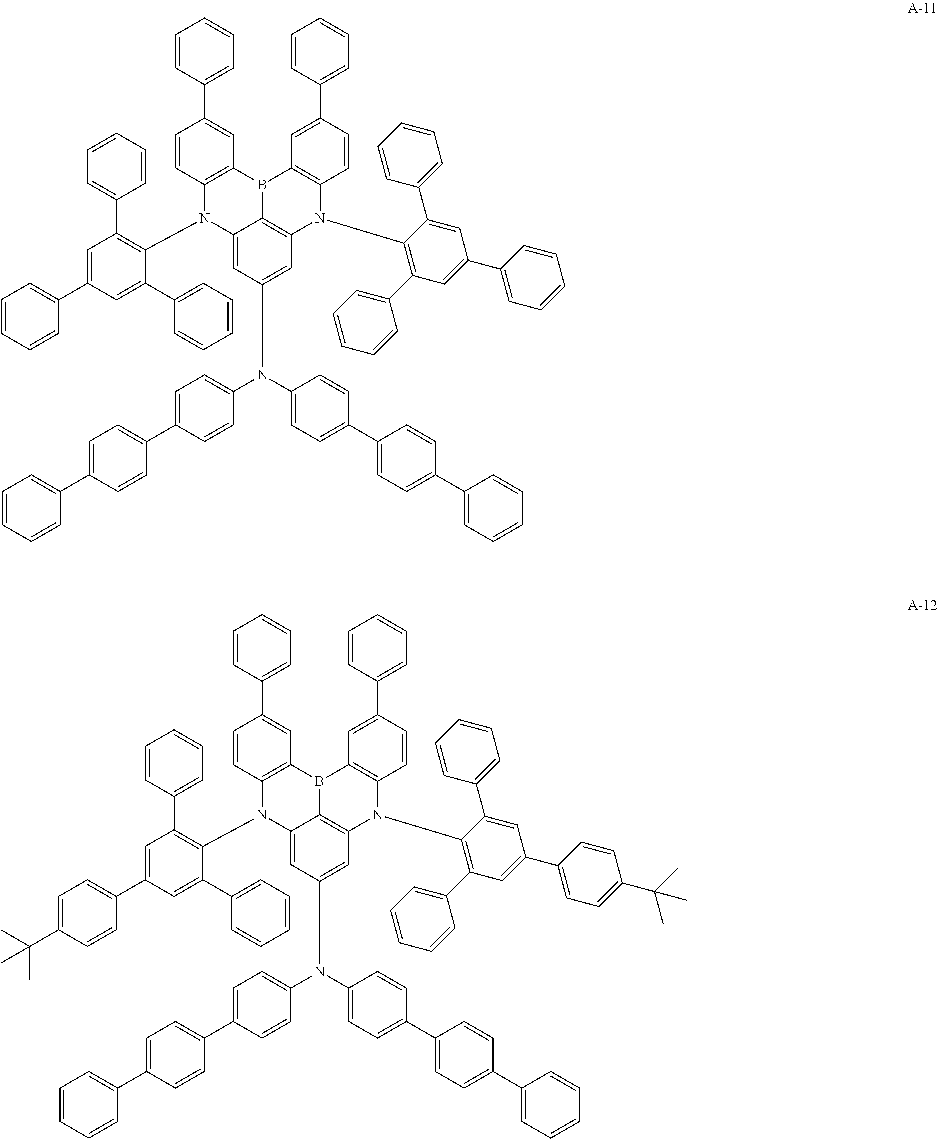 [SMILES: c1ccc(-c2ccc(-c3ccc(N(c4ccc(-c5ccc(-c6ccccc6)cc5)cc4)c4cc5c6c(c4)N(c4c(-c7ccccc7)cc(-c7ccccc7)cc4-c4ccccc4)c4ccc(-c7ccccc7)cc4B6c4cc(-c6ccccc6)ccc4N5c4c(-c5ccccc5)cc(-c5ccccc5)cc4-c4ccccc4)cc3)cc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccc(-c8ccccc8)cc7)cc6)c6ccc(-c7ccc(-c8ccccc8)cc7)cc6)cc3c54)c(-c3ccccc3)c2)cc1]

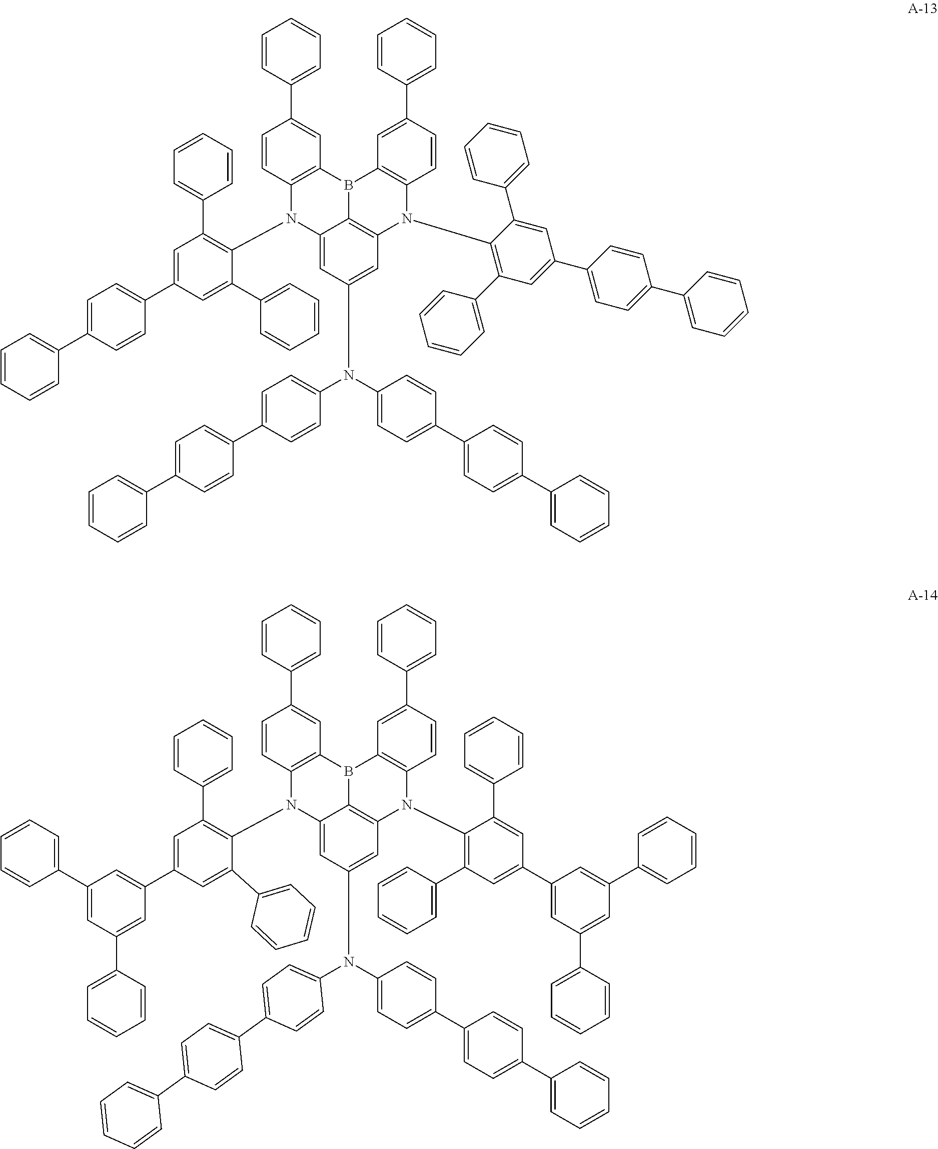 [SMILES: c1ccc(-c2ccc(-c3ccc(N(c4ccc(-c5ccc(-c6ccccc6)cc5)cc4)c4cc5c6c(c4)N(c4c(-c7ccccc7)cc(-c7ccc(-c8ccccc8)cc7)cc4-c4ccccc4)c4ccc(-c7ccccc7)cc4B6c4cc(-c6ccccc6)ccc4N5c4c(-c5ccccc5)cc(-c5ccc(-c6ccccc6)cc5)cc4-c4ccccc4)cc3)cc2)cc1 ; c1ccc(-c2ccc(-c3ccc(N(c4ccc(-c5ccc(-c6ccccc6)cc5)cc4)c4cc5c6c(c4)N(c4c(-c7ccccc7)cc(-c7cc(-c8ccccc8)cc(-c8ccccc8)c7)cc4-c4ccccc4)c4ccc(-c7ccccc7)cc4B6c4cc(-c6ccccc6)ccc4N5c4c(-c5ccccc5)cc(-c5cc(-c6ccccc6)cc(-c6ccccc6)c5)cc4-c4ccccc4)cc3)cc2)cc1]

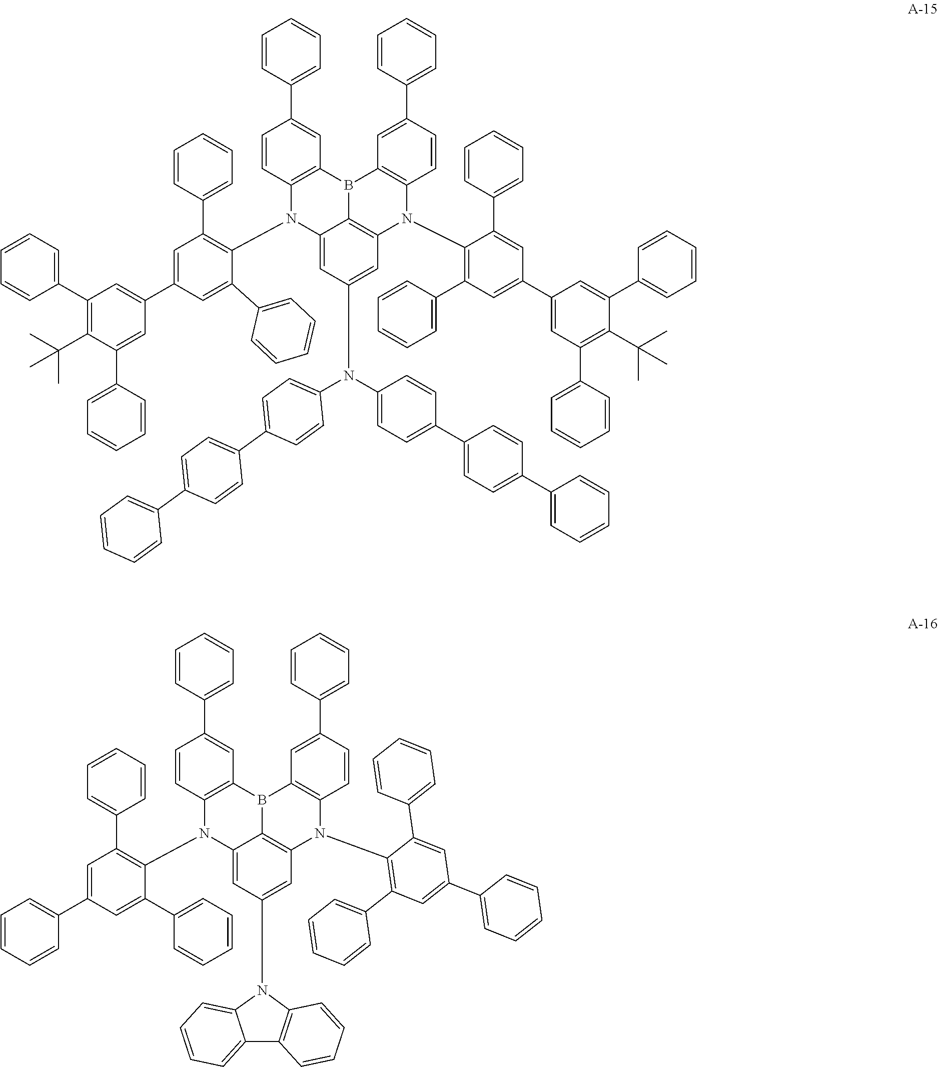 [SMILES: CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(N(c6ccc(-c7ccc(-c8ccccc8)cc7)cc6)c6ccc(-c7ccc(-c8ccccc8)cc7)cc6)cc3c54)c(-c3ccccc3)c2)cc1-c1ccccc1 ; c1ccc(-c2ccc3c(c2)B2c4cc(-c5ccccc5)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

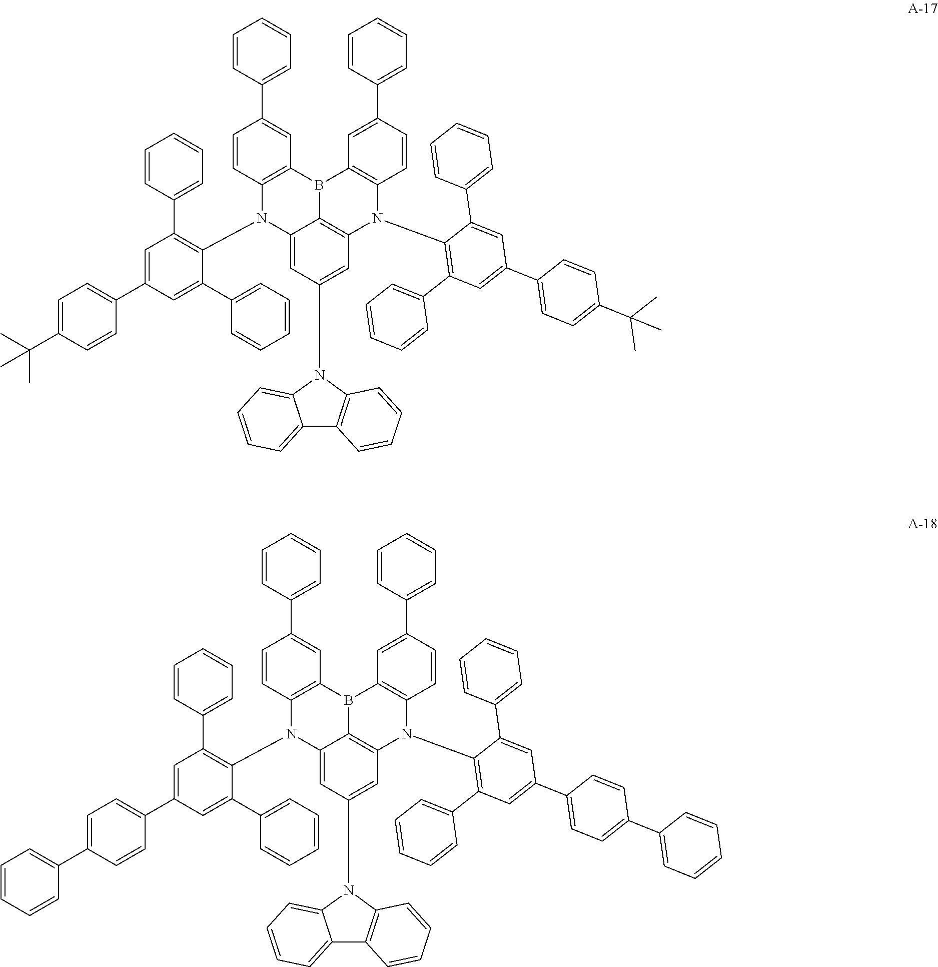 [SMILES: CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(-n6c7ccccc7c7ccccc76)cc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(-n7c8ccccc8c8ccccc87)cc4c65)c(-c4ccccc4)c3)cc2)cc1]

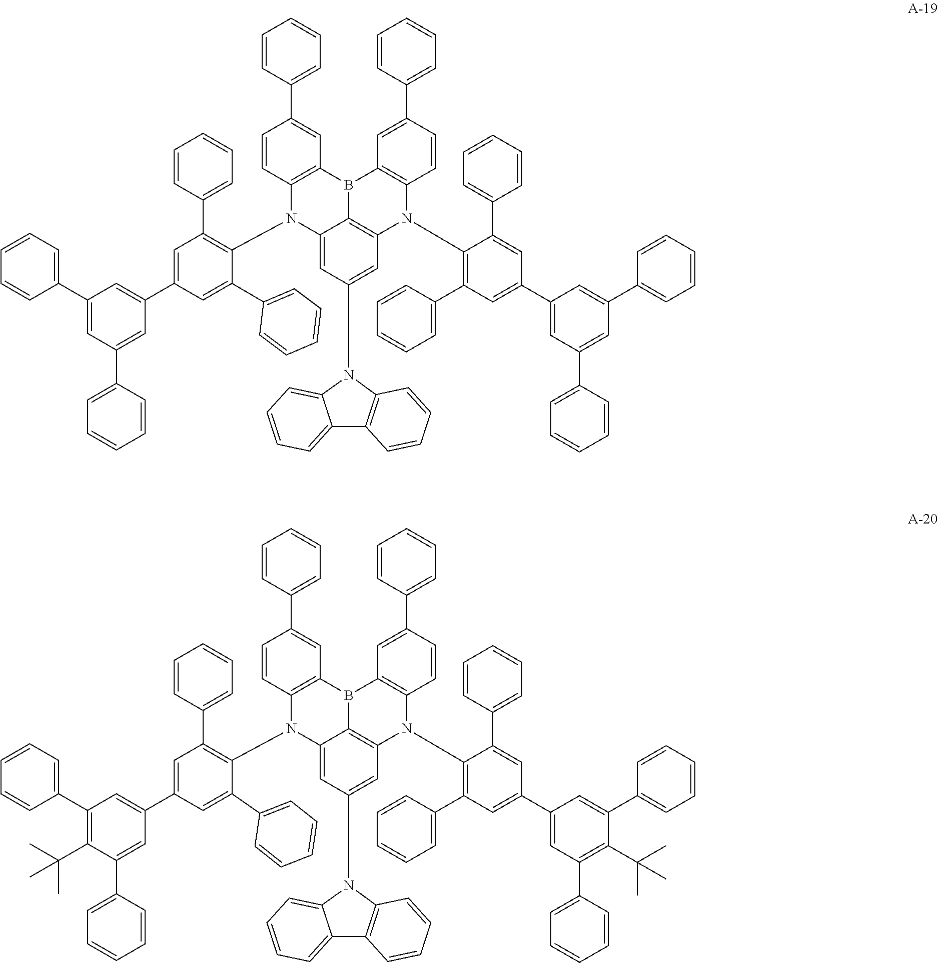 [SMILES: c1ccc(-c2cc(-c3ccccc3)cc(-c3cc(-c4ccccc4)c(N4c5ccc(-c6ccccc6)cc5B5c6cc(-c7ccccc7)ccc6N(c6c(-c7ccccc7)cc(-c7cc(-c8ccccc8)cc(-c8ccccc8)c7)cc6-c6ccccc6)c6cc(-n7c8ccccc8c8ccccc87)cc4c65)c(-c4ccccc4)c3)c2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(-n6c7ccccc7c7ccccc76)cc3c54)c(-c3ccccc3)c2)cc1-c1ccccc1]

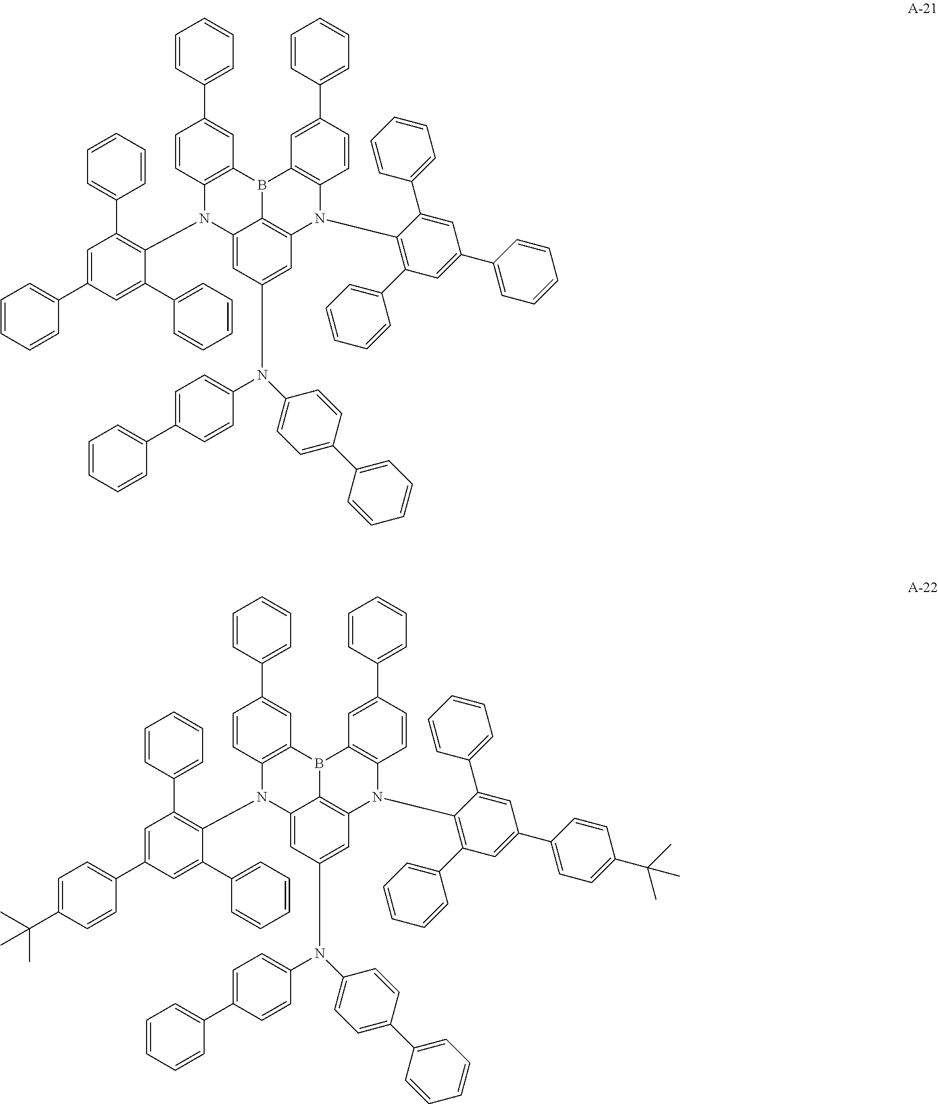 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccccc6)cc3B5c3cc(-c5ccccc5)ccc3N4c3c(-c4ccccc4)cc(-c4ccccc4)cc3-c3ccccc3)cc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccccc7)cc6)c6ccc(-c7ccccc7)cc6)cc3c54)c(-c3ccccc3)c2)cc1]

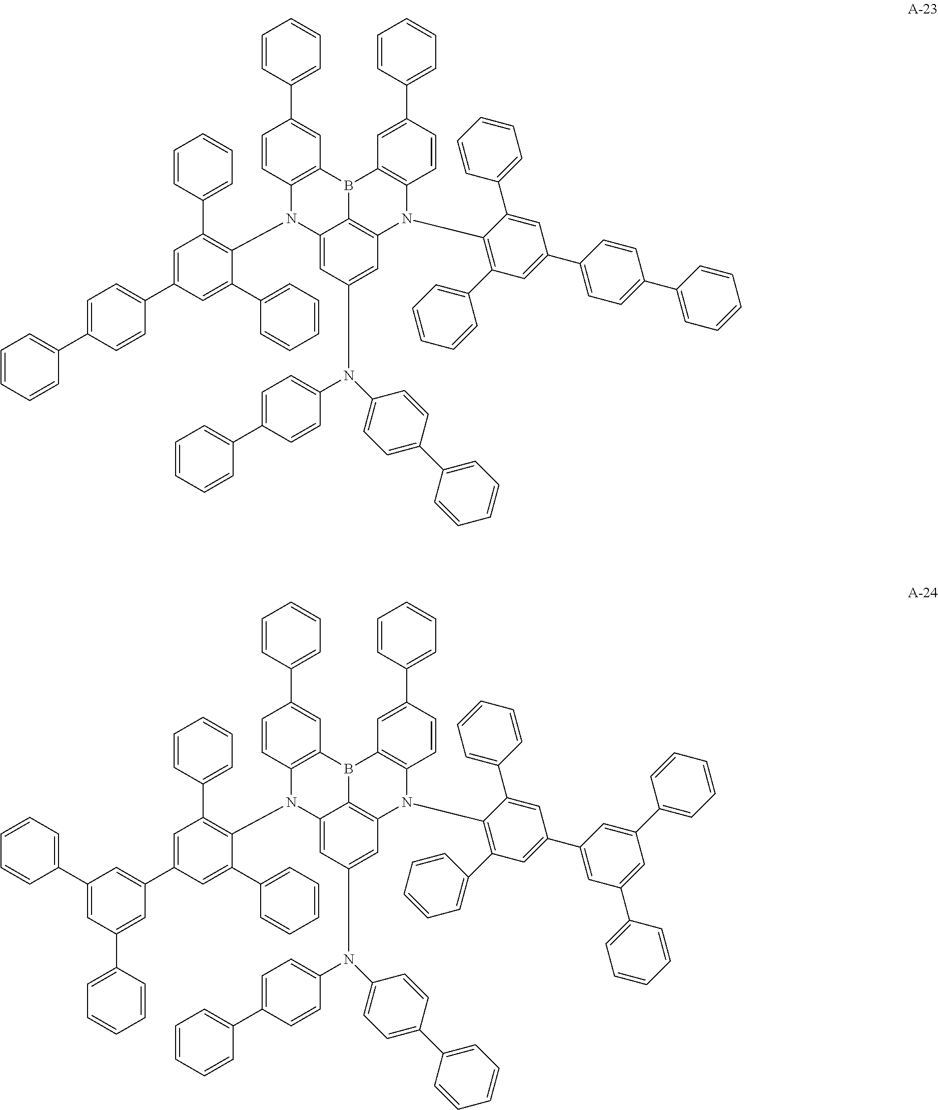 [SMILES: c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(N(c7ccc(-c8ccccc8)cc7)c7ccc(-c8ccccc8)cc7)cc4c65)c(-c4ccccc4)c3)cc2)cc1 ; c1ccc(-c2ccc(N(c3ccc(-c4ccccc4)cc3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3c(-c4ccccc4)cc(-c4cc(-c5ccccc5)cc(-c5ccccc5)c4)cc3-c3ccccc3)cc2)cc1]

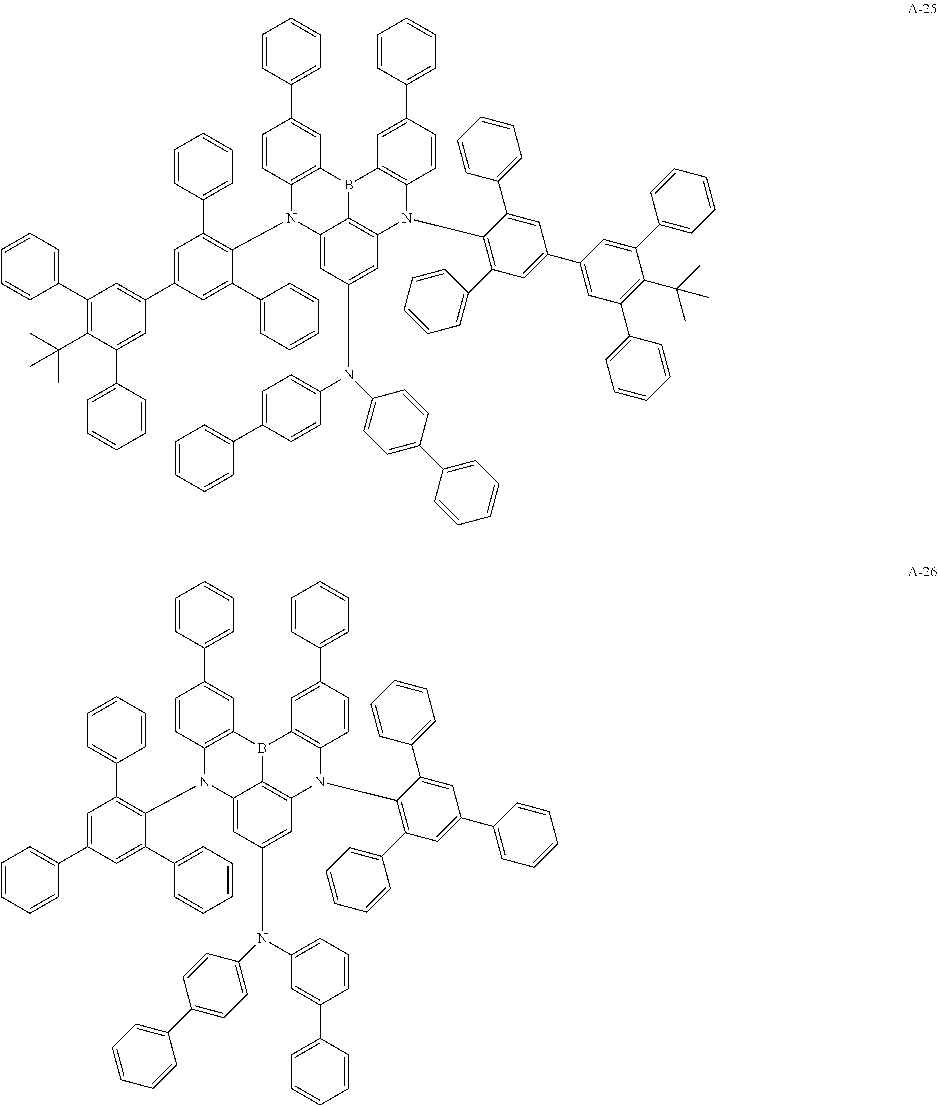 [SMILES: CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(N(c6ccc(-c7ccccc7)cc6)c6ccc(-c7ccccc7)cc6)cc3c54)c(-c3ccccc3)c2)cc1-c1ccccc1 ; c1ccc(-c2ccc(N(c3cccc(-c4ccccc4)c3)c3cc4c5c(c3)N(c3c(-c6ccccc6)cc(-c6ccccc6)cc3-c3ccccc3)c3ccc(-c6ccccc6)cc3B5c3cc(-c5ccccc5)ccc3N4c3c(-c4ccccc4)cc(-c4ccccc4)cc3-c3ccccc3)cc2)cc1]

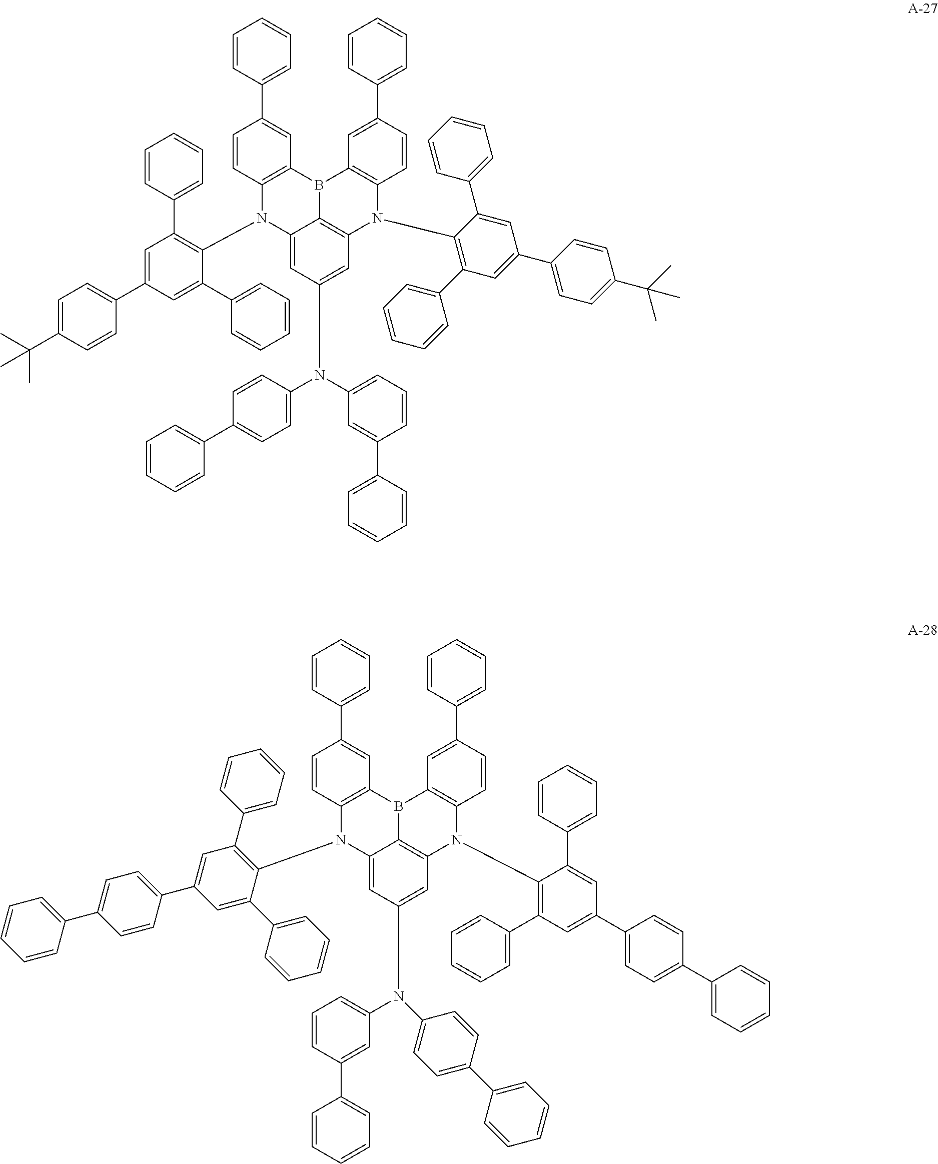 [SMILES: CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccccc7)cc6)c6cccc(-c7ccccc7)c6)cc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(N(c7ccc(-c8ccccc8)cc7)c7cccc(-c8ccccc8)c7)cc4c65)c(-c4ccccc4)c3)cc2)cc1]

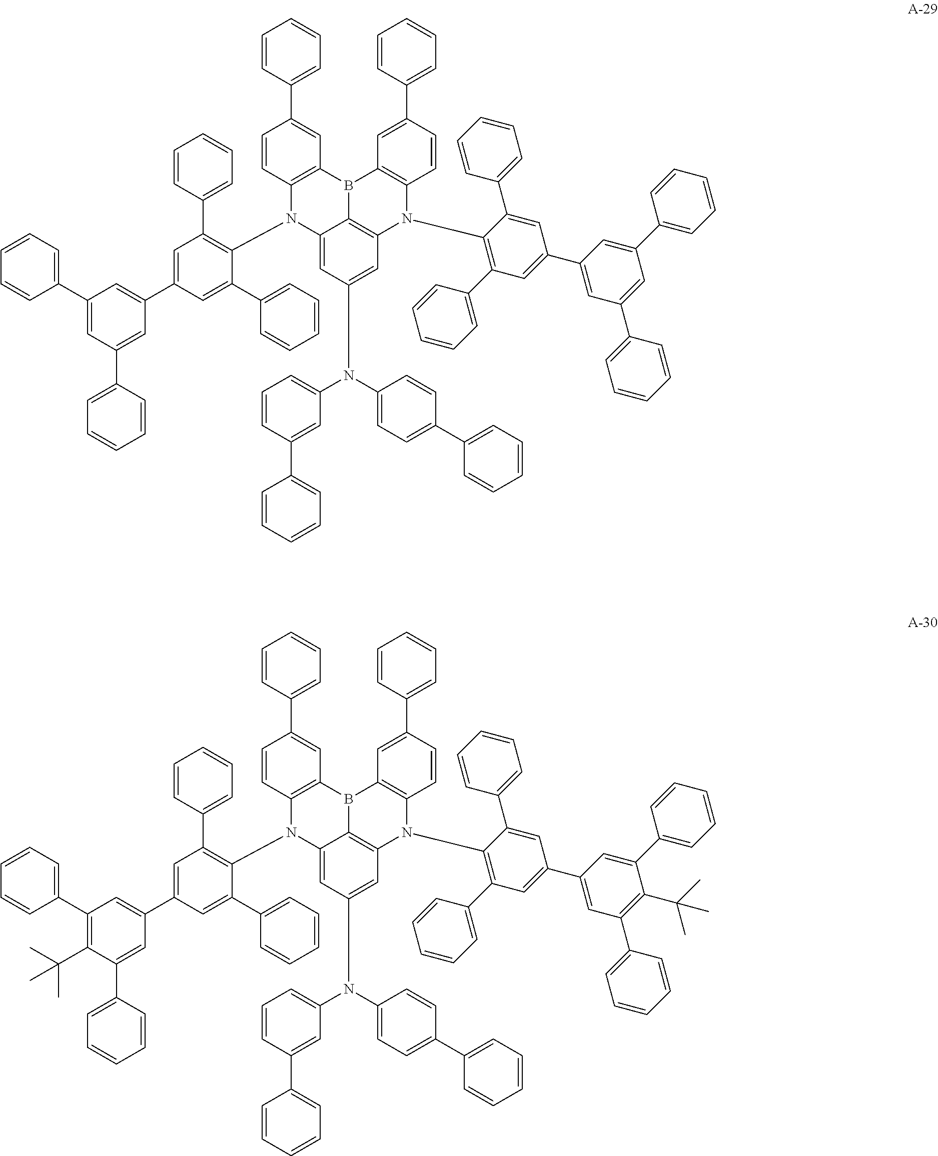 [SMILES: c1ccc(-c2ccc(N(c3cccc(-c4ccccc4)c3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3c(-c4ccccc4)cc(-c4cc(-c5ccccc5)cc(-c5ccccc5)c4)cc3-c3ccccc3)cc2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(N(c6ccc(-c7ccccc7)cc6)c6cccc(-c7ccccc7)c6)cc3c54)c(-c3ccccc3)c2)cc1-c1ccccc1]

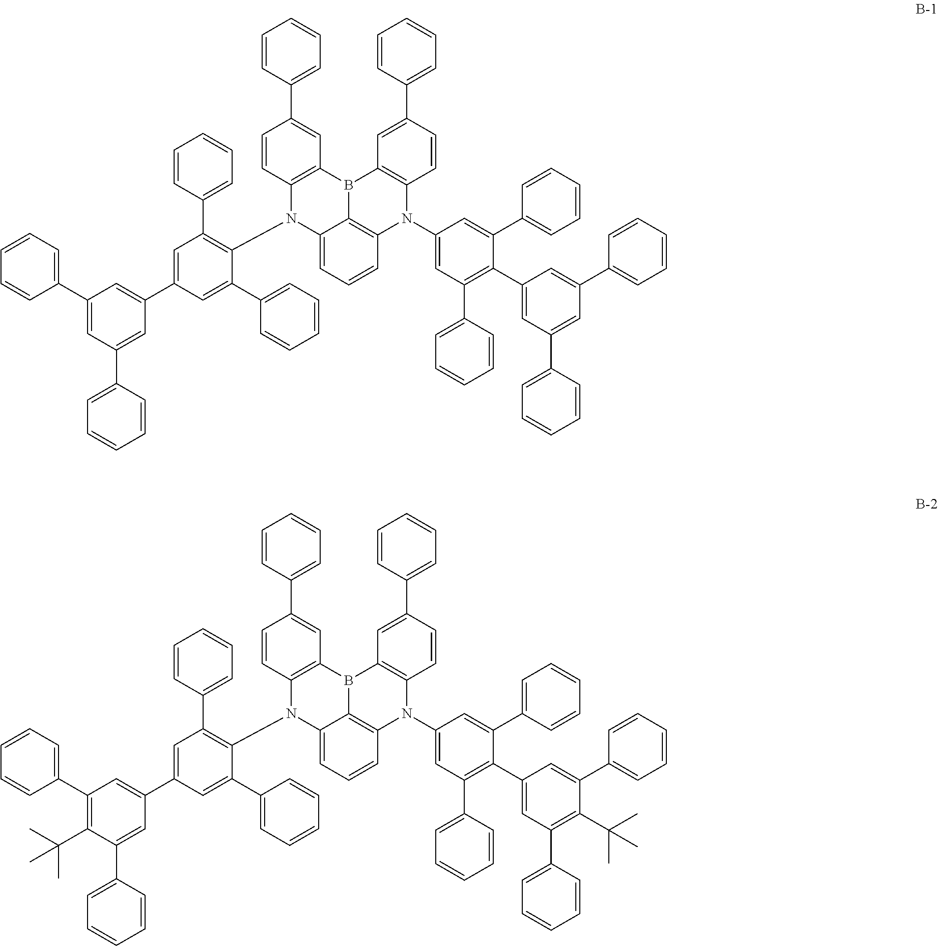 [SMILES: c1ccc(-c2cc(-c3ccccc3)cc(-c3cc(-c4ccccc4)c(N4c5ccc(-c6ccccc6)cc5B5c6cc(-c7ccccc7)ccc6N(c6cc(-c7ccccc7)c(-c7cc(-c8ccccc8)cc(-c8ccccc8)c7)c(-c7ccccc7)c6)c6cccc4c65)c(-c4ccccc4)c3)c2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cccc3c54)c(-c3ccccc3)c2)cc1-c1ccccc1]

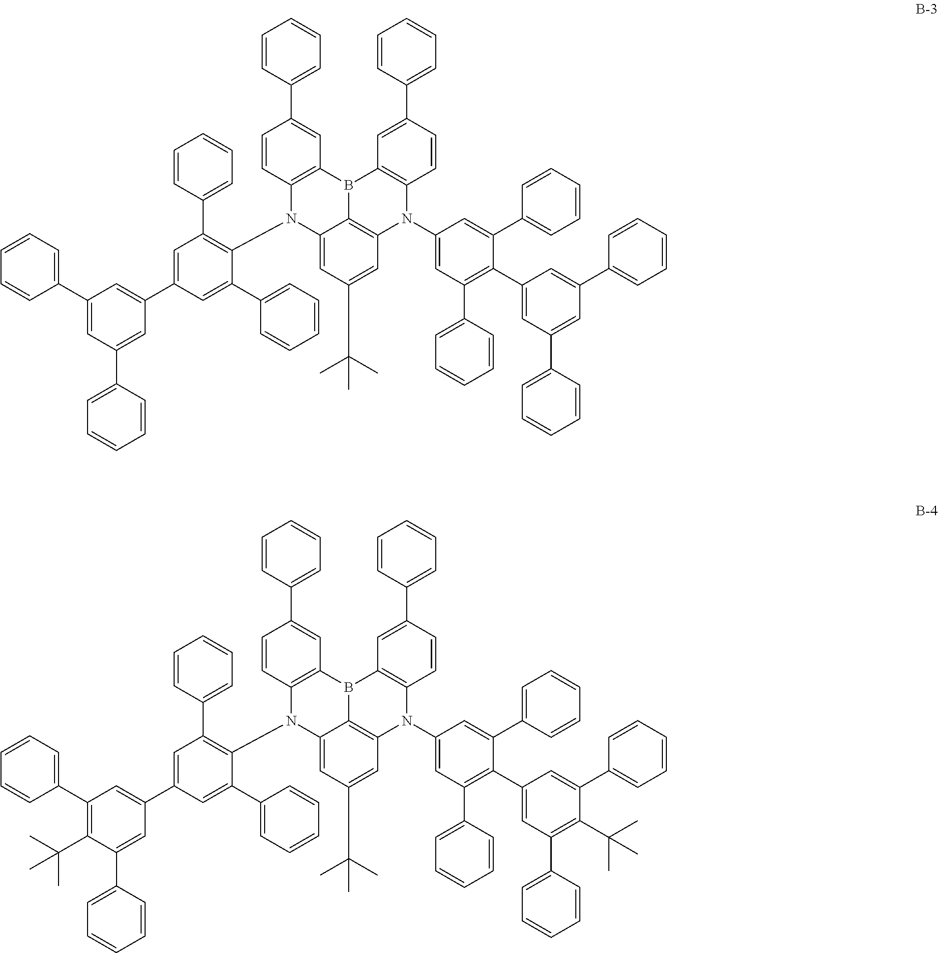 [SMILES: CC(C)(C)c1cc2c3c(c1)N(c1c(-c4ccccc4)cc(-c4cc(-c5ccccc5)cc(-c5ccccc5)c4)cc1-c1ccccc1)c1ccc(-c4ccccc4)cc1B3c1cc(-c3ccccc3)ccc1N2c1cc(-c2ccccc2)c(-c2cc(-c3ccccc3)cc(-c3ccccc3)c2)c(-c2ccccc2)c1 ; CC(C)(C)c1cc2c3c(c1)N(c1c(-c4ccccc4)cc(-c4cc(-c5ccccc5)c(C(C)(C)C)c(-c5ccccc5)c4)cc1-c1ccccc1)c1ccc(-c4ccccc4)cc1B3c1cc(-c3ccccc3)ccc1N2c1cc(-c2ccccc2)c(-c2cc(-c3ccccc3)c(C(C)(C)C)c(-c3ccccc3)c2)c(-c2ccccc2)c1]

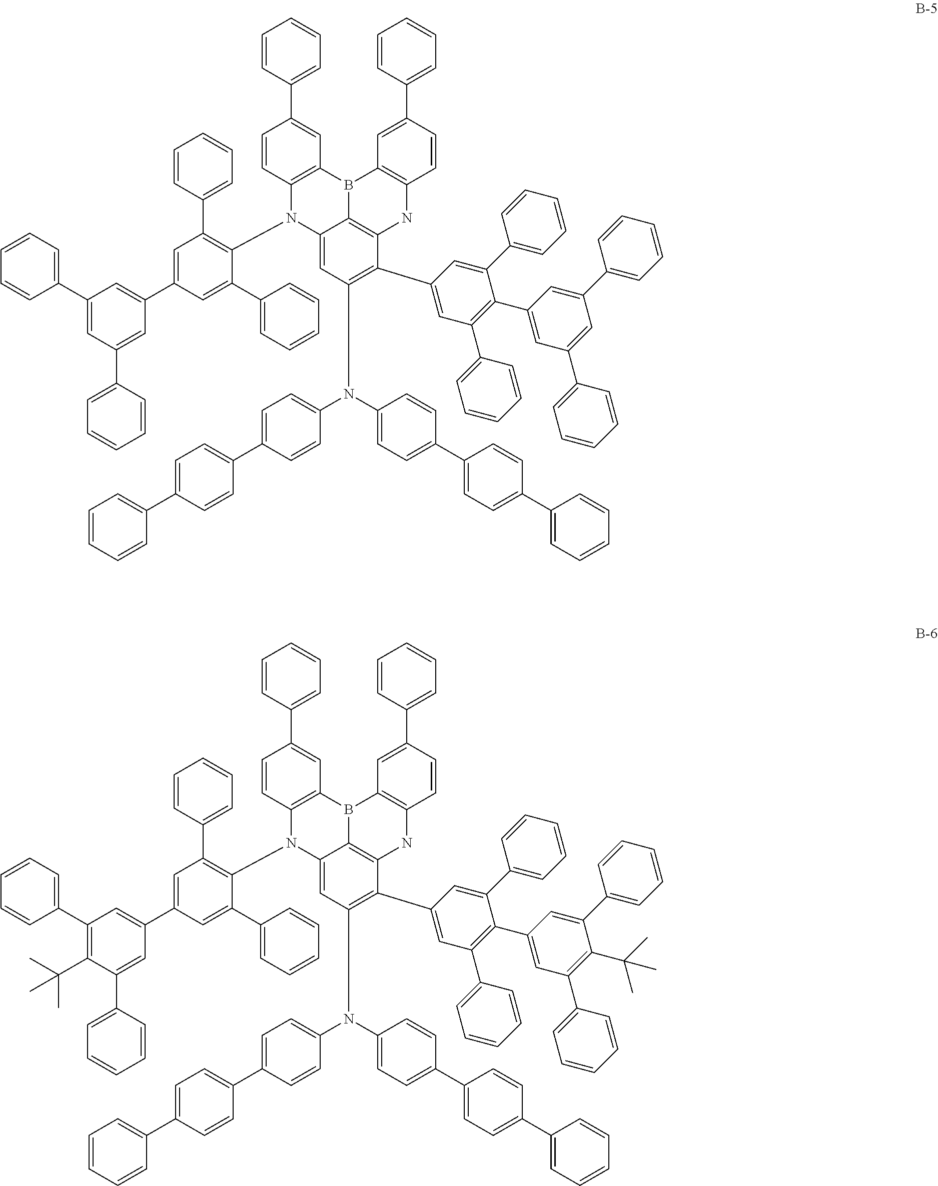

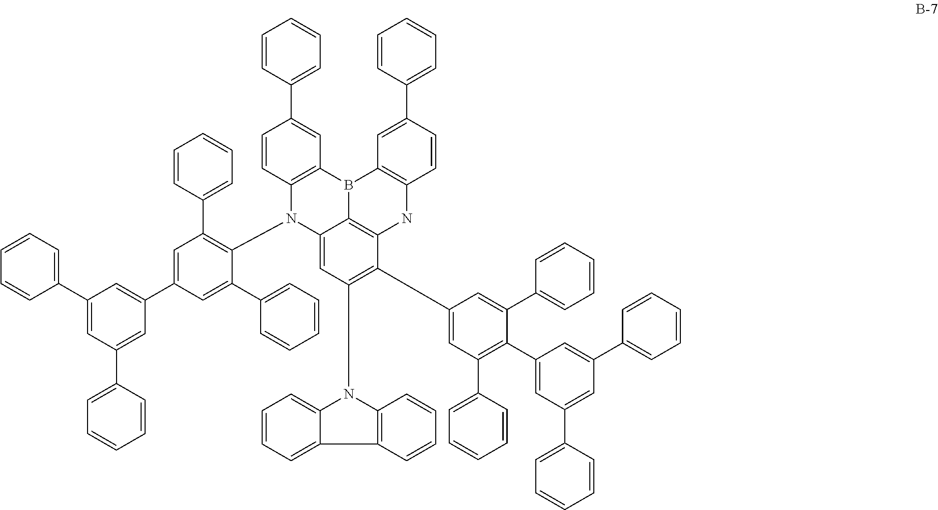 [SMILES: c1ccc(-c2cc(-c3ccccc3)cc(-c3cc(-c4ccccc4)c(N4c5ccc(-c6ccccc6)cc5B5c6cc(-c7ccccc7)ccc6Nc6c5c4cc(-n4c5ccccc5c5ccccc54)c6-c4cc(-c5ccccc5)c(-c5cc(-c6ccccc6)cc(-c6ccccc6)c5)c(-c5ccccc5)c4)c(-c4ccccc4)c3)c2)cc1]

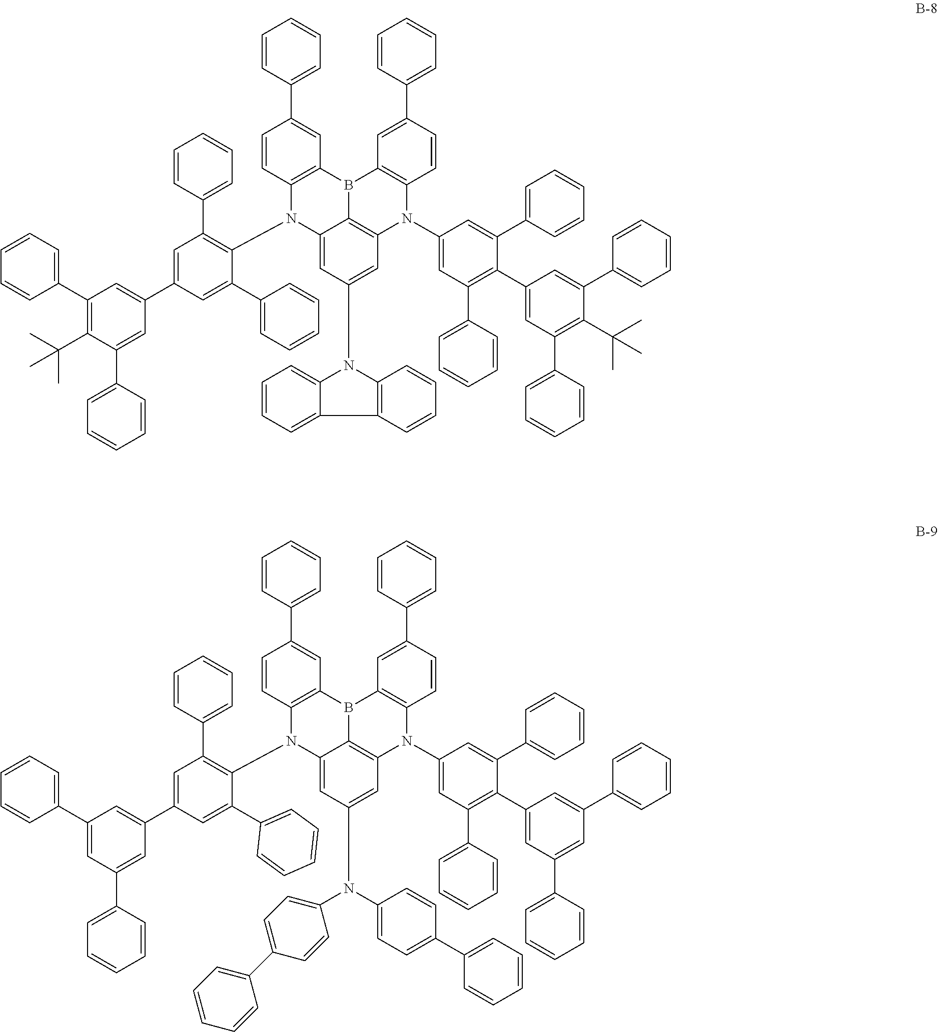 [SMILES: CC(C)(C)c1c(-c2ccccc2)cc(-c2cc(-c3ccccc3)c(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cc(-n6c7ccccc7c7ccccc76)cc3c54)c(-c3ccccc3)c2)cc1-c1ccccc1 ; c1ccc(-c2ccc(N(c3ccc(-c4ccccc4)cc3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3cc(-c4ccccc4)c(-c4cc(-c5ccccc5)cc(-c5ccccc5)c4)c(-c4ccccc4)c3)cc2)cc1]

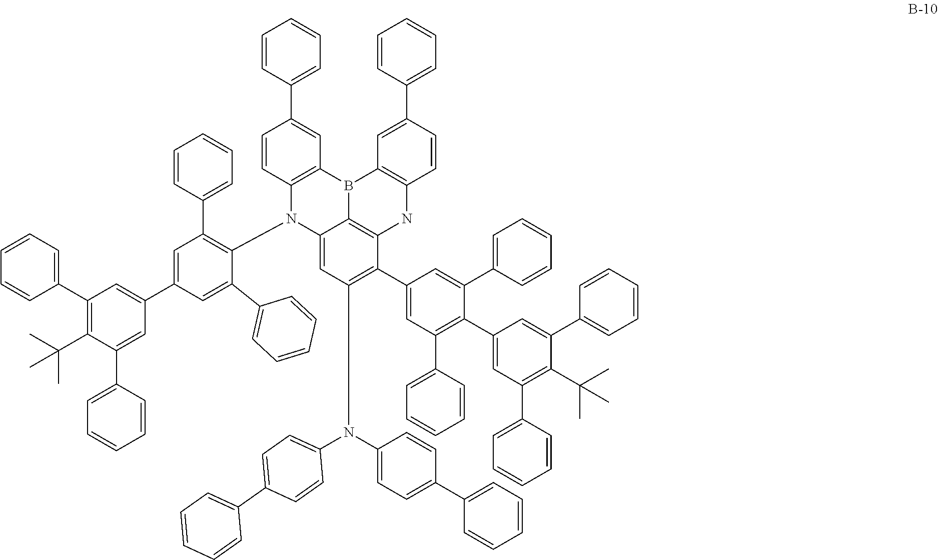 [SMILES: CC(C)(C)c1c(-c2ccccc2)cc(-c2cc(-c3ccccc3)c(N3c4ccc(-c5ccccc5)cc4B4c5cc(-c6ccccc6)ccc5Nc5c4c3cc(N(c3ccc(-c4ccccc4)cc3)c3ccc(-c4ccccc4)cc3)c5-c3cc(-c4ccccc4)c(-c4cc(-c5ccccc5)c(C(C)(C)C)c(-c5ccccc5)c4)c(-c4ccccc4)c3)c(-c3ccccc3)c2)cc1-c1ccccc1]

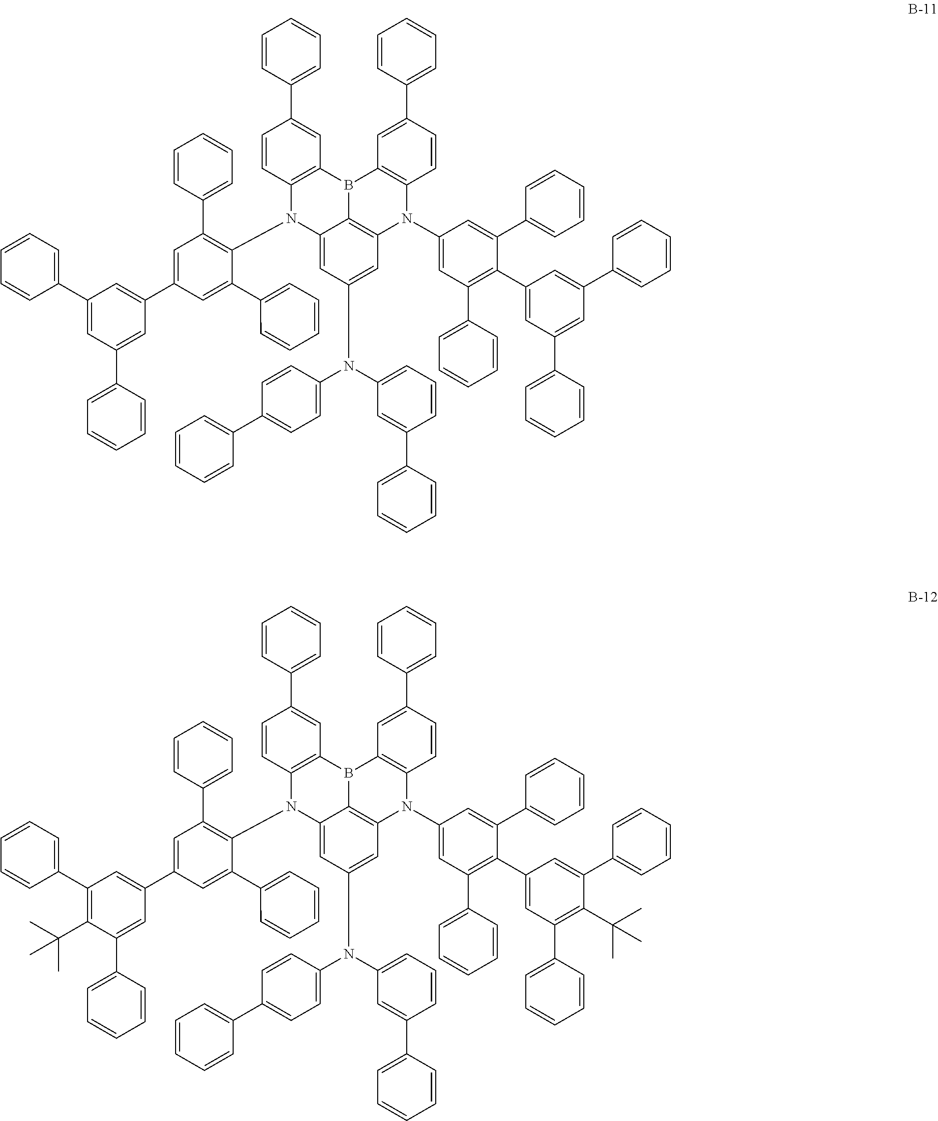 [SMILES: c1ccc(-c2ccc(N(c3cccc(-c4ccccc4)c3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3cc(-c4ccccc4)c(-c4cc(-c5ccccc5)cc(-c5ccccc5)c4)c(-c4ccccc4)c3)cc2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cc(N(c6ccc(-c7ccccc7)cc6)c6cccc(-c7ccccc7)c6)cc3c54)c(-c3ccccc3)c2)cc1-c1ccccc1]

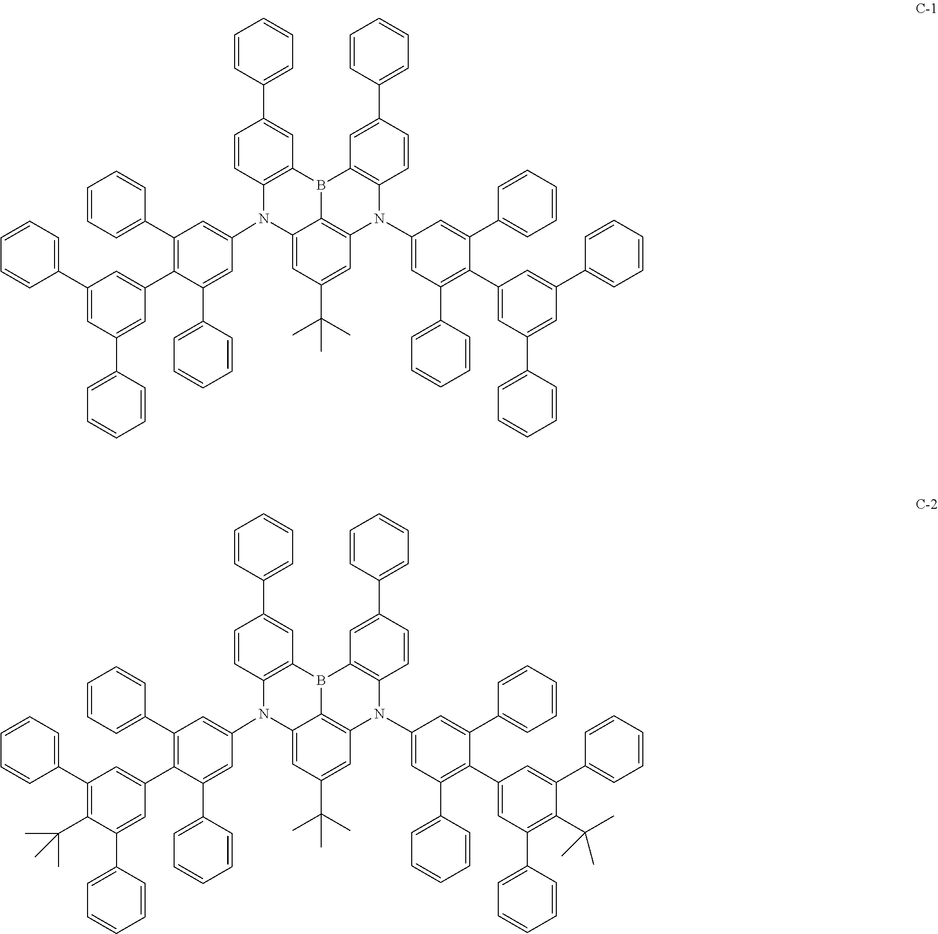 [SMILES: CC(C)(C)c1cc2c3c(c1)N(c1cc(-c4ccccc4)c(-c4cc(-c5ccccc5)cc(-c5ccccc5)c4)c(-c4ccccc4)c1)c1ccc(-c4ccccc4)cc1B3c1cc(-c3ccccc3)ccc1N2c1cc(-c2ccccc2)c(-c2cc(-c3ccccc3)cc(-c3ccccc3)c2)c(-c2ccccc2)c1 ; CC(C)(C)c1cc2c3c(c1)N(c1cc(-c4ccccc4)c(-c4cc(-c5ccccc5)c(C(C)(C)C)c(-c5ccccc5)c4)c(-c4ccccc4)c1)c1ccc(-c4ccccc4)cc1B3c1cc(-c3ccccc3)ccc1N2c1cc(-c2ccccc2)c(-c2cc(-c3ccccc3)c(C(C)(C)C)c(-c3ccccc3)c2)c(-c2ccccc2)c1]

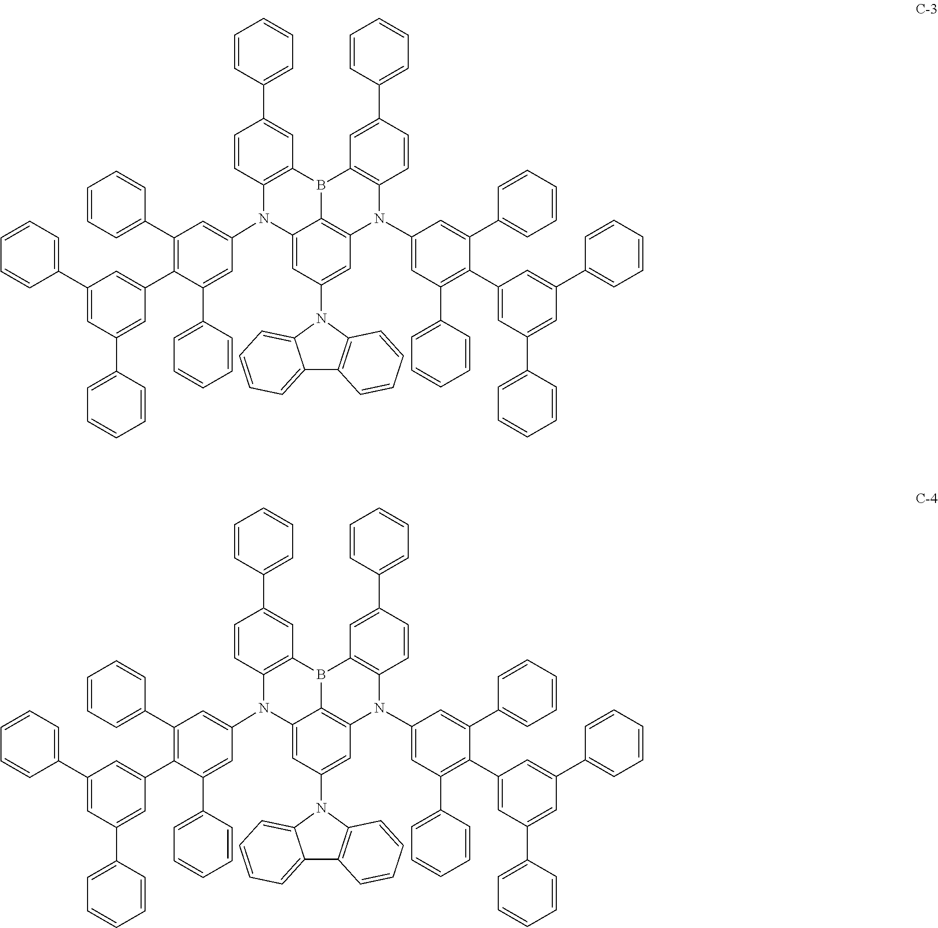 [SMILES: c1ccc(-c2cc(-c3ccccc3)cc(-c3c(-c4ccccc4)cc(N4c5ccc(-c6ccccc6)cc5B5c6cc(-c7ccccc7)ccc6N(c6cc(-c7ccccc7)c(-c7cc(-c8ccccc8)cc(-c8ccccc8)c7)c(-c7ccccc7)c6)c6cc(-n7c8ccccc8c8ccccc87)cc4c65)cc3-c3ccccc3)c2)cc1 ; c1ccc(-c2cc(-c3ccccc3)cc(-c3c(-c4ccccc4)cc(N4c5ccc(-c6ccccc6)cc5B5c6cc(-c7ccccc7)ccc6N(c6cc(-c7ccccc7)c(-c7cc(-c8ccccc8)cc(-c8ccccc8)c7)c(-c7ccccc7)c6)c6cc(-n7c8ccccc8c8ccccc87)cc4c65)cc3-c3ccccc3)c2)cc1]

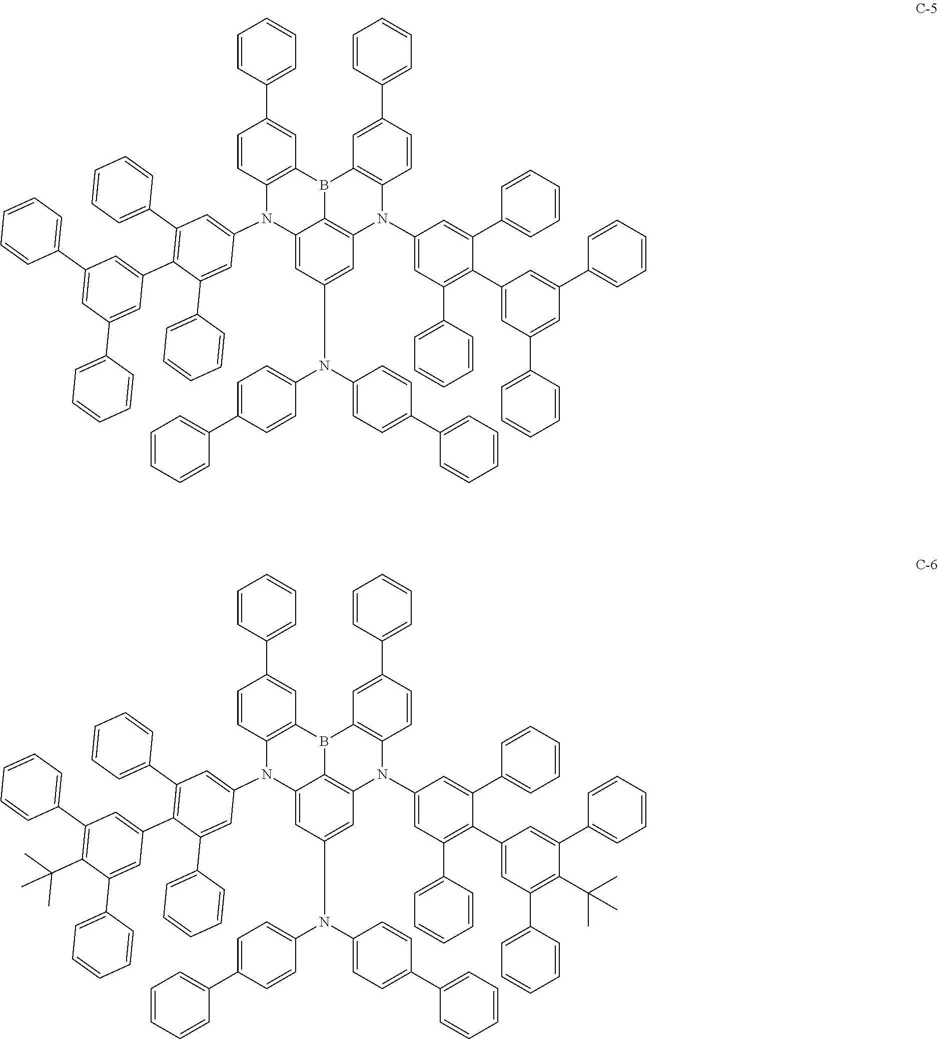 [SMILES: c1ccc(-c2ccc(N(c3ccc(-c4ccccc4)cc3)c3cc4c5c(c3)N(c3cc(-c6ccccc6)c(-c6cc(-c7ccccc7)cc(-c7ccccc7)c6)c(-c6ccccc6)c3)c3ccc(-c6ccccc6)cc3B5c3cc(-c5ccccc5)ccc3N4c3cc(-c4ccccc4)c(-c4cc(-c5ccccc5)cc(-c5ccccc5)c4)c(-c4ccccc4)c3)cc2)cc1 ; CC(C)(C)c1c(-c2ccccc2)cc(-c2c(-c3ccccc3)cc(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cc(N(c6ccc(-c7ccccc7)cc6)c6ccc(-c7ccccc7)cc6)cc3c54)cc2-c2ccccc2)cc1-c1ccccc1]

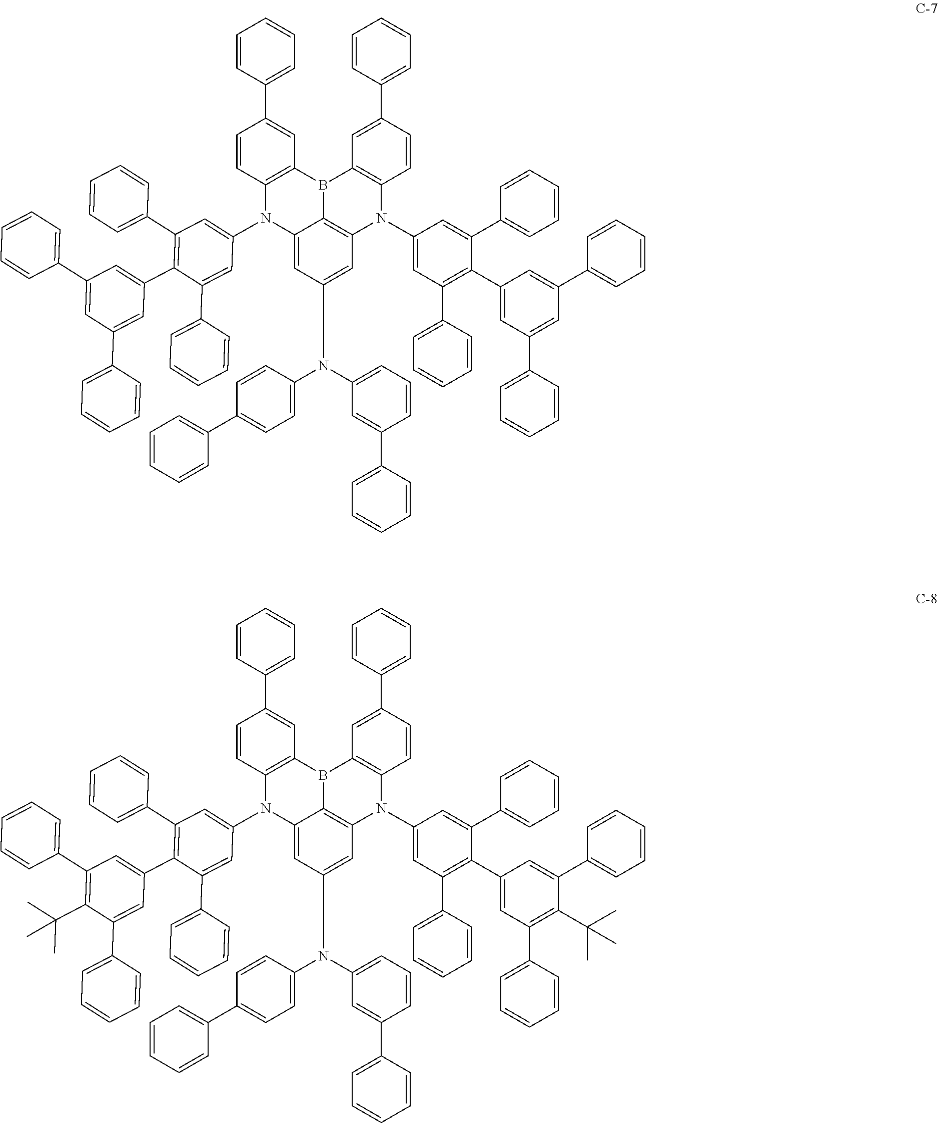 [SMILES: c1ccc(-c2ccc(N(c3cccc(-c4ccccc4)c3)c3cc4c5c(c3)N(c3cc(-c6ccccc6)c(-c6cc(-c7ccccc7)cc(-c7ccccc7)c6)c(-c6ccccc6)c3)c3ccc(-c6ccccc6)cc3B5c3cc(-c5ccccc5)ccc3N4c3cc(-c4ccccc4)c(-c4cc(-c5ccccc5)cc(-c5ccccc5)c4)c(-c4ccccc4)c3)cc2)cc1 ; CC(C)(C)c1c(-c2ccccc2)cc(-c2c(-c3ccccc3)cc(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cc(N(c6ccc(-c7ccccc7)cc6)c6cccc(-c7ccccc7)c6)cc3c54)cc2-c2ccccc2)cc1-c1ccccc1]

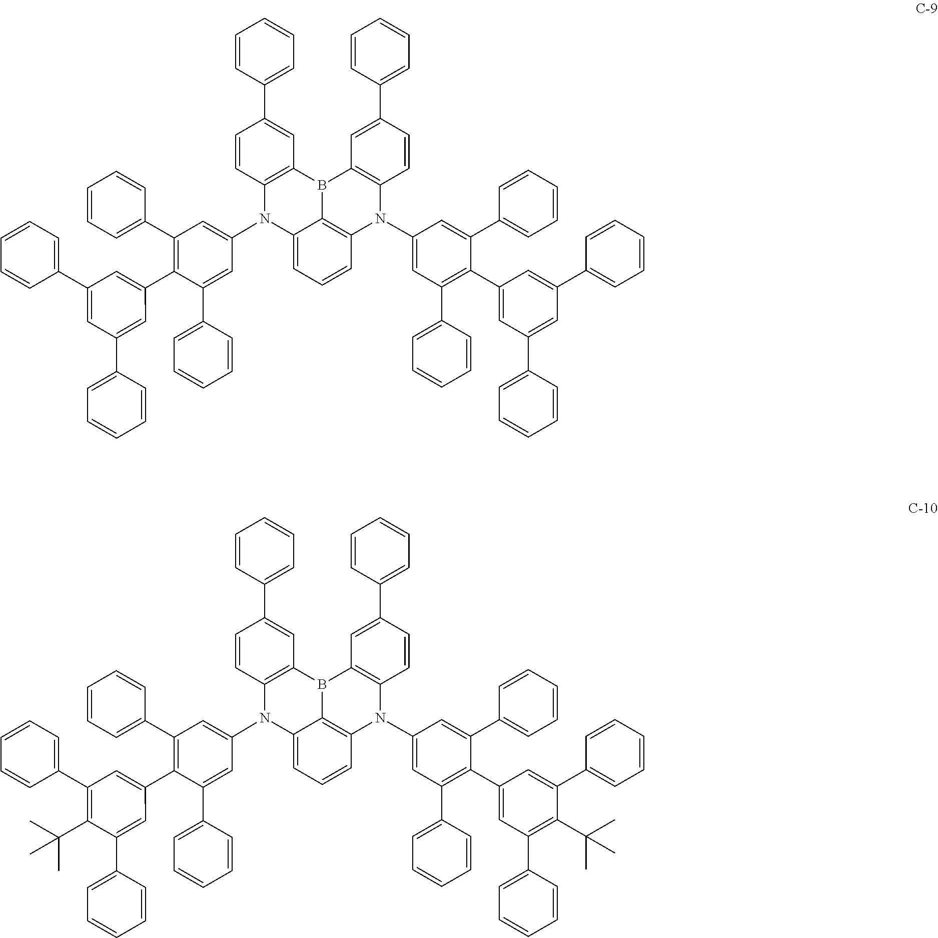 [SMILES: c1ccc(-c2cc(-c3ccccc3)cc(-c3c(-c4ccccc4)cc(N4c5ccc(-c6ccccc6)cc5B5c6cc(-c7ccccc7)ccc6N(c6cc(-c7ccccc7)c(-c7cc(-c8ccccc8)cc(-c8ccccc8)c7)c(-c7ccccc7)c6)c6cccc4c65)cc3-c3ccccc3)c2)cc1 ; CC(C)(C)c1c(-c2ccccc2)cc(-c2c(-c3ccccc3)cc(N3c4ccc(-c5ccccc5)cc4B4c5cc(-c6ccccc6)ccc5N(c5cc(-c6ccccc6)c(-c6cc(-c7ccccc7)c(C(C)(C)C)c(-c7ccccc7)c6)c(-c6ccccc6)c5)c5cccc3c54)cc2-c2ccccc2)cc1-c1ccccc1]

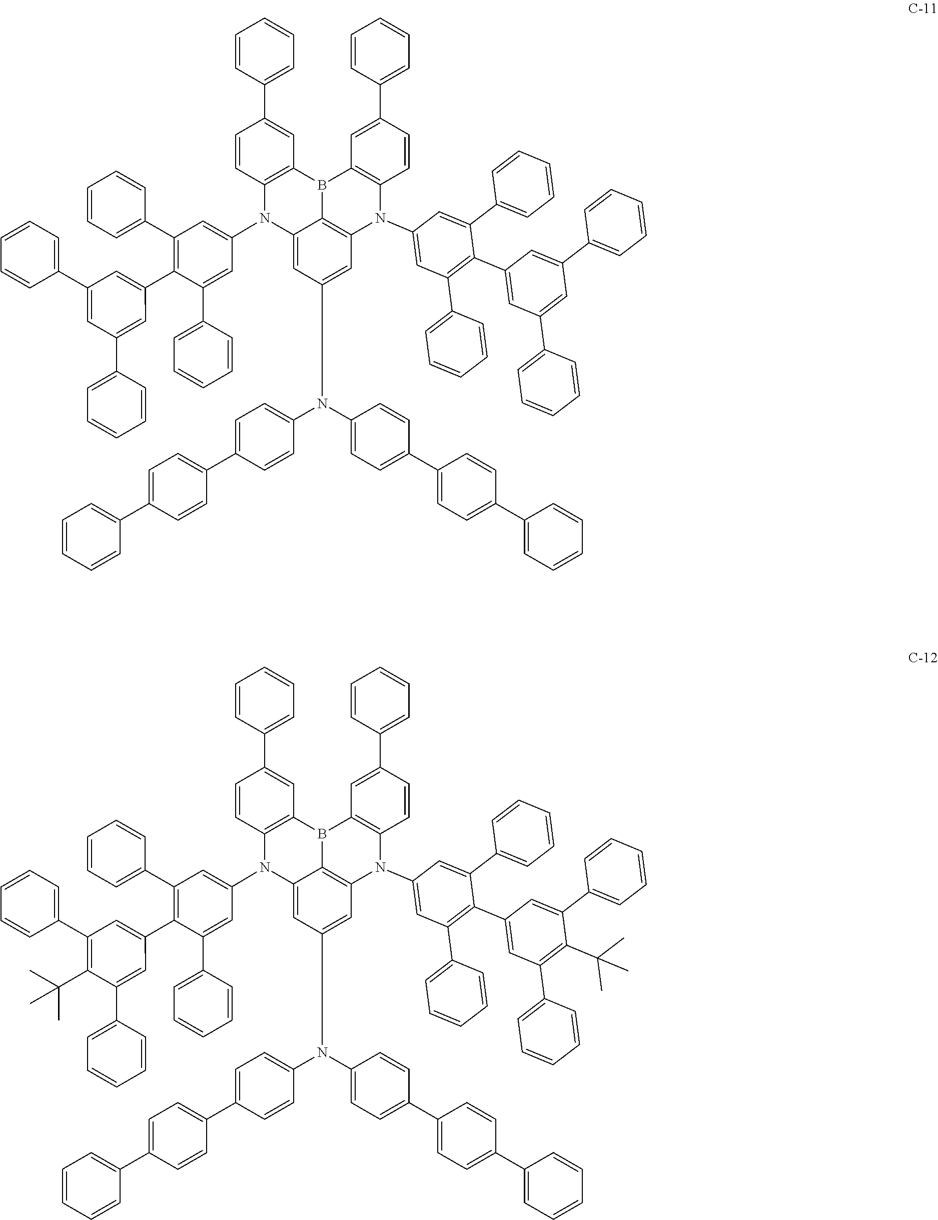

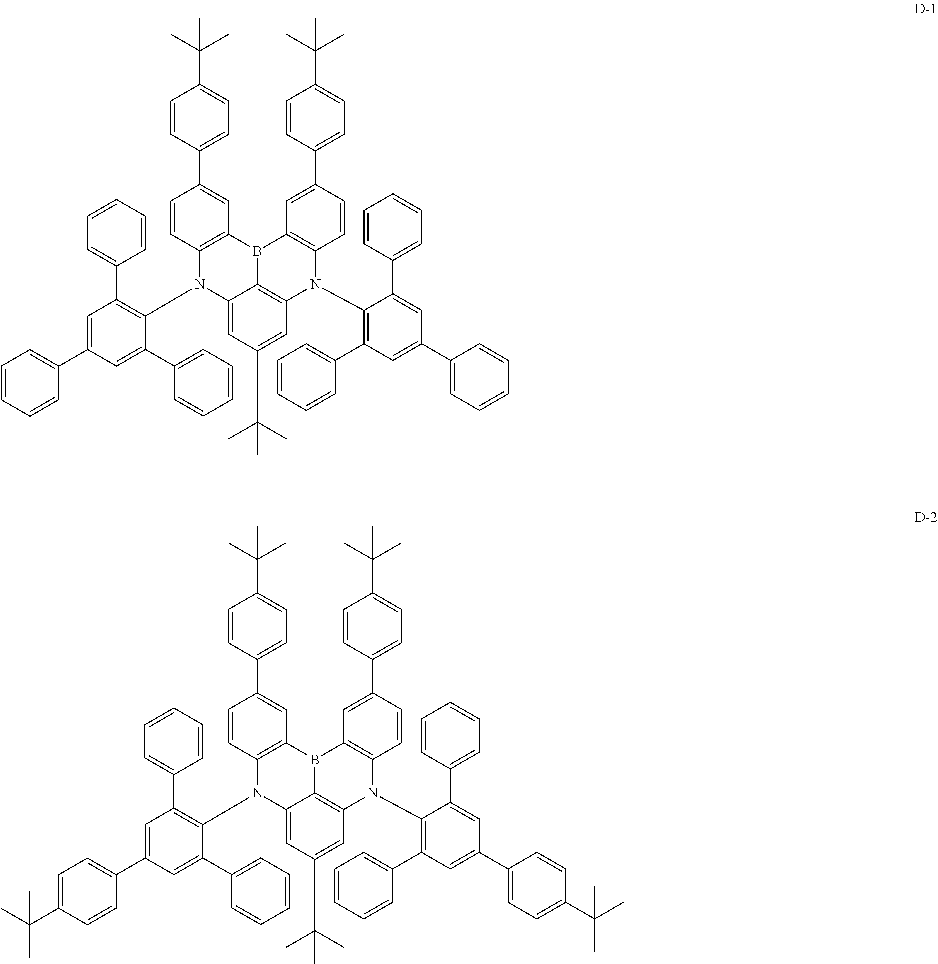 [SMILES: CC(C)(C)c1ccc(-c2ccc3c(c2)B2c4cc(-c5ccc(C(C)(C)C)cc5)ccc4N(c4c(-c5ccccc5)cc(-c5ccccc5)cc4-c4ccccc4)c4cc(C(C)(C)C)cc(c42)N3c2c(-c3ccccc3)cc(-c3ccccc3)cc2-c2ccccc2)cc1 ; CC(C)(C)c1ccc(-c2ccc3c(c2)B2c4cc(-c5ccc(C(C)(C)C)cc5)ccc4N(c4c(-c5ccccc5)cc(-c5ccc(C(C)(C)C)cc5)cc4-c4ccccc4)c4cc(C(C)(C)C)cc(c42)N3c2c(-c3ccccc3)cc(-c3ccc(C(C)(C)C)cc3)cc2-c2ccccc2)cc1]

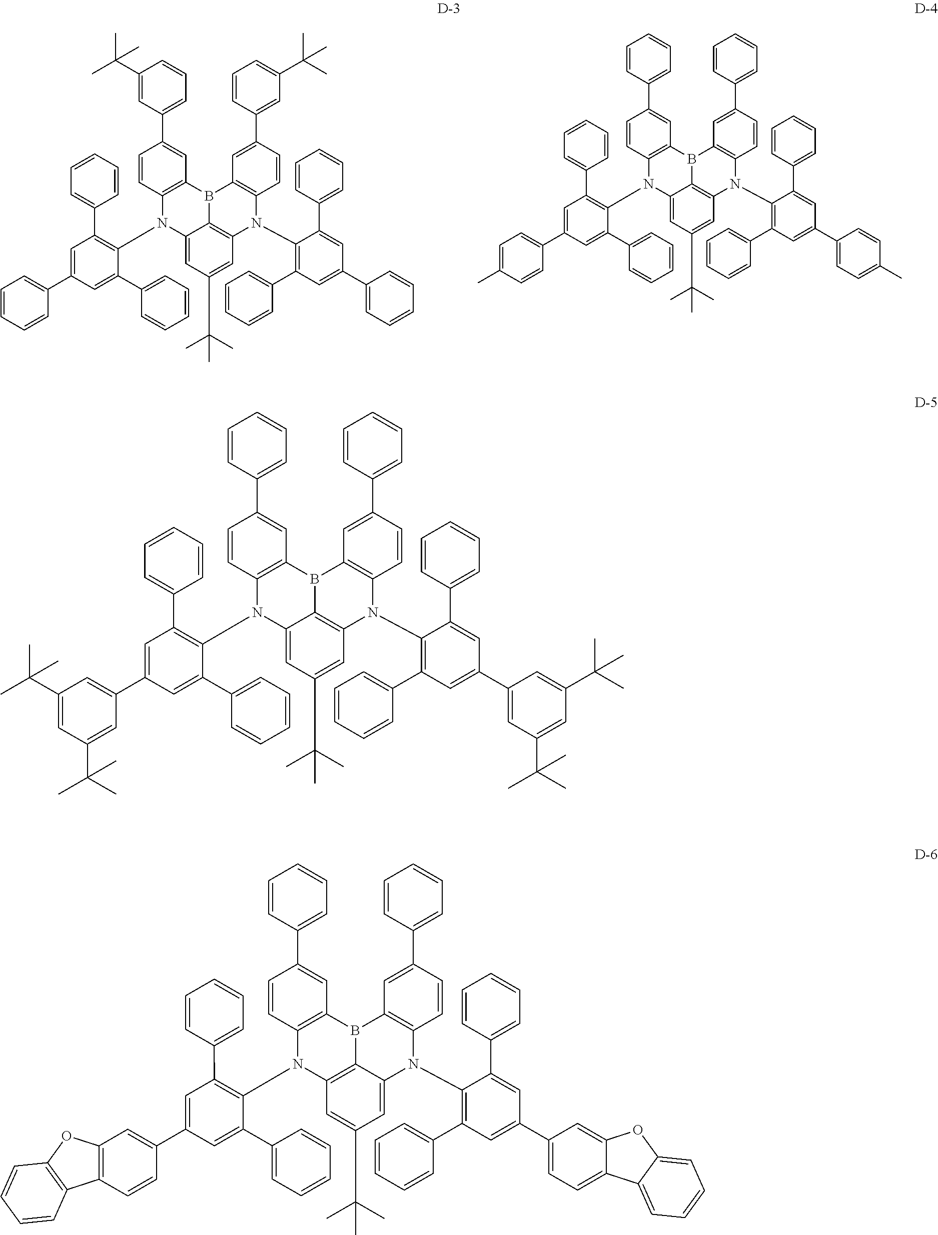

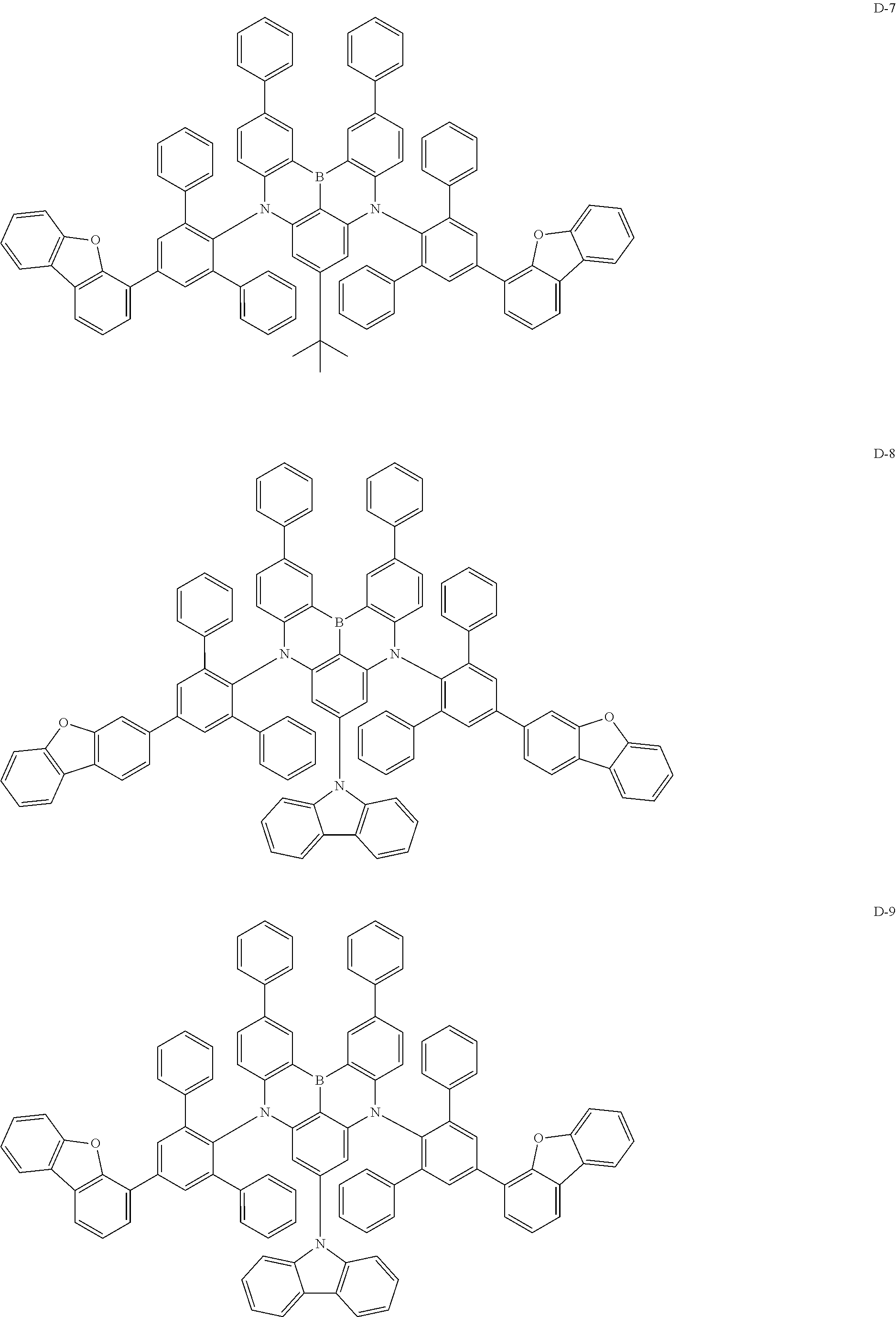

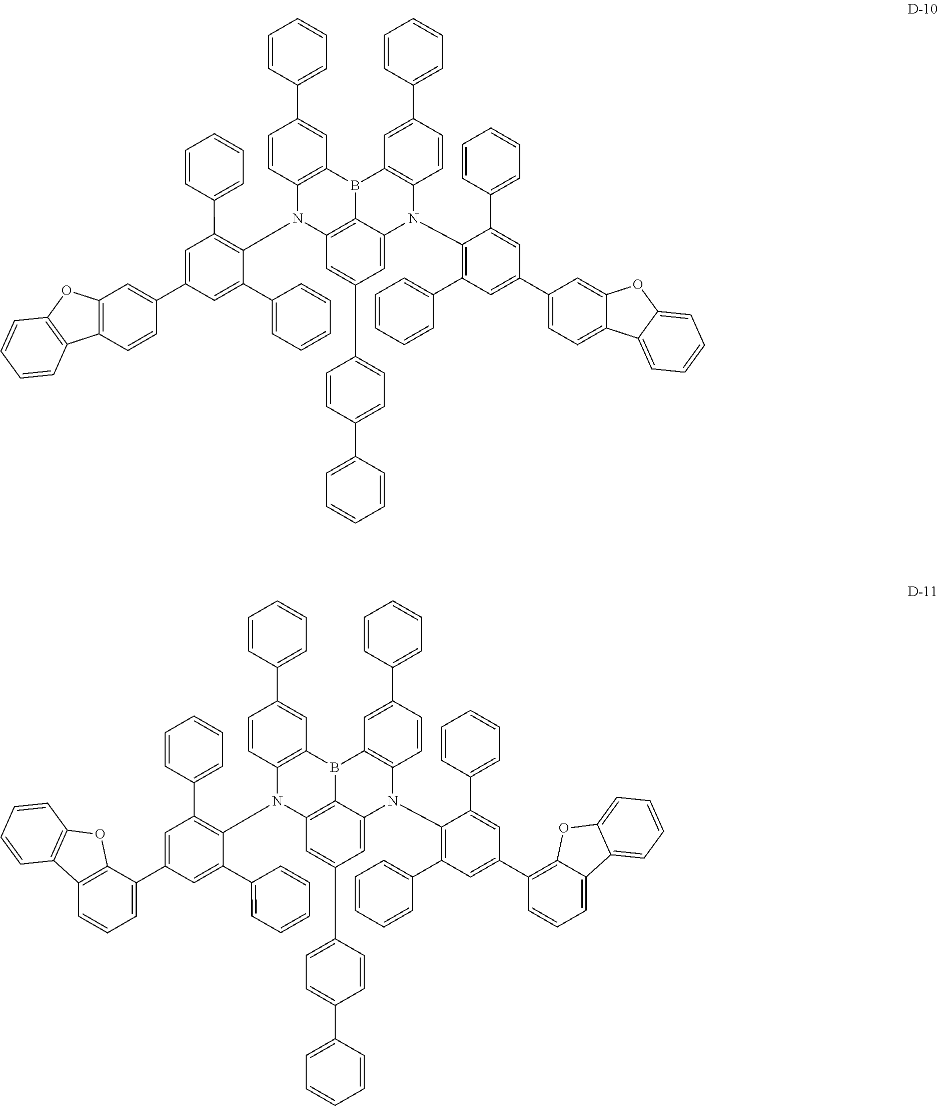 [SMILES: c1ccc(-c2ccc(-c3cc4c5c(c3)N(c3c(-c6ccccc6)cc(-c6ccc7c(c6)oc6ccccc67)cc3-c3ccccc3)c3ccc(-c6ccccc6)cc3B5c3cc(-c5ccccc5)ccc3N4c3c(-c4ccccc4)cc(-c4ccc5c(c4)oc4ccccc45)cc3-c3ccccc3)cc2)cc1 ; c1ccc(-c2ccc(-c3cc4c5c(c3)N(c3c(-c6ccccc6)cc(-c6cccc7c6oc6ccccc67)cc3-c3ccccc3)c3ccc(-c6ccccc6)cc3B5c3cc(-c5ccccc5)ccc3N4c3c(-c4ccccc4)cc(-c4cccc5c4oc4ccccc45)cc3-c3ccccc3)cc2)cc1]

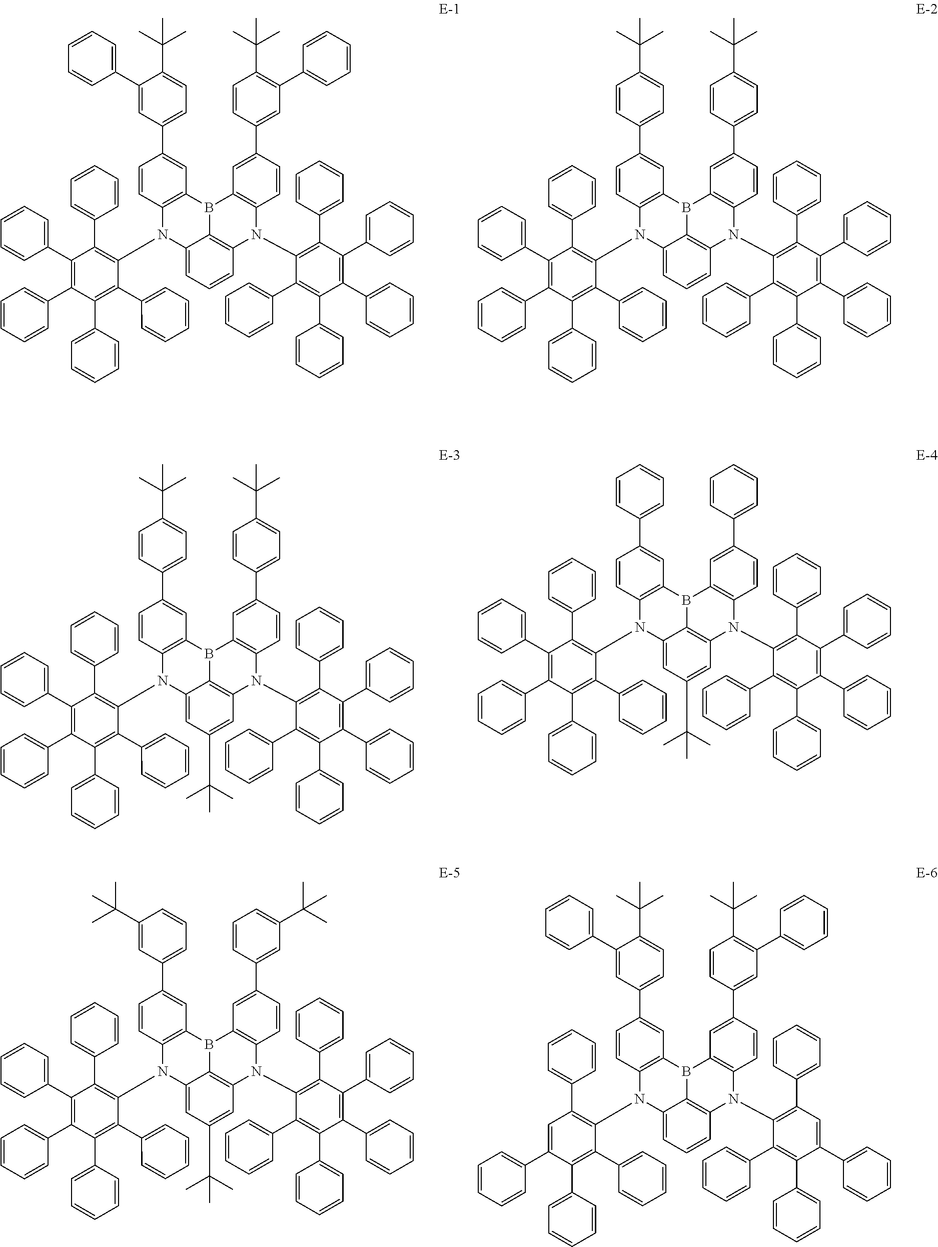

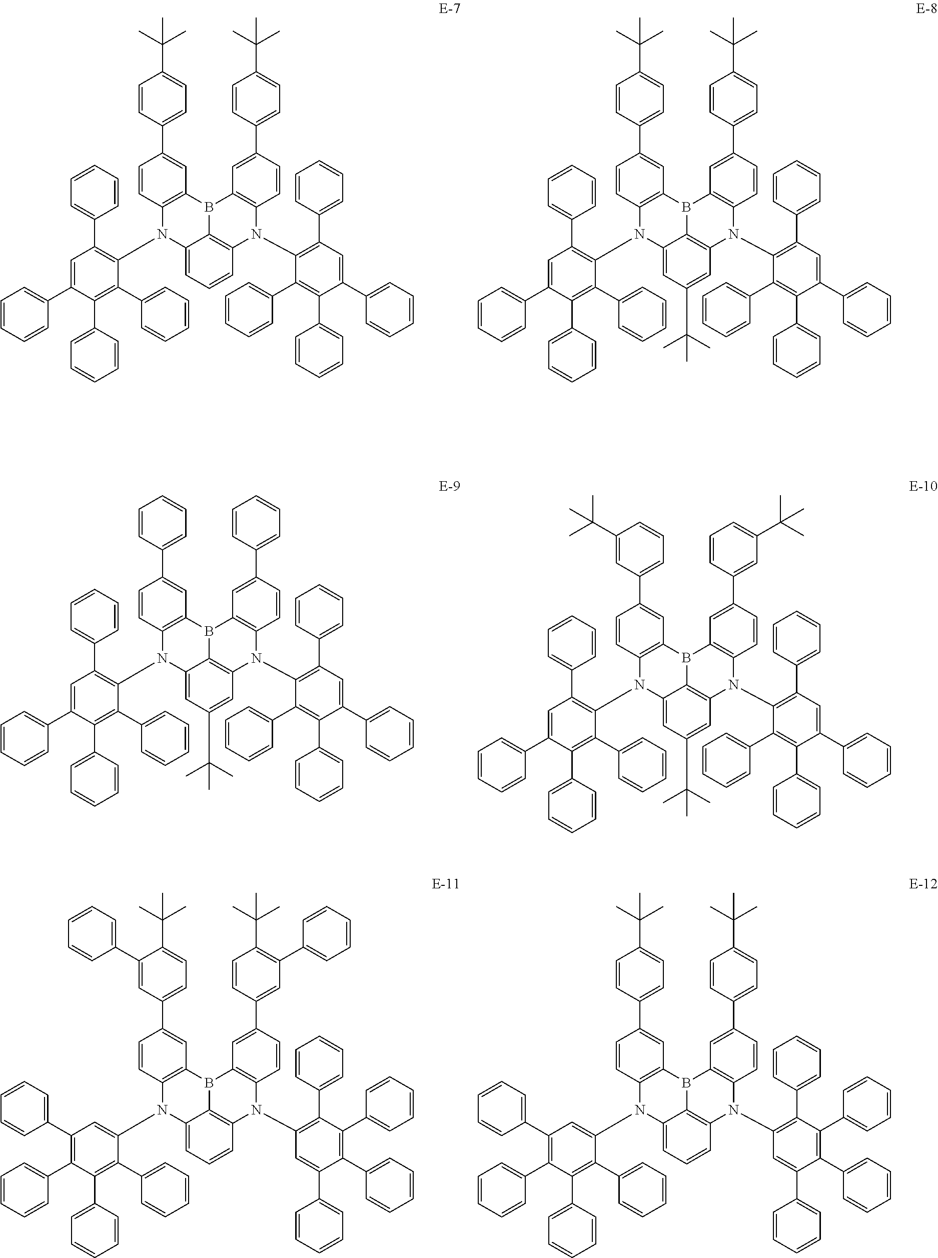

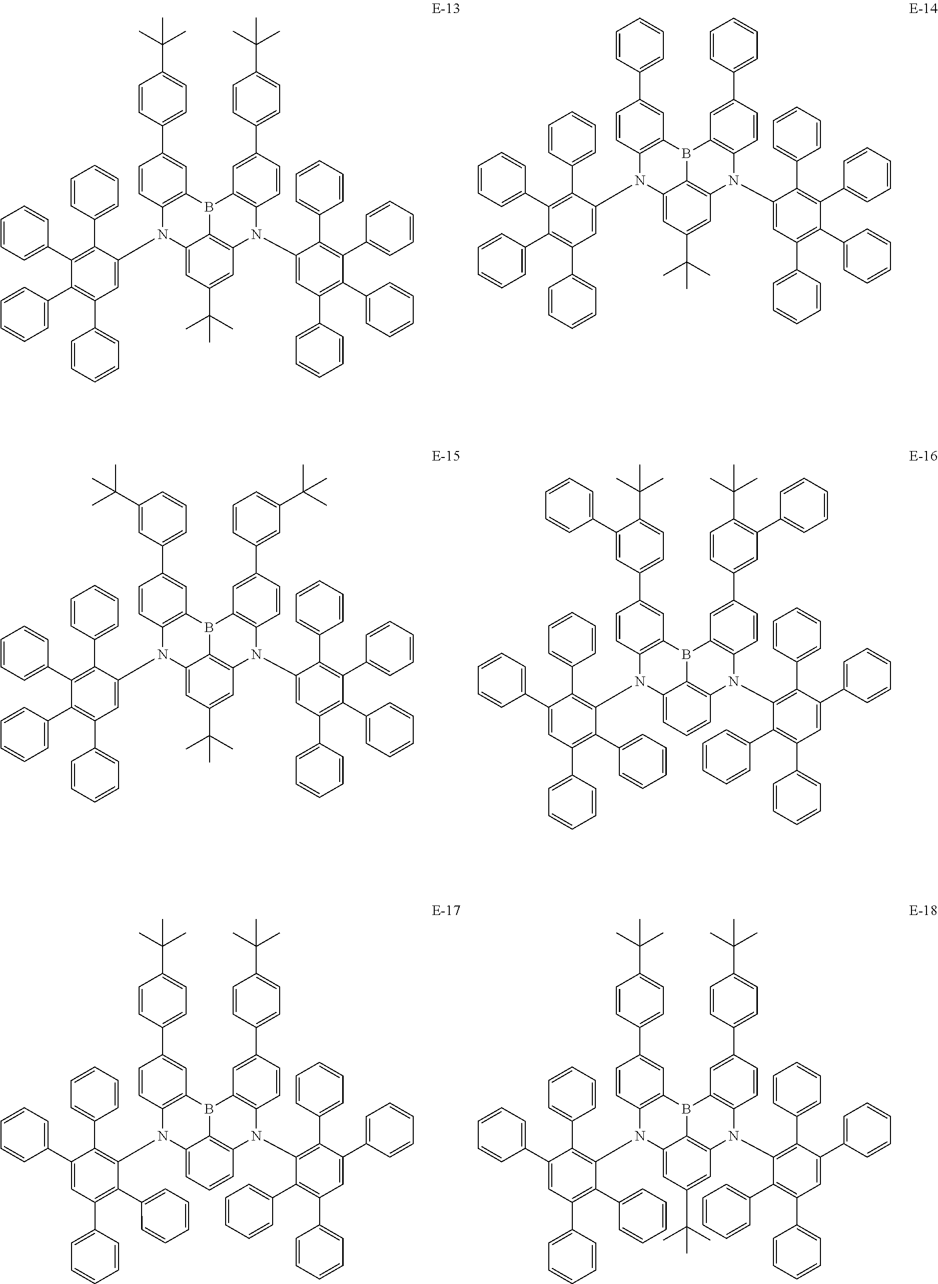

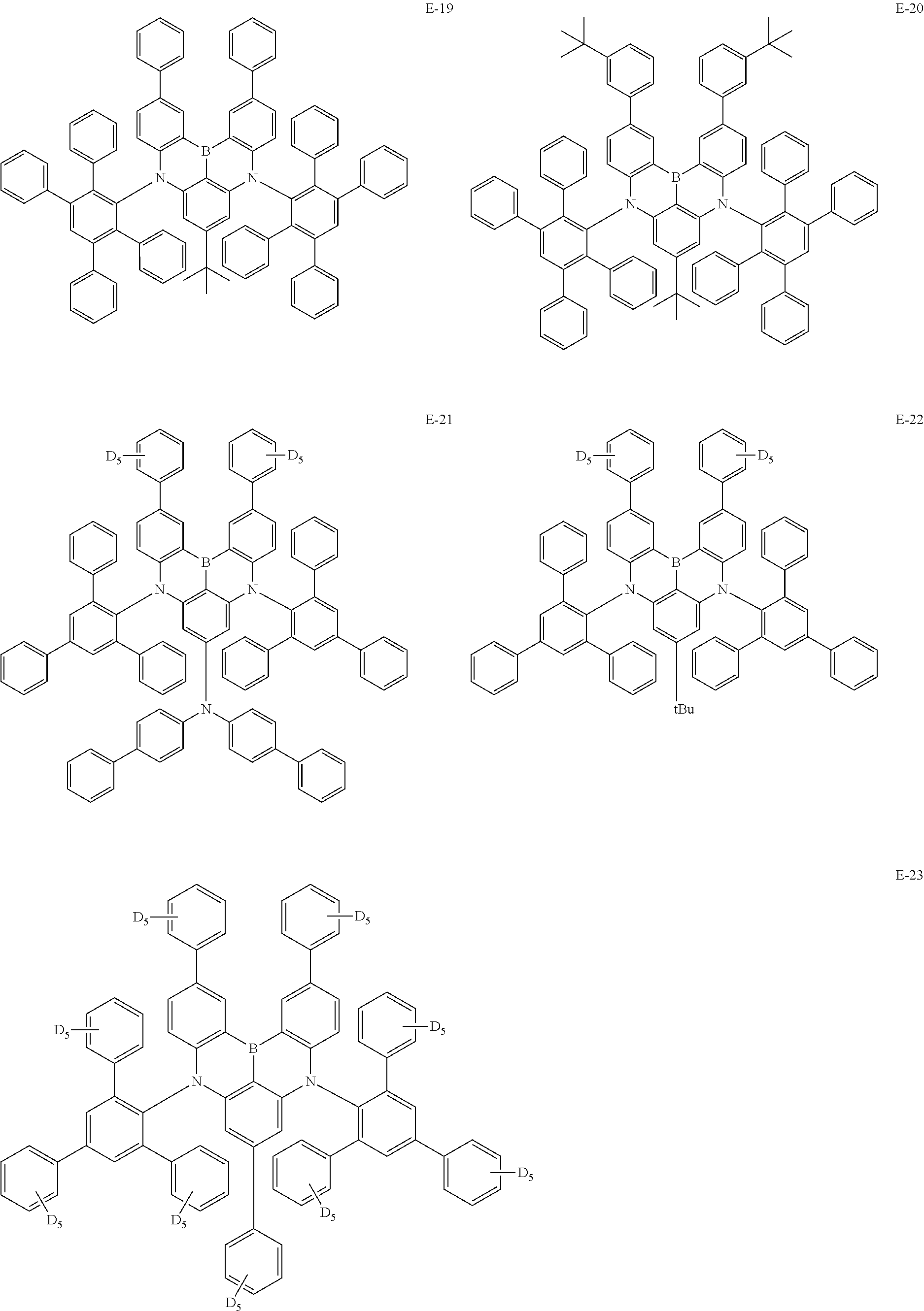

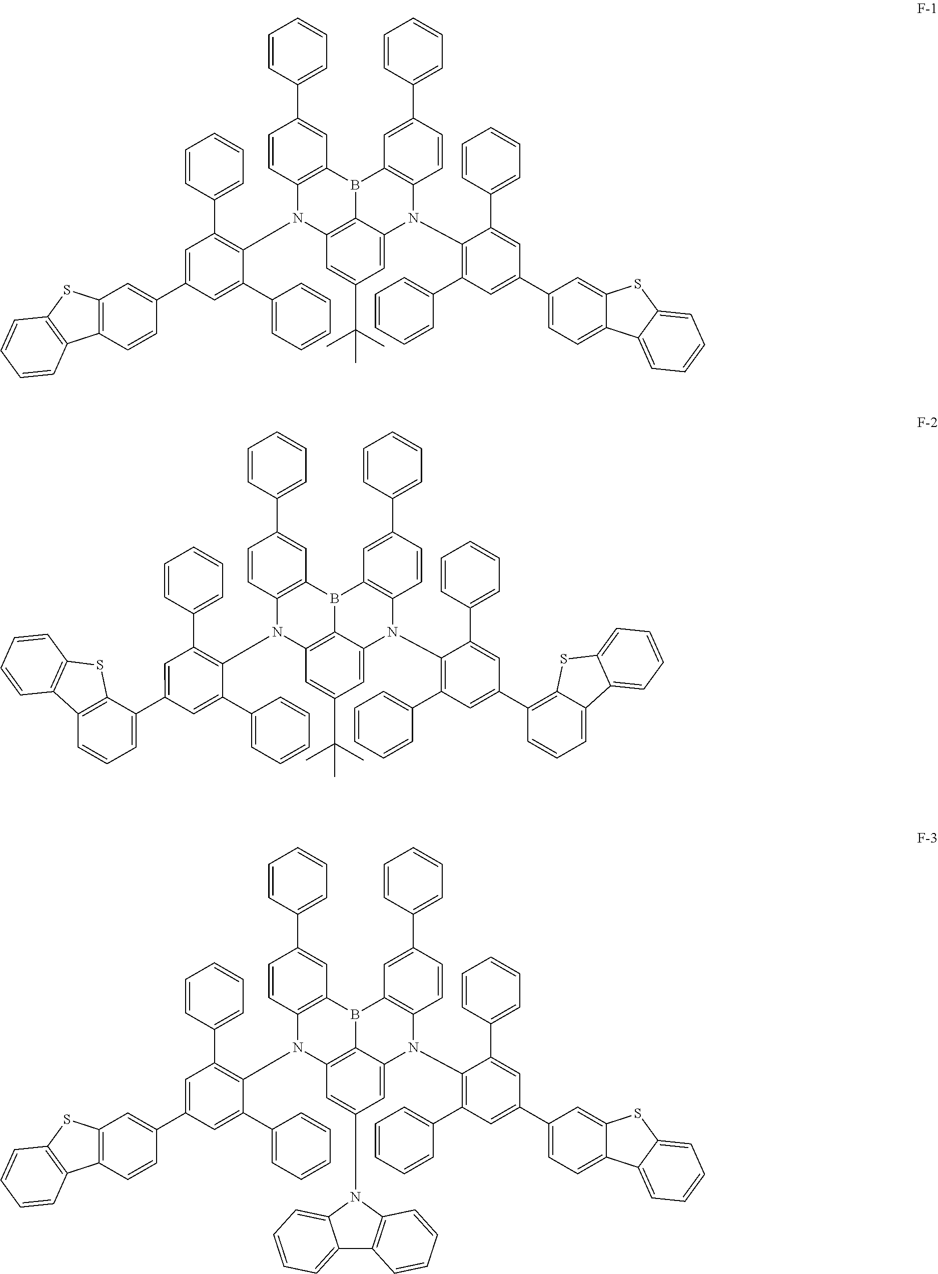

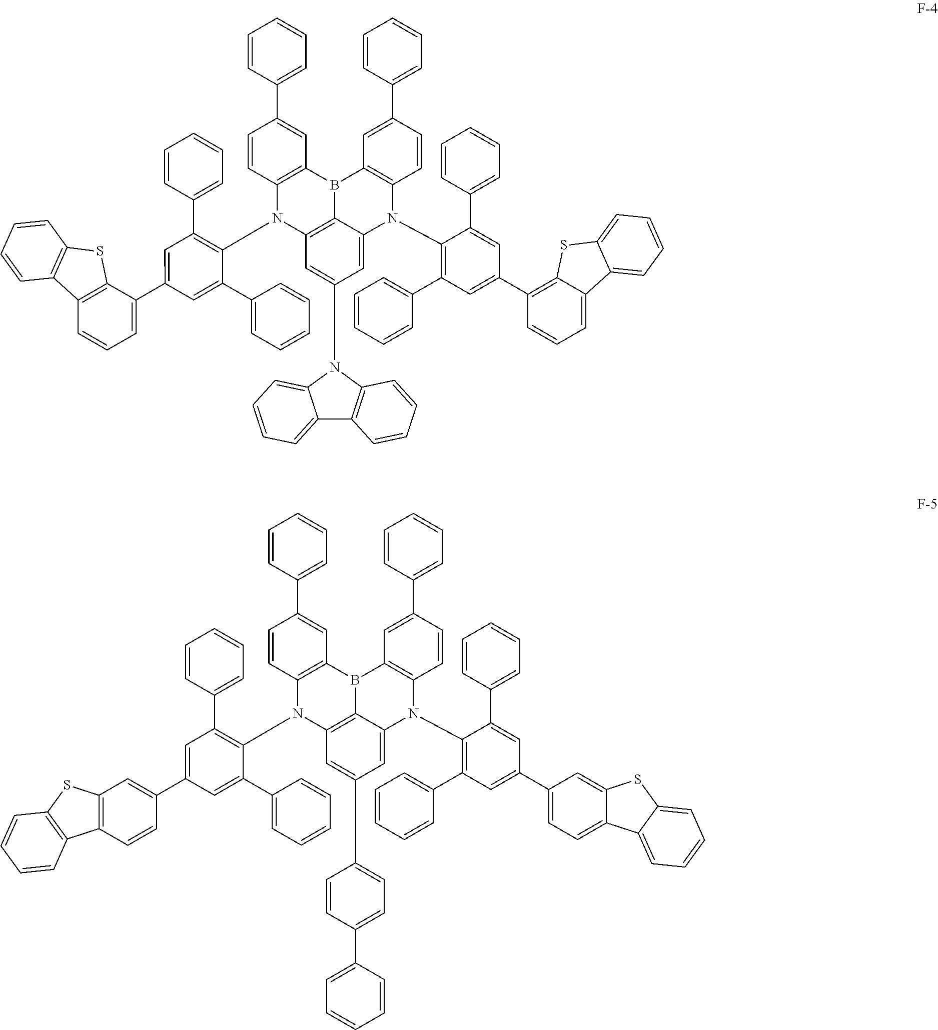 [SMILES: c1ccc(-c2ccc3c(c2)B2c4cc(-c5ccccc5)ccc4N(c4c(-c5ccccc5)cc(-c5cccc6c5sc5ccccc56)cc4-c4ccccc4)c4cc(-n5c6ccccc6c6ccccc65)cc(c42)N3c2c(-c3ccccc3)cc(-c3cccc4c3sc3ccccc34)cc2-c2ccccc2)cc1 ; c1ccc(-c2ccc(-c3cc4c5c(c3)N(c3c(-c6ccccc6)cc(-c6ccc7c(c6)sc6ccccc67)cc3-c3ccccc3)c3ccc(-c6ccccc6)cc3B5c3cc(-c5ccccc5)ccc3N4c3c(-c4ccccc4)cc(-c4ccc5c(c4)sc4ccccc45)cc3-c3ccccc3)cc2)cc1]

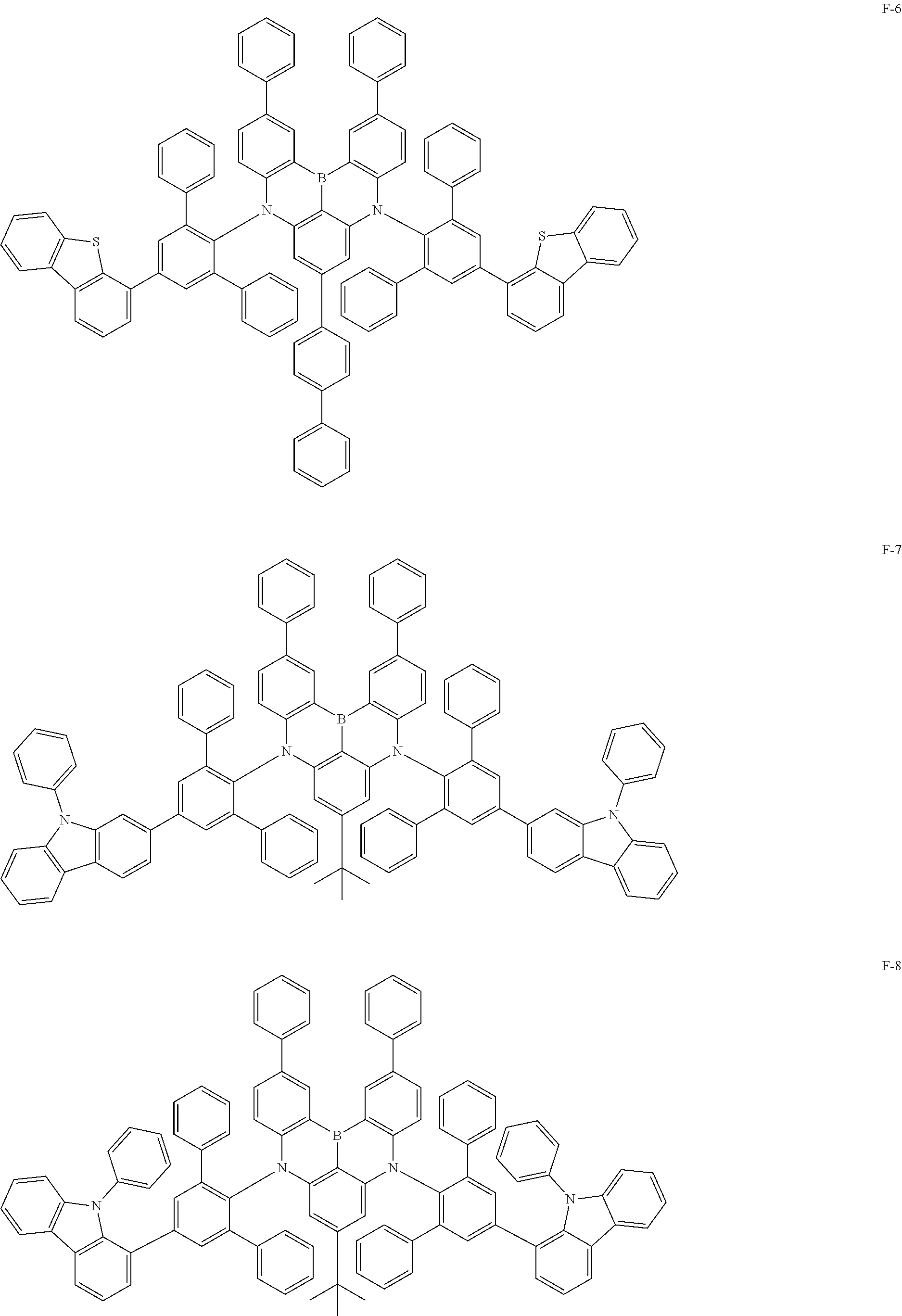

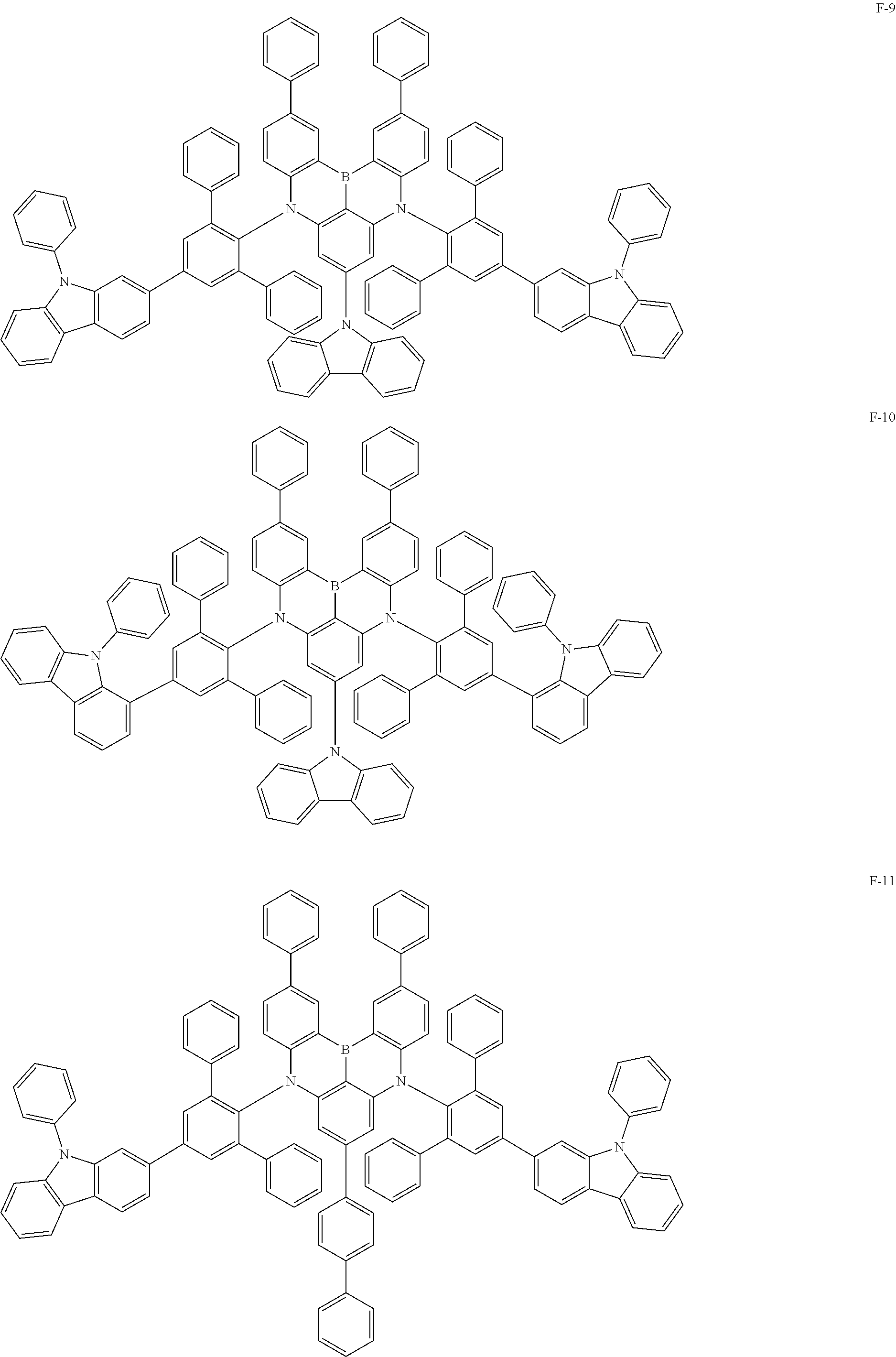

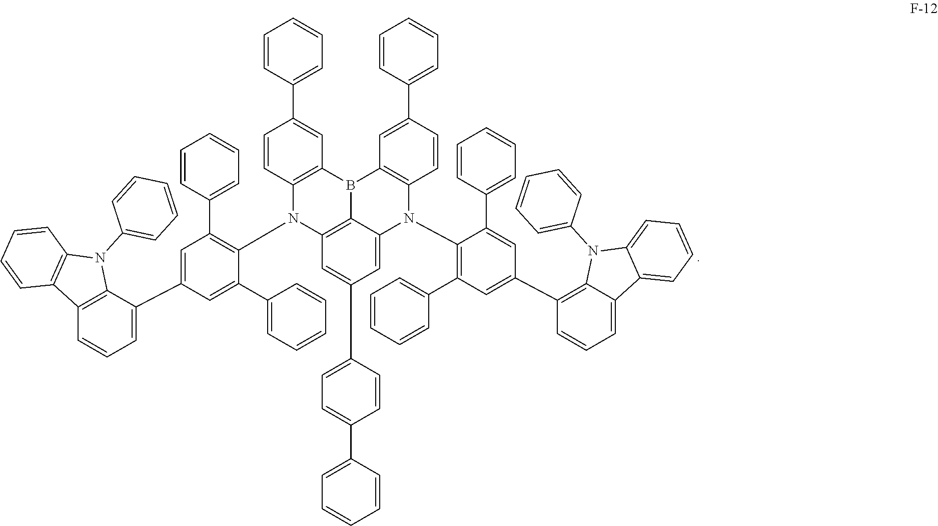 [SMILES: c1ccc(-c2ccc(-c3cc4c5c(c3)N(c3c(-c6ccccc6)cc(-c6cccc7c8ccccc8n(-c8ccccc8)c67)cc3-c3ccccc3)c3ccc(-c6ccccc6)cc3B5c3cc(-c5ccccc5)ccc3N4c3c(-c4ccccc4)cc(-c4cccc5c6ccccc6n(-c6ccccc6)c45)cc3-c3ccccc3)cc2)cc1]

13. A polycyclic compound represented by the following Formula 1: 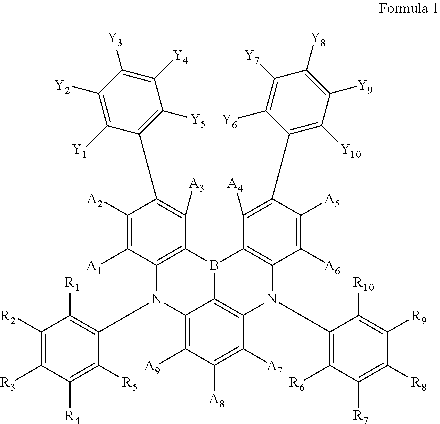
in Formula 1,
A₁ to A₉ are each independently a hydrogen atom, a deuterium atom, a halogen atom, a cyano group, a nitro group, a substituted or unsubstituted boron group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, where a case where at least one selected from among A₂ and A₅ is an unsubstituted carbazole group is excluded,
Y₁ to Y₁₀ are each independently a hydrogen atom, a deuterium atom, a halogen atom, a substituted or unsubstituted boron group, a substituted or unsubstituted amine group, a substituted or unsubstituted alkyl group of 1 to 20 carbon atoms, or a substituted or unsubstituted aryl group of 6 to 30 ring-forming carbon atoms, where a case where at least one selected from among Y₁, Y₅, Y₆ and Y₁₀ is a substituted or unsubstituted alkyl group of 1 to 20 carbon atoms is excluded,
R₁ to R₁₀ are each independently a hydrogen atom, a deuterium atom or represented by the following Formula 2, or combined with an adjacent group to form a ring, where at least three among R₁ to R₅, or at least three among R₆ to R₁₀ are each independently represented by the following Formula 2, and
a case where R₁ and R₅ are all hydrogen atoms, and R₂ to R₄ are all unsubstituted phenyl groups, or a case where R₆ and R₁₀ are all hydrogen atoms, and R₇ to R₉ are all unsubstituted phenyl groups are excluded: 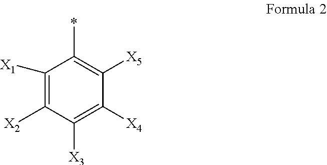
in Formula 2,
X₁ to X₅ are each independently a hydrogen atom, a deuterium atom, a halogen atom, a substituted or unsubstituted boron group, a substituted or unsubstituted amine group, a substituted or unsubstituted oxy group, a substituted or unsubstituted thio group, a substituted or unsubstituted alkyl group of 1 to 20 carbon atoms, or a substituted or unsubstituted aryl group of 6 to 30 ring-forming carbon atoms, or combined with an adjacent group to form a ring.

14. The polycyclic compound of claim 13, wherein the Formula 1 is represented by the following Formula 3: 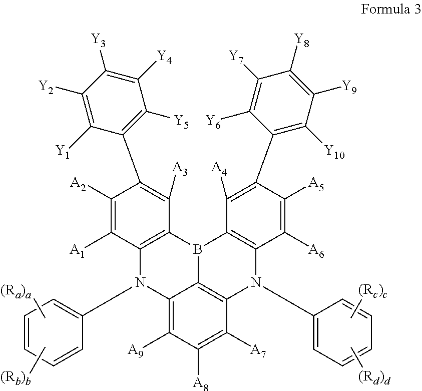
in Formula 3,
Rₐ and R_{c} are each independently represented by Formula 2,
R_{b} and R_{d} are each independently a hydrogen atom or a deuterium atom,
“a” and “c” are each independently an integer of 3 to 5,
“b” and “d” are each independently an integer of 0 to 2, and
A₁ to A₉, and Y₁ to Y₁₀ are the same as defined with respect to Formula 1.

15. The polycyclic compound of claim 13, wherein Formula 1 is represented by the following Formula 4: 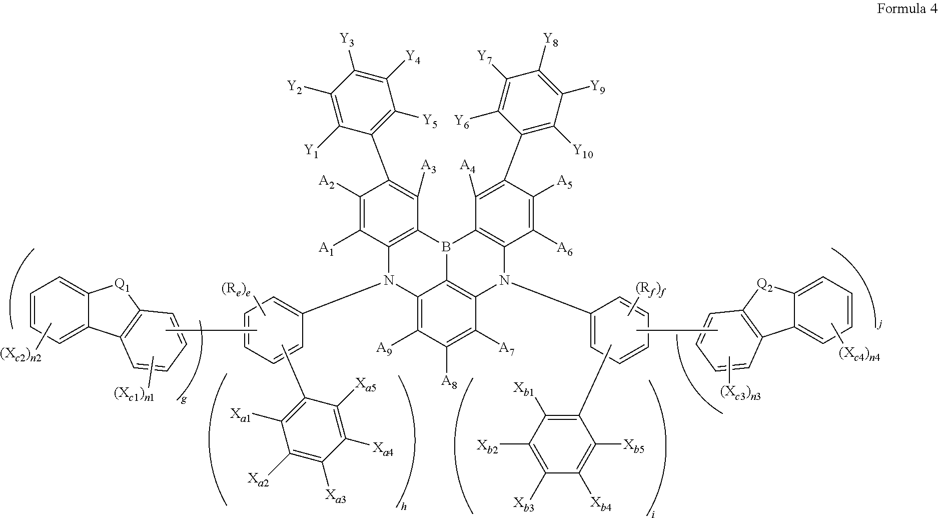
in Formula 4,
Q₁ and Q₂ are each independently 0, S or NR_{q},
R_{q} is a substituted or unsubstituted aryl group of 3 to 10 ring-forming carbon atoms,
Rₑ and R_{f} are each independently a hydrogen atom or a deuterium atom,
Xₐ₁ to Xₐ₅, X_{b1} to X_{b5}, and X_{c1} to X_{c4} are each independently a hydrogen atom, a deuterium atom, a substituted or unsubstituted alkyl group of 1 to 20 carbon atoms, or a substituted or unsubstituted aryl group of 6 to 30 ring-forming carbon atoms,
“e” and “f” are each independently an integer of 0 to 2,
“g” and “j” are each independently an integer of 0 or 1,
“h” and “i” are each independently an integer of 2 to 5,
n1 and n3 are each independently an integer of 0 to 3,
n2 and n4 are each independently an integer of 0 to 4, and
A₁ to A₉, and Y₁ to Y₁₀ are the same as defined with respect to Formula 1.

16. The polycyclic compound of claim 13, wherein Formula 1 is represented by any one selected from among the following Formula 5-1 to Formula 5-3: 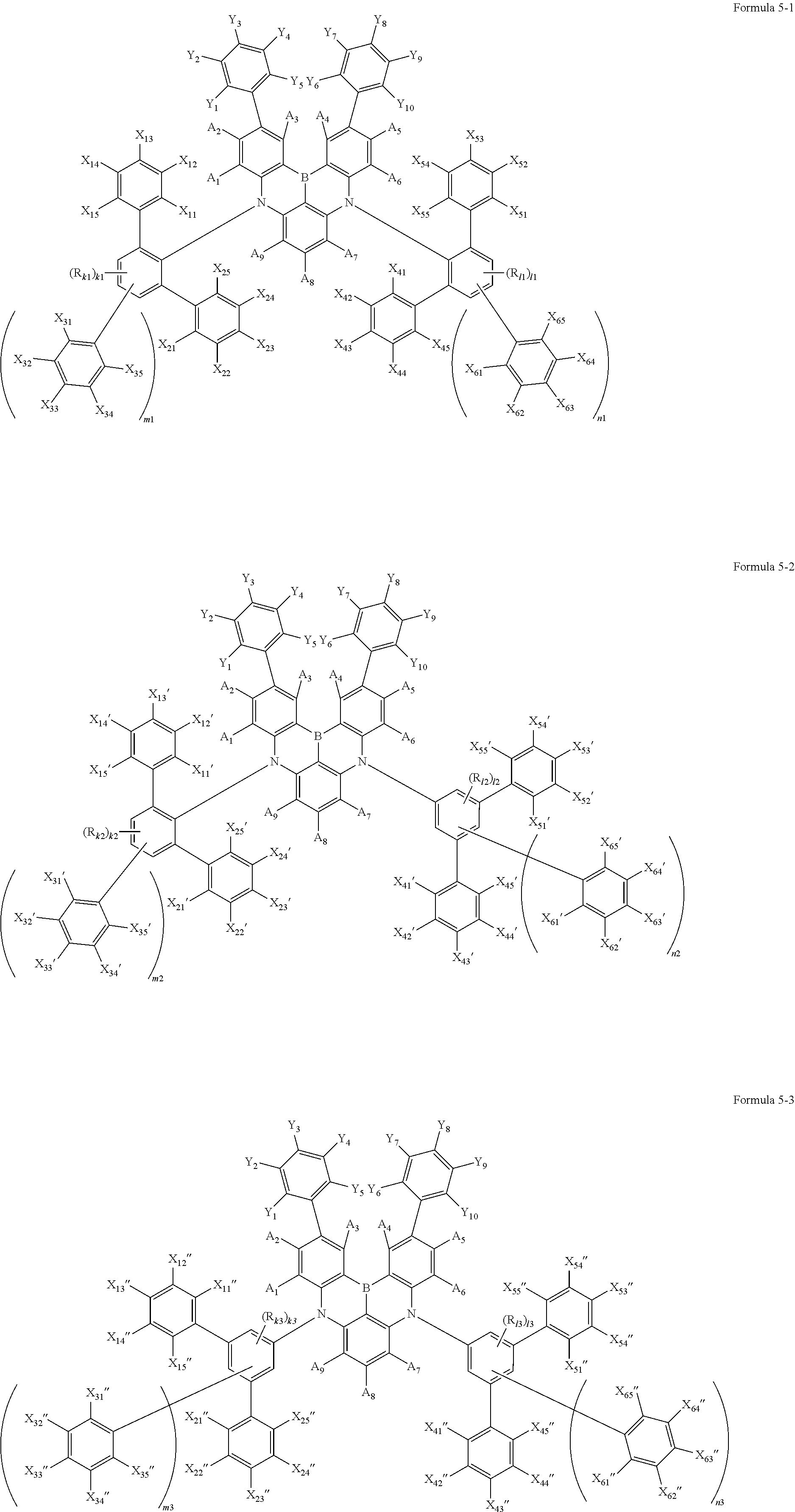
in Formula 5-1 to Formula 5-3,
Rₖ₁, Rₖ₂, Rₖ₃, Rₗ₁, Rₗ₂, and R₁₃ are each independently a hydrogen atom, or a deuterium atom,
X₁₁ to X₁₅, X₂₁ to X₂₅, X₃₁ to X₃₅, X₄₁ to X₄₅, X₅₁ to X₅₅, X₆₁ to X₆₅, X₁₁′ to X₁₅′, X₂₁′ to X₂₅′, X₃₁′ to X₃₅′, X₄₁′ to X₄₅′, X₅₁′ to X₅₅′, X₆₁′ to X₆₅′, X₁₁″ to X₁₅″, X₂₁″ to X₂₅″, X₃₁″ to X₃₅″, X₄₁″ to X₄₅″, X₅₁″ to X₅₅″, and X₆₁″ to X₆₅″ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle,
k1 to k3, and 11 to 13 are each independently an integer of 0 to 2,
m1 to m3, and n1 to n3 are each independently an integer of 1 to 3, and
A₁ to A₉, and Y₁ to Y₁₀ are the same as defined with respect to Formula 1.

17. The polycyclic compound of claim 16, wherein Formula 5-1 is represented by any one selected from among the following Formula 5-1-1 to Formula 5-1-4: 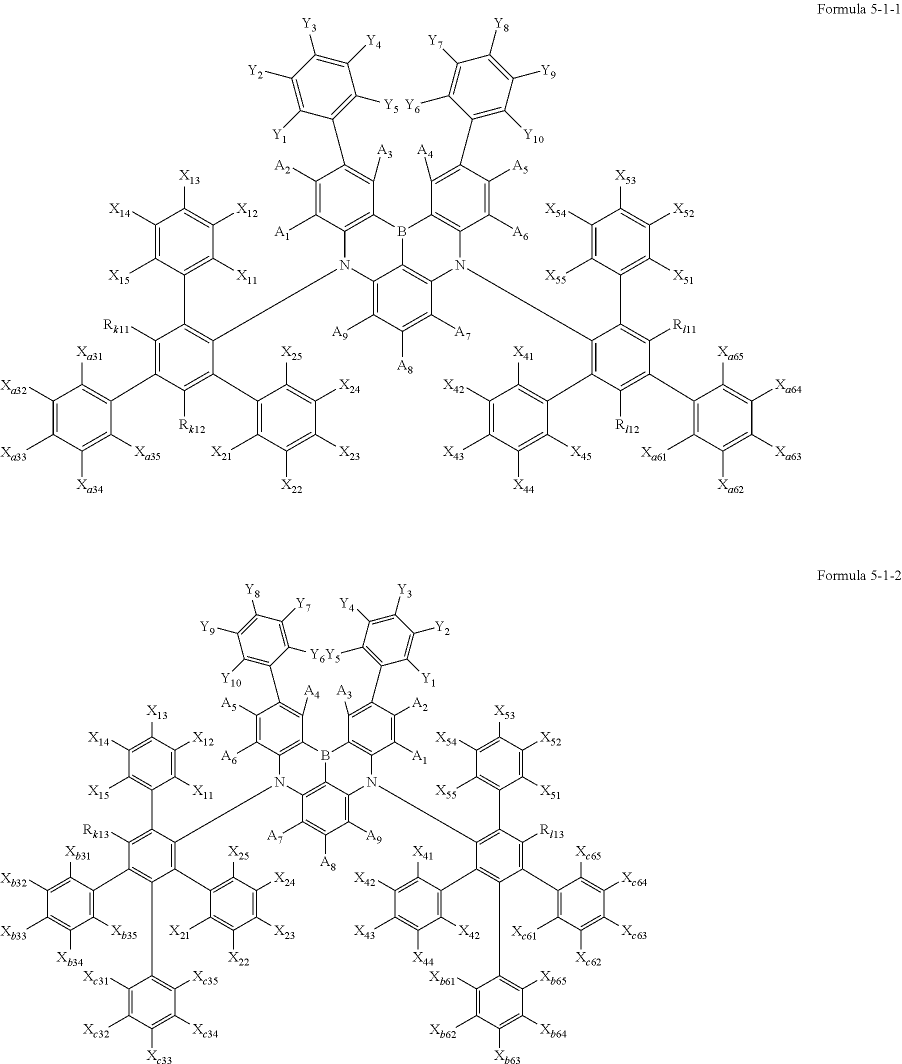 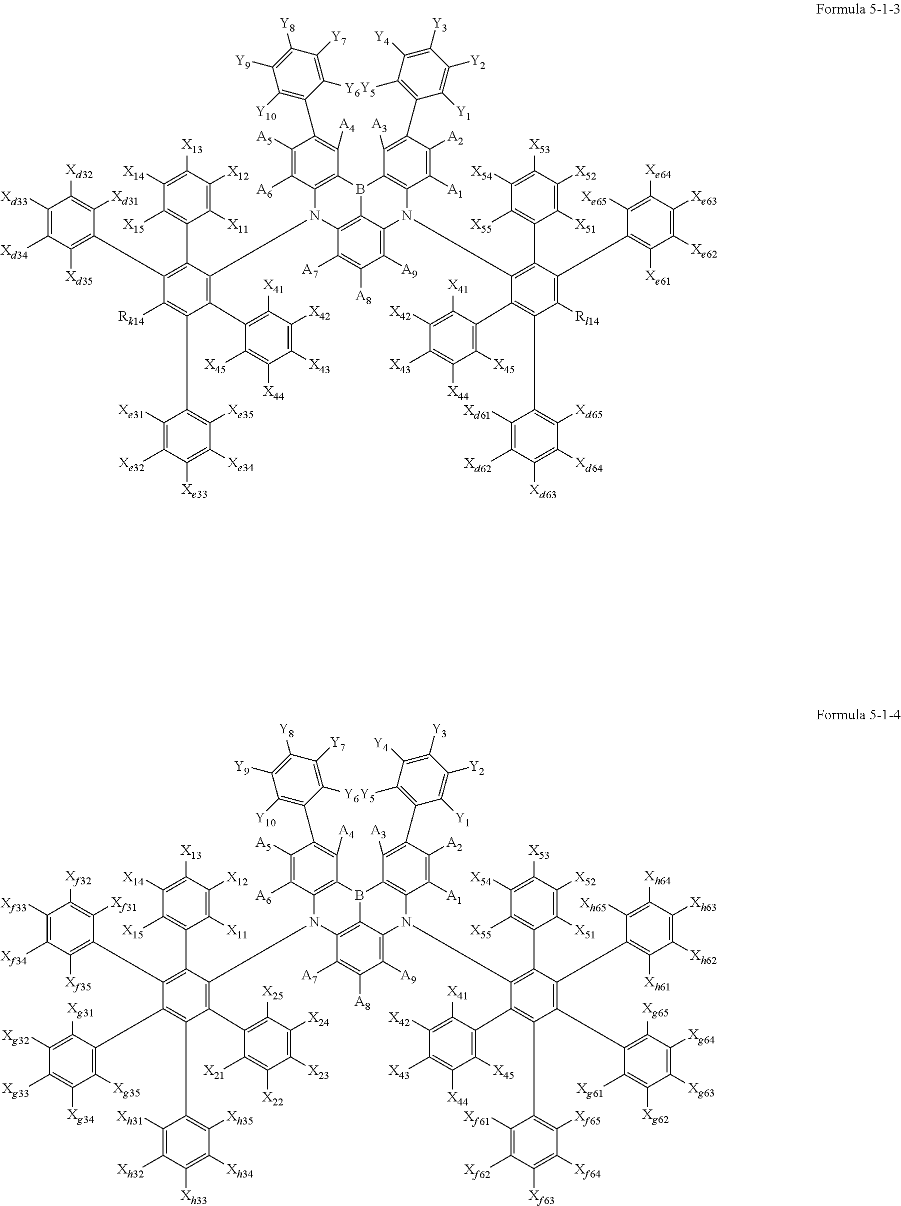
in Formula 5-1-1 to Formula 5-1-4,
Rₖ₁₁ to Rₖ₁₄, and Rₗ₁₁ to Rₗ₁₄ are each independently a hydrogen atom or a deuterium atom, and
Xₐ₃₁ to Xₐ₃₅, X_{b31} to X_{b35}, X_{c31} to X_{c35}, X_{d31} to X_{d35}, Xₑ₃₁ to Xₑ₃₅, X_{f31} to X_{f35}, X_{g31} to X_{g35}, Xₕ₃₁ to Xₕ₃₅, Xₐ₆₁ to Xₐ₆₅, X_{b61} to X_{b65}, X_{c61} to X_{c65}, X_{d61} to X_{d65}, Xₑ₆₁ to Xₑ₆₅, X_{f61} to X_{f65}, X_{g61} to X_{g65}, and Xₕ₆₁ to Xₕ₆₅ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle, and
A₁ to A₉, Y₁ to Y₁₀, X₁₁ to X₁₅, X₂₁ to X₂₅, X₄₁ to X₄₅, and X₅₁ to X₅₅ are the same as defined with respect to Formula 1 and Formula 5-1.

18. The polycyclic compound of claim 16, wherein Formula 5-2 is represented by the following Formula 5-2-1: 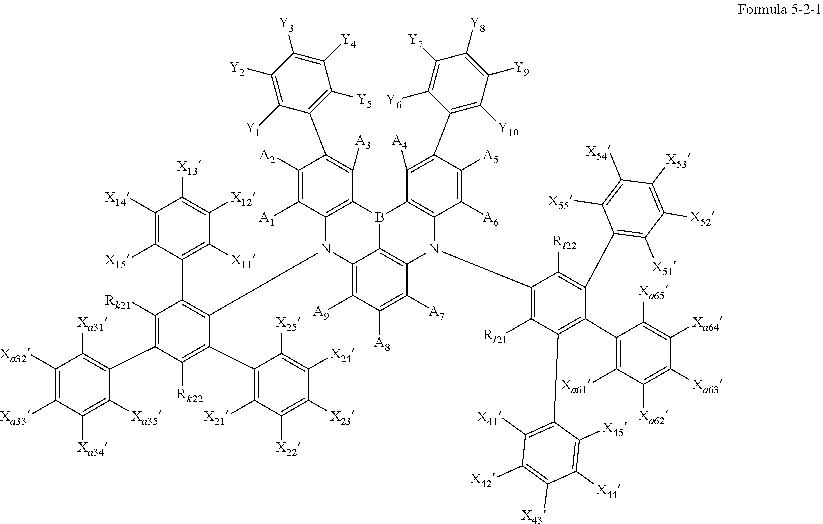
in Formula 5-2-1,
Rₖ₂₁, Rₖ₂₂, Rₗ₂₁ and Rₗ₂₂ are each independently a hydrogen atom or a deuterium atom,
Xₐ₃₁′ to Xₐ₃₅′, and Xₐ₆₁′ to Xₐ₆₅′ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a heterocycle, and
A₁ to A₉, Y₁ to Y₁₀, X₁₁′ to X₁₅′, X₂₁′ to X₂₅′, X₄₁′ to X₄₅′, and X₅₁′ to X₅₅′ are the same as defined with respect to Formula 1 and Formula 5-2.

19. The polycyclic compound of claim 16, wherein Formula 5-3 is represented by the following Formula 5-3-1 or Formula 5-3-2: 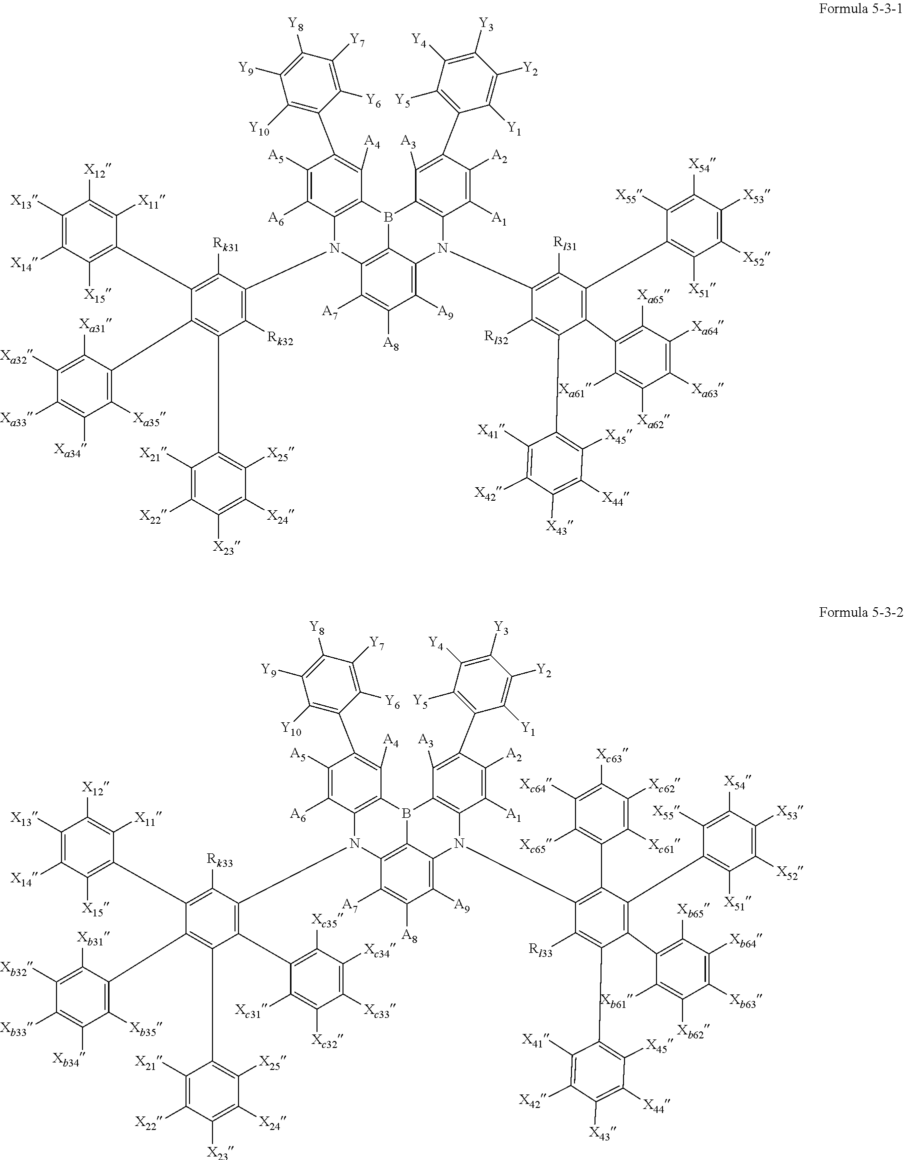
in Formula 5-3-1 and Formula 5-3-2,
Rₖ₃₁, Rₖ₃₂, Rₖ₃₃, Rₗ₃₁, Rₗ₃₂ and Rₗ₃₃ are each independently a hydrogen atom or a deuterium atom,
Xₐ₃₁″ to Xₐ₃₅″, X_{b31}″ to X_{b35}″, X_{c31}″ to X_{c35}″, Xₐ₆₁″ to Xₐ₆₅″, X_{b61}″ to X_{b65}″ and X_{c61}″ to X_{c65}″ are each independently a hydrogen atom, a deuterium atom, a substituted or unsubstituted alkyl group of 1 to 20 carbon atoms, or a substituted or unsubstituted aryl group of 6 to 30 ring-forming carbon atoms, or combined with an adjacent group to form a ring,
A₁ to A₉, Y₁ to Y₁₀, X₁₁″ to X₁₅″, X₂₁″ to X₂₅″, X₄₁″ to X₄₅″, and X₅₁″ to X₅₅″ are the same as defined with respect to Formula 1 and Formula 5-3.

20. The polycyclic compound of claim 13, wherein Formula 1 comprises any one selected from among compounds in the following Compound Group 1: 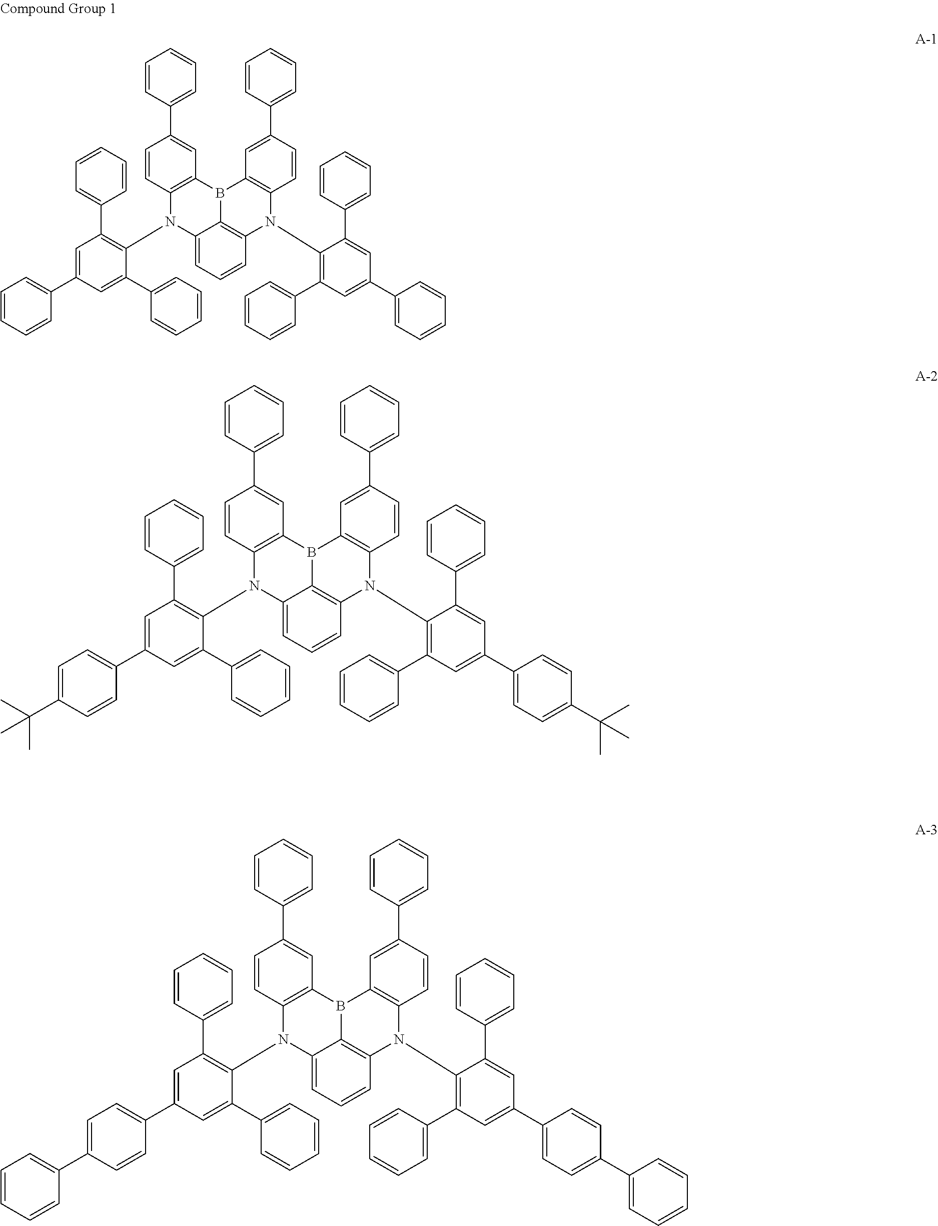 [SMILES: c1ccc(-c2ccc3c(c2)B2c4cc(-c5ccccc5)ccc4N(c4c(-c5ccccc5)cc(-c5ccccc5)cc4-c4ccccc4)c4cccc(c42)N3c2c(-c3ccccc3)cc(-c3ccccc3)cc2-c2ccccc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cccc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cccc4c65)c(-c4ccccc4)c3)cc2)cc1] 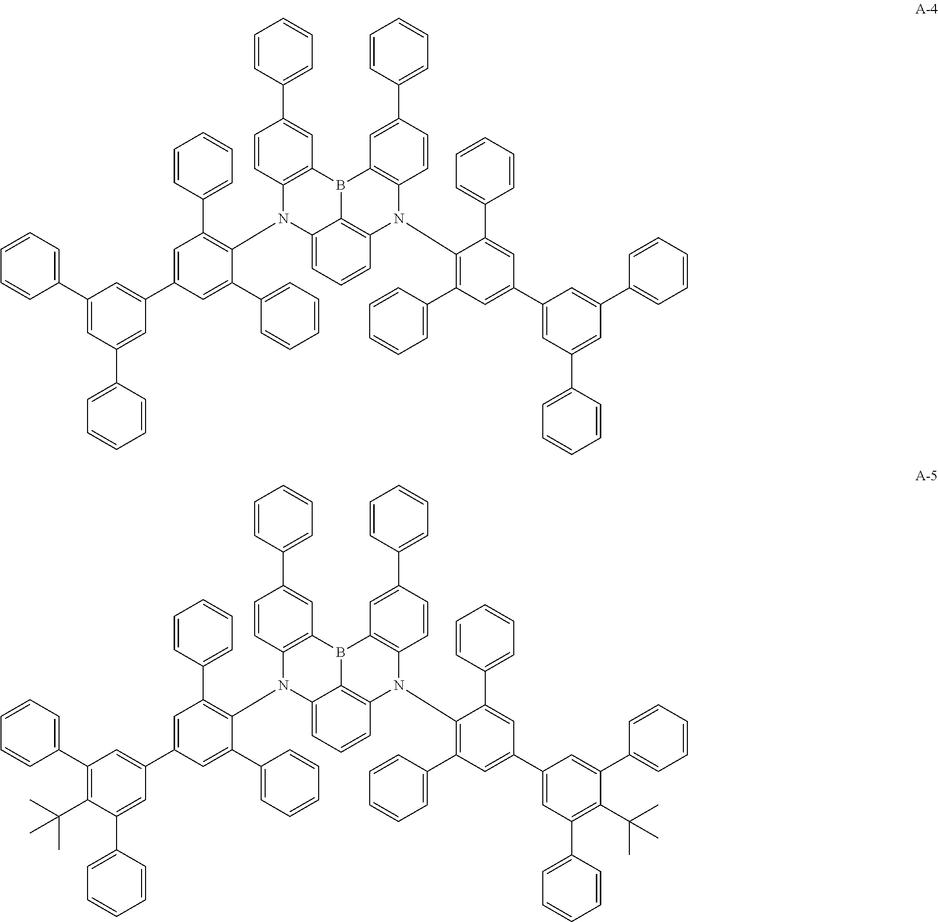 [SMILES: c1ccc(-c2cc(-c3ccccc3)cc(-c3cc(-c4ccccc4)c(N4c5ccc(-c6ccccc6)cc5B5c6cc(-c7ccccc7)ccc6N(c6c(-c7ccccc7)cc(-c7cc(-c8ccccc8)cc(-c8ccccc8)c7)cc6-c6ccccc6)c6cccc4c65)c(-c4ccccc4)c3)c2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cccc3c54)c(-c3ccccc3)c2)cc1-c1ccccc1] 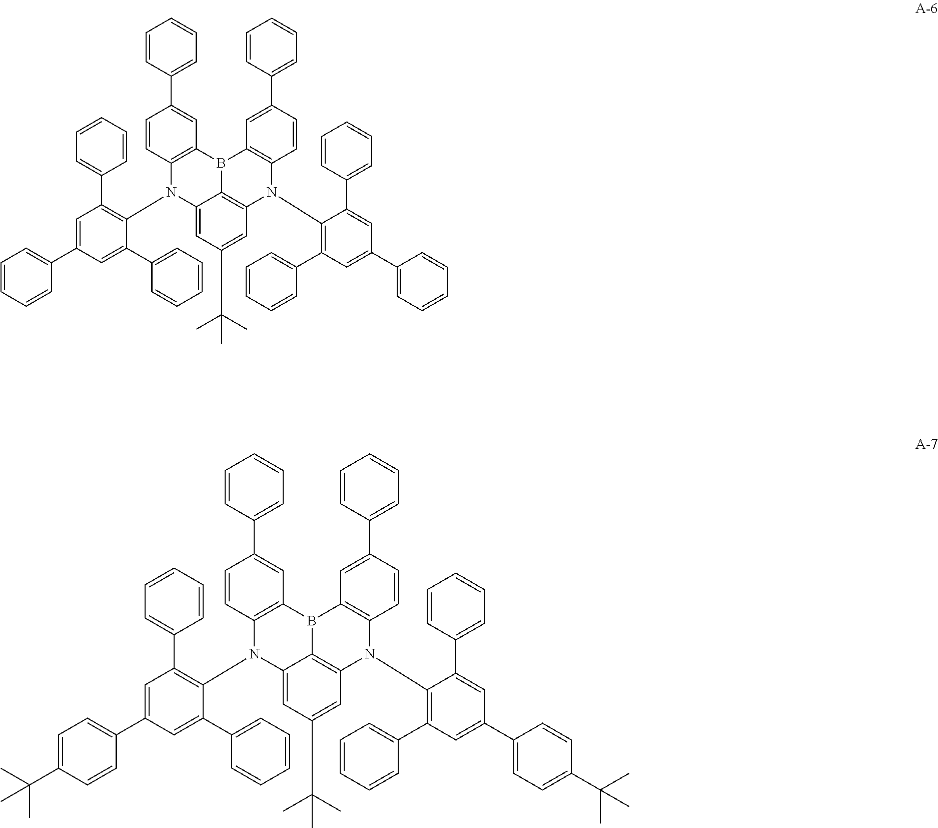 [SMILES: CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(C(C)(C)C)cc3c54)c(-c3ccccc3)c2)cc1] 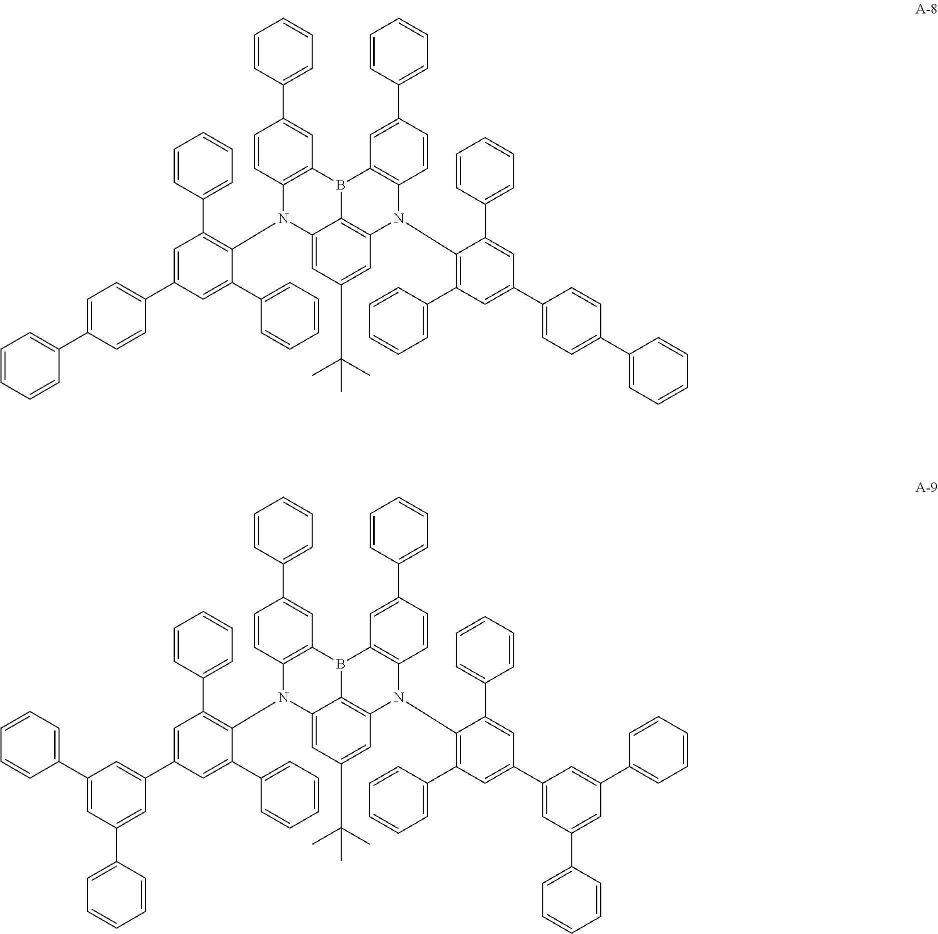 [SMILES: CC(C)(C)c1cc2c3c(c1)N(c1c(-c4ccccc4)cc(-c4ccc(-c5ccccc5)cc4)cc1-c1ccccc1)c1ccc(-c4ccccc4)cc1B3c1cc(-c3ccccc3)ccc1N2c1c(-c2ccccc2)cc(-c2ccc(-c3ccccc3)cc2)cc1-c1ccccc1 ; CC(C)(C)c1cc2c3c(c1)N(c1c(-c4ccccc4)cc(-c4cc(-c5ccccc5)cc(-c5ccccc5)c4)cc1-c1ccccc1)c1ccc(-c4ccccc4)cc1B3c1cc(-c3ccccc3)ccc1N2c1c(-c2ccccc2)cc(-c2cc(-c3ccccc3)cc(-c3ccccc3)c2)cc1-c1ccccc1] 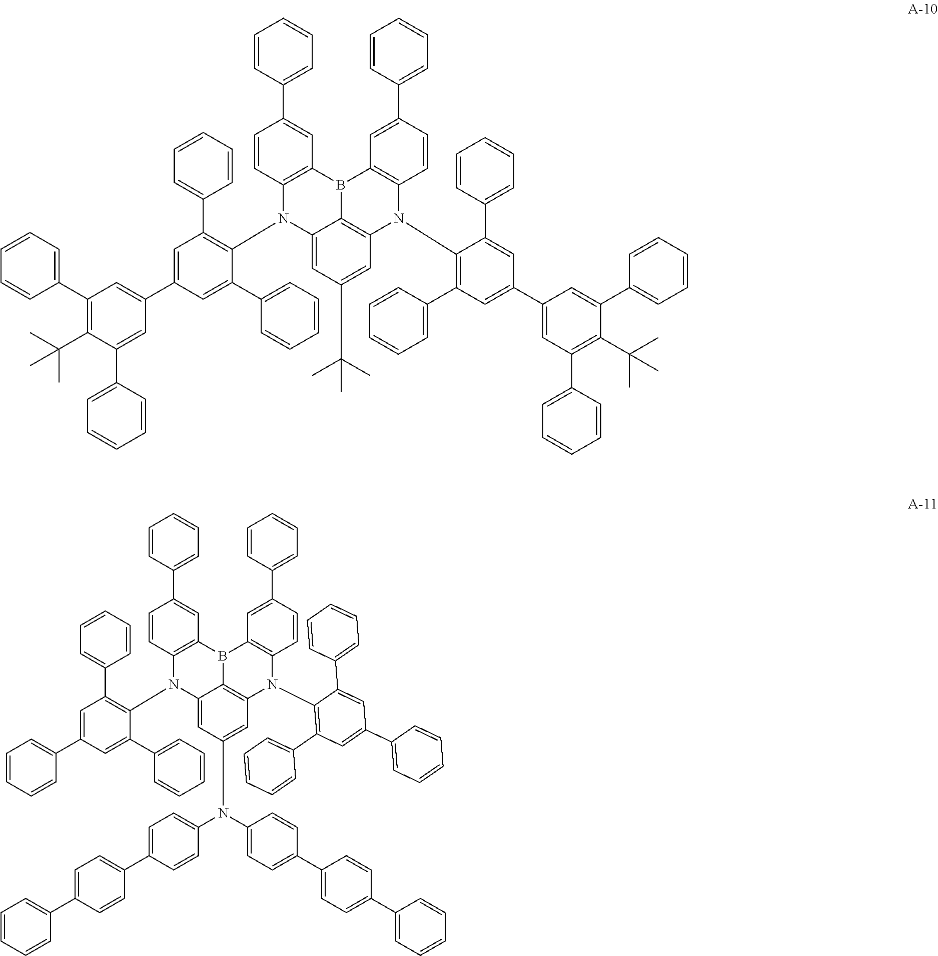 [SMILES: CC(C)(C)c1cc2c3c(c1)N(c1c(-c4ccccc4)cc(-c4cc(-c5ccccc5)c(C(C)(C)C)c(-c5ccccc5)c4)cc1-c1ccccc1)c1ccc(-c4ccccc4)cc1B3c1cc(-c3ccccc3)ccc1N2c1c(-c2ccccc2)cc(-c2cc(-c3ccccc3)c(C(C)(C)C)c(-c3ccccc3)c2)cc1-c1ccccc1 ; c1ccc(-c2ccc(-c3ccc(N(c4ccc(-c5ccc(-c6ccccc6)cc5)cc4)c4cc5c6c(c4)N(c4c(-c7ccccc7)cc(-c7ccccc7)cc4-c4ccccc4)c4ccc(-c7ccccc7)cc4B6c4cc(-c6ccccc6)ccc4N5c4c(-c5ccccc5)cc(-c5ccccc5)cc4-c4ccccc4)cc3)cc2)cc1] 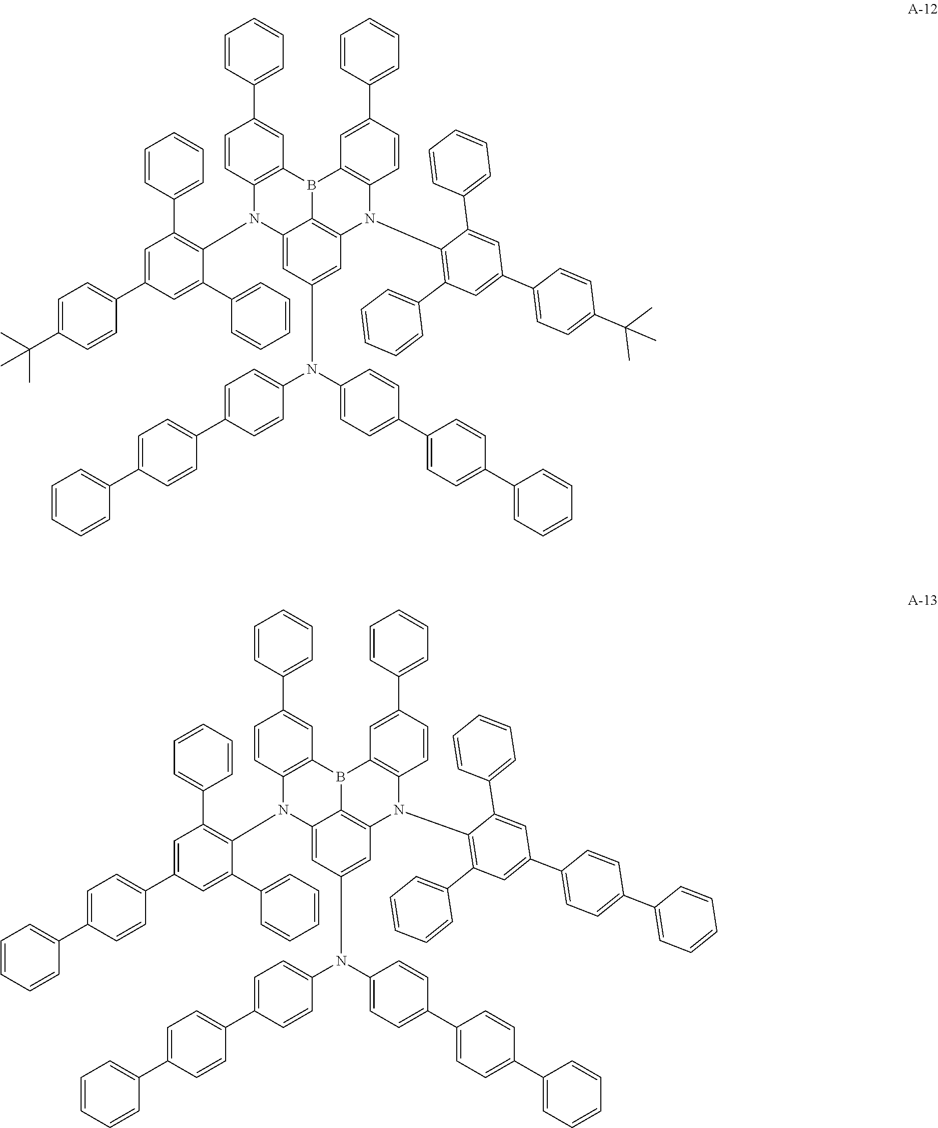 [SMILES: CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccc(-c8ccccc8)cc7)cc6)c6ccc(-c7ccc(-c8ccccc8)cc7)cc6)cc3c54)c(-c3ccccc3)c2)cc1 ; c1ccc(-c2ccc(-c3ccc(N(c4ccc(-c5ccc(-c6ccccc6)cc5)cc4)c4cc5c6c(c4)N(c4c(-c7ccccc7)cc(-c7ccc(-c8ccccc8)cc7)cc4-c4ccccc4)c4ccc(-c7ccccc7)cc4B6c4cc(-c6ccccc6)ccc4N5c4c(-c5ccccc5)cc(-c5ccc(-c6ccccc6)cc5)cc4-c4ccccc4)cc3)cc2)cc1] 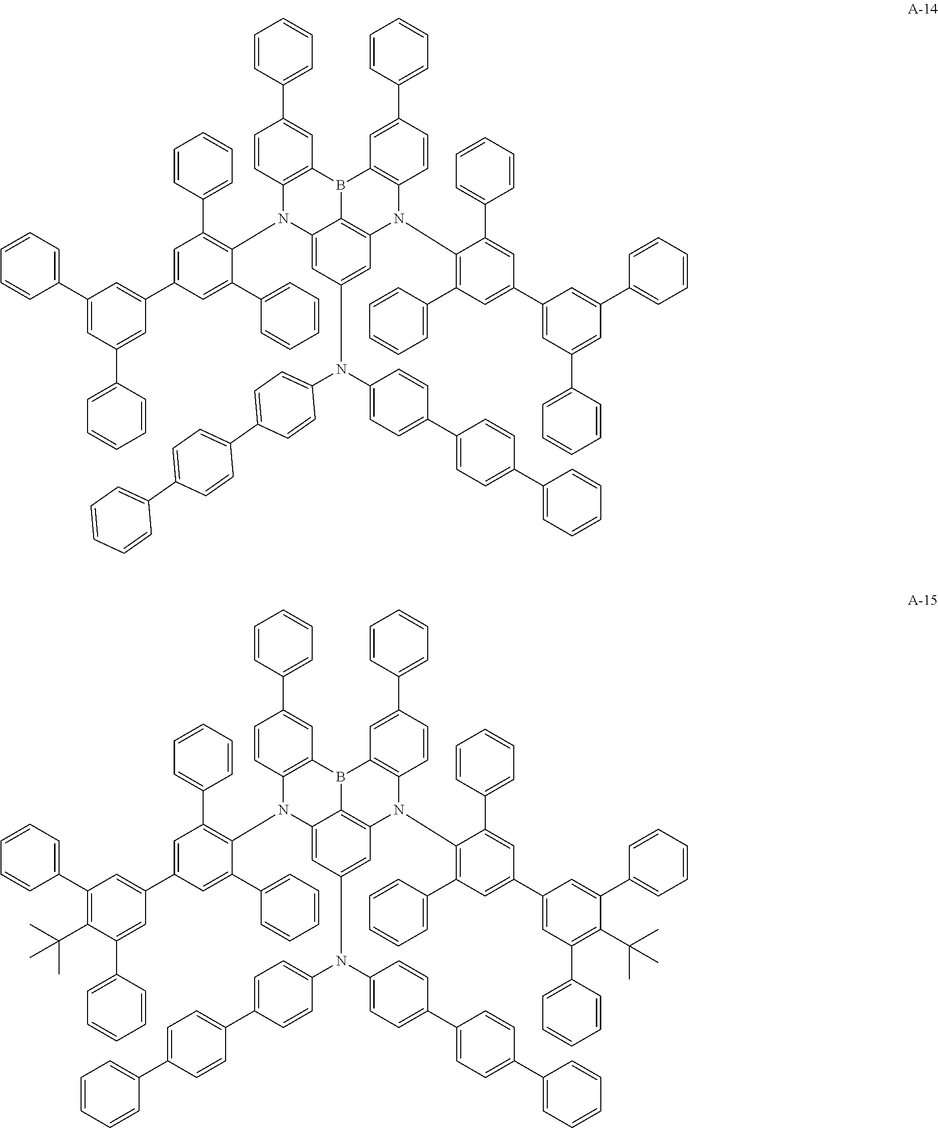 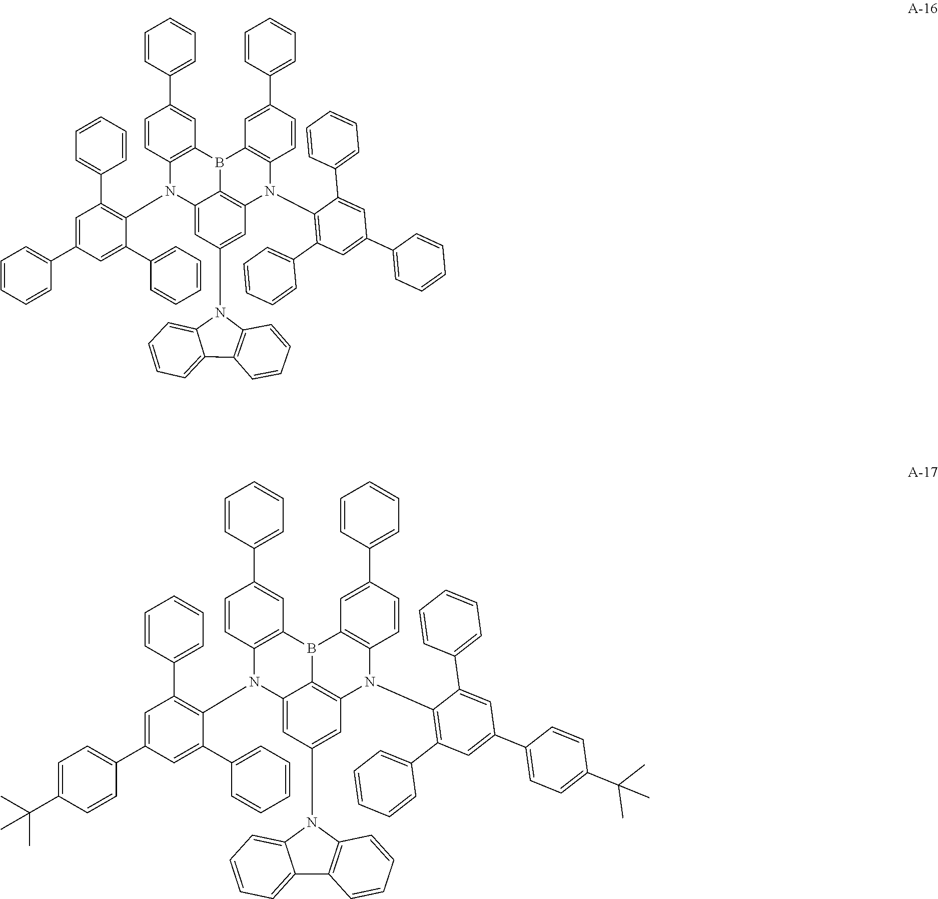 [SMILES: c1ccc(-c2ccc3c(c2)B2c4cc(-c5ccccc5)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(-n6c7ccccc7c7ccccc76)cc3c54)c(-c3ccccc3)c2)cc1] 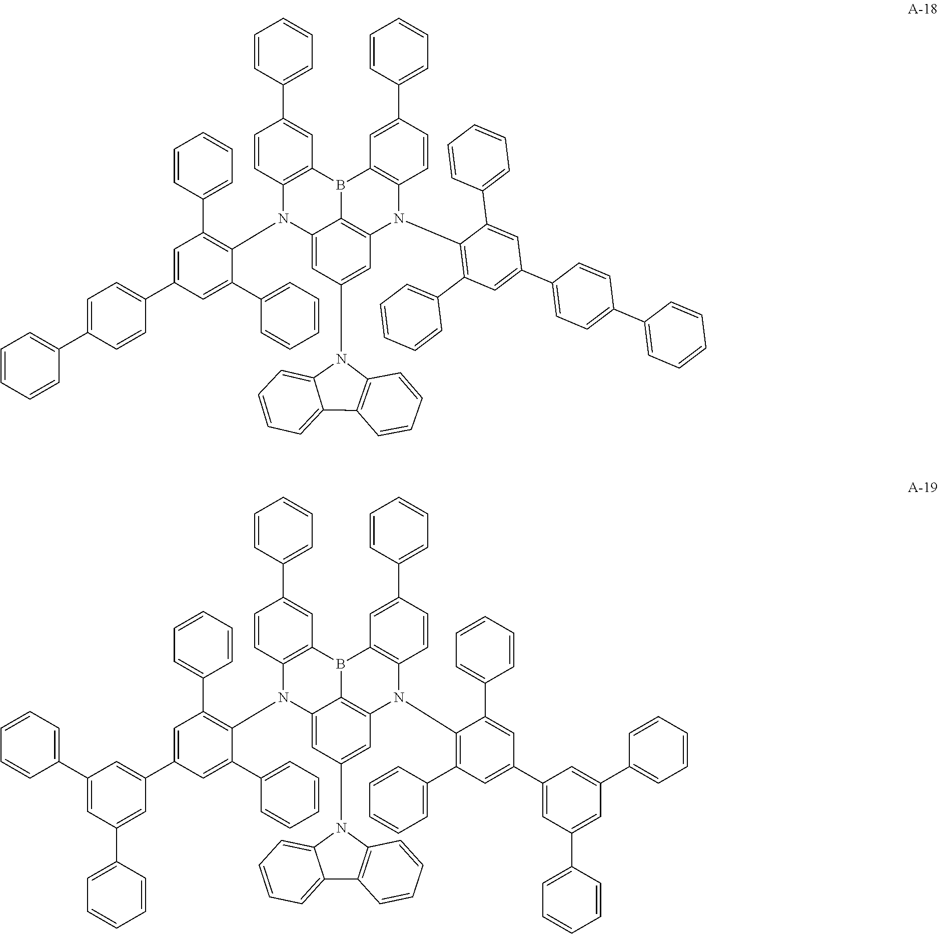 [SMILES: c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(-n7c8ccccc8c8ccccc87)cc4c65)c(-c4ccccc4)c3)cc2)cc1 ; c1ccc(-c2cc(-c3ccccc3)cc(-c3cc(-c4ccccc4)c(N4c5ccc(-c6ccccc6)cc5B5c6cc(-c7ccccc7)ccc6N(c6c(-c7ccccc7)cc(-c7cc(-c8ccccc8)cc(-c8ccccc8)c7)cc6-c6ccccc6)c6cc(-n7c8ccccc8c8ccccc87)cc4c65)c(-c4ccccc4)c3)c2)cc1] 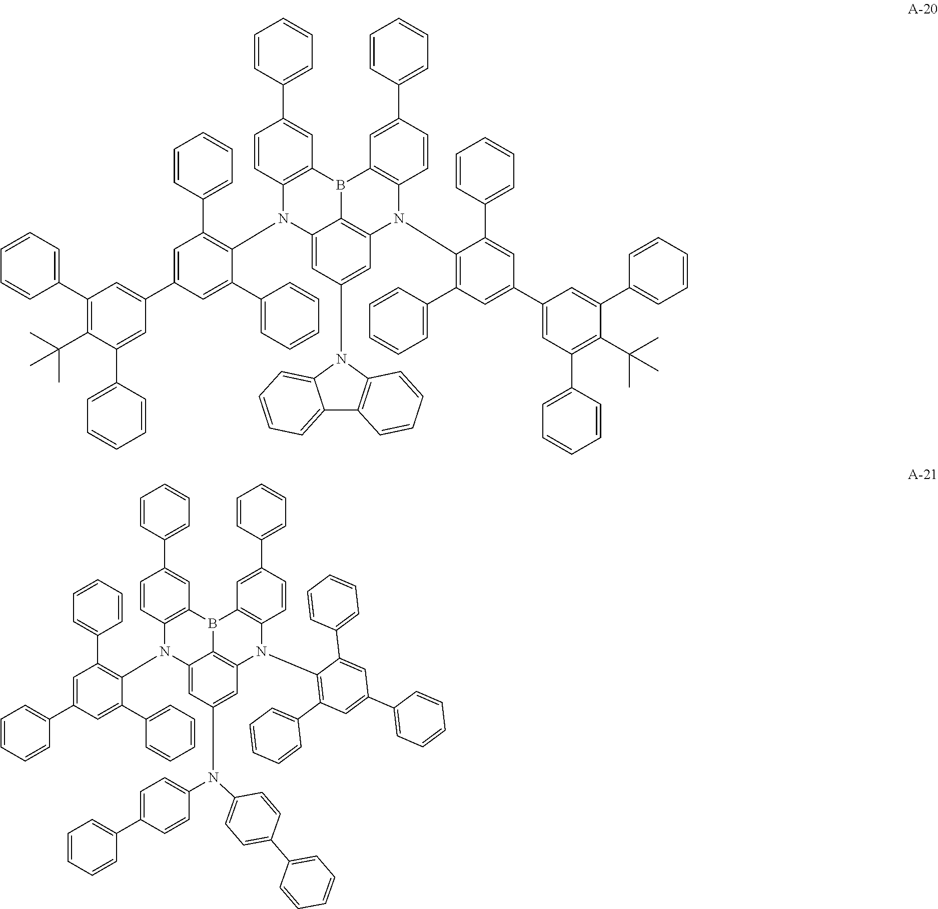 [SMILES: CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(-n6c7ccccc7c7ccccc76)cc3c54)c(-c3ccccc3)c2)cc1-c1ccccc1 ; c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccccc6)cc3B5c3cc(-c5ccccc5)ccc3N4c3c(-c4ccccc4)cc(-c4ccccc4)cc3-c3ccccc3)cc2)cc1] 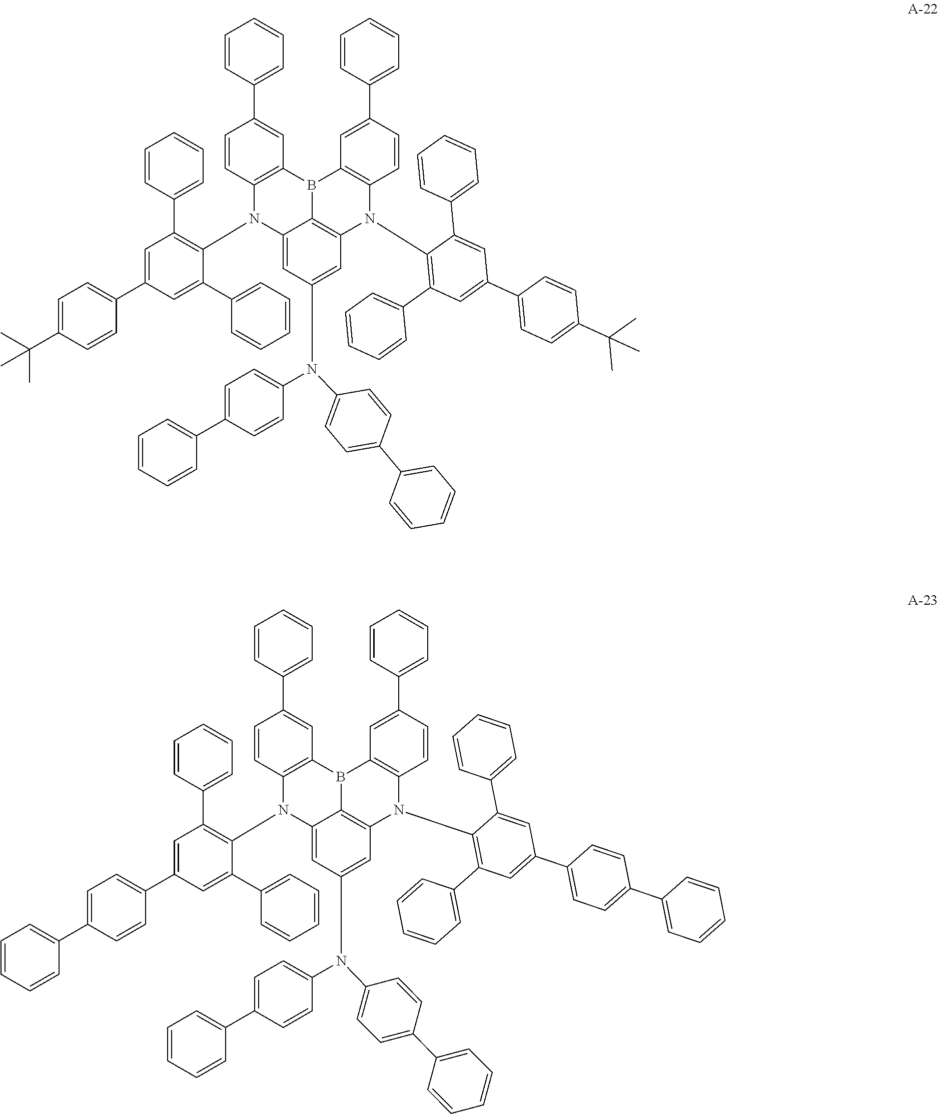 [SMILES: CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccccc7)cc6)c6ccc(-c7ccccc7)cc6)cc3c54)c(-c3ccccc3)c2)cc1 ; c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(N(c7ccc(-c8ccccc8)cc7)c7ccc(-c8ccccc8)cc7)cc4c65)c(-c4ccccc4)c3)cc2)cc1] 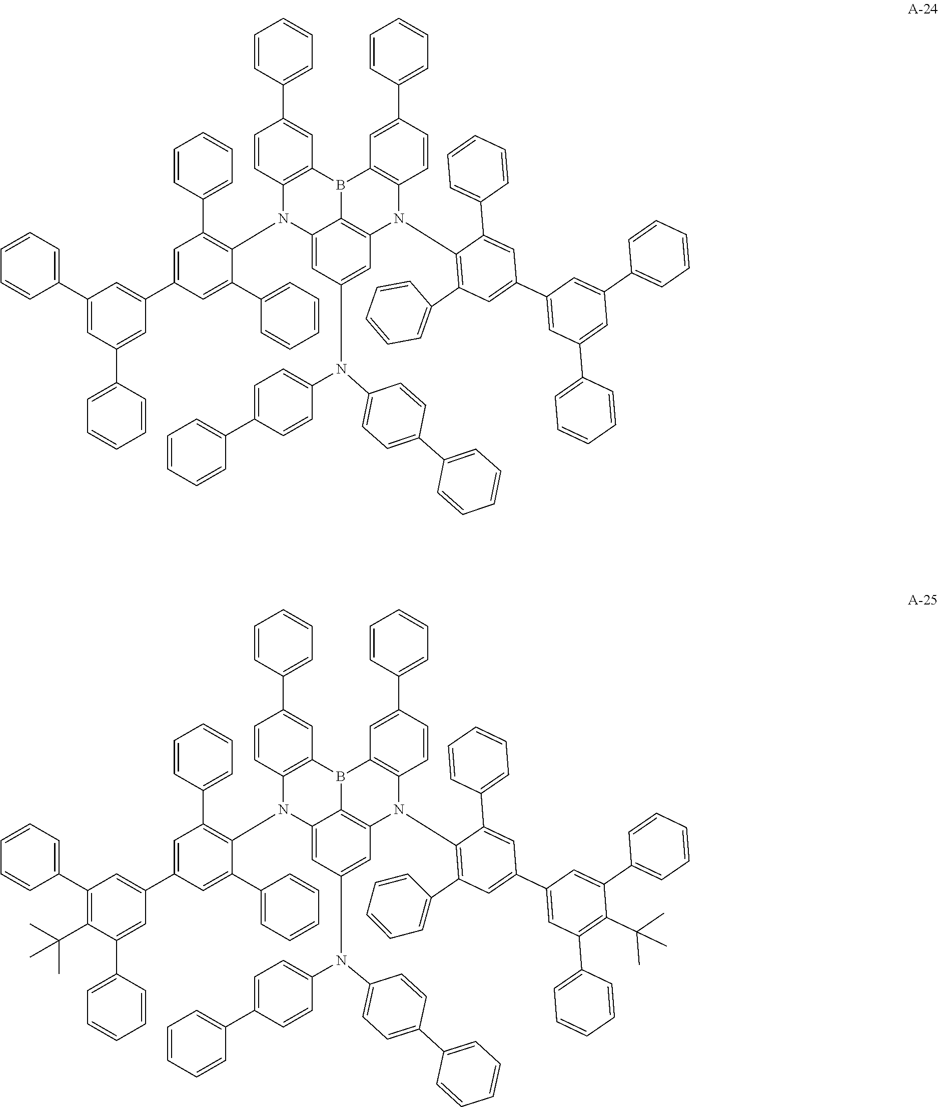 [SMILES: c1ccc(-c2ccc(N(c3ccc(-c4ccccc4)cc3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3c(-c4ccccc4)cc(-c4cc(-c5ccccc5)cc(-c5ccccc5)c4)cc3-c3ccccc3)cc2)cc1 ; CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(N(c6ccc(-c7ccccc7)cc6)c6ccc(-c7ccccc7)cc6)cc3c54)c(-c3ccccc3)c2)cc1-c1ccccc1] 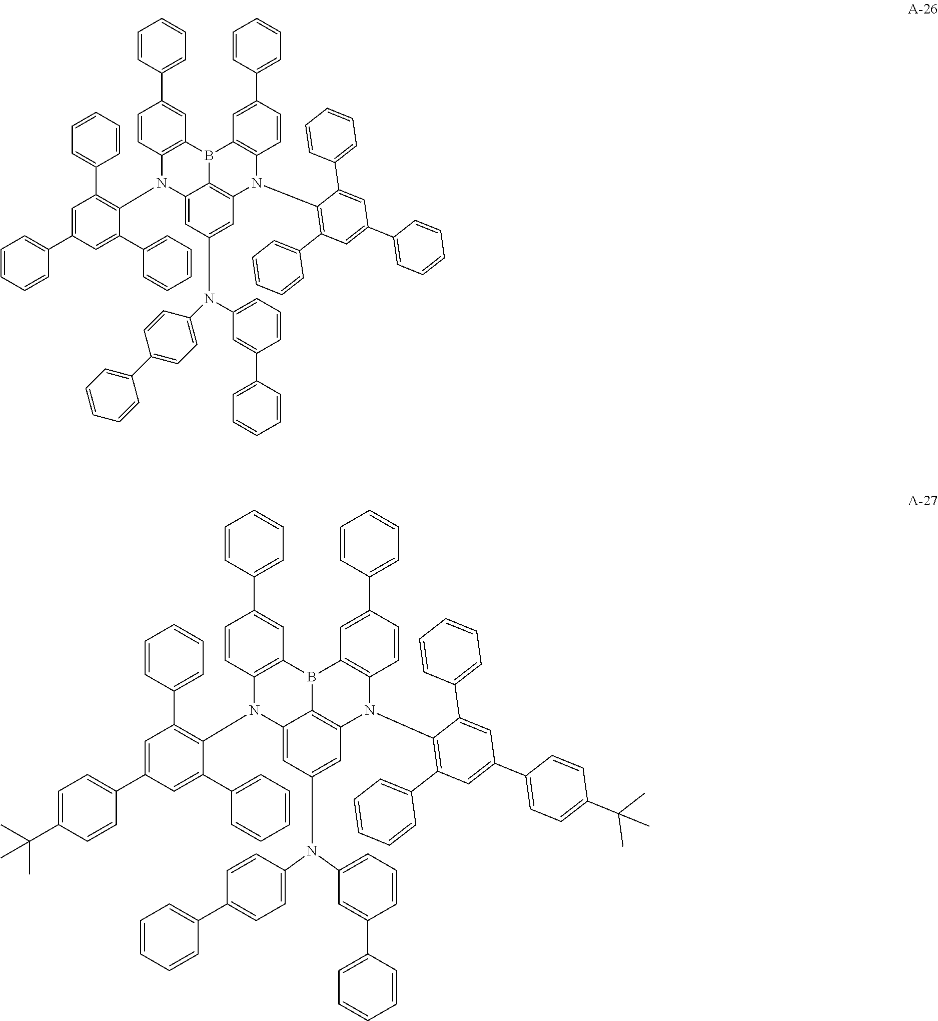 [SMILES: c1ccc(-c2ccc(N(c3cccc(-c4ccccc4)c3)c3cc4c5c(c3)N(c3c(-c6ccccc6)cc(-c6ccccc6)cc3-c3ccccc3)c3ccc(-c6ccccc6)cc3B5c3cc(-c5ccccc5)ccc3N4c3c(-c4ccccc4)cc(-c4ccccc4)cc3-c3ccccc3)cc2)cc1 ; CC(C)(C)c1ccc(-c2cc(-c3ccccc3)c(N3c4ccc(-c5ccccc5)cc4B4c5cc(-c6ccccc6)ccc5N(c5c(-c6ccccc6)cc(-c6ccc(C(C)(C)C)cc6)cc5-c5ccccc5)c5cc(N(c6ccc(-c7ccccc7)cc6)c6cccc(-c7ccccc7)c6)cc3c54)c(-c3ccccc3)c2)cc1] 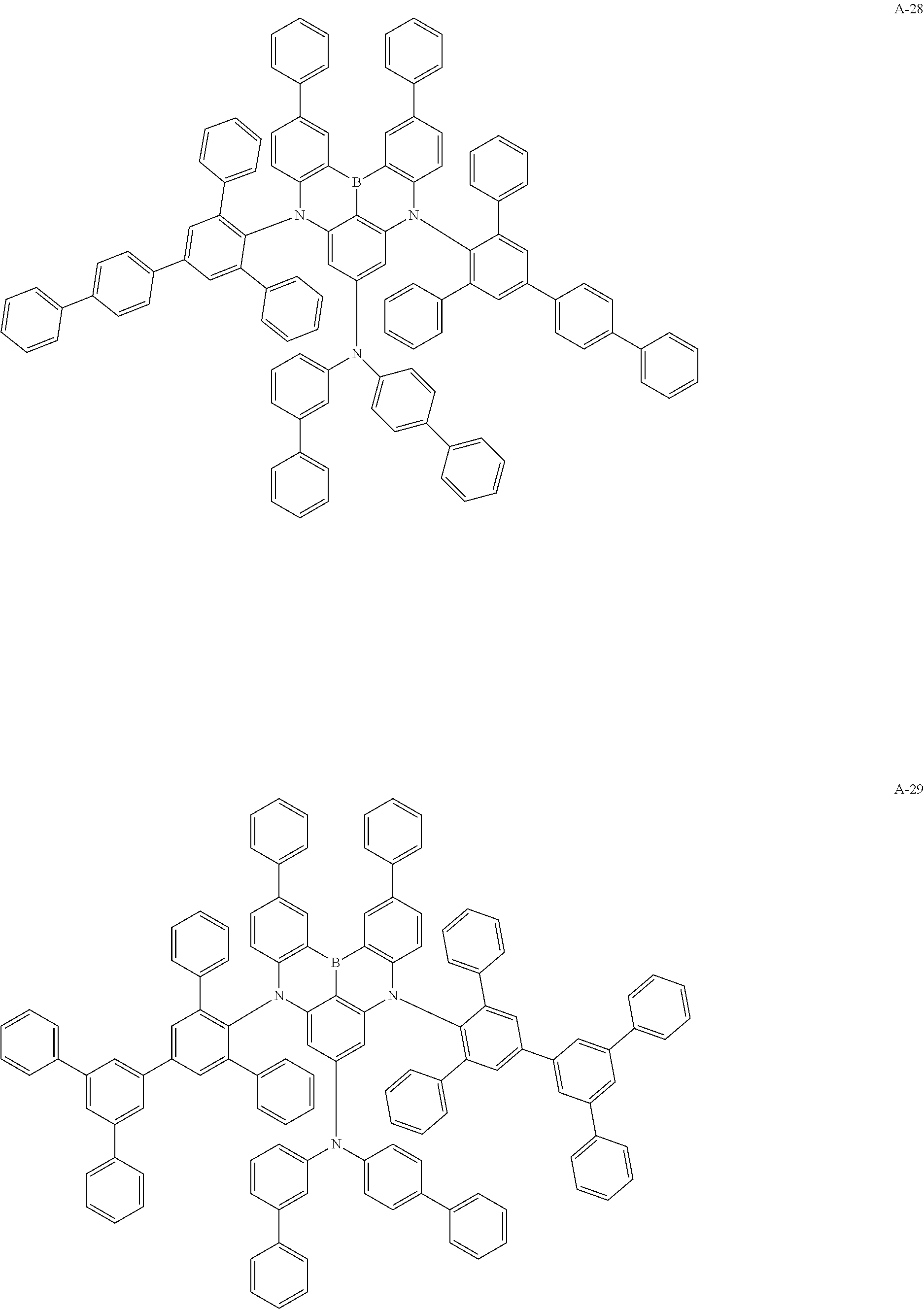 [SMILES: c1ccc(-c2ccc(-c3cc(-c4ccccc4)c(N4c5ccc(-c6ccccc6)cc5B5c6cc(-c7ccccc7)ccc6N(c6c(-c7ccccc7)cc(-c7ccc(-c8ccccc8)cc7)cc6-c6ccccc6)c6cc(N(c7ccc(-c8ccccc8)cc7)c7cccc(-c8ccccc8)c7)cc4c65)c(-c4ccccc4)c3)cc2)cc1 ; c1ccc(-c2ccc(N(c3cccc(-c4ccccc4)c3)c3cc4c5c(c3)N(c3c(-c6ccccc6)cc(-c6cc(-c7ccccc7)cc(-c7ccccc7)c6)cc3-c3ccccc3)c3ccc(-c6ccccc6)cc3B5c3cc(-c5ccccc5)ccc3N4c3c(-c4ccccc4)cc(-c4cc(-c5ccccc5)cc(-c5ccccc5)c4)cc3-c3ccccc3)cc2)cc1] 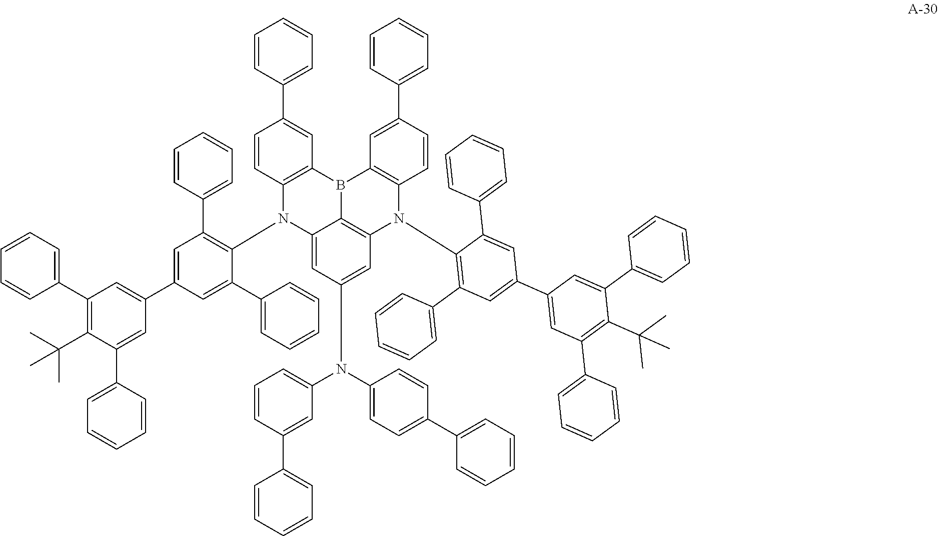 [SMILES: CC(C)(C)c1c(-c2ccccc2)cc(-c2cc(-c3ccccc3)c(N3c4ccc(-c5ccccc5)cc4B4c5cc(-c6ccccc6)ccc5N(c5c(-c6ccccc6)cc(-c6cc(-c7ccccc7)c(C(C)(C)C)c(-c7ccccc7)c6)cc5-c5ccccc5)c5cc(N(c6ccc(-c7ccccc7)cc6)c6cccc(-c7ccccc7)c6)cc3c54)c(-c3ccccc3)c2)cc1-c1ccccc1] 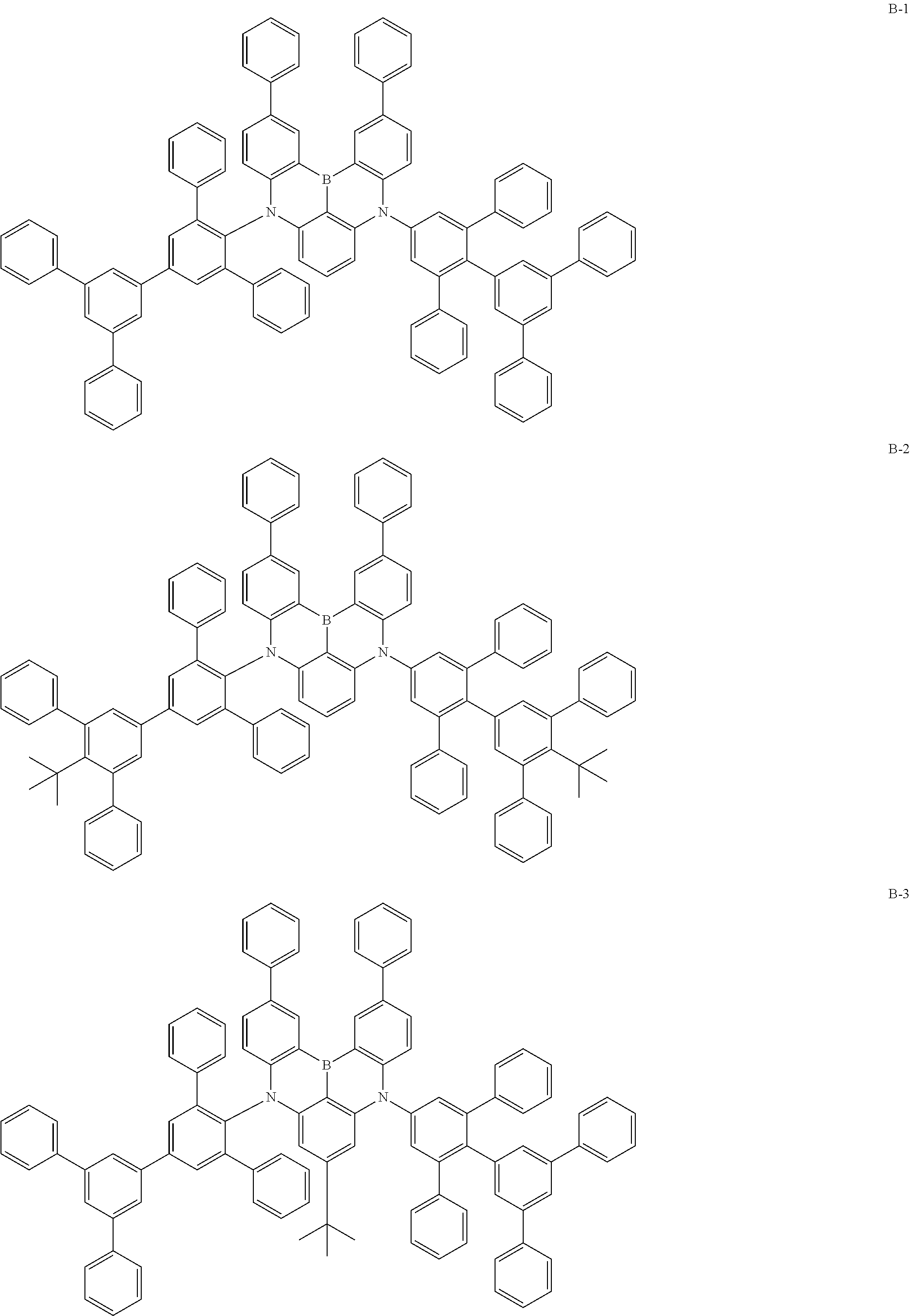 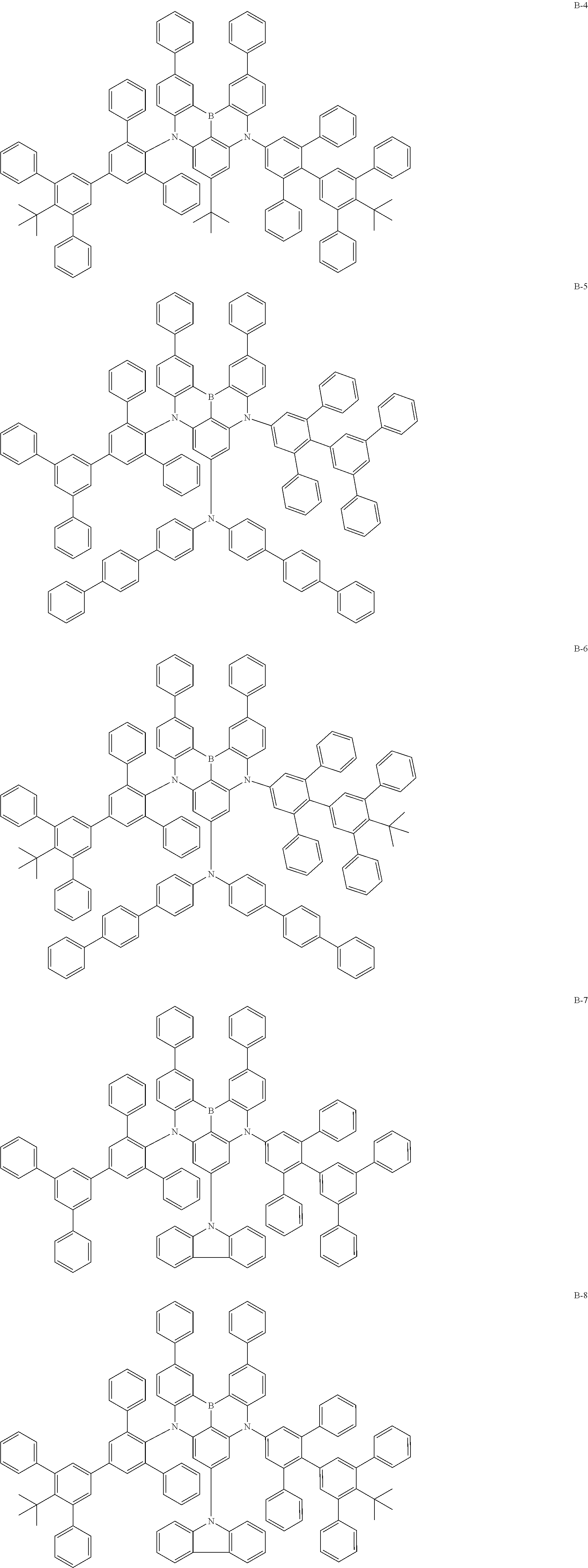 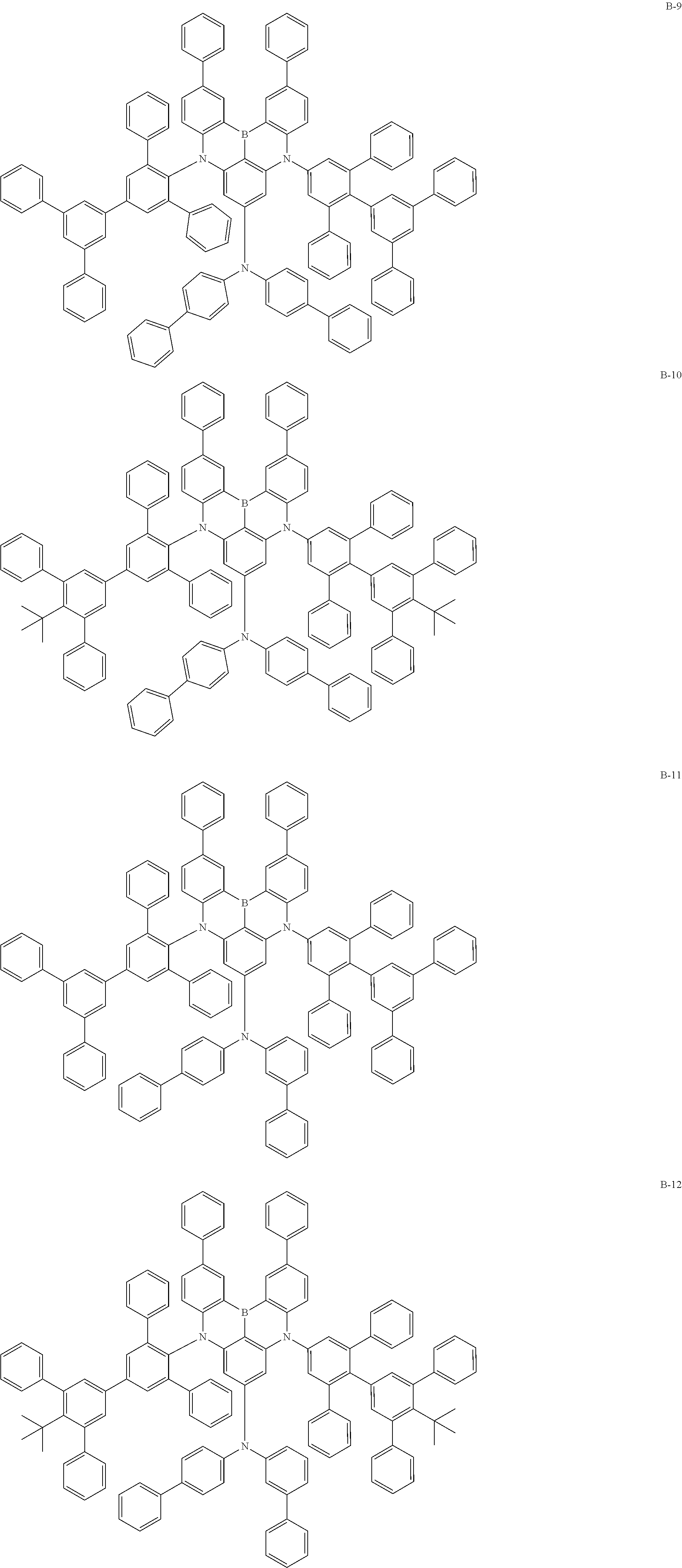 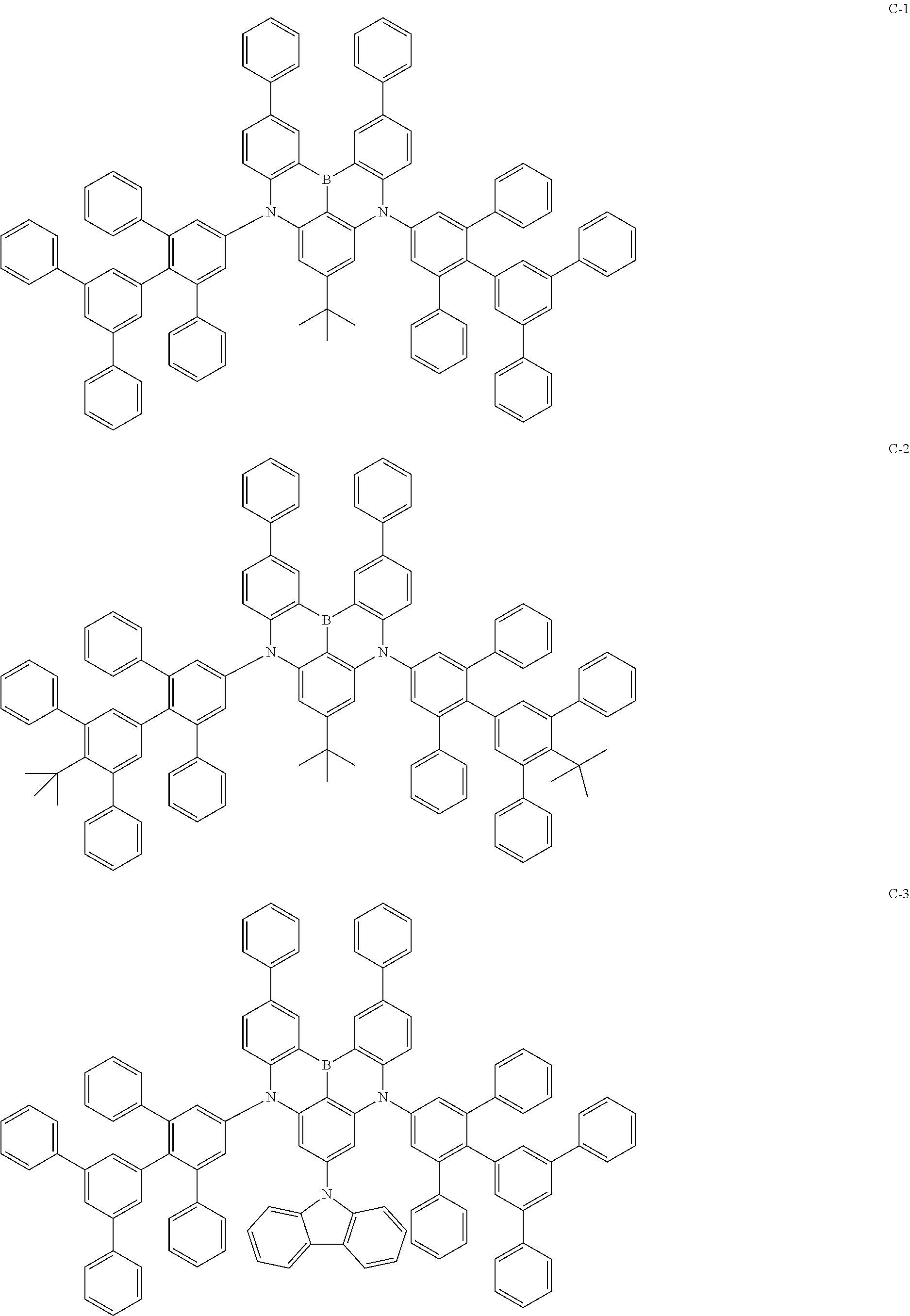 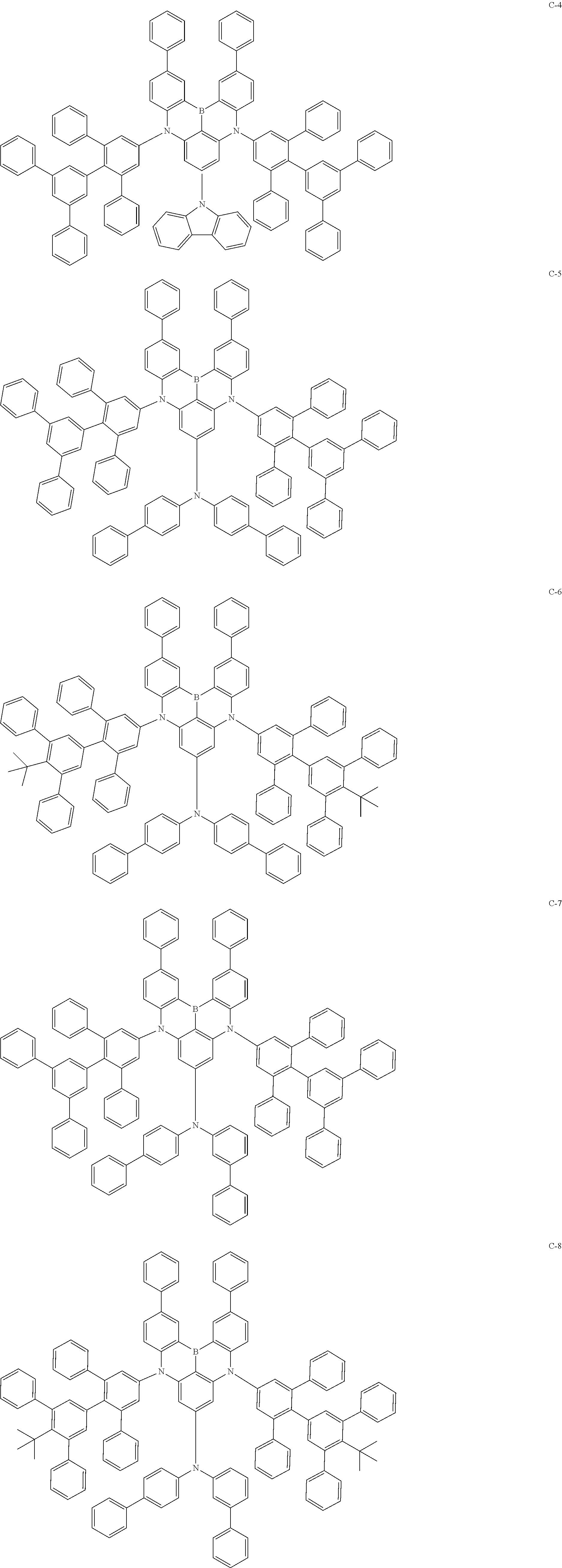 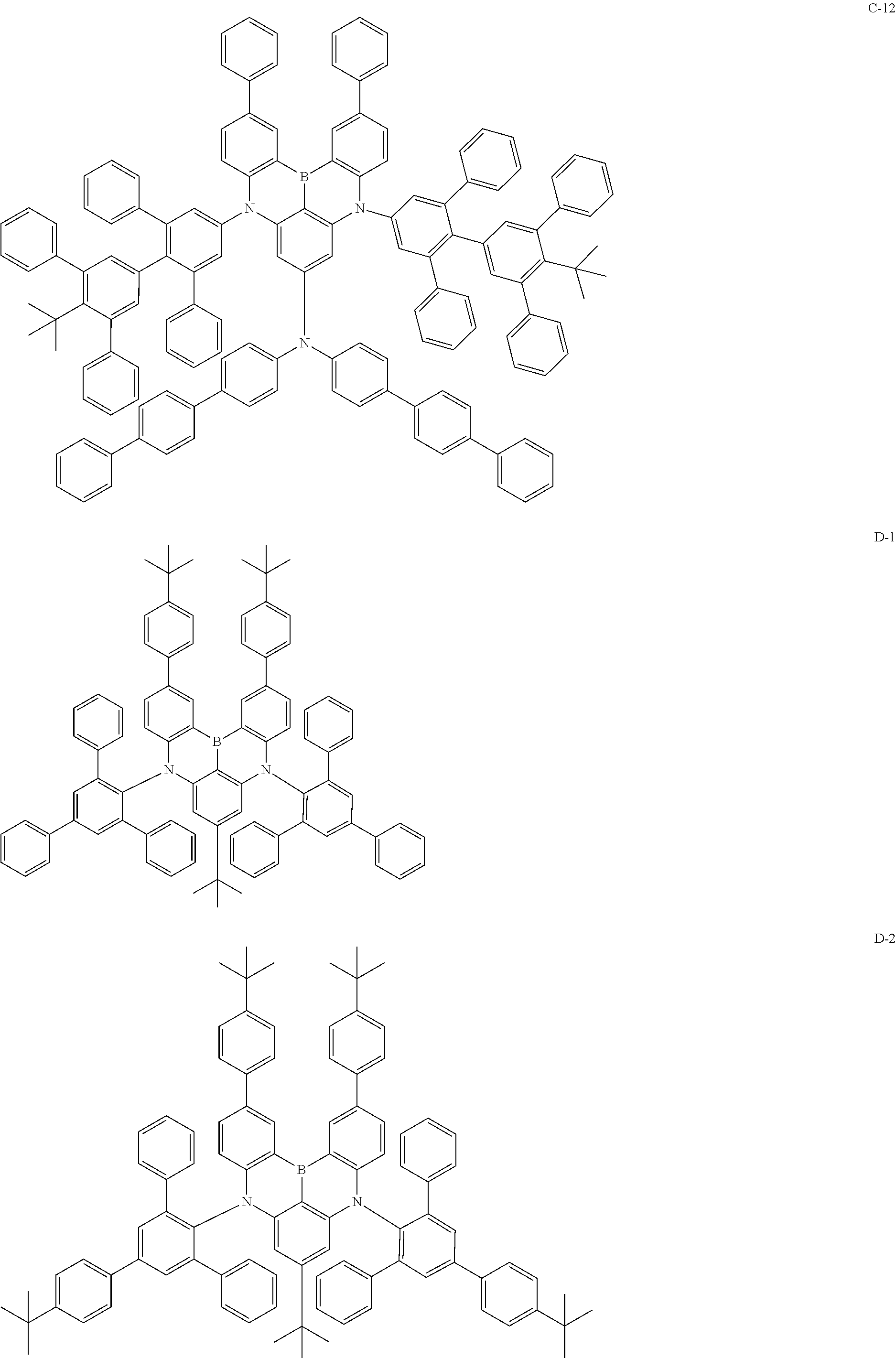 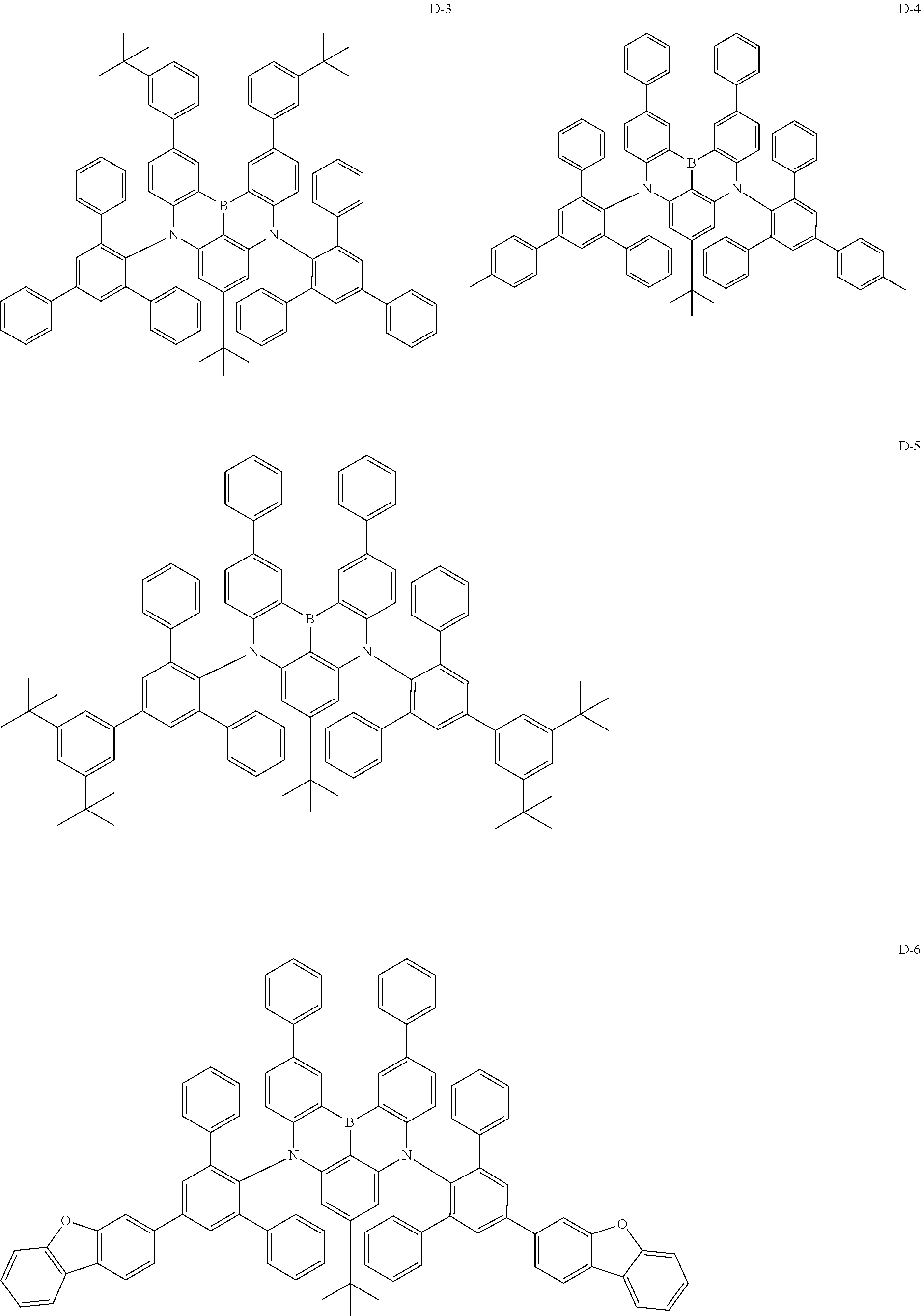 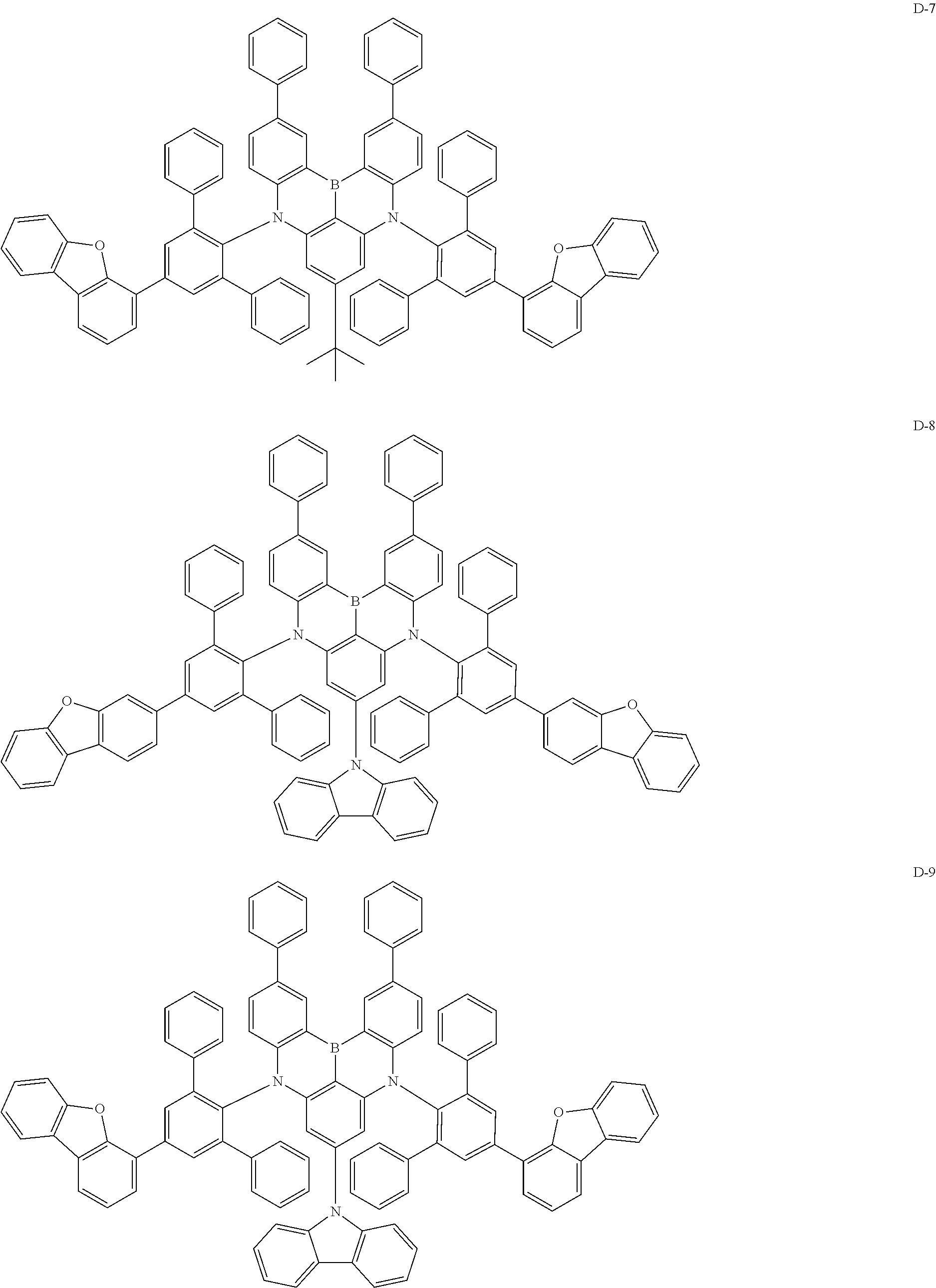 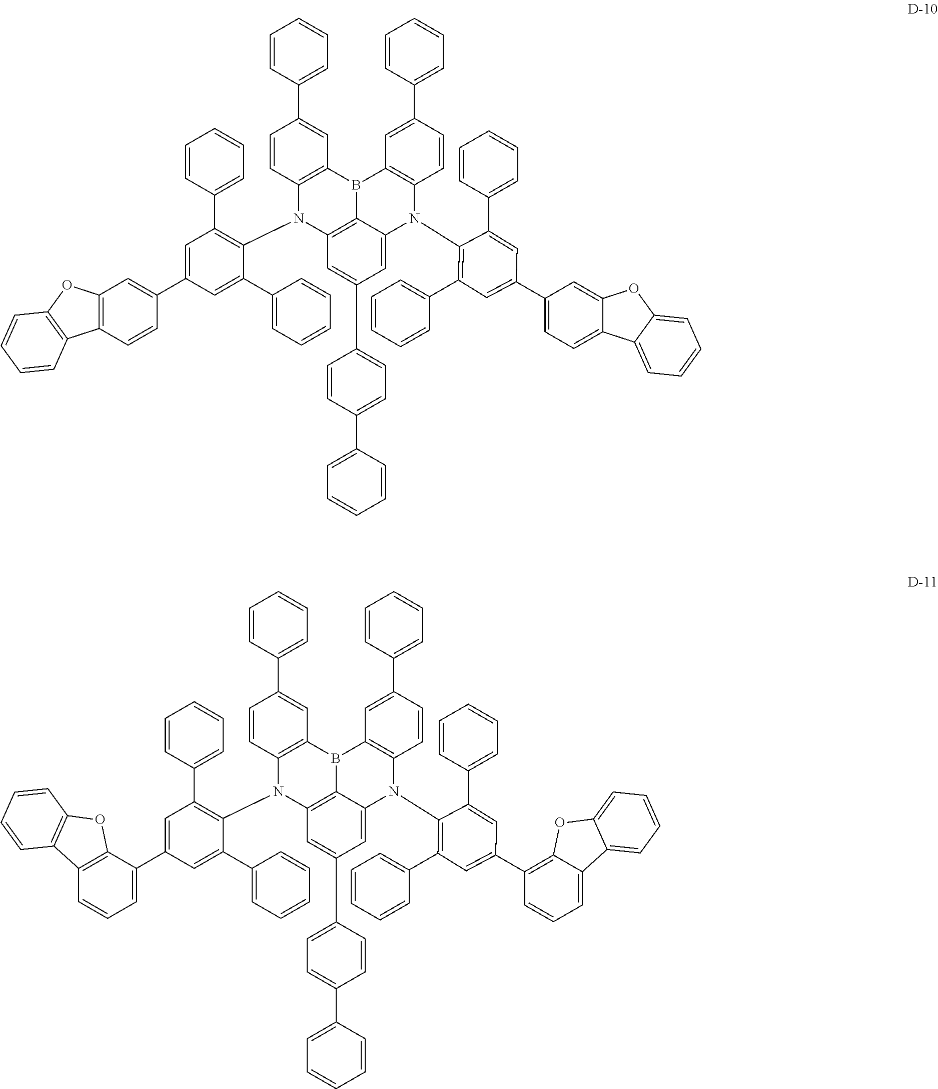 [SMILES: c1ccc(-c2ccc(-c3cc4c5c(c3)N(c3c(-c6ccccc6)cc(-c6ccc7c(c6)oc6ccccc67)cc3-c3ccccc3)c3ccc(-c6ccccc6)cc3B5c3cc(-c5ccccc5)ccc3N4c3c(-c4ccccc4)cc(-c4ccc5c(c4)oc4ccccc45)cc3-c3ccccc3)cc2)cc1 ; c1ccc(-c2ccc(-c3cc4c5c(c3)N(c3c(-c6ccccc6)cc(-c6cccc7c6oc6ccccc67)cc3-c3ccccc3)c3ccc(-c6ccccc6)cc3B5c3cc(-c5ccccc5)ccc3N4c3c(-c4ccccc4)cc(-c4cccc5c4oc4ccccc45)cc3-c3ccccc3)cc2)cc1] 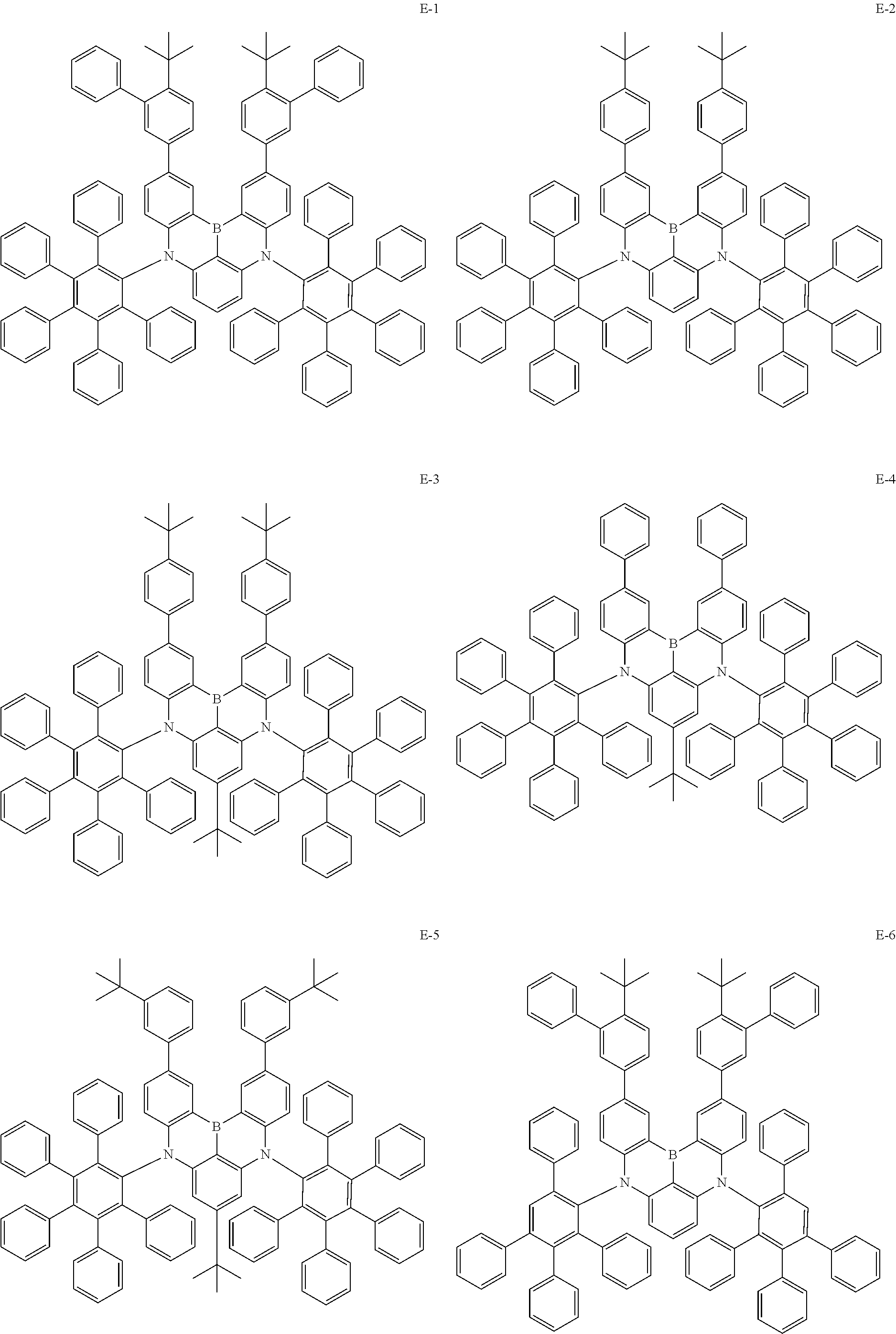 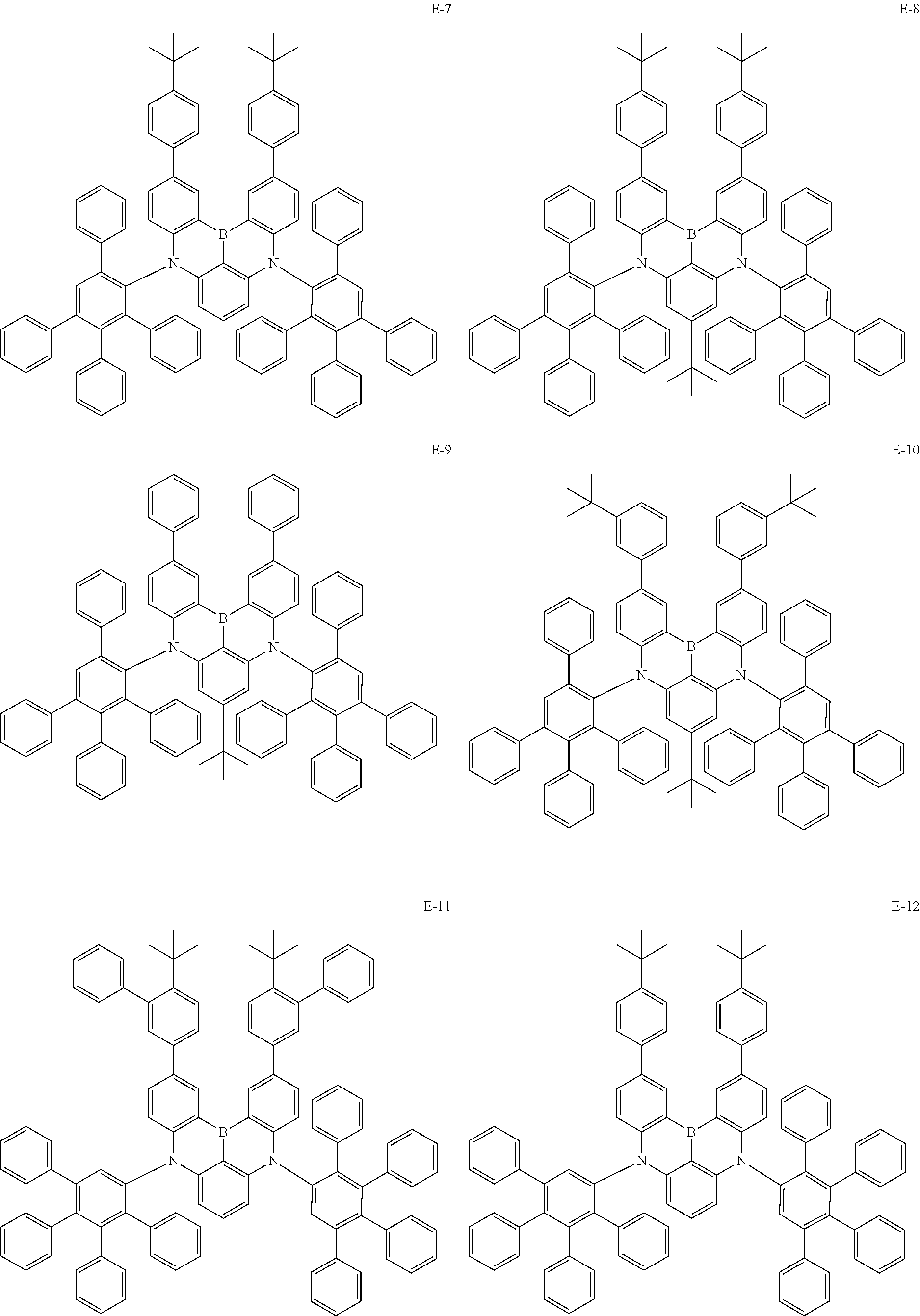 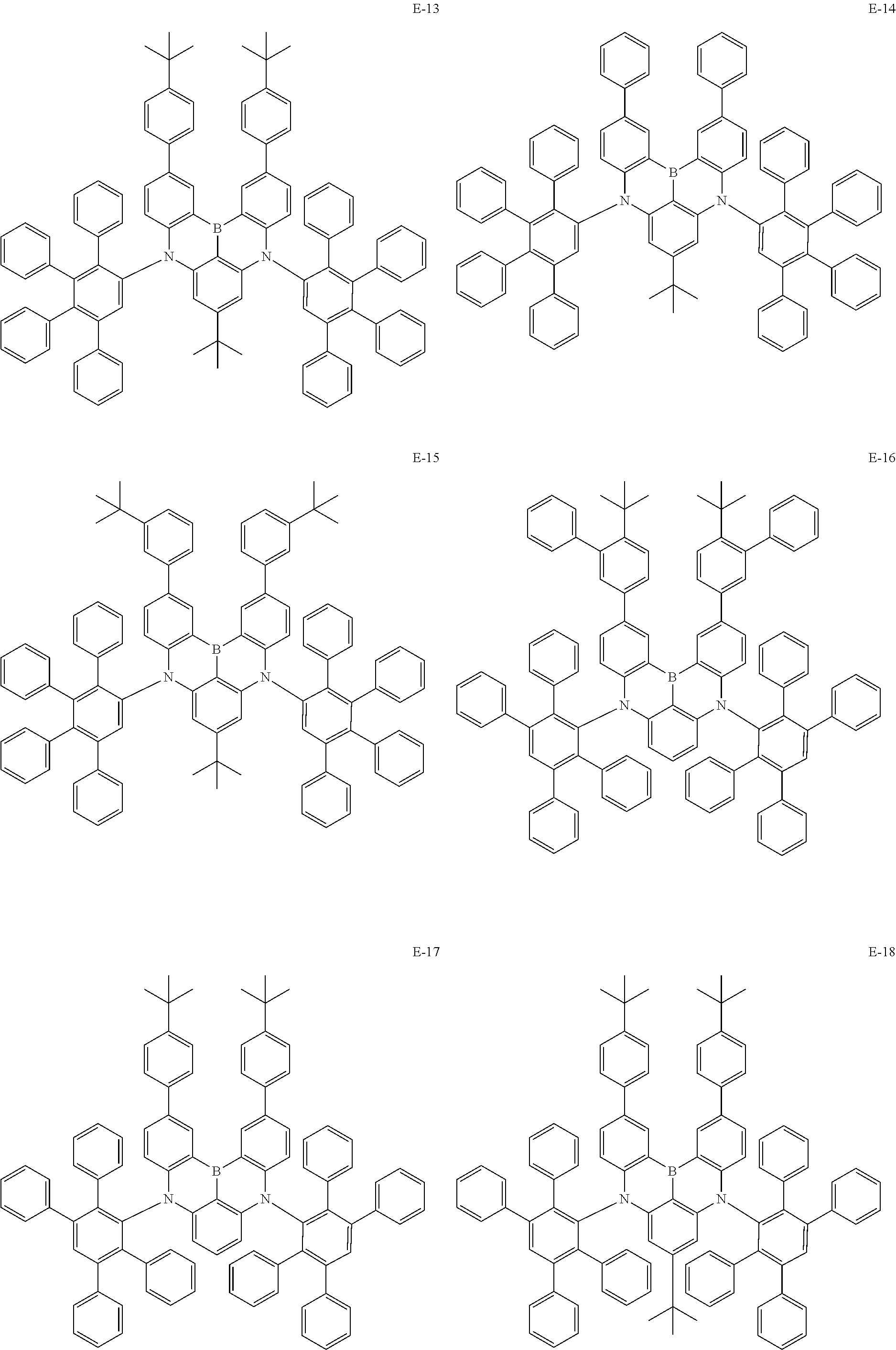 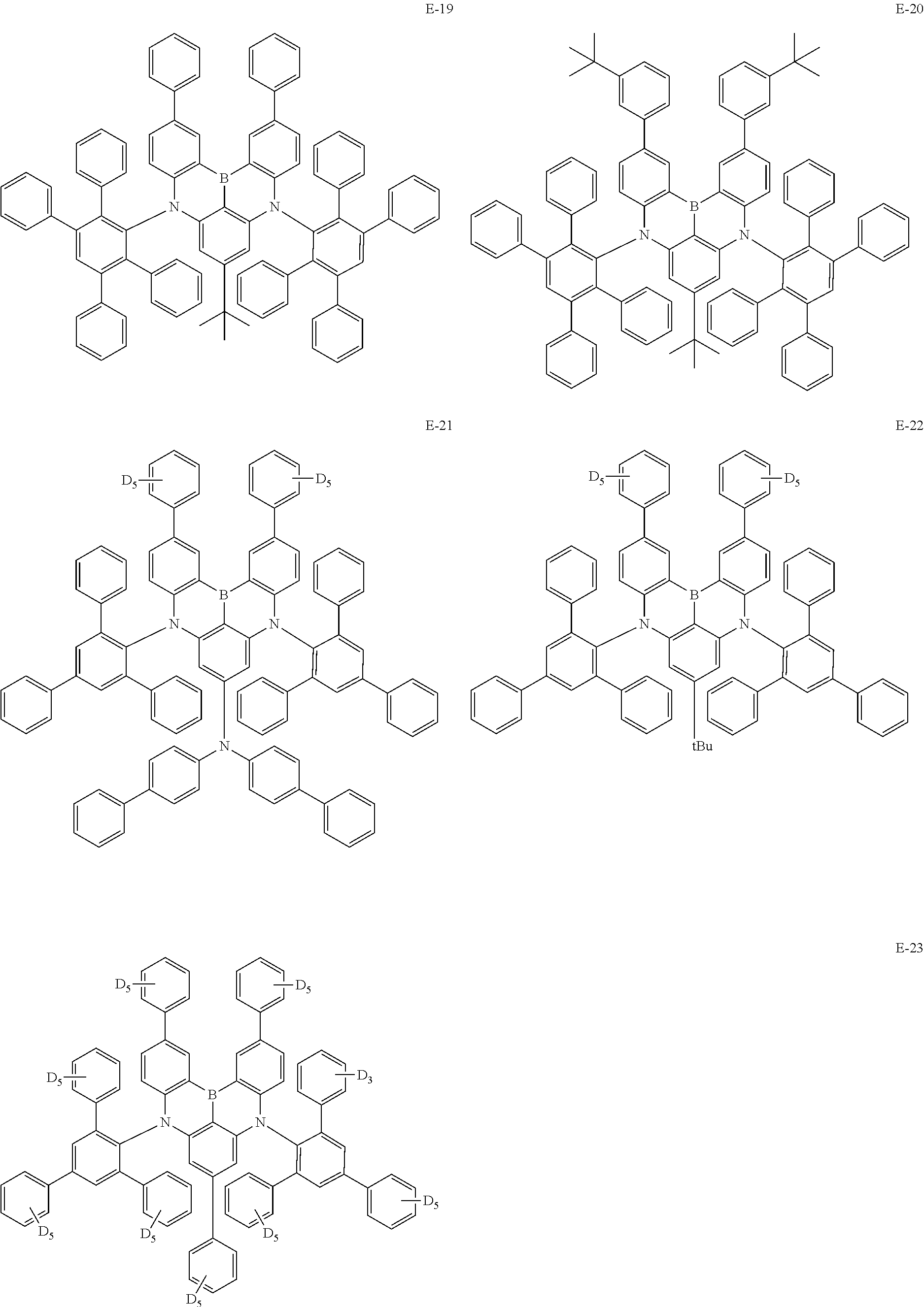 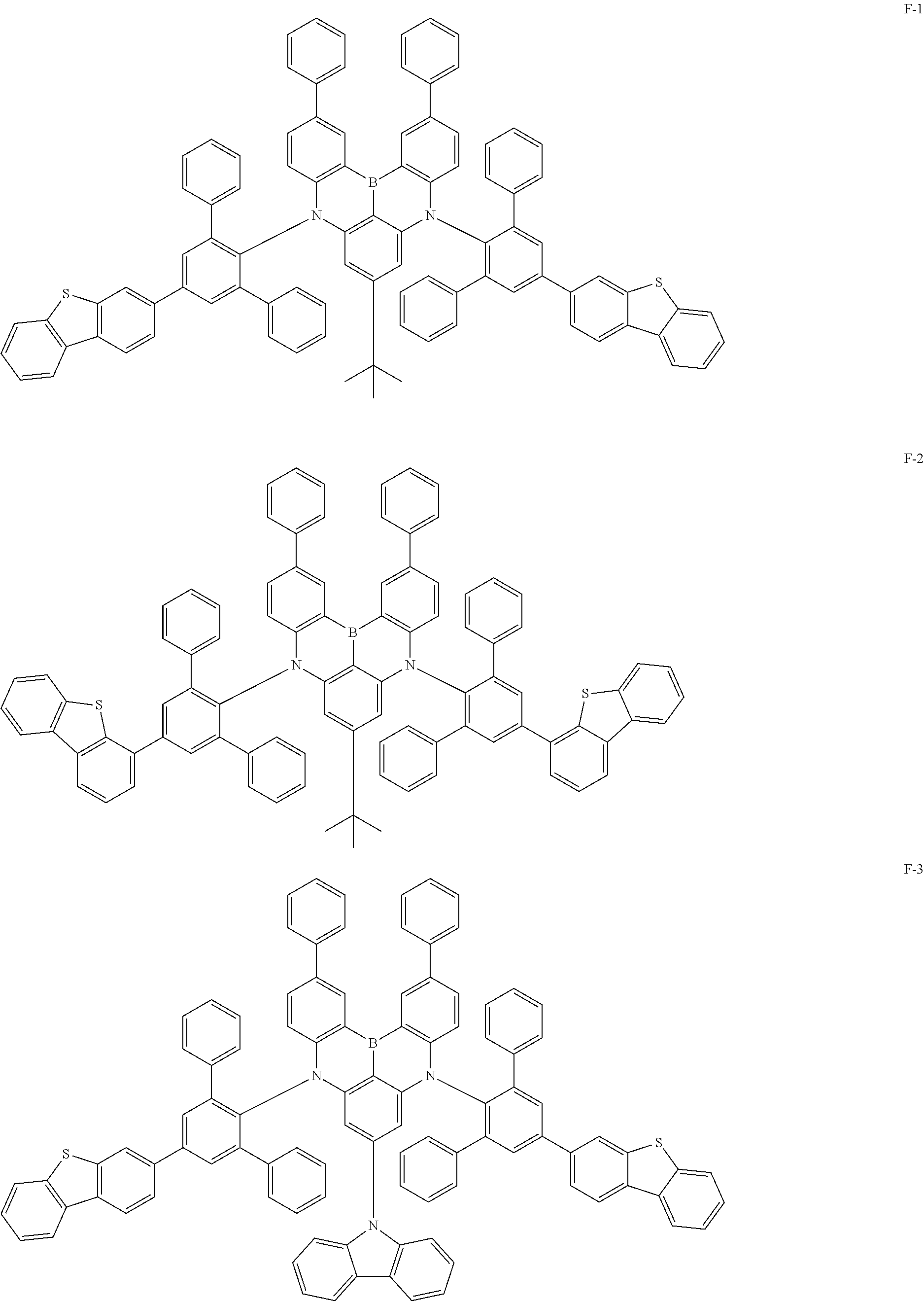 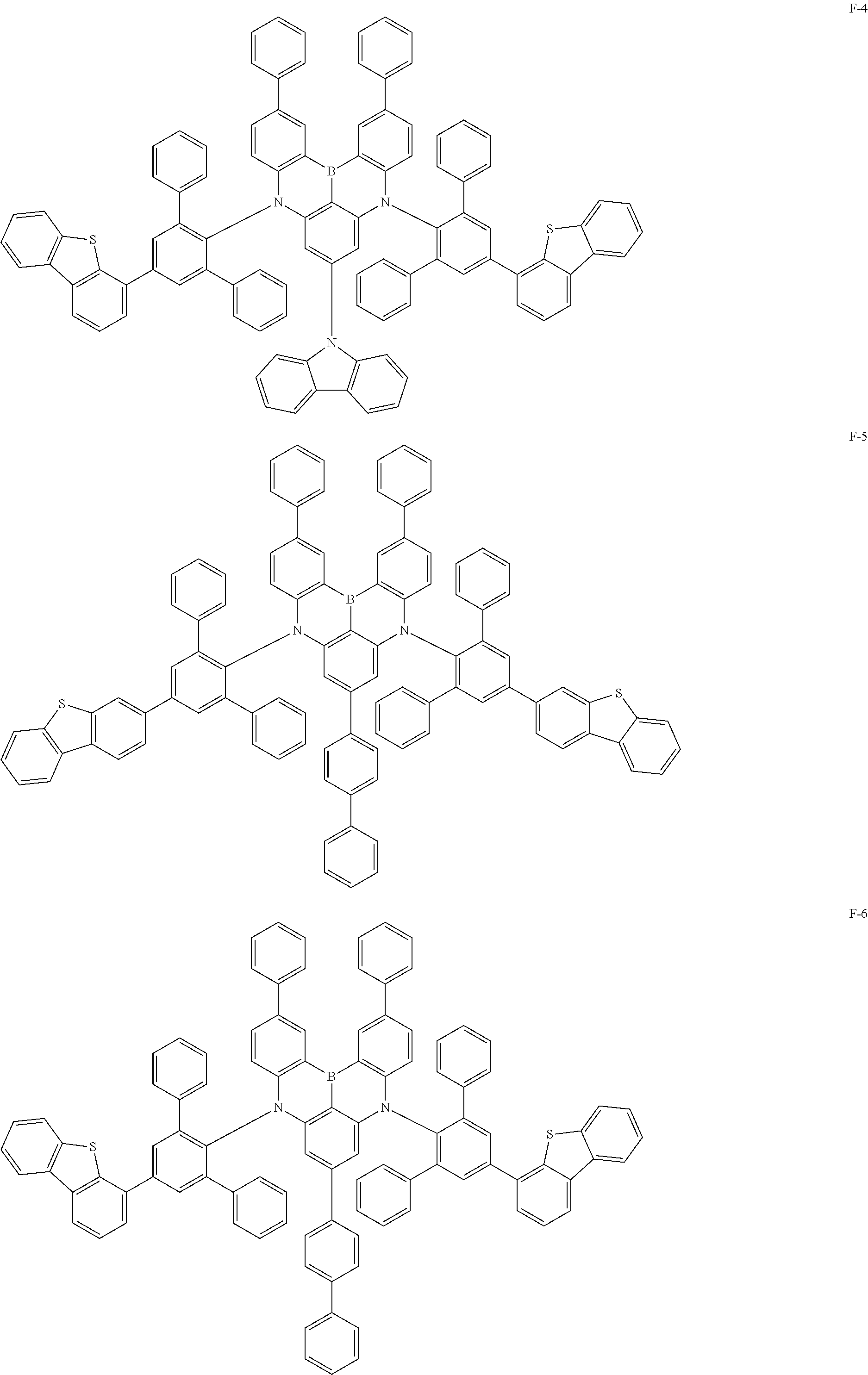 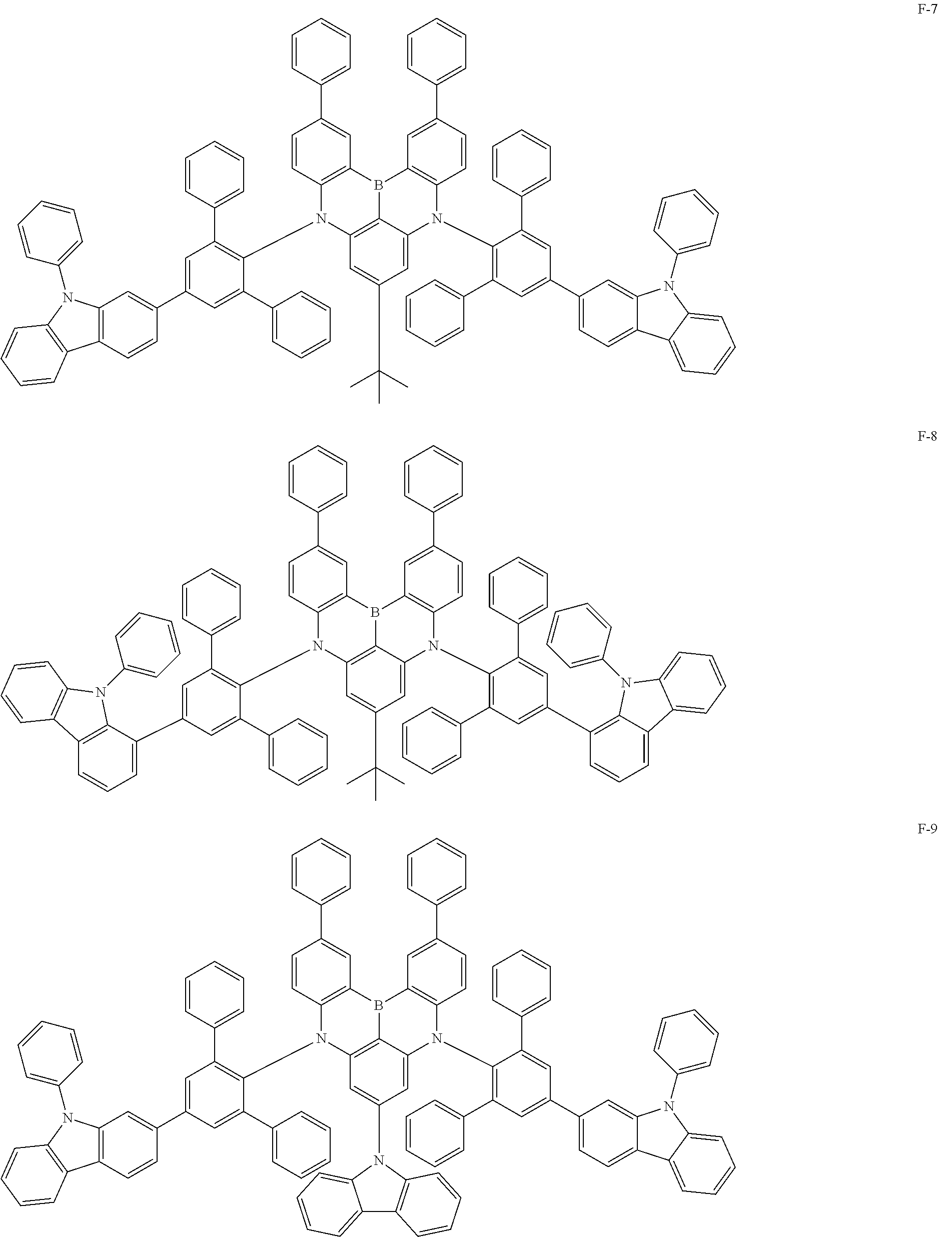 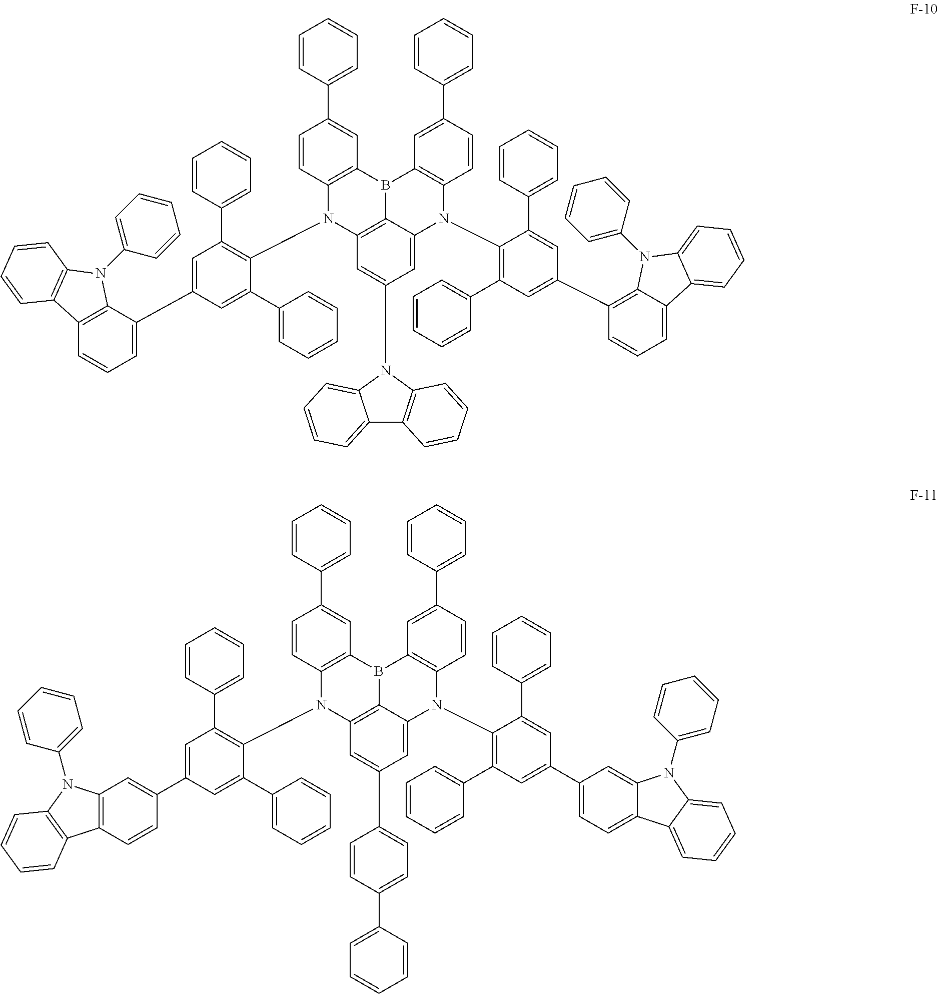 [SMILES: c1ccc(-c2ccc3c(c2)B2c4cc(-c5ccccc5)ccc4N(c4c(-c5ccccc5)cc(-c5cccc6c7ccccc7n(-c7ccccc7)c56)cc4-c4ccccc4)c4cc(-n5c6ccccc6c6ccccc65)cc(c42)N3c2c(-c3ccccc3)cc(-c3cccc4c5ccccc5n(-c5ccccc5)c34)cc2-c2ccccc2)cc1 ; c1ccc(-c2ccc(-c3cc4c5c(c3)N(c3c(-c6ccccc6)cc(-c6ccc7c8ccccc8n(-c8ccccc8)c7c6)cc3-c3ccccc3)c3ccc(-c6ccccc6)cc3B5c3cc(-c5ccccc5)ccc3N4c3c(-c4ccccc4)cc(-c4ccc5c6ccccc6n(-c6ccccc6)c5c4)cc3-c3ccccc3)cc2)cc1] 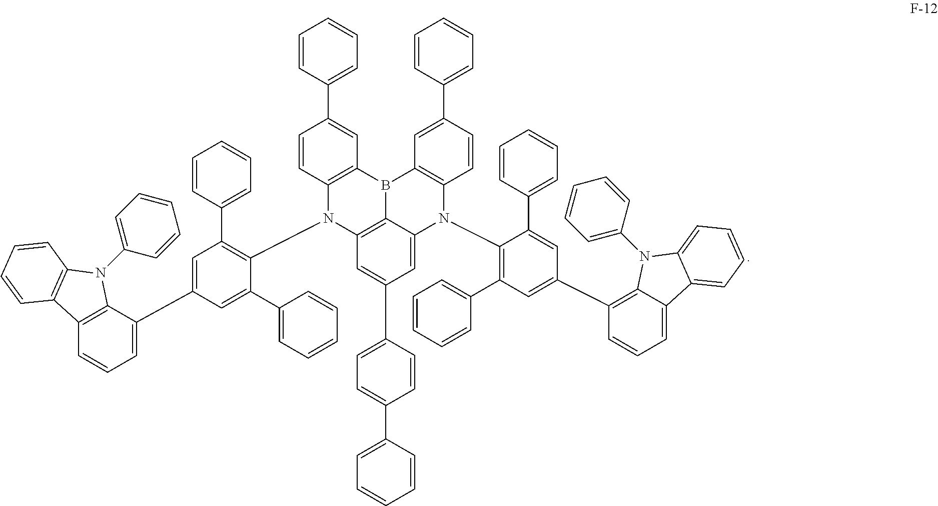 [SMILES: c1ccc(-c2ccc(-c3cc4c5c(c3)N(c3c(-c6ccccc6)cc(-c6cccc7c8ccccc8n(-c8ccccc8)c67)cc3-c3ccccc3)c3ccc(-c6ccccc6)cc3B5c3cc(-c5ccccc5)ccc3N4c3c(-c4ccccc4)cc(-c4cccc5c6ccccc6n(-c6ccccc6)c45)cc3-c3ccccc3)cc2)cc1]
